(19) United States
(12) Patent Application Publication
(10) Pub. No.: US 2024/0292736 A1
(43) Pub. Date: Aug. 29, 2024

(54) ORGANIC ELECTROLUMINESCENT MATERIALS AND DEVICES

(71) Applicant: Universal Display Corporation, Ewing, NJ (US)

(72) Inventors: Alexey Borisovich DYATKIN, Ambler, PA (US); Pierre-Luc T. BOUDREAULT, Pennington, NJ (US); Jui-Yi TSAI, Newton, PA (US); Wei-Chun SHIH, Lawrenceville, NJ (US); Jerald FELDMAN, Cherry Hill, NJ (US)

(73) Assignee: Universal Display Corporation, Ewing, NJ (US)

(21) Appl. No.: 18/414,657

(22) Filed: Jan. 17, 2024

Related U.S. Application Data
(60) Provisional application No. 63/482,344, filed on Jan. 31, 2023.
(60) Provisional application No. 63/459,415, filed on Apr. 14, 2023.
(60) Provisional application No. 63/484,004, filed on Feb. 9, 2023.
(60) Provisional application No. 63/459,773, filed on Apr. 17, 2023.
(60) Provisional application No. 63/488,719, filed on Mar. 6, 2023.
(60) Provisional application No. 63/497,148, filed on Apr. 19, 2023.

(51) Int. Cl. H10K 85/40; C07F 15/00; C09K 11/06; H10K 50/11; H10K 85/30

(52) U.S. Cl. CPC H10K 85/40; C07F 15/0033; C09K 11/06; H10K 85/342; C09K 2211/1033; C09K 2211/1048; C09K 2211/185; H10K 50/11

(57) ABSTRACT

Provided is a compound having a formula of Ir(L_{A})ₚ(L_{B})_{q}(L_{C})ᵣ, wherein L_{A} has a structure of Formula IA:

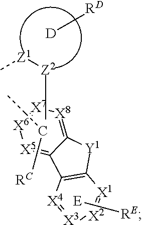

L_{B} has a structure of Formula IB;

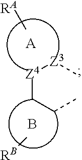

and L_{C} is a bidentate ligand. In the compound p+q+r=3; each of moieties A, B, and D is a monocyclic ring or a polycyclic fused ring system; Z¹ to Z⁴ and X¹ to X⁸ are each C or N; two adjacent R^{C} or R^{E} are joined to form Formula II,

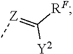

Y¹ and Y² are each linking groups; Z is CR^{Z} or N; each R, R′, R^{A}, R^{B}, R^{C}, R^{D}, R^{E}, R^{F}, and R^{Z} is hydrogen or a General Substituent defined herein; and at least one of R^{A} or R^{B} comprises a silyl or germyl group. Formulations, OLEDs, and consumer products containing such compounds are also provided.

### CROSS-REFERENCE TO RELATED APPLICATIONS

This application claims priority under 35 U.S.C. § 119(e) to U.S. Provisional Applications No. 63/497,148, filed on Apr. 19, 2023, No. 63/459,773, filed on Apr. 17, 2023, No. 63/459,415, filed on Apr. 14, 2023, No. 63/488,719, filed on Mar. 6, 2023, No. 63/484,004, filed on Feb. 9, 2023, and No. 63/482,344, filed on Jan. 31, 2023, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound having a formula of Ir(L_{A})ₚ(L_{B})_{q}(L_{C})ᵣ, wherein L_{A} has a structure of Formula IA,

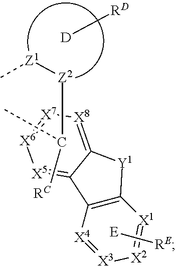

L_{B} has a structure of Formula IB;

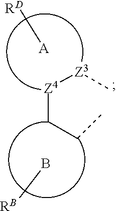

and L_{C} is a bidentate ligand; and wherein:
p is 1, 2, or 3; q is 0, 1, or 2; r is 0, 1, or 2; and p+q+r=3;
each of moiety A, moiety B, and moiety D is independently a monocyclic ring or a polycyclic fused ring system, wherein the monocyclic ring or each ring of the polycyclic fused ring system is independently a 5-membered or 6-membered carbocyclic or heterocyclic ring;
Z¹, Z², Z³, and Z⁴ are each independently C or N;
X¹, X², X³, X⁴, X⁵, X⁶, X⁷, and X⁸ are each independently C or N;
two adjacent R^{C} or two adjacent R^{E} are joined to form a structure of Formula II,

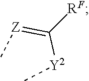

the dashed lines in Formula II represent bonds to two adjacent ones of X¹ to X⁸ that are C;
Y¹ and Y² are each independently selected from the group consisting of BR, NR, PR, P(O)R, O, S, Se, C═O, C═S, C═Se, C═NR′, C═CRR′ S═O, SO₂, CRR′, SiRR′, and GeRR′;
Z is CR^{Z} or N; R^{A}, R^{B}, R^{C}, R^{D}, and R^{E} each independently represents mono to the maximum allowable substitution, or no substitution;
each R, R′, R^{A}, R^{B}, R^{C}, R^{D}, R^{E}, R^{F}, and R^{Z} is independently a hydrogen or a moiety selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
at least one of R^{A} or R^{B} comprises a silyl or germyl group; and
any two substituents may be joined or fused to form a ring.

In another aspect, the present disclosure provides a formulation comprising a compound having a formula of Ir(L_{A})ₚ(L_{B})_{q}(L_{C})ᵣ as described herein.

In yet another aspect, the present disclosure provides an OLED having an organic layer comprising a compound having a formula of Ir(L_{A})ₚ(L_{B})_{q}(L_{C})ᵣ as described herein.

In yet another aspect, the present disclosure provides a consumer product comprising an OLED with an organic layer comprising a compound having a formula of Ir(L_{A})ₚ(L_{B})_{q}(L_{C})ᵣ as described herein.

### BRIEF DESCRIPTION OF THE DRAWINGS

FIG. 1 shows an organic light emitting device.

FIG. 2 shows an inverted organic light emitting device that does not have a separate electron transport layer.

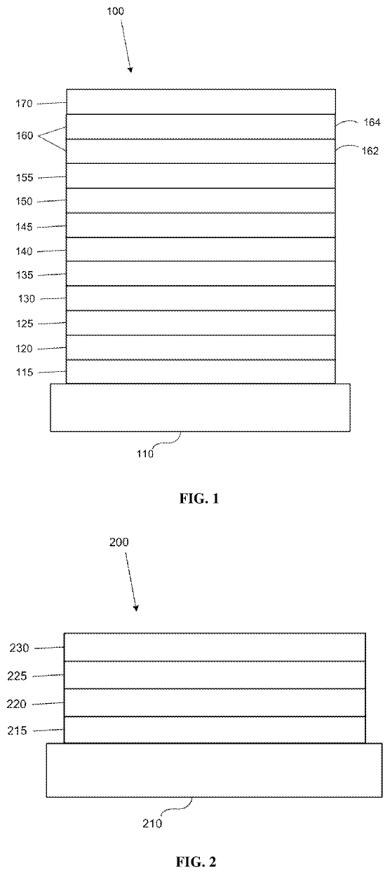

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level.

Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value.

Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “selenyl” refers to a —SeRₛ radical.

The term “sulfinyl” refers to a —S(O)—Rₛ radical.

The term “sulfonyl” refers to a —SO₂—Rₛ radical.

The term “phosphino” refers to a —P(Rₛ)₂ radical, wherein each Rₛ can be same or different.

The term “silyl” refers to a —Si(Rₛ)₃ radical, wherein each Rₛ can be same or different.

The term “germyl” refers to a —Ge(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N.

Preferred alkenyl, cycloalkenyl, or heteroalkenyl groups are those containing two to fifteen carbon atoms.

Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more General Substituents.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the Most Preferred General Substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[fh]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The Compounds of the Present Disclosure

The present disclosure is related to iridium (III) complexes with DBX-derived polyaromatic system ligands that have been identified as providing narrow green PHOLED emitters. The combination of such ligands with trialkyl silyl-substituted ancillary ligands should provide compounds with an improved combination of spectral and physicochemical properties.

In one aspect, the present disclosure provides a compound having a formula of Ir(L_{A})ₚ(L_{B})_{q}(L_{C})ᵣ, wherein L_{A} has a structure of Formula IA,

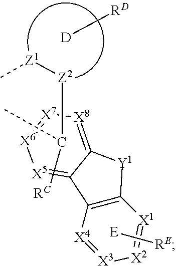

L_{B} has a structure of Formula IB,

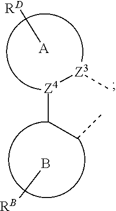

and L_{C} is a bidentate ligand; and wherein p is 1, 2, or 3; q is 0, 1, or 2; r is 0, 1, or 2; and p+q+r=3;
each of moiety A, moiety B, and moiety D is independently a monocyclic ring or a polycyclic fused ring system, wherein the monocyclic ring or each ring of the polycyclic fused ring system is independently a 5-membered or 6-membered carbocyclic or heterocyclic ring;
Z¹, Z², Z³, and Z⁴ are each independently C or N;
X¹, X², X³, X⁴, X⁵, X⁶, X⁷, and X⁸ are each independently C or N;
two adjacent R^{C} or two adjacent R^{E} are joined to form a structure of Formula II,

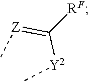

the dashed lines in Formula II represent bonds to two adjacent ones of X¹ to X⁸ that are C;
Y¹ and Y² are each independently selected from the group consisting of BR, NR, PR, P(O)R, O, S, Se, C═O, C═S, C═Se, C═NR′, C═CRR′ S═O, SO₂, CRR′, SiRR′, and GeRR′;
Z is CR^{Z} or N;
R^{A}, R^{B}, R^{C}, R^{D}, and R^{E} each independently represents mono to the maximum allowable substitution, or no substitution;
each R, R′, R^{A}, R^{B}, R^{C}, R^{D}, R^{E}, R^{F}, and R^{Z} is independently a hydrogen or a moiety selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
at least one of R^{A} or R^{B} comprises a silyl or germyl group; and
any two substituents may be joined or fused to form a ring.

In some embodiments, L_{C} can be selected from the group consisting of the structures defined for L_{A} or L_{B} in this disclosure. In some embodiments, L_{C} can be the same structure as L_{A} or L_{B}. In some embodiments, L_{C} can be a substituted or unsubstituted phenylpyridine or a substituted or unsubstituted acetylacetonate.

In some embodiments, the compound is heteroleptic. In some embodiments, the compound is homoleptic.

In some embodiments, the present disclosure provides a compound having a formula Ir(L_{B})ₘ(L_{A})ₙ, having a structure of Formula I,

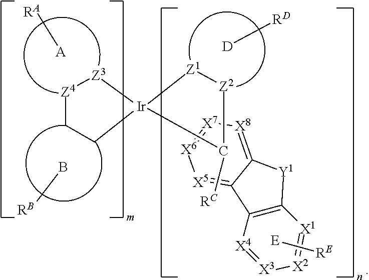

### In Formula I:

m and n are each independently 1 or 2;
m+n=3;
when m is 2, each L_{B} can be the same or different;
each of moiety A, moiety B, and moiety D is independently a monocyclic ring or a polycyclic fused ring system, wherein the monocyclic ring or each ring of the polycyclic fused ring system is independently a 5-membered or 6-membered carbocyclic or heterocyclic ring;
Z¹, Z², Z³, and Z⁴ are each independently C or N;
X¹, X², X³, X⁴, X⁵, X⁶, X⁷, and X⁸ are each independently C or N;
two adjacent R^{C} or two adjacent R^{E} are joined to form a structure of Formula II,

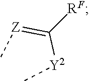

the dashed lines in Formula II represent bonds to two adjacent ones of X¹ to X⁸ that are C;
Y¹ and Y² are each independently selected from the group consisting of BR, NR, PR, P(O)R, O, S, Se, C═O, C═S, C═Se, C═NR′, C═CRR′ S═O, SO₂, CRR′, SiRR′, and GeRR′;
Z is CR^{Z} or N;
R^{A}, R^{B}, R^{C}, R^{D}, and R^{E} each independently represents mono to the maximum allowable substitutions, or no substitution;
each R, R′, R^{A}, R^{B}, R^{C}, R^{D}, R^{E}, R^{F}, and R^{Z} is independently a hydrogen or a moiety selected from the group consisting of the General Substituents defined herein;
at least one of R^{A} or R^{B} comprises a silyl or germyl group; and
any two substituents can be joined or fused to form a ring.

In some embodiments, L_{B} can be the same as L_{A}. In some embodiments, L_{B} can be different from L_{A}.

In some embodiments, the compound is homoleptic. In some embodiments, the compound is heteroleptic.

In some embodiments, m is 2 and each L_{B} is the same. In some embodiments, m is 2 and each L_{B} is the different. In some embodiments, each R, R′, R^{A}, R^{B}, R^{C}, R^{D}, R^{E}, R^{F}, and R^{Z} is independently a hydrogen or a moiety selected from the group consisting of the Preferred General Substituents defined herein. In some embodiments, each R, R′, R^{A}, R^{B}, R^{C}, R^{D}, R^{E}, R^{F}, and R^{Z} is independently a hydrogen or a moiety selected from the group consisting of the More Preferred General Substituents defined herein. In some embodiments, each R, R′, R^{A}, R^{B}, R^{C}, R^{D}, R^{E}, R^{F}, and R^{Z} is independently a hydrogen or a moiety selected from the group consisting of the Most Preferred General Substituents defined herein.

In some embodiments, each of moiety A, moiety B, and moiety D is independently selected from the group consisting of benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments, the aza variant includes one N on a benzo ring. In some embodiments, the aza variant includes one N on a benzo ring and the N is bonded to the metal M.

In some embodiments, moiety A is a monocyclic ring.

In some embodiments, moiety A is a polycyclic fused ring system.

In some embodiments, moiety A is pyridine, imidazole, imidazole derived carbene, benzimidazole derived carbene, or benzimidazole. In some embodiments, moiety A is pyridine.

In some embodiments, moiety B is a monocyclic ring.

In some embodiments, moiety B is a polycyclic fused ring system.

In some embodiments, moiety B is benzene or naphthalene. In some embodiments, moiety B is benzene.

In some embodiments, moiety D is a monocyclic ring.

In some embodiments, moiety D is a polycyclic fused ring system.

In some embodiments, moiety D is pyridine, imidazole, imidazole derived carbene, benzimidazole derived carbene, or benzimidazole. In some embodiments, moiety D is pyridine. In some embodiments, moiety D is imidazole. In some embodiments, moiety D is benzimidazole.

In some embodiments, each of moiety A, moiety B, and moiety C can independently be a polycyclic fused ring structure. In some embodiments, each of moiety A, moiety B, and moiety C can independently be a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, each of moiety A, moiety B, and moiety C can independently be selected from the group consisting of dibenzofuran, dibenzothiophene, dibenzoselenophene, and aza-variants thereof. In some such embodiments, each of moiety A, moiety B, and moiety C can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof.

In some such embodiments, the aza-variants contain exactly one N atom at the 6-position (ortho to the O, S, or Se) with a substituent at the 7-position (meta to the O, S, or Se).

In some embodiments, each of moiety A, moiety B, and moiety C can independently be a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, each of moiety A, moiety B, and moiety C independently be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, each of moiety A, moiety B, and moiety C can independently be an aza version of the polycyclic fused rings described above. In some such embodiments, each of moiety A, moiety B, and moiety C can independently contain exactly one aza N atom. In some such embodiments, each of moiety A, moiety B, and moiety C can contain exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho position of the aza N atom is substituted.

In some embodiments, m=1 and n=2. In some embodiments, m=2 and n=1.

In some embodiments, Z³ is N and Z⁴ is C.

In some embodiments, Z³ is C and Z⁴ is N. In some such embodiments, Z³ is a carbene C.

In some embodiments, Z¹ is N and Z² is C.

In some embodiments, Z¹ is C and Z² is N. In some such embodiments, Z¹ is a carbene C.

In some embodiments, ring C is coordinated to Ir by a C atom.

In some embodiments, each of X¹ to X⁴ is C. In some embodiments, at least one of X¹ to X⁴ is N. In some embodiments, exactly one of X¹ to X⁴ is N.

In some embodiments, each of X⁵ to X⁸ is C. In some embodiments, at least one of X⁵ to X⁸ is N. In some embodiments, exactly one of X⁵ to X⁸ is N.

In some embodiments, Z is CR^{Z}. In some embodiments, Z is N.

In some embodiments, Y¹ is selected from the group consisting of O, S, and Se. In some embodiments, Y¹ is O. In some embodiments, Y¹ is S. In some embodiments, Y¹ is Se.

In some embodiments, Y¹ is selected from the group consisting of BR, NR, and PR.

In some embodiments, Y¹ is selected from the group consisting of P(O)R, C═O, C═S, C═Se, C═NR′, C═CR′R″, S═O, and SO₂.

In some embodiments, Y¹ is selected from the group consisting of CRR′, SiRR′, and GeRR′.

In some embodiments, Z is CR^{Z}, and R^{Z} is joined or fused to R^{F} to form a fused ring or fused ring system.

In some such embodiments, the fused ring or fused ring system is selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene. In some such embodiments, the fused ring or fused ring system is benzene.

In some embodiments, Formula II is bonded to X¹ and X². In some embodiments, Formula II is bonded to X² and X³. In some embodiments, Formula II is bonded to X³ and X⁴. In some embodiments where Formula II is bonded to one of X¹ to X⁴, Y² is on the same side of the moiety comprising rings C and E as Y¹. In some embodiments where Formula II is bonded to one of X¹ to X⁴, Z is on the same side of the moiety comprising rings C and E as Y¹.

In some embodiments, Formula II is attached to X⁵ and X⁶. In some such embodiments, Z is bonded to X⁵, while Z is bonded to X⁶ in other embodiments.

In some embodiments, Formula II is attached to X⁷ and X⁸. In some such embodiments, Z is bonded to X⁷, while Z is bonded to X⁸ in others.

In some embodiments, at least one R^{A} is not hydrogen or deuterium. In some embodiments, at least two R^{A} are not hydrogen or deuterium.

In some embodiments, at least one R^{A} comprises a moiety selected from the group consisting of alkyl, silyl, partially or fully deuterated variants thereof, partially or fully fluorinated variants thereof, and combinations thereof.

In some embodiments, at least two R^{A} each independently comprise a moiety selected from the group consisting of alkyl, silyl, partially or fully deuterated variants thereof, partially or fully fluorinated variants thereof, and combinations thereof.

In some embodiments, each R^{A} is hydrogen.

In some embodiments, at least one R^{A} comprises silyl or germyl. In some embodiments, at least one R^{A} comprises silyl. In some embodiments, at least one R^{A} comprises tetramethylsilyl or tetrephenylsilyl.

In some embodiments, at least one R^{A} comprises germyl. In some embodiments, at least one R^{A} comprises tetramethylgermyl or tetraphenylgermyl.

In some embodiments, at least one R^{B} is not hydrogen or deuterium. In some embodiments, at least two R^{B} are not hydrogen or deuterium.

In some embodiments, at least one R^{B} comprises a moiety selected from the group consisting of fluorine, CN, aryl, alkyl, partially or fully deuterated variants thereof, partially or fully fluorinated variants thereof, and combinations thereof. In some embodiments, at least two R^{B} independently comprise a moiety selected from the group consisting of fluorine, CN, aryl, alkyl, partially or fully deuterated variants thereof, partially or fully fluorinated variants thereof, and combinations thereof.

In some embodiments, at least one R^{B} comprises silyl or germyl. In some embodiments, at least one R^{B} comprises silyl. In some embodiments, at least one R^{B} comprises tetramethylsilyl or tetrephenylsilyl.

In some embodiments, at least one R^{B} comprises germyl. In some embodiments, at least one R^{B} comprises tetramethylgermyl or tetraphenylgermyl.

In some embodiments, each R^{B} is hydrogen.

In some embodiments, at least one R^{C} is not hydrogen or deuterium.

In some embodiments, at least one R^{C} comprises a moiety selected from the group consisting of alkyl, silyl, partially or fully deuterated variants thereof, partially or fully fluorinated variants thereof, and combinations thereof.

In some embodiments, each R^{C} is hydrogen.

In some embodiments, at least one R^{D} is not hydrogen or deuterium. In some embodiments, at least two R^{D} are not hydrogen or deuterium.

In some embodiments, at least one R^{D} comprises a moiety selected from the group consisting of aryl, alkyl, cycloalkyl, silyl, heteroaryl, partially or fully deuterated variants thereof, and combinations thereof. In some embodiments, at least two R^{D} independently comprise a moiety selected from the group consisting of aryl, alkyl, cycloalkyl, silyl, heteroaryl, partially or fully deuterated variants thereof, and combinations thereof.

In some embodiments, at least one R^{D} is aryl or heteroaryl.

In some embodiments, at least one R^{D} is aryl or heteroaryl, where at least one position adjacent to the bond with moiety D is not hydrogen or deuterium. In some embodiments, at least one R^{D} is aryl or heteroaryl, where at least one position adjacent to the bond with moiety D is selected from the group consisting of alkyl, cycloalkyl, aryl, heteroaryl, partially or fully deuterated, and combinations thereof. In some such embodiments, the aryl or heteroaryl is a benzene.

In some embodiments, at least one R^{D} is aryl or heteroaryl, where each position adjacent to the bond with moiety D is not hydrogen or deuterium. In some embodiments, at least one R^{D} is aryl or heteroaryl, where each position adjacent to the bond with moiety D is independently selected form the group consisting of alkyl, cycloalkyl, aryl, heteroaryl, partially or fully deuterated, and combinations thereof. In some such embodiments, the aryl or heteroaryl is a benzene.

In some embodiments, each R^{D} is hydrogen.

In some embodiments, R^{F} is not bonded or fused to another moiety and R^{F} is not hydrogen or deuterium. In some such embodiments, R^{F} is selected from the group consisting of aryl, alkyl, cycloalkyl, silyl, heteroaryl, partially or fully deuterated variants thereof, partially or fully fluorinated variants thereof, and combinations thereof.

In some embodiments, the compound having a formula of Ir(L_{A})ₚ(L_{B})_{q}(L_{C})ᵣ, comprises an electron-withdrawing group. In some embodiments, the electron-withdrawing group has a Hammett constant larger than 0.

In some embodiments, the electron-withdrawing group has a Hammett constant equal or larger than 0.1, 0.2, 0.3, 0.4, 0.5, 0.6, 0.7, 0.8, 0.9, 1.0, or 1.1.

In some embodiments, the compound comprises an electron-withdrawn group selected from the group consisting of the structures of the following EWG1 LIST: F, CF₃, CN, COCH₃, CHO, COCF₃, COOMe, COOCF₃, NO₂, SF₃, SiF₃, PF₄, SFs, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

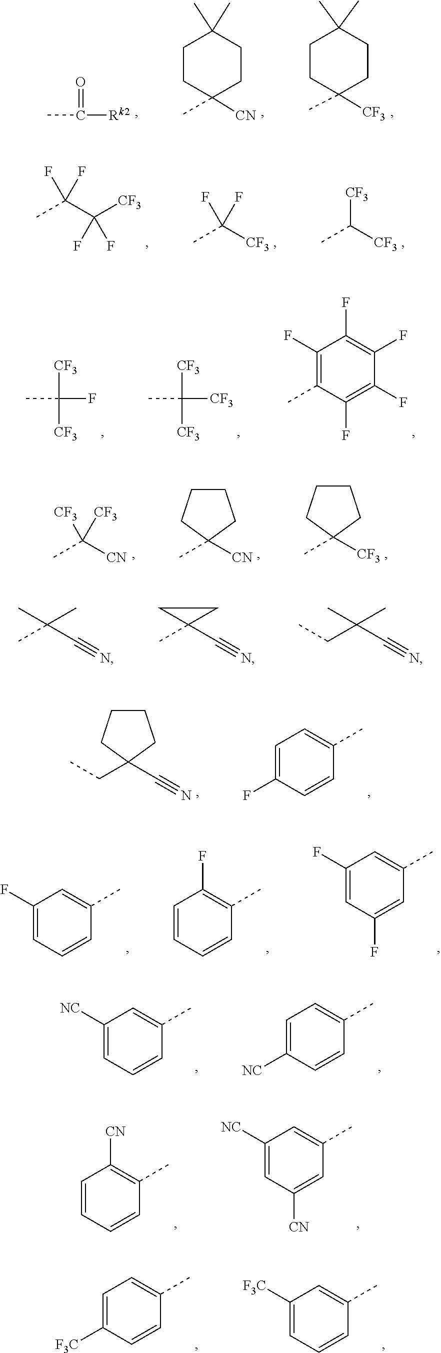

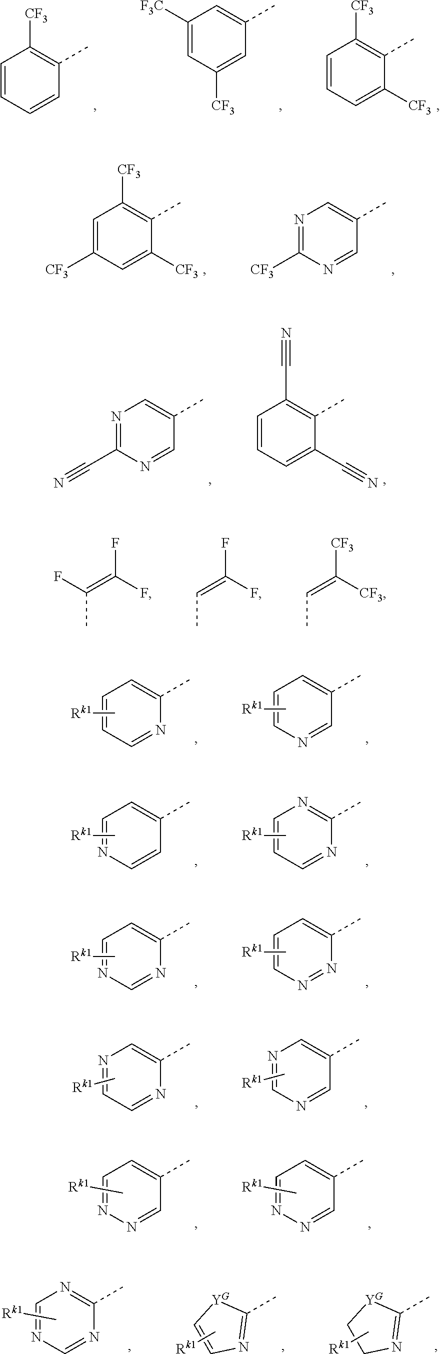

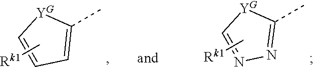

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of the General Substituents defined herein.

In some embodiments, the compound comprises an electron-withdrawing group selected from the group consisting of the structures of the following EWG2 List:

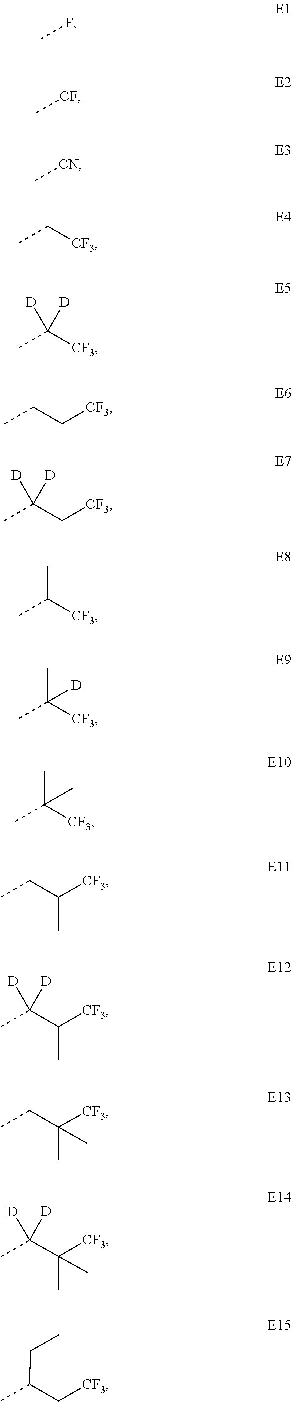

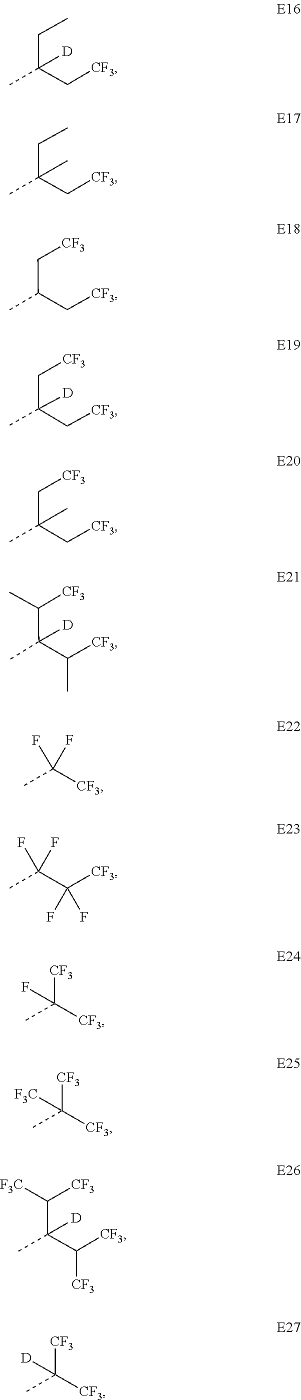

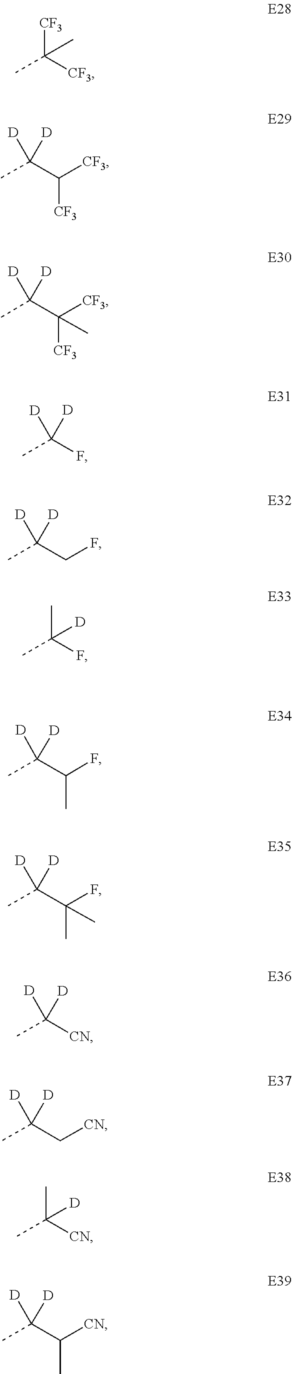

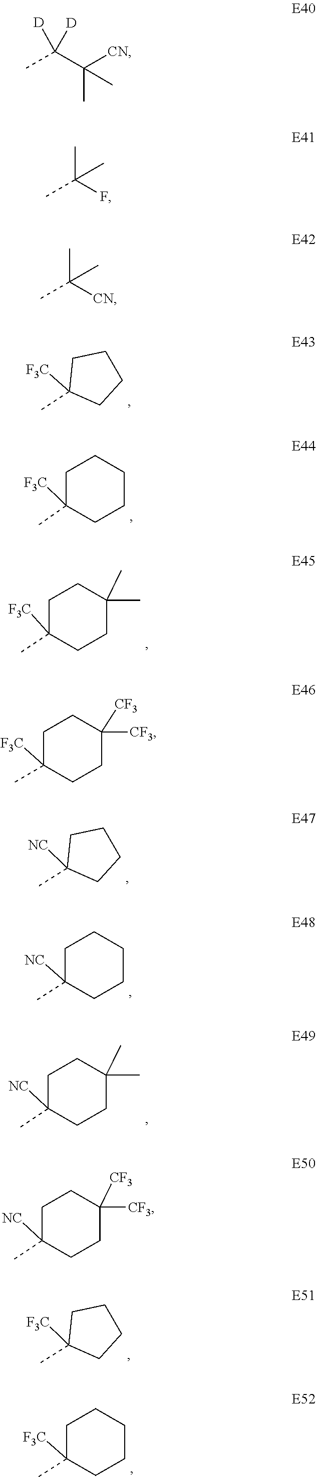

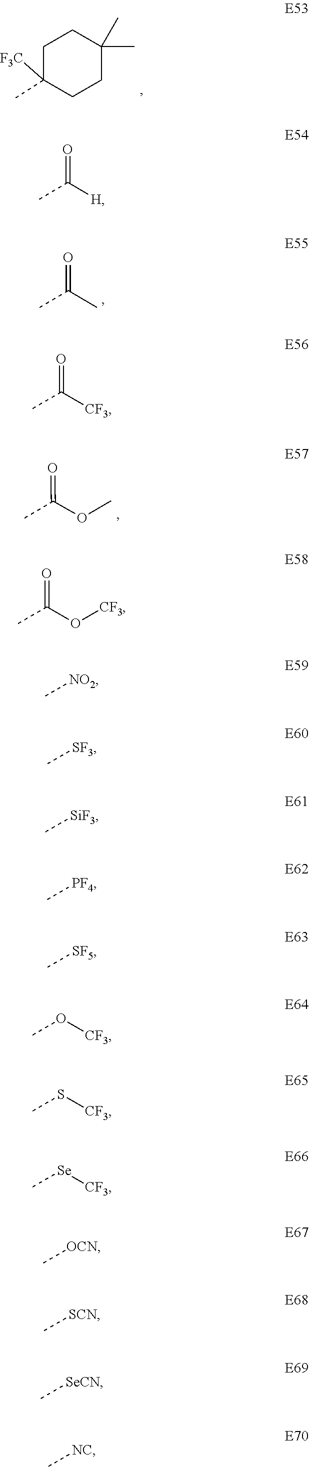

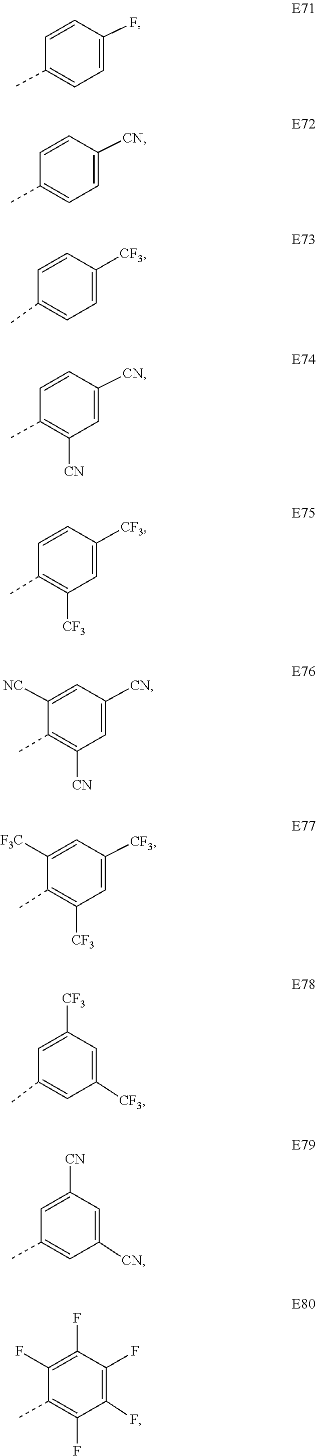

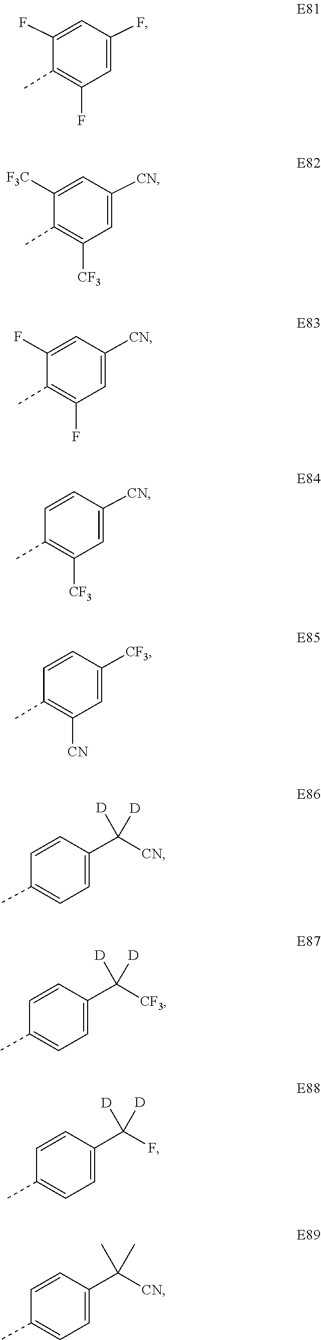

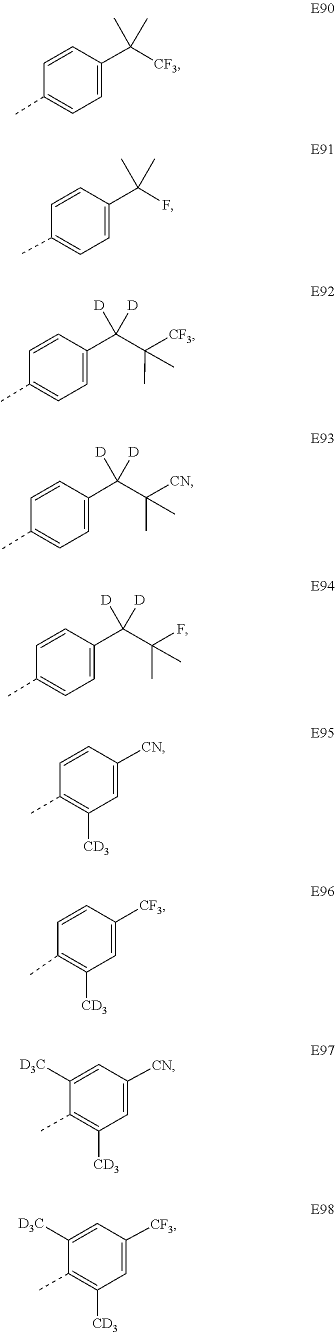

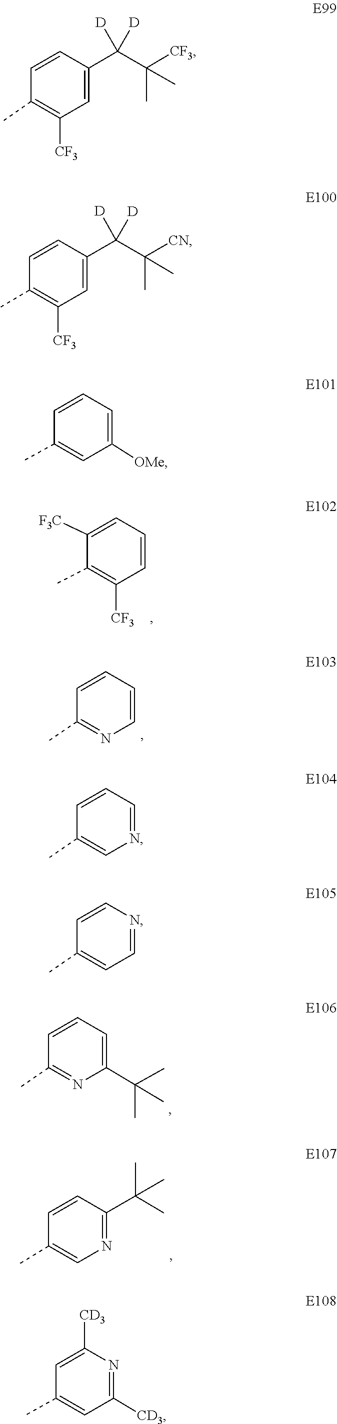

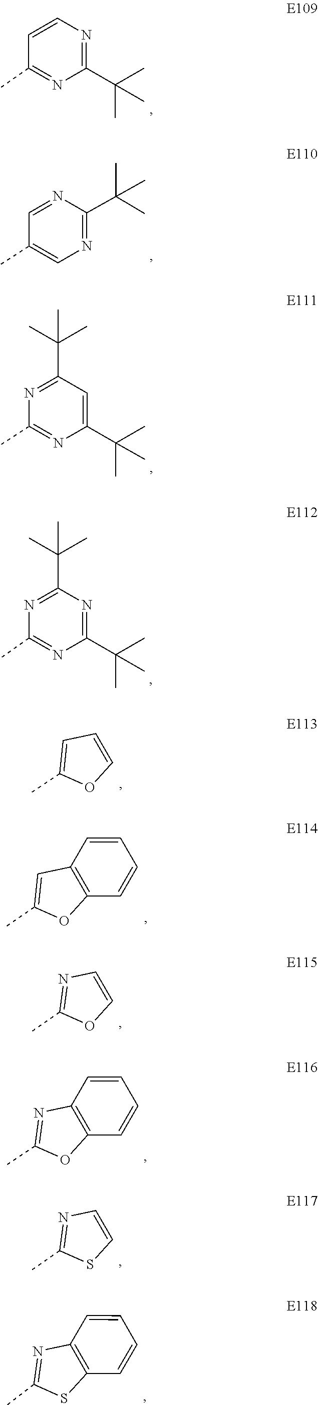

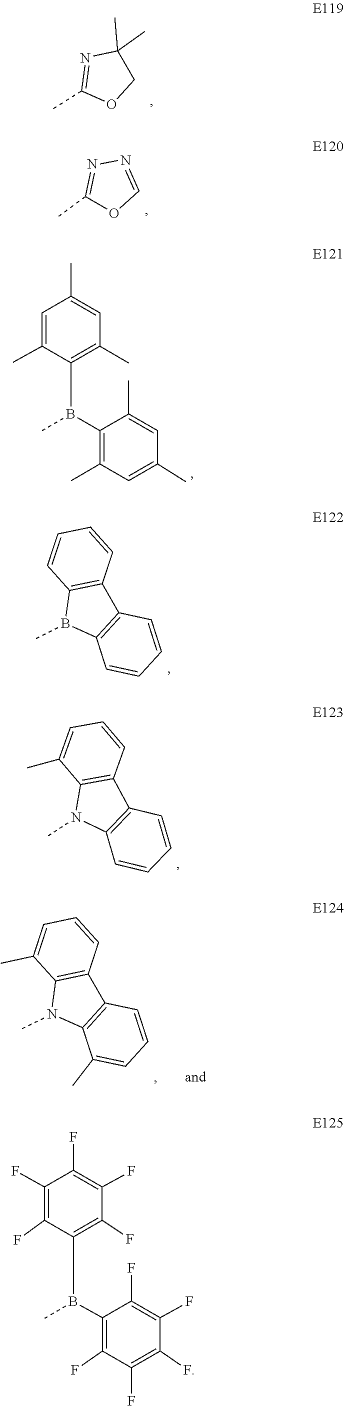

In some embodiments, the compound comprises an electron-withdrawing group selected from the group consisting of the structures of the following EWG3 LIST:

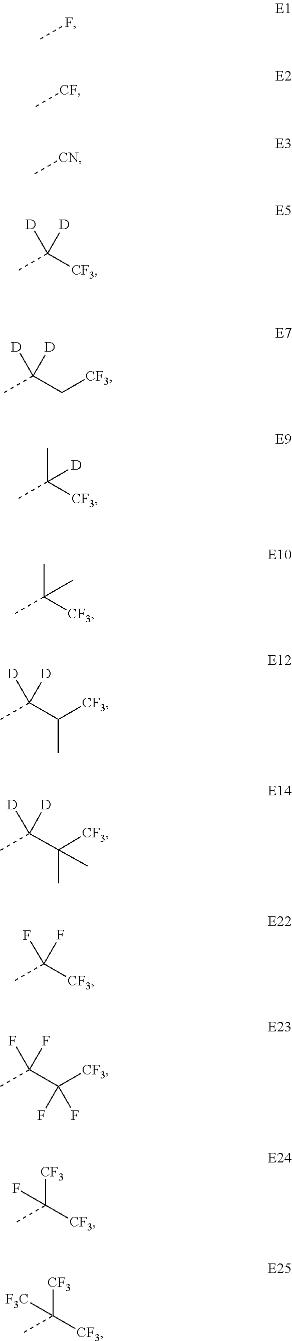

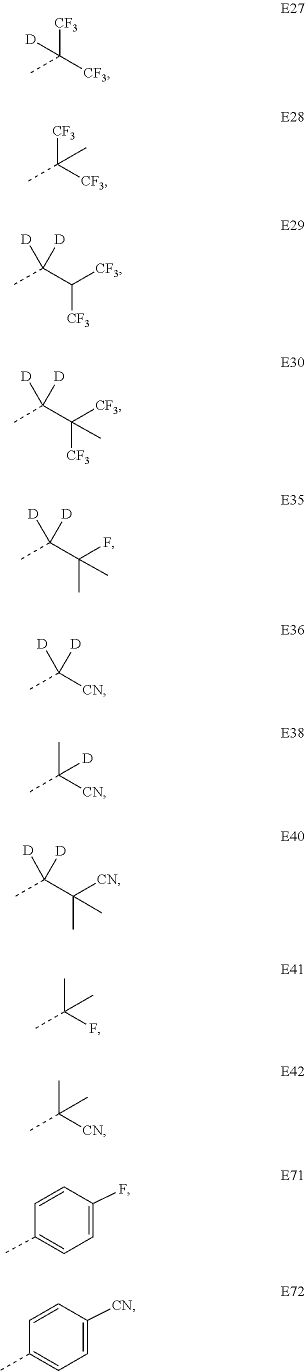

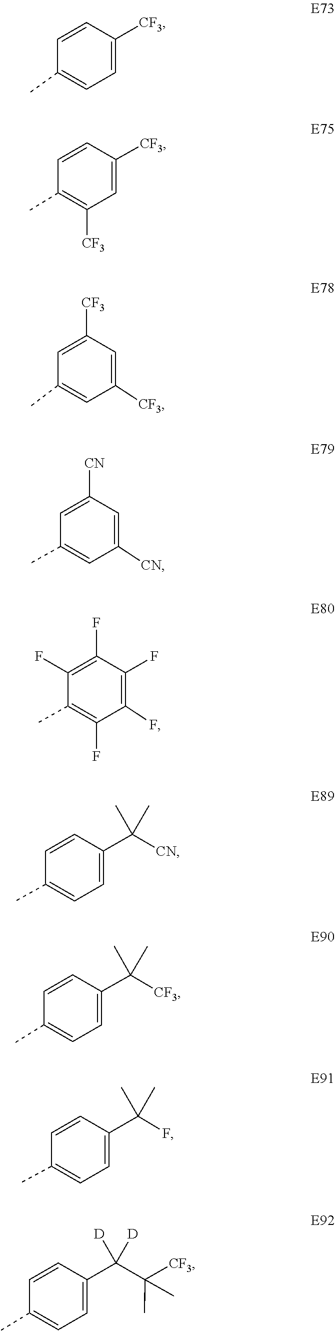

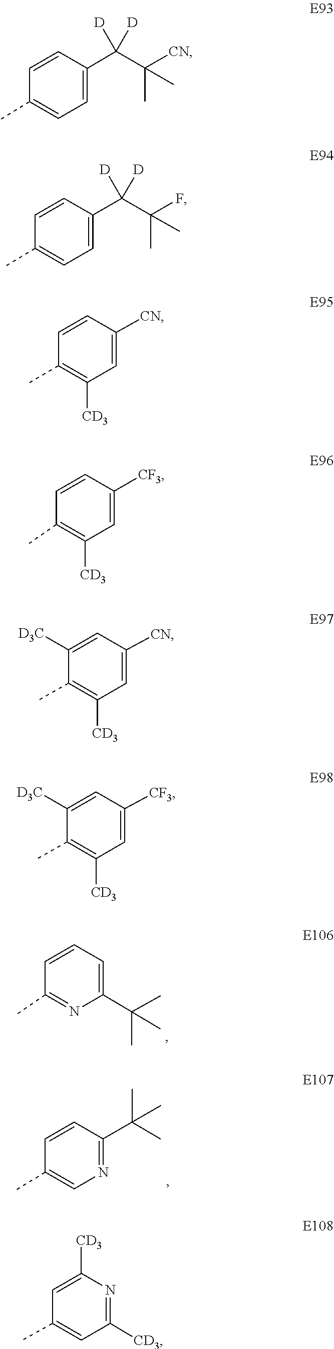

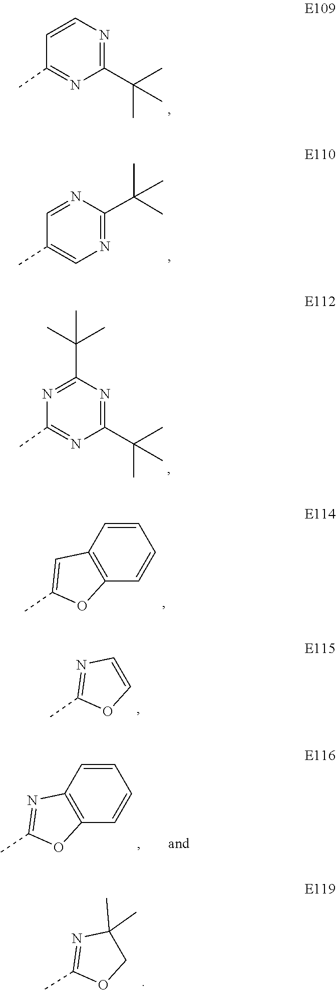

In some embodiments, the compound comprises an electron-withdrawing group selected from the group consisting of the structures of the following EWG4 LIST:

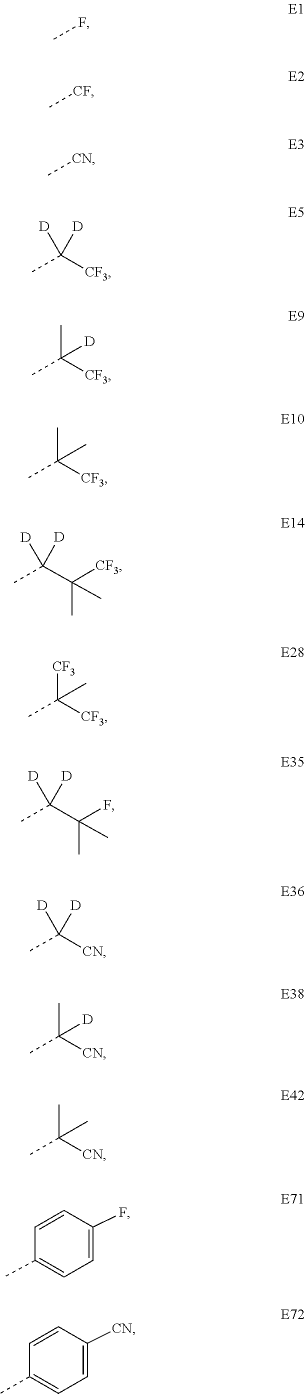

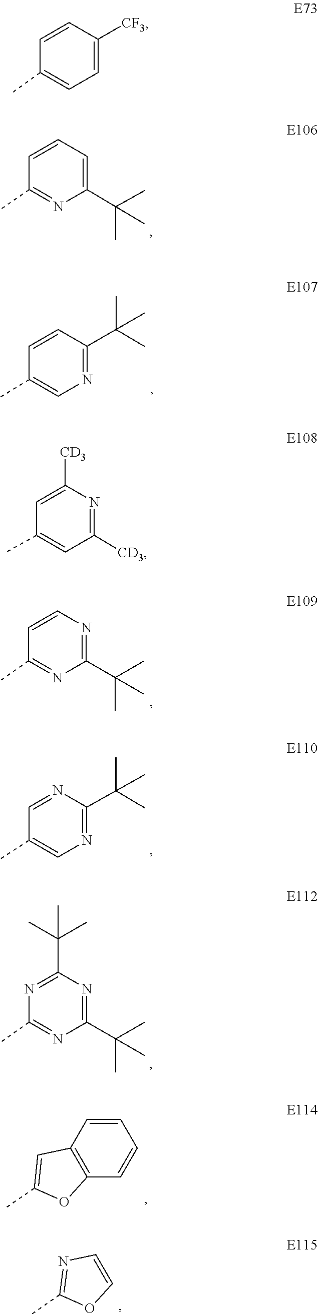

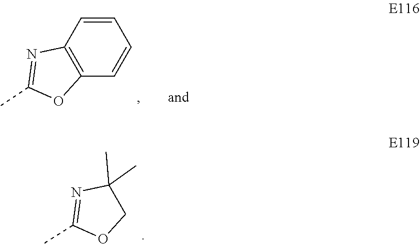

In some embodiments, the compound comprises an electron-withdrawing group that is a n-electron deficient electron-withdrawing group. In some embodiments, the π-electron deficient electron-withdrawing group is selected from the group consisting of the structures of the following Pi-EWG LIST: CN, COCH₃, CHO, COCF₃, COOMe, COOCF₃, NO₂, SF₃, SiF₃, PF₄, SFs, OCF₃, SCF₃, SeCF₃, SOCF₃, SeOCF₃, SO₂F, SO₂CF₃, SeO₂CF₃, OSeO₂CF₃, OCN, SCN, SeCN, NC, +N(R¹²)₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

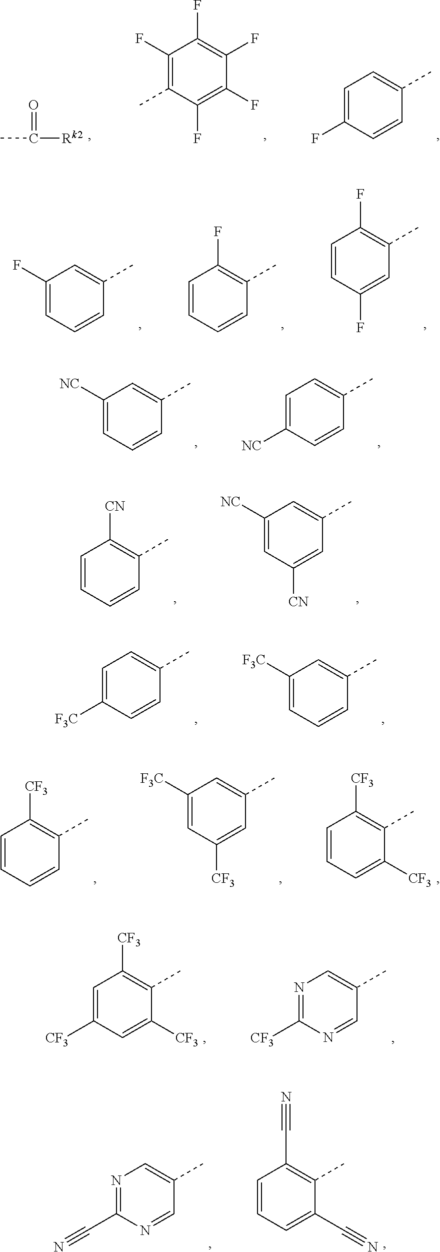

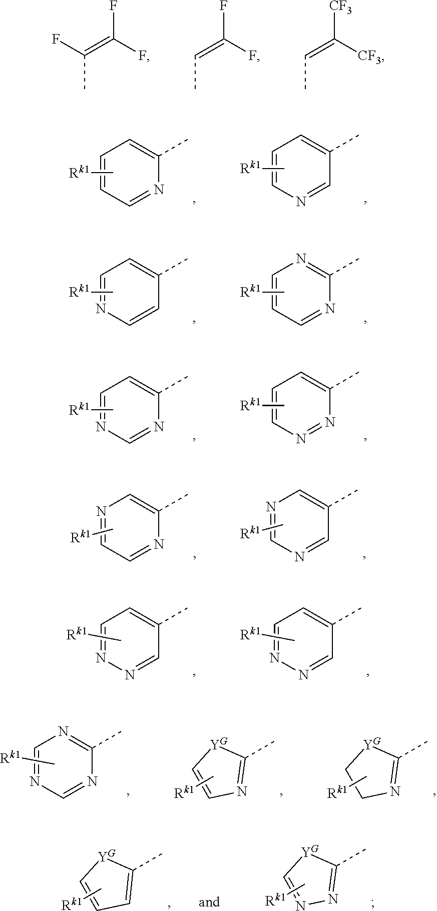

wherein the variables are the same as previously defined.

In some embodiments, the ligand L_{A} is selected from the group consisting of the structures of the following LIST 1:

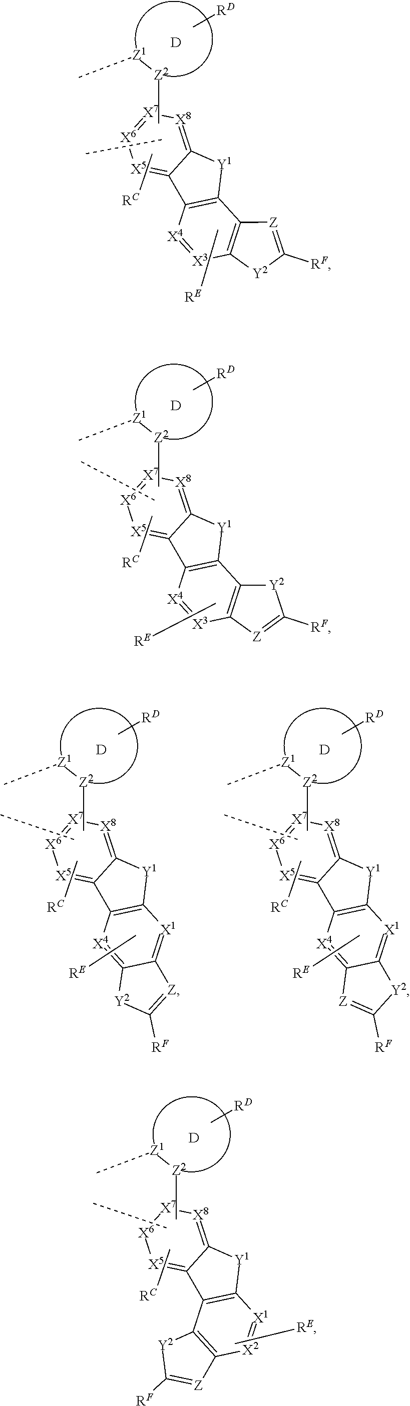

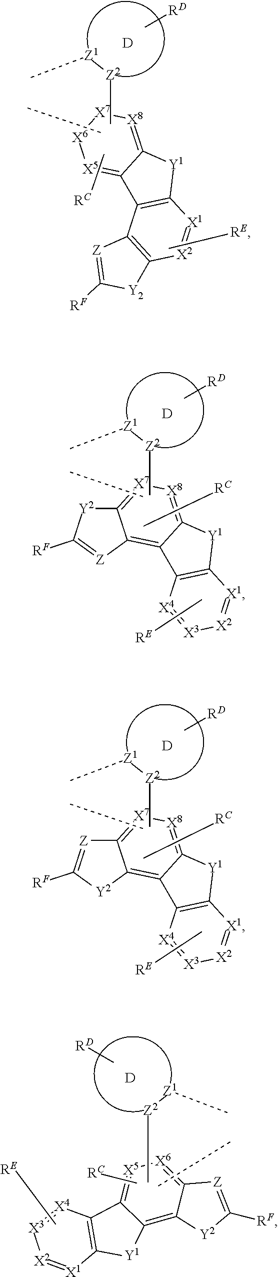

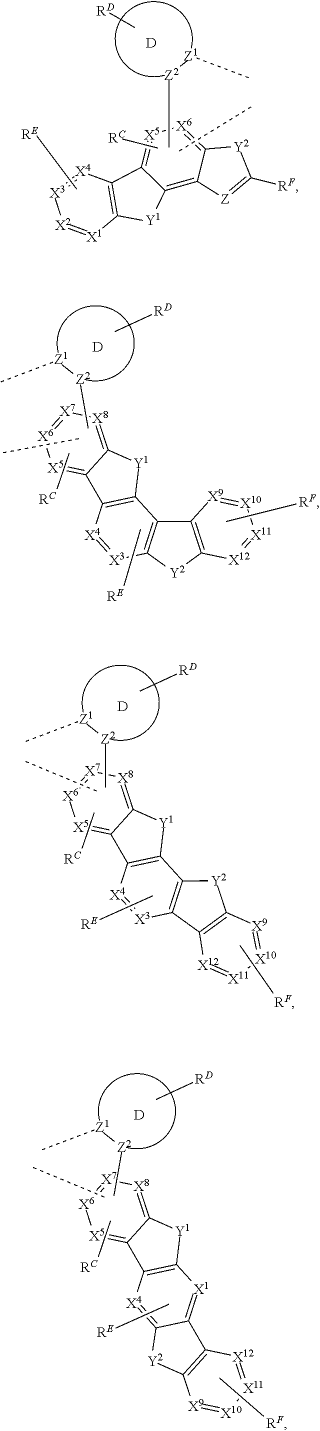

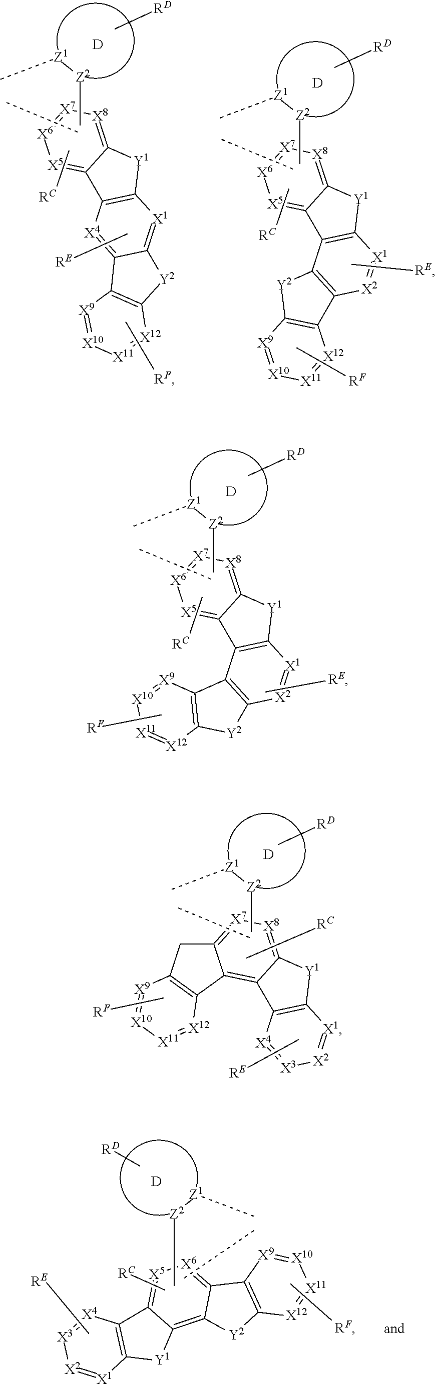

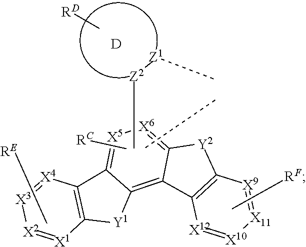

and
wherein each of X⁹ to X¹² is independently C or N.

In some embodiments, the ligand L_{A} is selected from the group consisting of the structures of the following

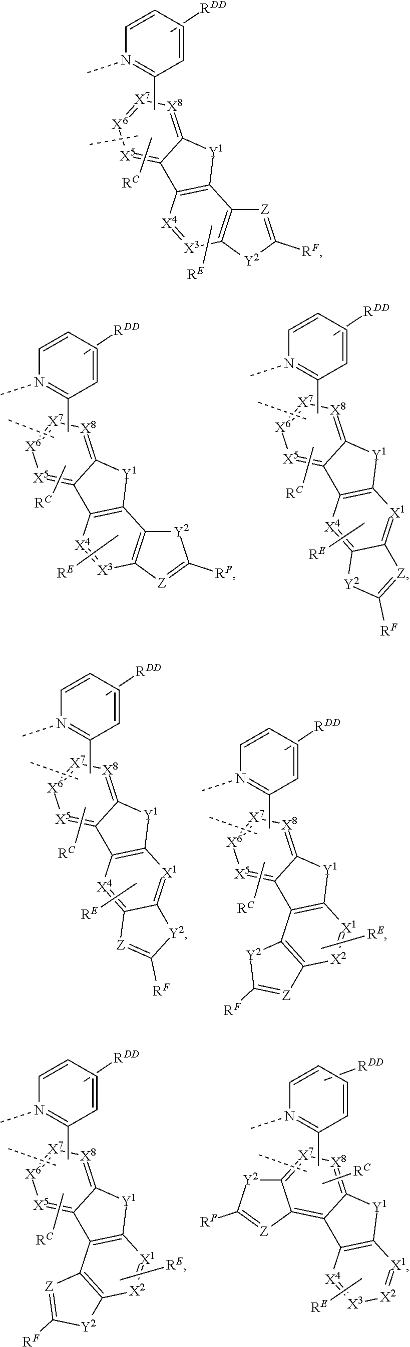

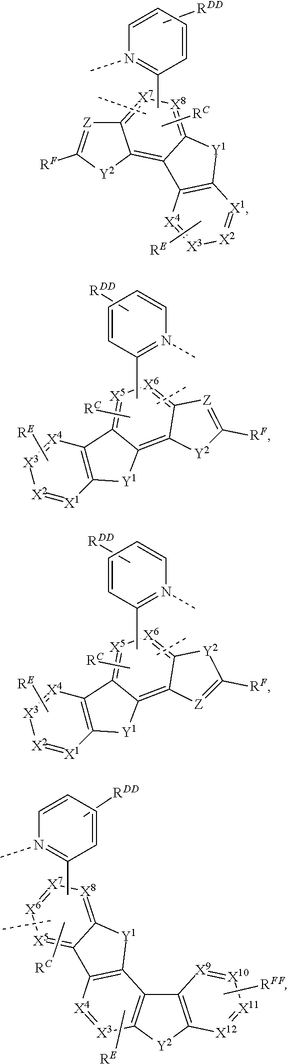

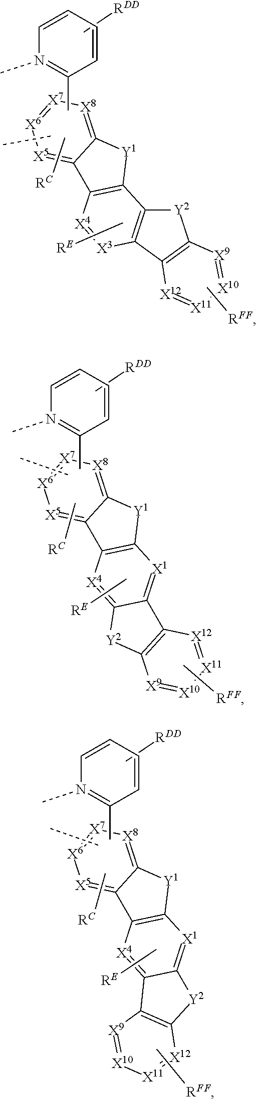

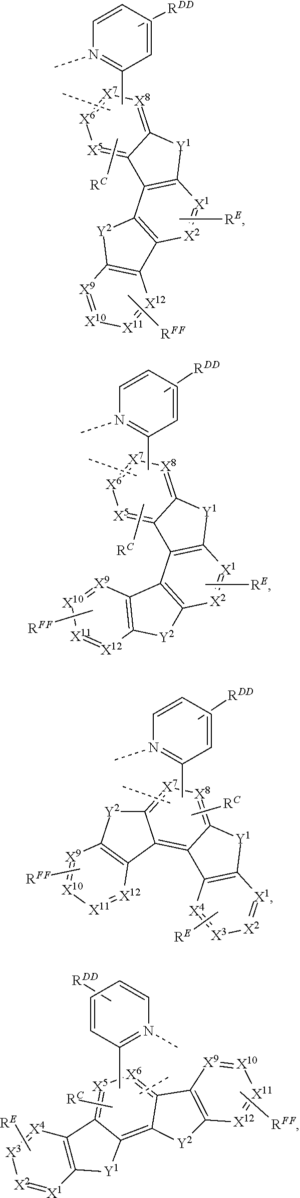

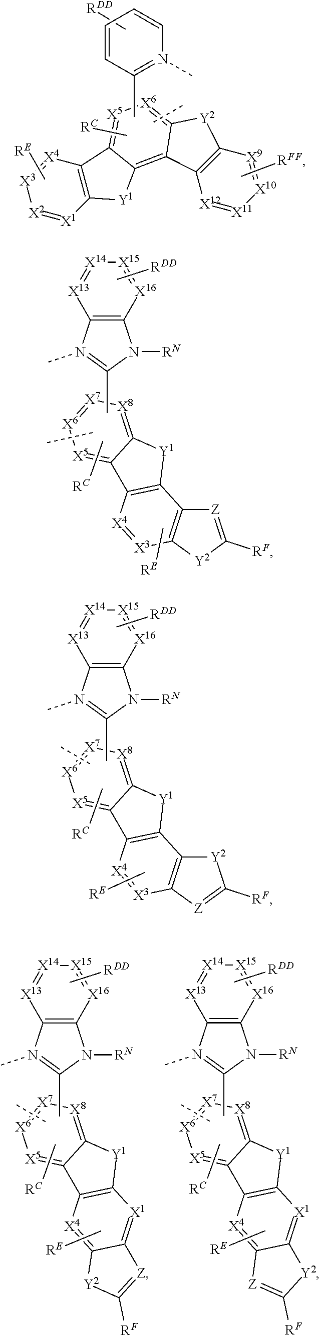

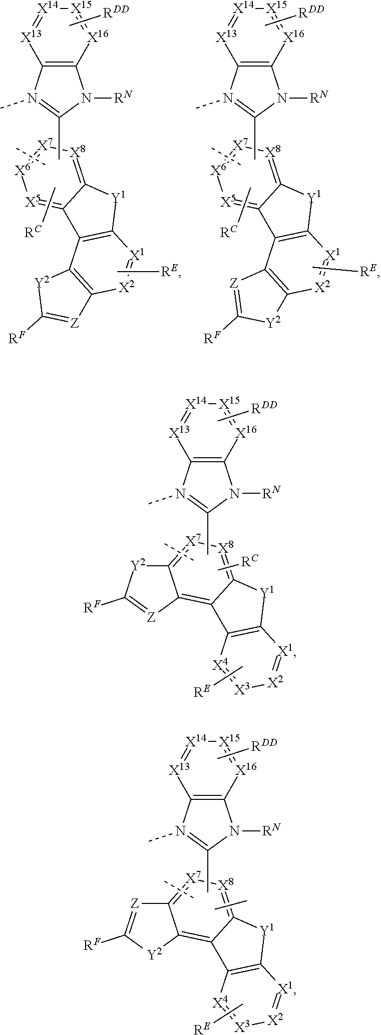

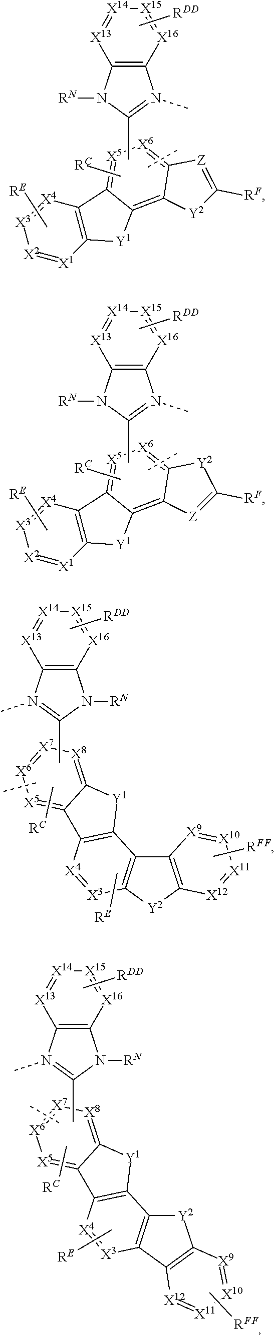

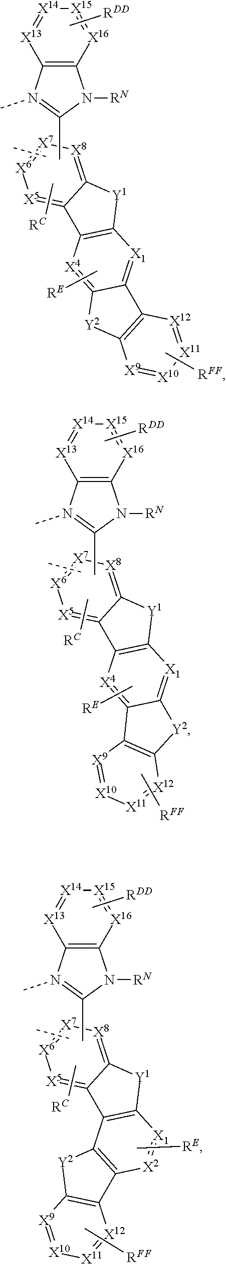

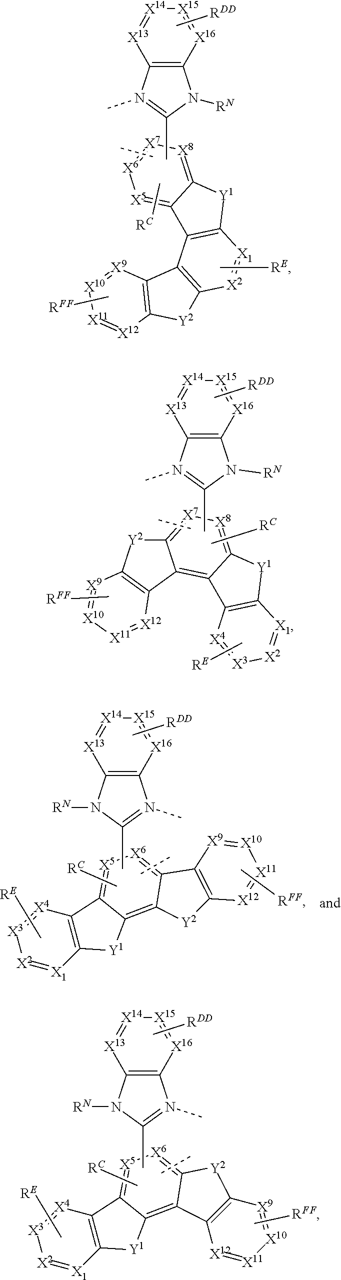

wherein:
each of X⁹ to X¹⁶ is independently C or N;
each of R^{DD} and R^{FF} independently represents mono to the maximum allowable substitutions, or no substitutions;
each R^{N}, R^{DD}, and R^{FF} is independently a hydrogen or a moiety selected from the group consisting of the General Substituents defined herein; and
any two substituents can be joined or fused to form a ring.

In some embodiments of the compound that are defined by ligands having one or more of the following substituents, R^{A}, R^{B}, R^{C}, R^{D}, R^{E}, R^{F}, R^{DD}, R^{FF}, and R^{N}, at least one of such substituents in a given compound is or comprises an electron-withdrawing group from the EWG1 LIST as defined herein. In some embodiments of the compound that are defined by ligands having one or more of the following substituents, R^{A}, R^{B}, R^{C}, R^{D}, R^{E}, R^{F}, R^{DD}R^{FF}, and R^{N}, at least one of such substituents in a given compound is or comprises an electron-withdrawing group from the EWG2 LIST as defined herein. In some embodiments of the compound that are defined by ligands having one or more of the following substituents, R^{A}, R^{B}, R^{C}, R^{D}, R^{E}, R^{F}, R^{DD}, R^{FF}, and R^{N}, at least one of such substituents in a given compound is or comprises an electron-withdrawing group from the EWG3 LIST as defined herein. In some embodiments of the compound that are defined by ligands having one or more of the following substituents, R^{A}, R^{B}, R^{C}, R^{D}, R^{E}, R^{F}, R^{DD}, R^{FF}, and R^{N}, at least one of such substituents in a given compound is or comprises an electron-withdrawing group from the EWG4 LIST as defined herein. In some embodiments of the compound that are defined by ligands having one or more of the following substituents, R^{A}, R^{B}, R^{C}, R^{D}, R^{E}, R^{F}, R^{DD}, R^{FF}, and R^{N}, at least one of such substituents in a given compound is or comprises an electron-withdrawing group from the Pi-EWG LIST as defined herein.

In some embodiments where the compound has R^{A}, at least one R^{A} is or comprises an electron-withdrawing group from the EWG1 LIST as defined herein. In some embodiments where the compound has R^{A}, at least one R^{A} is or comprises an electron-withdrawing group from the EWG2 LIST as defined herein. In some embodiments where the compound has R^{A}, at least one R^{A} is or comprises an electron-withdrawing group from the EWG3 LIST as defined herein. In some embodiments where the compound has R^{A}, at least one R^{A} is or comprises an electron-withdrawing group from the EWG4 LIST as defined herein. In some embodiments where the compound has R^{A}, at least one R^{A} is or comprises an electron-withdrawing group from the Pi-EWG LIST as defined herein.

In some embodiments where the compound has R^{B}, at least one R^{B} is or comprises an electron-withdrawing group from the EWG1 LIST as defined herein. In some embodiments where the compound has R^{B}, at least one R^{B} is or comprises an electron-withdrawing group from the EWG2 LIST as defined herein. In some embodiments where the compound has R^{B}, at least one R^{B} is or comprises an electron-withdrawing group from the EWG3 LIST as defined herein. In some embodiments where the compound has R^{B}, at least one R^{B} is or comprises an electron-withdrawing group from the EWG4 LIST as defined herein. In some embodiments where the compound has R^{B}, at least one R^{B} is or comprises an electron-withdrawing group from the Pi-EWG LIST as defined herein.

In some embodiments where the compound has R^{C}, at least one R^{C} is or comprises an electron-withdrawing group from the EWG1 LIST as defined herein. In some embodiments where the compound has R^{C}, at least one R^{C} is or comprises an electron-withdrawing group from the EWG2 LIST as defined herein. In some embodiments where the compound has R^{C}, at least one R^{C} is or comprises an electron-withdrawing group from the EWG3 LIST as defined herein. In some embodiments where the compound has R^{C}, at least one R^{C} is or comprises an electron-withdrawing group from the EWG4 LIST as defined herein. In some embodiments where the compound has R^{C}, at least one R^{C} is or comprises an electron-withdrawing group from the Pi-EWG LIST as defined herein.

In some embodiments where the compound has R^{D}, at least one R^{D} is or comprises an electron-withdrawing group from the EWG1 LIST as defined herein. In some embodiments where the compound has R^{D}, at least one R^{D} is or comprises an electron-withdrawing group from the EWG2 LIST as defined herein. In some embodiments where the compound has R^{D}, at least one R^{D} is or comprises an electron-withdrawing group from the EWG3 LIST as defined herein. In some embodiments where the compound has R^{D}, at least one R^{D} is or comprises an electron-withdrawing group from the EWG4 LIST as defined herein. In some embodiments where the compound has R^{D}, at least one R^{D} is or comprises an electron-withdrawing group from the Pi-EWG LIST as defined herein.

In some embodiments where the compound has R^{E}, at least one R^{E} is or comprises an electron-withdrawing group from the EWG1 LIST as defined herein. In some embodiments where the compound has R^{E}, at least one R^{E} is or comprises an electron-withdrawing group from the EWG2 LIST as defined herein. In some embodiments where the compound has R^{E}, at least one R^{E} is or comprises an electron-withdrawing group from the EWG3 LIST as defined herein. In some embodiments where the compound has R^{E}, at least one R^{E} is or comprises an electron-withdrawing group from the EWG4 LIST as defined herein. In some embodiments where the compound has R^{E}, at least one R^{E} is or comprises an electron-withdrawing group from the Pi-EWG LIST as defined herein.

In some embodiments where the compound has R^{F}, at least one R^{F} is or comprises an electron-withdrawing group from the EWG1 LIST as defined herein. In some embodiments where the compound has R^{F}, at least one R^{F} is or comprises an electron-withdrawing group from the EWG2 LIST as defined herein. In some embodiments where the compound has R^{F}, at least one R^{F} is or comprises an electron-withdrawing group from the EWG3 LIST as defined herein. In some embodiments where the compound has R^{F}, at least one R^{F} is or comprises an electron-withdrawing group from the EWG4 LIST as defined herein. In some embodiments where the compound has R^{F}, at least one R^{F} is or comprises an electron-withdrawing group from the Pi-EWG LIST as defined herein.

In some embodiments where the compound has R^{DD}, at least one R^{DD} is or comprises an electron-withdrawing group from the EWG1 LIST as defined herein. In some embodiments where the compound has R^{DD}, at least one R^{DD} is or comprises an electron-withdrawing group from the EWG2 LIST as defined herein. In some embodiments where the compound has R^{DD}, at least one R^{DD} is or comprises an electron-withdrawing group from the EWG3 LIST as defined herein. In some embodiments where the compound has R^{DD}, at least one R^{DD} is or comprises an electron-withdrawing group from the EWG4 LIST as defined herein. In some embodiments where the compound has R^{DD}, at least one R^{DD} is or comprises an electron-withdrawing group from the Pi-EWG LIST as defined herein.

In some embodiments where the compound has R′, at least one R^{FF} is or comprises an electron-withdrawing group from the EWG1 LIST as defined herein. In some embodiments where the compound has R^{FF}, at least one R^{FF} is or comprises an electron-withdrawing group from the EWG2 LIST as defined herein. In some embodiments where the compound has R′, at least one R^{FF} is or comprises an electron-withdrawing group from the EWG3 LIST as defined herein. In some embodiments where the compound has R^{FF}, at least one R^{FF} is or comprises an electron-withdrawing group from the EWG4 LIST as defined herein. In some embodiments where the compound has R^{FF}, at least one R^{FF} is or comprises an electron-withdrawing group from the Pi-EWG LIST as defined herein.

In some embodiments where the compound has R^{N}, R^{N} is or comprises an electron-withdrawing group from the EWG1 LIST as defined herein. In some embodiments where the compound has R^{N}, R^{N} is or comprises an electron-withdrawing group from the EWG2 LIST as defined herein. In some embodiments where the compound has R^{N}, R^{N} is or comprises an electron-withdrawing group from the EWG3 LIST as defined herein. In some embodiments where the compound has R^{N}, R^{N} is or comprises an electron-withdrawing group from the EWG4 LIST as defined herein. In some embodiments where the compound has R^{N}, R^{N} is or comprises an electron-withdrawing group from the Pi-EWG LIST as defined herein.

In some embodiments, the ligand L_{A} is selected from L_{Aw}(Rk)(Rl)(Rm)(Rn)(T)(Z), and w is an integer from 1 to 60, Z and each of Rk, Rl, Rm, and Rn is independently selected from the group consisting of R1 to R115, T is selected from the group consisting of T1 to T10; Z is selected from the group consisting of Z1 to Z6; wherein each of L_{A1}(R1)(R1)(R1)(R30)(T1)(Z1) to L_{A60}(R115)(R115)(R115)(R115)(T10)(Z6) is defined in the following LIST 3a:

| Compound | Structure |
|---|---|
| L_{A1}(Rk)(Rl)(Rm)(Rn)(T) (Z), wherein L_{A1}(R1)(R1)(R1)(R30) (T1)(Z1) to L_{A1}(R115)(R115)(R115) (R115)(T10)(Z6), have the structure | 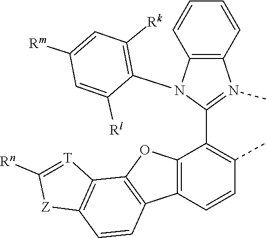 |
| L_{A2}(Rk)(Rl)(Rm)(Rn)(T) (Z), wherein L_{A2}(R1)(R1)(R1)(R30) (T1)(Z1) to L_{A2}(R115)(R115)(R115) (R115)(T10)(Z6), have the structure | 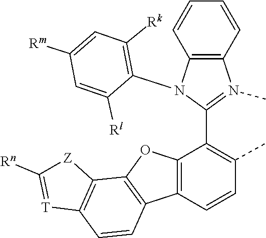 |
| L_{A3}(Rk)(Rl)(Rm)(Rn)(T) (Z), wherein L_{A3}(R1)(R1)(R1)(R30) (T1)(Z1) to L_{A3}(R115)(R115)(R115) (R115)(T10)(Z6), have the structure | 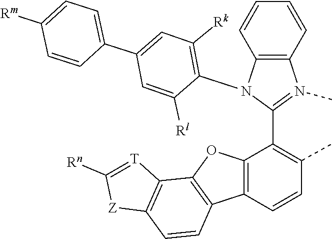 |
| L_{A4}(Rk)(Rl)(Rm)(Rn) (T)(Z), wherein L_{A4}(R1)(R1)(R1)(R30) (T1)(Z1) to L_{A4}(R115)(R115)(R115) (R115)(T10)(Z6), have the structure | 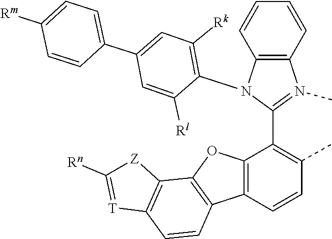 |
| L_{A5}(Rk)(Rl)(Rm)(Rn) (T)(Z), wherein L_{A5}(R1)(R1)(R1)(R30) (T1)(Z1) to L_{A5}(R115)(R115)(R115) (R115)(T10)(Z6), have the structure | 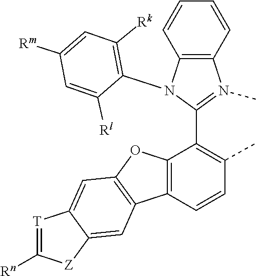 |
| L_{A6}(Rk)(Rl)(Rm)(Rn) (T)(Z), wherein L_{A6}(R1)(R1)(R1)(R30) (T1)(Z1) to L_{A6}(R115)(R115)(R115) (R115)(T10)(Z6), have the structure | 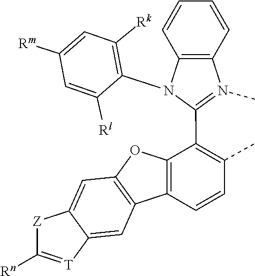 |
| L_{A7}(Rk)(Rl)(Rm)(Rn) (T)(Z), wherein L_{A7}(R1)(R1)(R1)(R30) (T1)(Z1) to L_{A7}(R115)(R115)(R115) (R115)(T10)(Z6), have the structure | 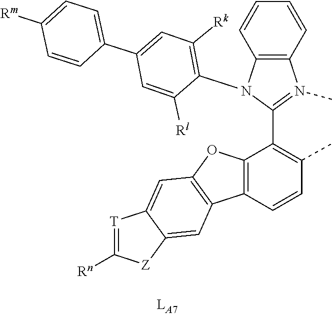 |
| L_{A8}(Rk)(Rl)(Rm)(Rn) (T)(Z), wherein L_{A8}(R1)(R1)(R1)(R30) (T1)(Z1) to L_{A8}(R115)(R115)(R115) (R115)(T10)(Z6), have the structure | 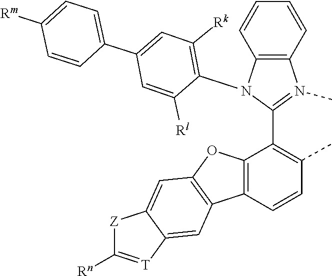 |
| L_{A9}(Rk)(Rl)(Rm)(Rn)(T) (Z), wherein L_{A9}(R1)(R1)(R1)(R30) (T1)(Z1) to L_{A9}(R115)(R115)(R115) (R115)(T10)(Z6), have the structure | 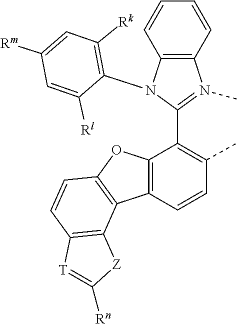 |
| L_{A10}(Rk)(Rl)(Rm)(Rn) (T)(Z), wherein L_{A10}(R1)(R1)(R1)(R30) (T1)(Z1) to L_{A10}(R115)(R115)(R115) (R115)(T10)(Z6), have the structure | 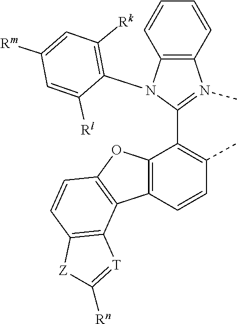 |
| L_{A11}(Rk)(Rl)(Rm)(Rn) (T)(Z), wherein L_{A11}(R1)(R1)(R1)(R30) (T1)(Z1) to L_{A11}(R115)(R115)(R115) (R115)(T10)(Z6), have the structure | 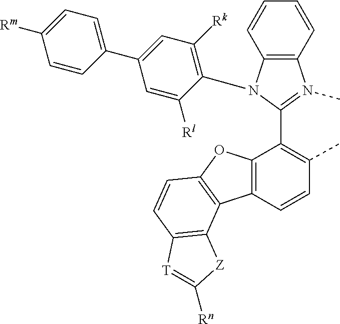 |
| L_{A12}(Rk)(Rl)(Rm)(Rn)(T) (Z), wherein L_{A12}(R1)(R1)(R1)(R30) (T1)(Z1) to L_{A12}(R115)(R115)(R115) (R115)(T10)(Z6), have the structure | 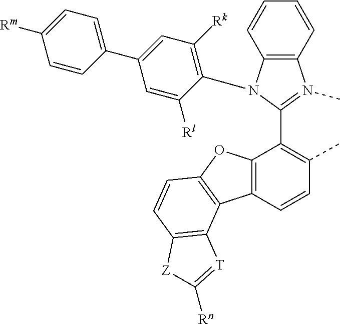 |
| L_{A13}(Rk)(Rl)(Rm)(Rn)(T) (Z), wherein L_{A13}(R1)(R1)(R1)(R30) (T1)(Z1) to L_{A13}(R115)(R115)(R115) (R115)(T10)(Z6), have the structure | 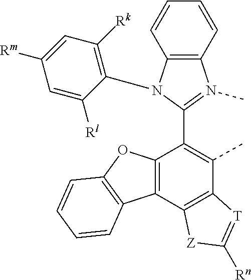 |
| L_{A14}(Rk)(Rl)(Rm)(Rn) (T)(Z), wherein L_{A14}(R1)(R1)(R1)(R30) (T1)(Z1) to L_{A14}(R115)(R115)(R115) (R115)(T10)(Z6), have the structure | 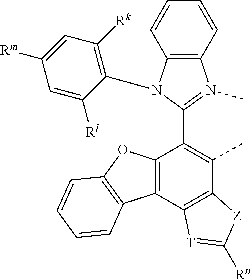 |
| L_{A15}(Rk)(Rl)(Rm)(Rn) (T)(Z), wherein L_{A15}(R1)(R1)(R1)(R30) (T1)(Z1) to L_{A15}(R115)(R115)(R115) (R115)(T10)(Z6), have the structure | 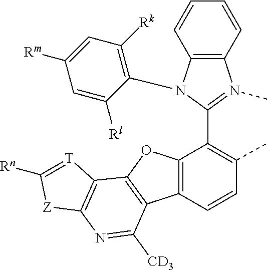 |
| L_{A16}(Rk)(Rl)(Rm)(Rn) (T)(Z), wherein L_{A16}(R1)(R1)(R1)(R30) (T1)(Z1) to L_{A16}(R115)(R115)(R115) (R115)(T10)(Z6), have the structure | 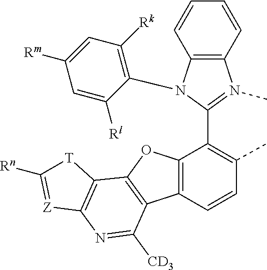 |
| L_{A17}(Rk)(Rl)(Rm)(Rn) (T)(Z), wherein L_{A17}(R1)(R1)(R1)(R30) (T1)(Z1) to L_{A17}(R115)(R115)(R115) (R115)(T10)(Z6), have the structure | 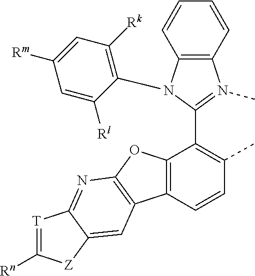 |
| L_{A18}(Rk)(Rl)(Rm)(Rn) (T)(Z), wherein L_{A18}(R1)(R1)(R1)(R30) (T1)(Z1) to L_{A18}(R115)(R115)(R115) (R115)(T10)(Z6), have the structure | 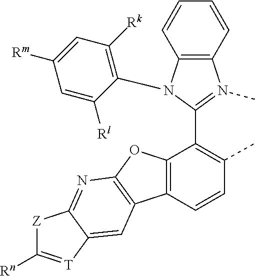 |
| L_{A19}(Rk)(Rl)(Rm)(Rn) (T)(Z), wherein L_{A19}(R1)(R1)(R1)(R30) (T1)(Z1) to L_{A19}(R115)(R115)(R115) (R115)(T10)(Z6), have the structure | 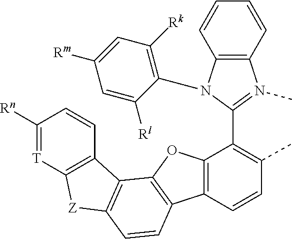 |
| L_{A20}(Rk)(Rl)(Rm)(Rn) (T)(Z), wherein L_{A20}(R1)(R1)(R1)(R30) (T1)(Z1) to L_{A20}(R115)(R115)(R115) (R115)(T10)(Z6), have the structure | 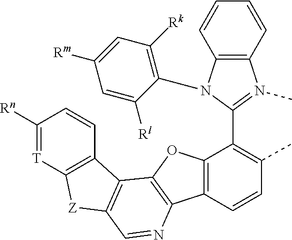 |
| L_{A21}(Rk)(Rl)(Rm)(Rn) (T)(Z), wherein L_{A21}(R1)(R1)(R1)(R30) (T1)(Z1) to L_{A21}(R115)(R115)(R115) (R115)(T10)(Z6), have the structure | 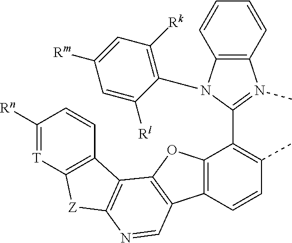 |
| L_{A22}(Rk)(Rl)(Rm)(Rn) (T)(Z), wherein L_{A22}(R1)(R1)(R1)(R30) (T1)(Z1) to L_{A22}(R115)(R115)(R115) (R115)(T10)(Z6), have the structure | 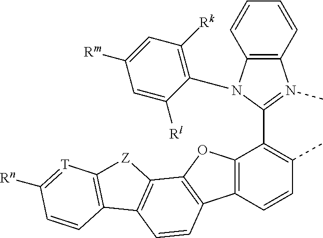 |
| L_{A23}(Rk)(Rl)(Rm)(Rn) (T)(Z), wherein L_{A23}(R1)(R1)(R1)(R30) (T1)(Z1) to L_{A23}(R115)(R115)(R115) (R115)(T10)(Z6), have the structure | 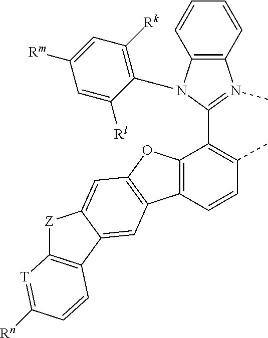 |
| L_{A24}(Rk)(Rl)(Rm)(Rn) (T)(Z), wherein L_{A24}(R1)(R1)(R1)(R30) (T1)(Z1) to L_{A24}(R115)(R115)(R115) (R115)(T10)(Z6), have the structure | 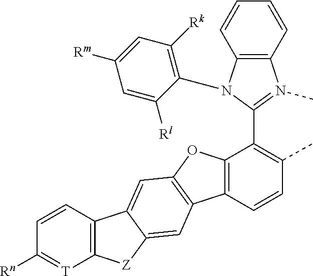 |
| L_{A25}(Rk)(Rl)(Rm)(Rn) (T)(Z), wherein L_{A25}(R1)(R1)(R1)(R30) (T1)(Z1) to L_{A25}(R115)(R115)(R115) (R115)(T10)(Z6), have the structure | 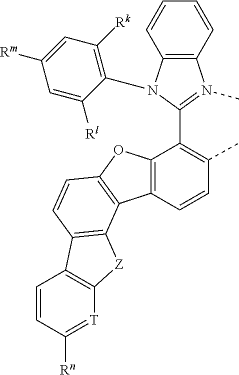 |
| L_{A26}(Rk)(Rl)(Rm)(Rn) (T)(Z), wherein L_{A26}(R1)(R1)(R1)(R30) (T1)(Z1) to L_{A26}(R115)(R115)(R115) (R115)(T10)(Z6), have the structure | 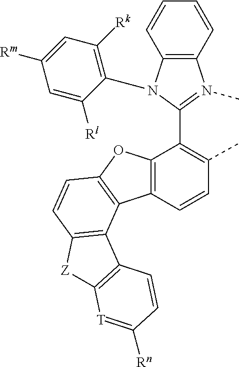 |
| L_{A27}(Rk)(Rl)(Rm)(Rn) (T)(Z), wherein L_{A27}(R1)(R1)(R1)(R30) (T1)(Z1) to L_{A27}(R115)(R115)(R115) (R115)(T10)(Z6), have the structure | 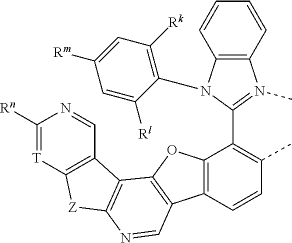 |
| L_{A28}(Rk)(Rl)(Rm)(Rn) (T)(Z), wherein L_{A28}(R1)(R1)(R1)(R30) (T1)(Z1) to L_{A28}(R115)(R115)(R115) (R115)(T10)(Z6), have the structure | 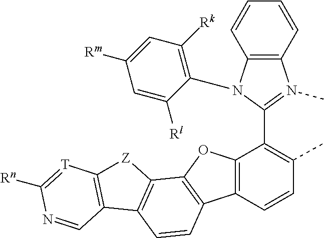 |
| L_{A29}(Rk)(Rl)(Rm)(Rn) (T)(Z), wherein L_{A29}(R1)(R1)(R1)(R30) (T1)(Z1) to L_{A29}(R115)(R115)(R115) (R115)(T10)(Z6), have the structure | 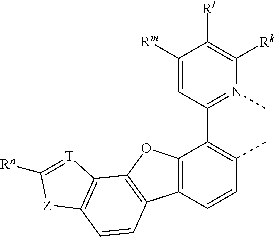 |
| L_{A30}(Rk)(Rl)(Rm)(Rn) (T)(Z), wherein L_{A30}(R1)(R1)(R1)(R30) (T1)(Z1) to L_{A30}(R115)(R115)(R115) (R115)(T10)(Z6), have the structure | 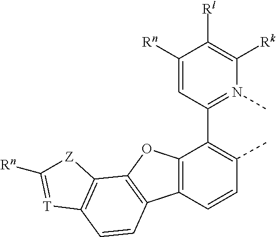 |
| L_{A31}(Rk)(Rl)(Rm)(Rn)(T) (Z), wherein L_{A31}(R1)(R1)(R1)(R30) (T1)(Z1) to L_{A31}(R115)(R115)(R115) (R115)(T10)(Z6), have the structure | 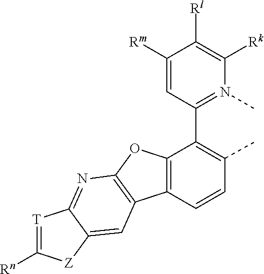 |
| L_{A32}(Rk)(Rl)(Rm)(Rn) (T)(Z), wherein L_{A32}(R1)(R1)(R1)(R30) (T1)(Z1) to L_{A32}(R115)(R115)(R115) (R115)(T10)(Z6), have the structure | 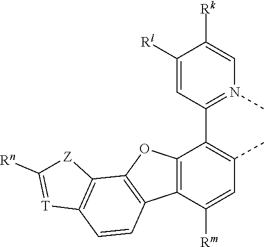 |
| L_{A33}(Rk)(Rl)(Rm)(Rn) (T)(Z), wherein L_{A33}(R1)(R1)(R1)(R30) (T1)(Z1) to L_{A33}(R115)(R115)(R115) (R115)(T10)(Z6), have the structure | 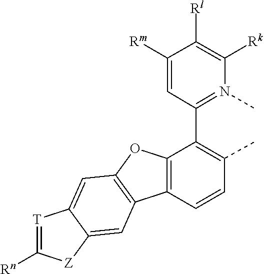 |
| L_{A34}(Rk)(Rl)(Rm)(Rn) (T)(Z), wherein L_{A34}(R1)(R1)(R1)(R30) (T1)(Z1) to L_{A34}(R115)(R115)(R115) (R115)(T10)(Z6), have the structure | 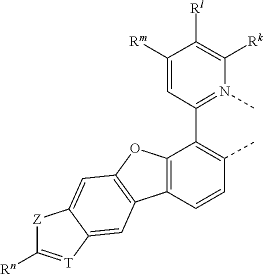 |
| L_{A35}(Rk)(Rl)(Rm)(Rn) (T)(Z), wherein L_{A35}(R1)(R1)(R1)(R30) (T1)(Z1) to L_{A35}(R115)(R115)(R115) (R115)(T10)(Z6), have the structure | 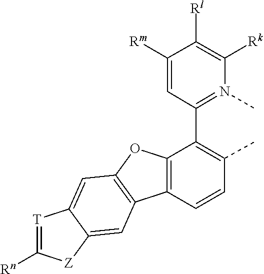 |
| L_{A36}(Rk)(Rl)(Rm)(Rn)(T) (Z), wherein L_{A36}(R1)(R1)(R1)(R30) (T1)(Z1) to L_{A36}(R115)(R115)(R115) (R115)(T10)(Z6), have the structure | 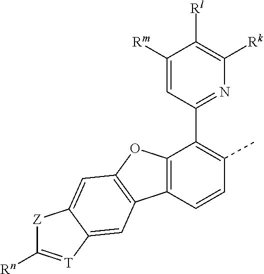 |
| L_{A37}(Rk)(Rl)(Rm)(Rn) (T)(Z), wherein L_{A37}(R1)(R1)(R1)(R30) (T1)(Z1) to L_{A37}(R115)(R115)(R115) (R115)(T10)(Z6), have the structure | 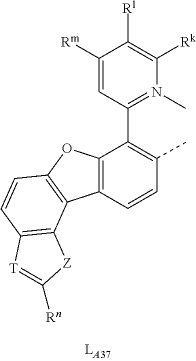 |
| L_{A38}(Rk)(Rl)(Rm)(Rn) (T)(Z), wherein L_{A38}(R1)(R1)(R1)(R30) (T1)(Z1) to L_{A38}(R115)(R115)(R115) (R115)(T10)(Z6), have the structure | 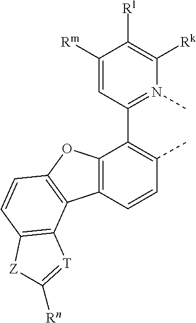 |
| L_{A39}(Rk)(Rl)(Rm)(Rn) (T)(Z), wherein L_{A39}(R1)(R1)(R1)(R30) (T1)(Z1) to L_{A39}(R115)(R115)(R115) (R115)(T10)(Z6), have the structure | 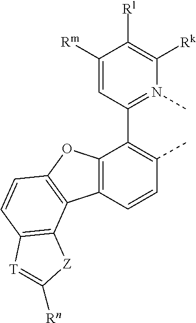 |
| L_{A40}(Rk)(Rl)(Rm)(Rn) (T)(Z), wherein L_{A40}(R1)(R1)(R1)(R30) (T1)(Z1) to L_{A40}(R115)(R115)(R115) (R115)(T10)(Z6), have the structure | 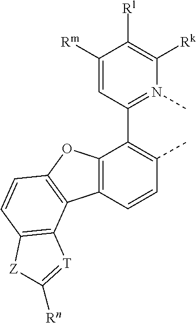 |
| L_{A41}(Rk)(Rl)(Rm)(Rn) (T)(Z), wherein L_{A421}(R1)(R1)(R1)(R30) (T1)(Z1) to L_{A41}(R115)(R115)(R115) (R115)(T10)(Z6), have the structure | 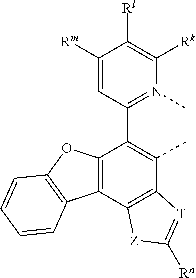 |
| L_{A42}(Rk)(Rl)(Rm)(Rn) (T)(Z), wherein L_{A42}(R1)(R1)(R1)(R30) (T1)(Z1) to L_{A42}(R115)(R115)(R115) (R115)(T10)(Z6), have the structure | 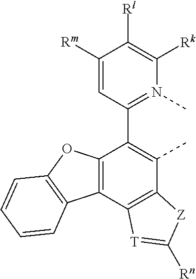 |
| L_{A43}(Rk)(Rl)(Rm)(Rn) (T)(Z), wherein L_{A43}(R1)(R1)(R1)(R30) (T1)(Z1) to L_{A43}(R115)(R115)(R115) (R115)(T10)(Z6), have the structure | 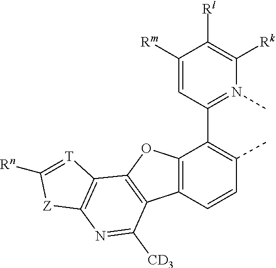 |
| L_{A44}(Rk)(Rl)(Rm)(Rn) (T)(Z), wherein L_{A44}(R1)(R1)(R1)(R30) (T1)(Z1) to L_{A44}(R115)(R115)(R115) (R115)(T10)(Z6), have the structure | 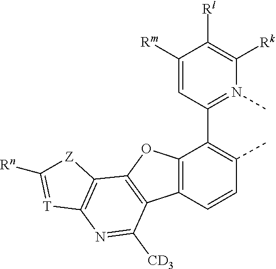 |
| L_{A45}(Rk)(Rl)(Rm)(Rn) (T)(Z), wherein L_{A45}(R1)(R1)(R1)(R30) (T1)(Z1) to L_{A45}(R115)(R115)(R115) (R115)(T10)(Z6), have the structure | 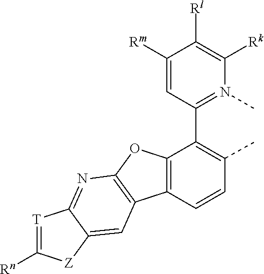 |
| L_{A46}(Rk)(Rl)(Rm)(Rn) (T)(Z), wherein L_{A46}(R1)(R1)(R1)(R30) (T1)(Z1) to L_{A46}(R115)(R115)(R115) (R115)(T10)(Z6), have the structure | 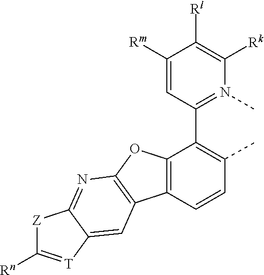 |
| L_{A47}(Rk)(Rl)(Rm)(Rn) (T)(Z), wherein L_{A47}(R1)(R1)(R1)(R30) (T1)(Z1) to L_{A47}(R115)(R115)(R115) (R115)(T10)(Z6), have the structure | 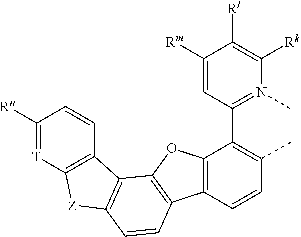 |
| L_{A48}(Rk)(Rl)(Rm)(Rn) (T)(Z), wherein L_{A48}(R1)(R1)(R1)(R30) (T1)(Z1) to L_{A48}(R115)(R115)(R115) (R115)(T10)(Z6), have the structure | 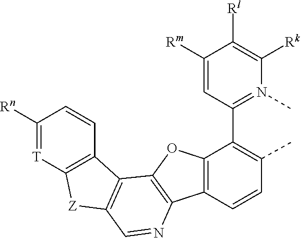 |
| L_{A49}(Rk)(Rl)(Rm)(Rn) (T)(Z), wherein L_{A49}(R1)(R1)(R1)(R30) (T1)(Z1) to L_{A49}(R115)(R115)(R115) (R115)(T10)(Z6), have the structure | 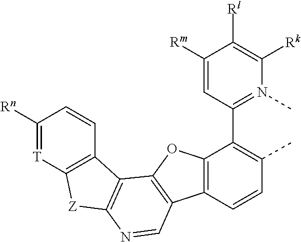 |
| L_{A50}(Rk)(Rl)(Rm)(Rn) (T)(Z), wherein L_{A50}(R1)(R1)(R1)(R30) (T1)(Z1) to L_{A50}(R115)(R115)(R115) (R115)(T10)(Z6), have the structure | 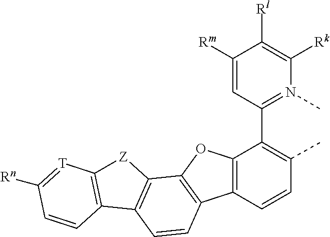 |
| L_{A51}(Rk)(Rl)(Rm)(Rn(T) (Z), wherein L_{A51}(R1)(R1)(R1)(R30) (T1)(Z1) to L_{A51}(R115)(R115)(R115) (R115)(T10)(Z6), have the structure | 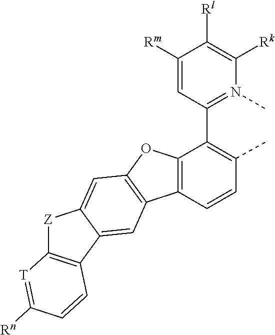 |
| L_{A52}(Rk)(Rl)(Rm)(Rn) (T)(Z), wherein L_{A52}(R1)(R1)(R1)(R30) (T1)(Z1) to L_{A52}(R115)(R115)(R115) (R115)(T10)(Z6), have the structure | 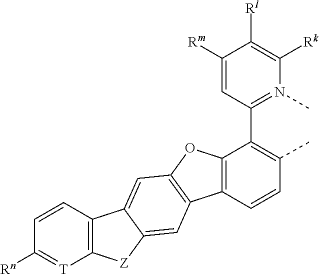 |
| L_{A53}(Rk)(Rl)(Rm)(Rn) (T)(Z), wherein L_{A53}(R1)(R1)(R1)(R30) (T1)(Z1) to L_{A53}(R115)(R115)(R115) (R115)(T10)(Z6), have the structure | 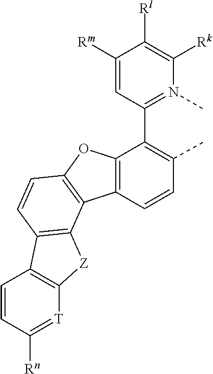 |
| L_{A54}(Rk)(Rl)(Rm)(Rn) (T)(Z), wherein L_{A54}(R1)(R1)(R1)(R30) (T1)(Z1) to L_{A54}(R115)(R115)(R115) (R115)(T10)(Z6), have the structure | 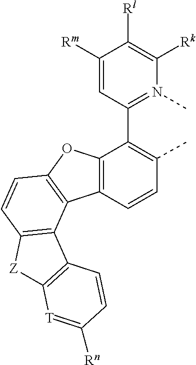 |
| L_{A55}(Rk)(Rl)(Rm)(Rn) (T)(Z), wherein L_{A55}(R1)(R1)(R1)(R30) (T1)(Z1) to L_{A55}(R115)(R115)(R115) (R115)(T10)(Z6), have the structure | 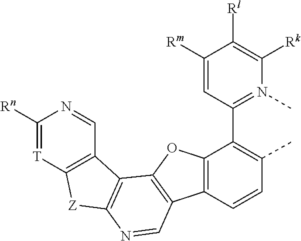 |
| L_{A56}(Rk)(Rl)(Rm)(Rn) (T)(Z), wherein L_{A56}(R1)(R1)(R1)(R30) (T1)(Z1) to L_{A56}(R115)(R115)(R115) (R115)(T10)(Z6), have the structure | 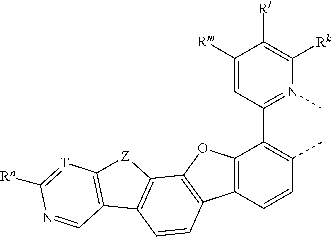 |
| L_{A57}(Rk)(Rl)(Rm)(Rn) (T)(Z), wherein L_{A57}(R1)(R1)(R1)(R30) (T1)(Z1) to L_{A57}(R115)(R115)(R115) (R115)(T10)(Z6), have the structure | 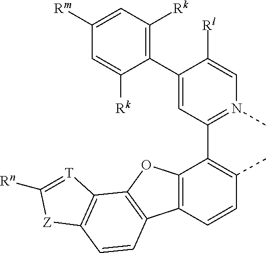 |
| L_{A58}(Rk)(Rl)(Rm)(Rn) (T)(Z), wherein L_{A58}(R1)(R1)(R1)(R30) (T1)(Z1) to L_{A58}(R115)(R115)(R115) (R115)(T10)(Z6), have the structure | 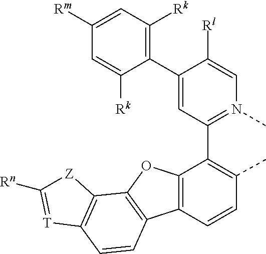 |
| L_{A59}(Rk)(R)(Rm)(Rn) (T)(Z), wherein L_{A59}(R1)(R1)(R1)(R30) (T1)(Z1) to L_{A59}(R115)(R115)(R115) (R115)(T10)(Z6), have the structure | 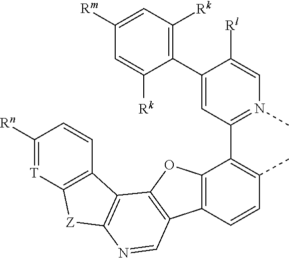 |
| L_{A60}(Rk)(Rl)(Rm)(Rn) (T)(Z), wherein L_{A60}(R1)(R1)(R1)(R30) (T1)(Z1) to L_{A60}(R115)(R115)(R115) (R115)(T10)(Z6), have the structure | 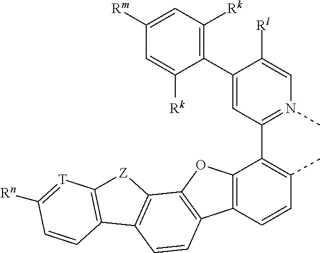 |

wherein R1 to R115 have the following structures:

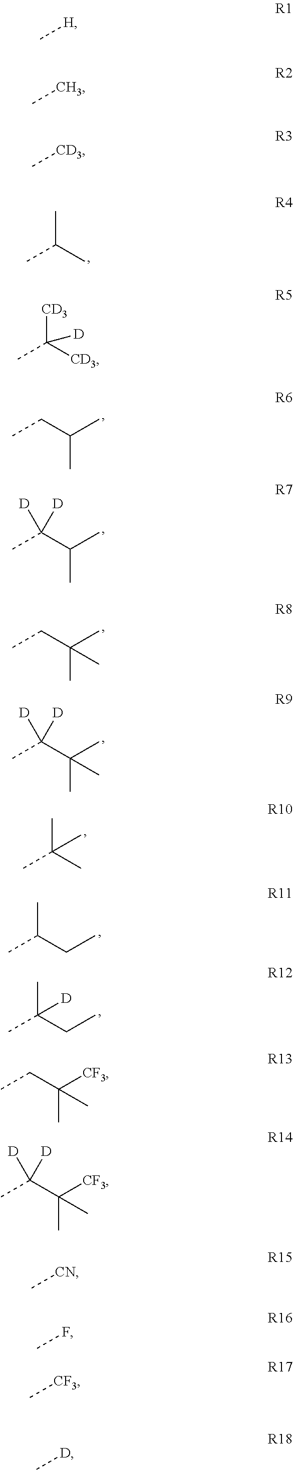

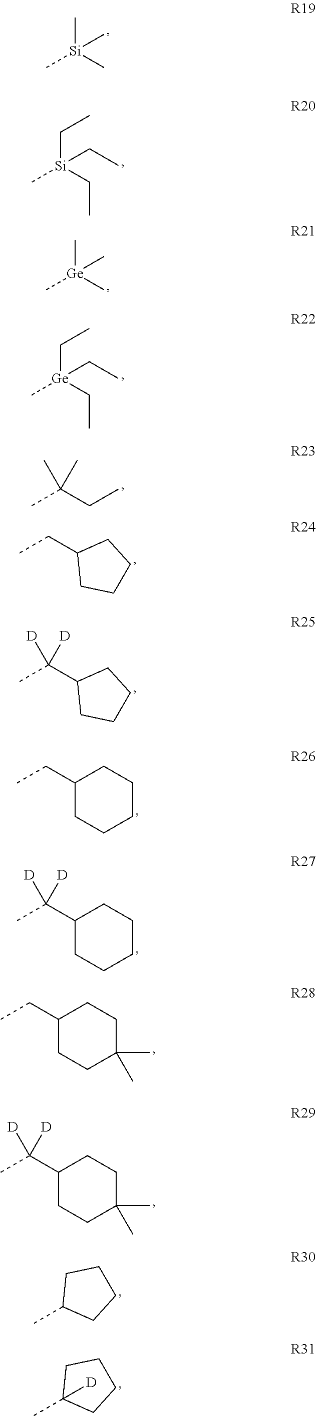

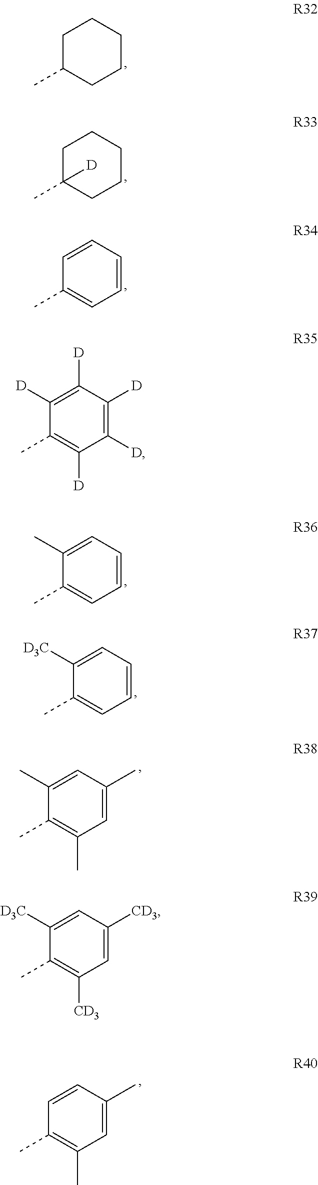

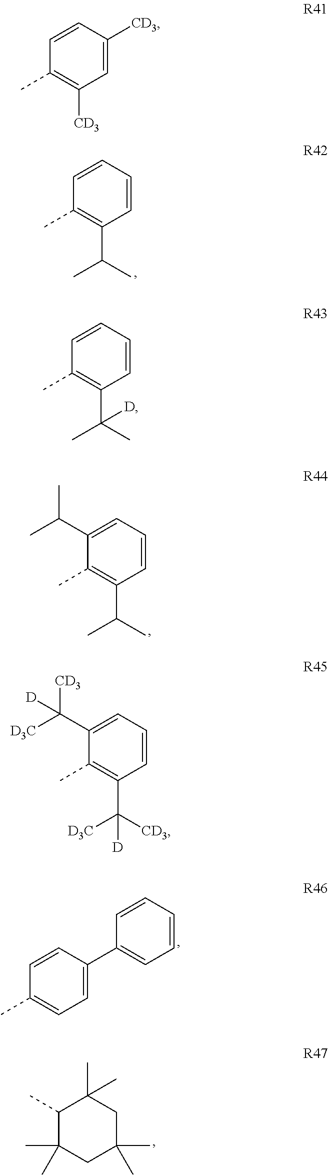

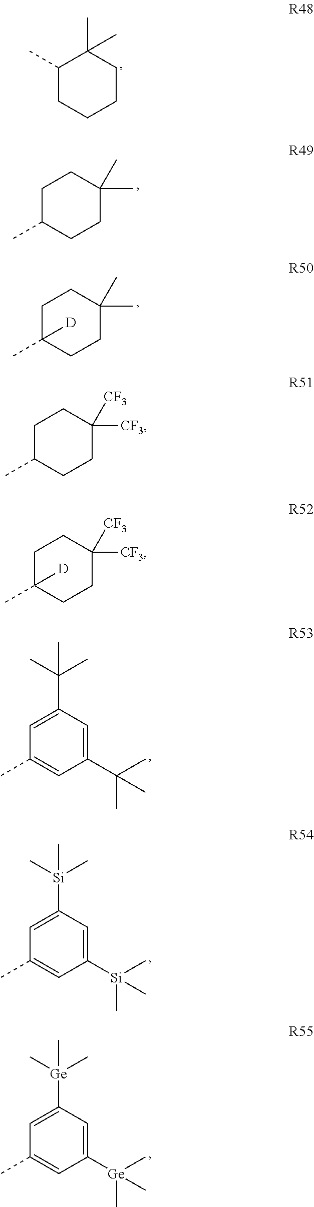

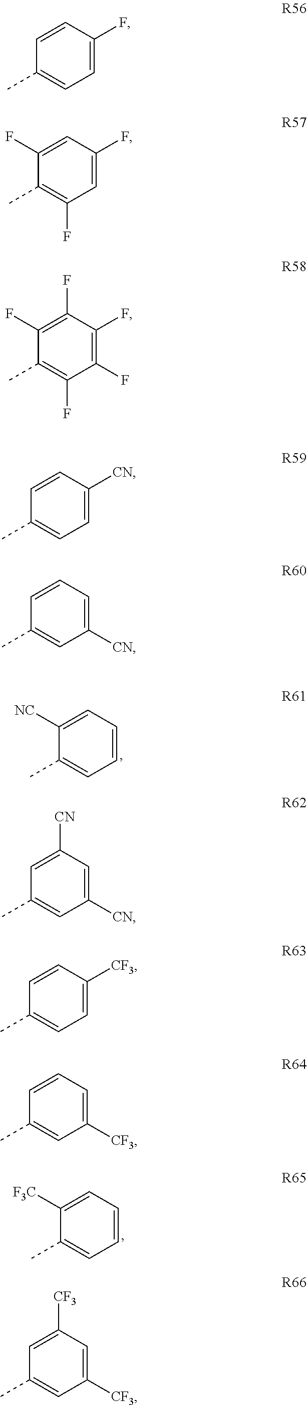

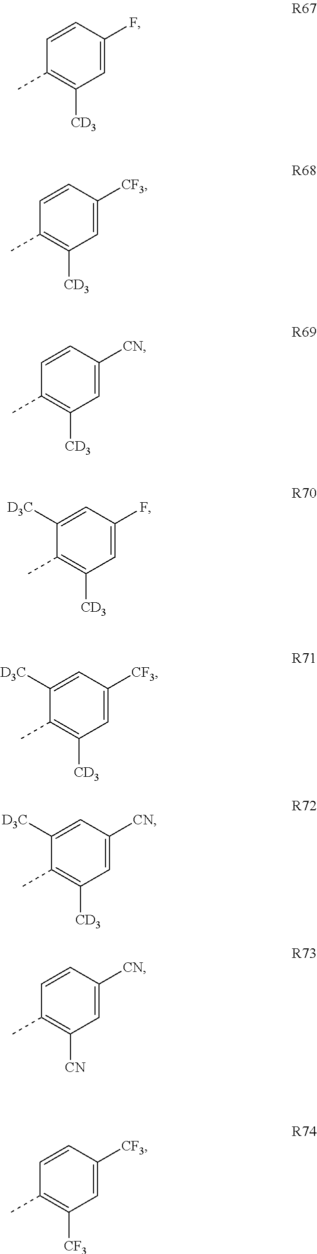

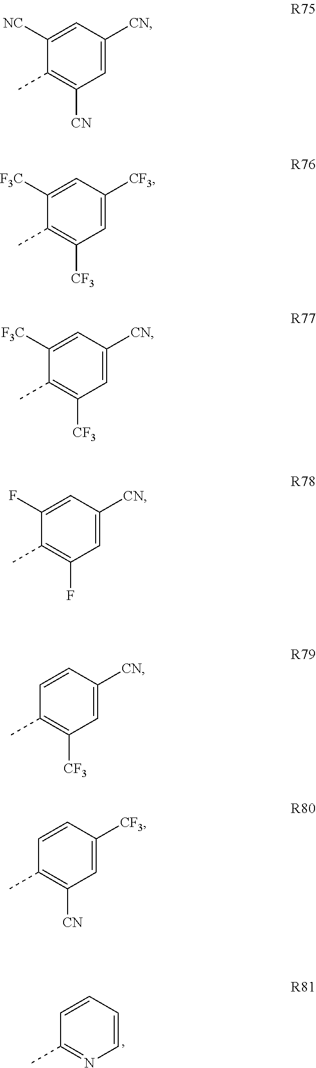

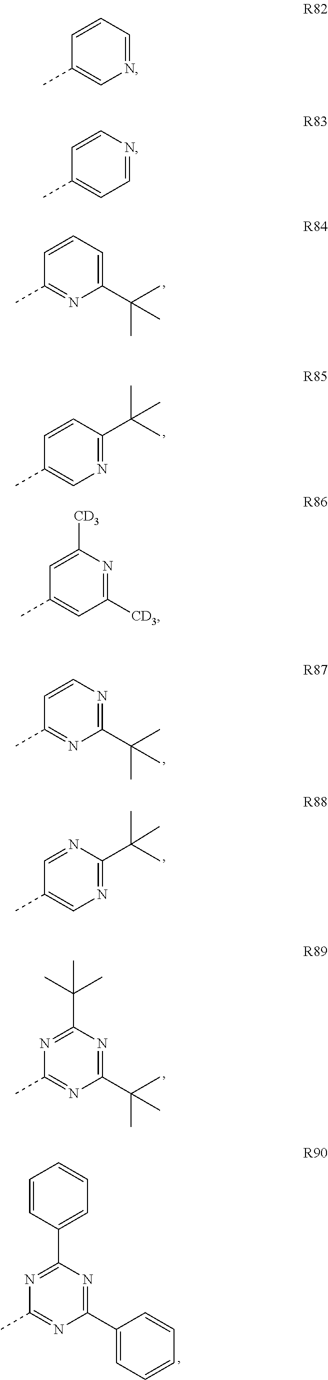

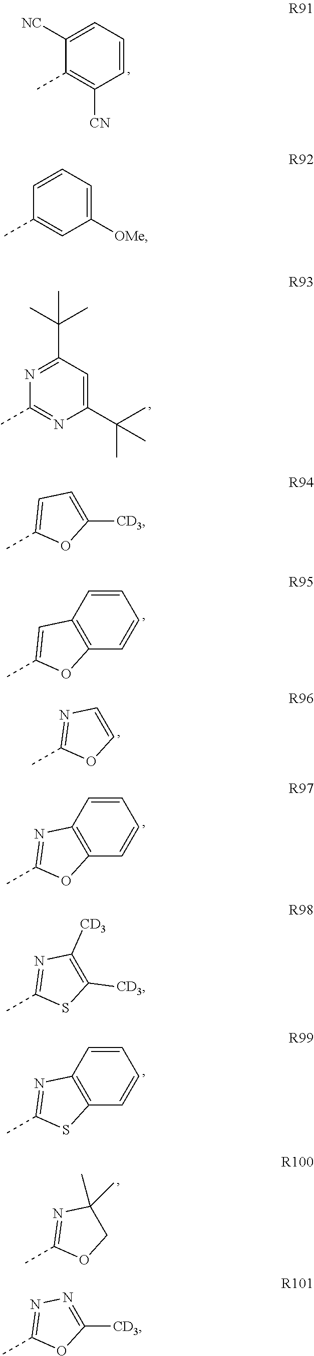

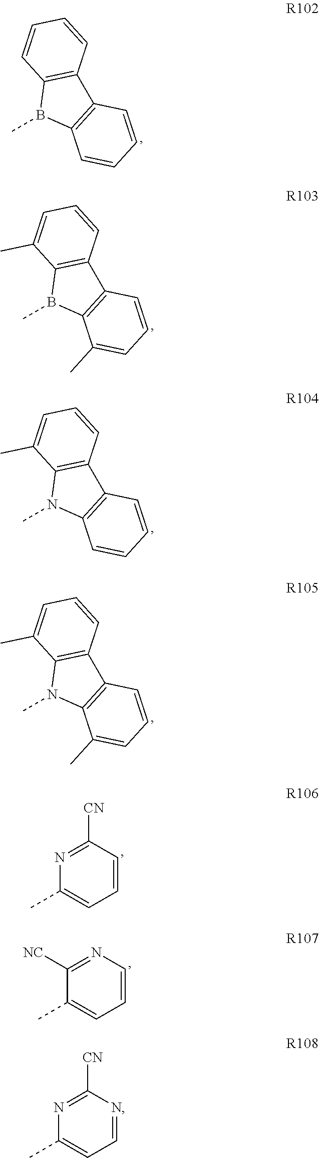

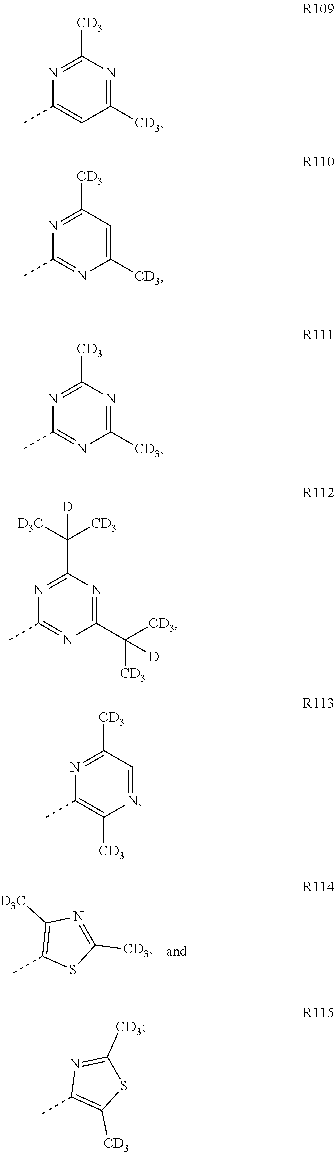

wherein T1 to T10 have the following structures:

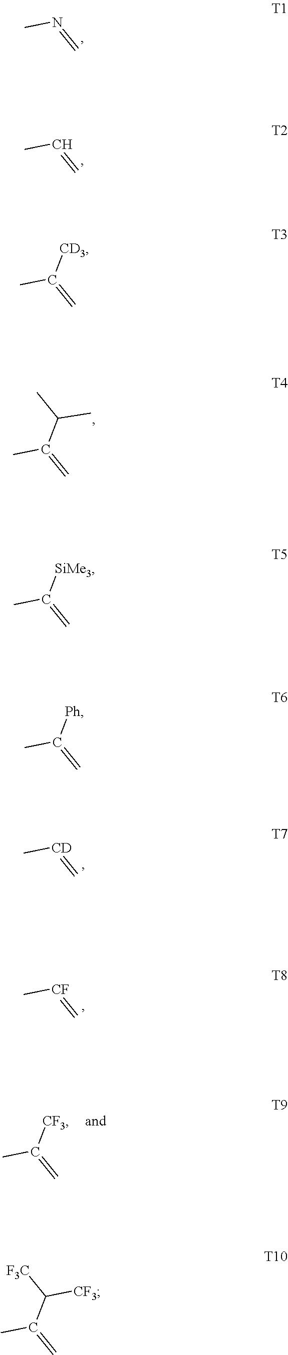

wherein Z1 to Z6 have the following structures:

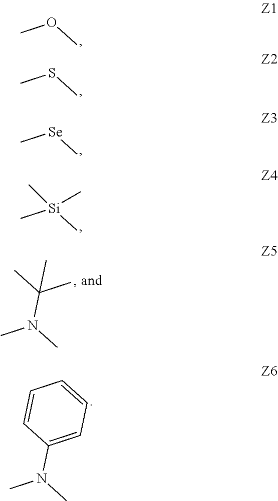

In some embodiments, the ligand L_{A} is L_{Ai}, and i is an integer from 1 to 143, and each L_{Ai} is defined by the structures in the following LIST 3:

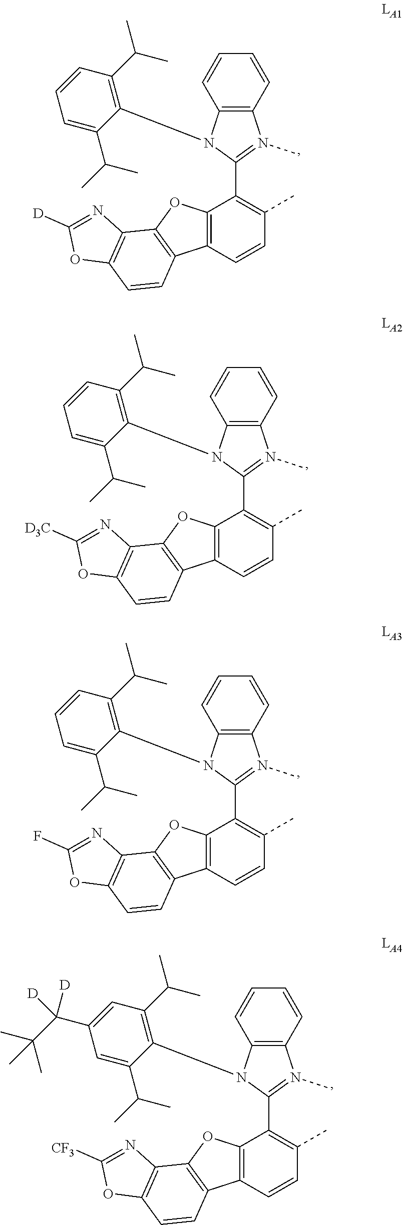

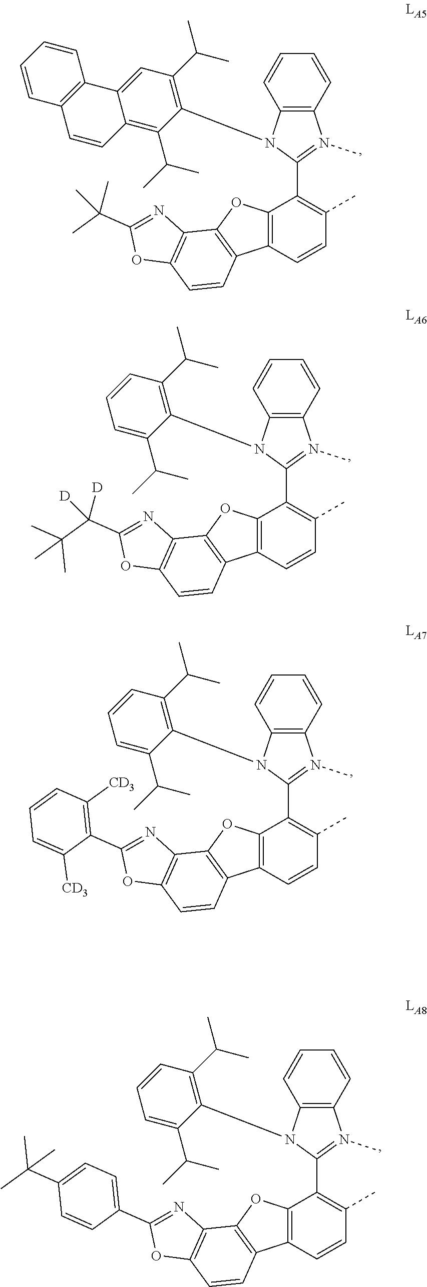

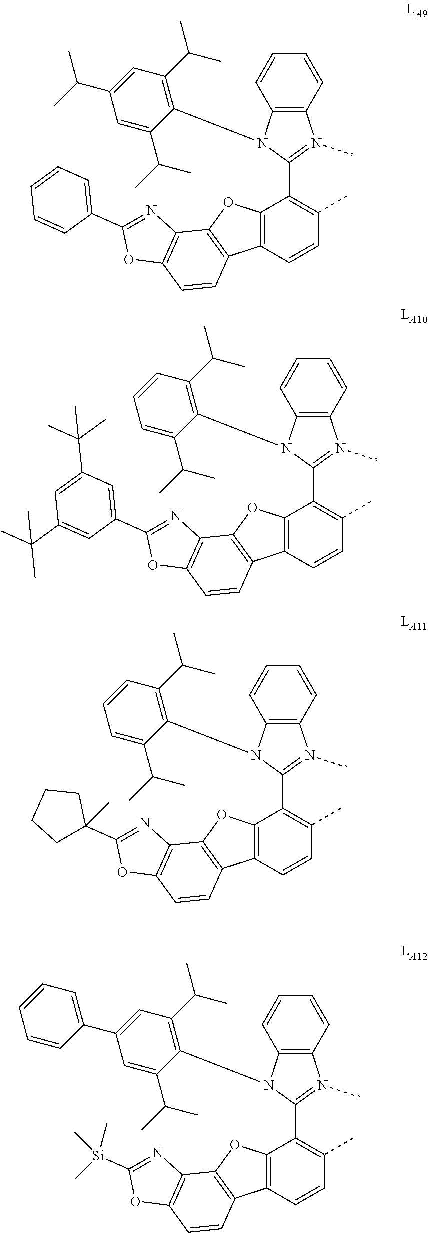

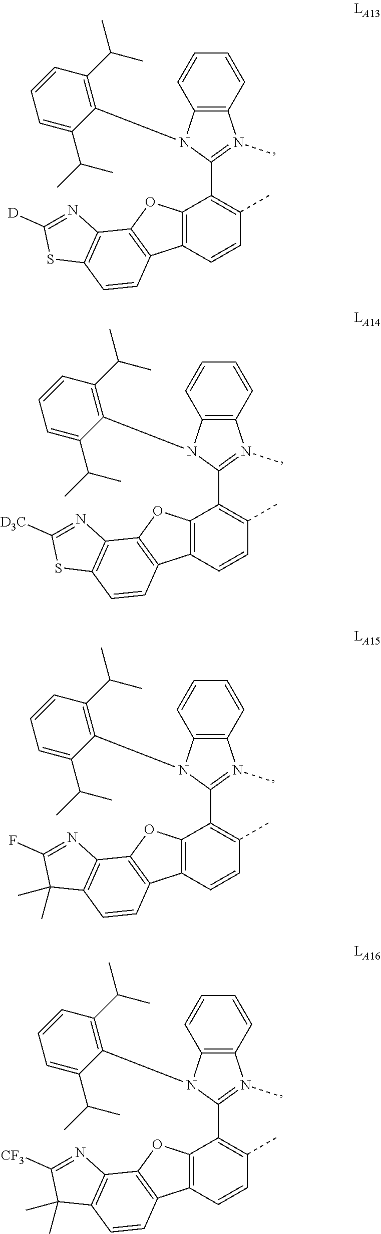

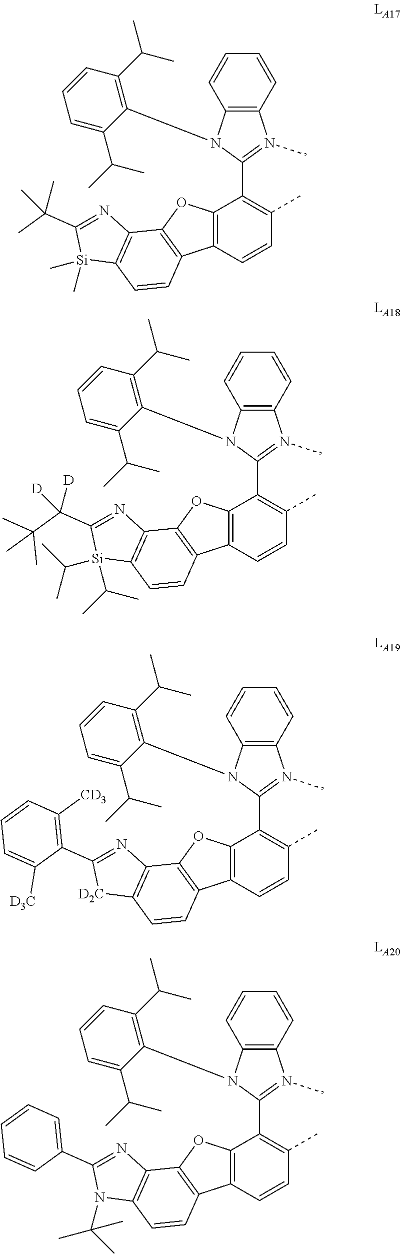

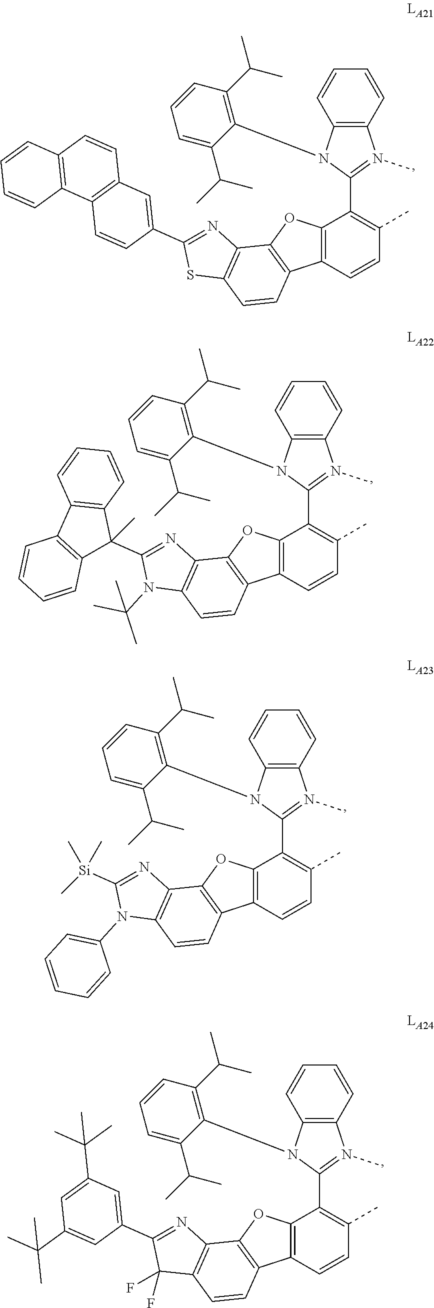

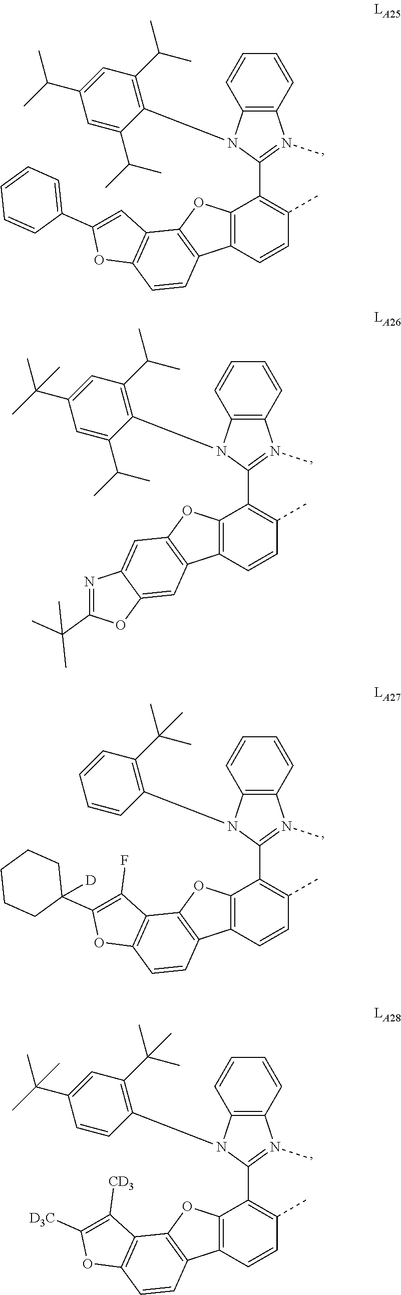

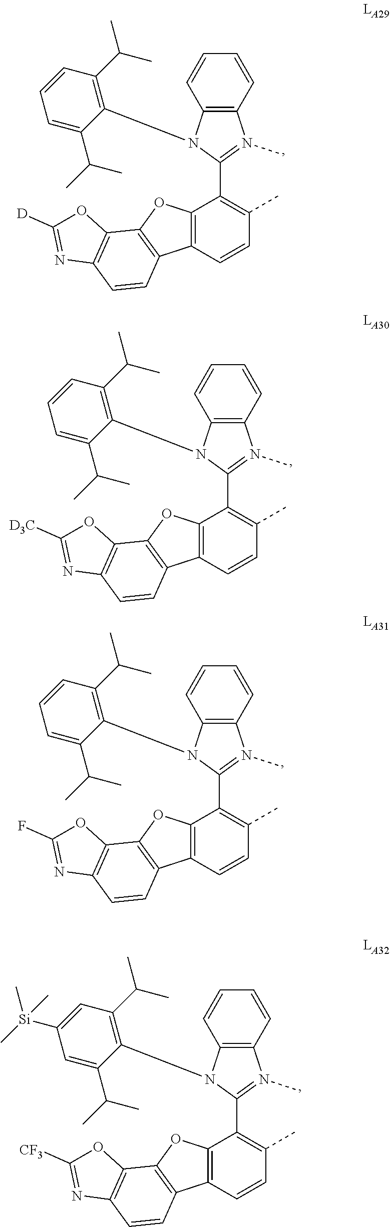

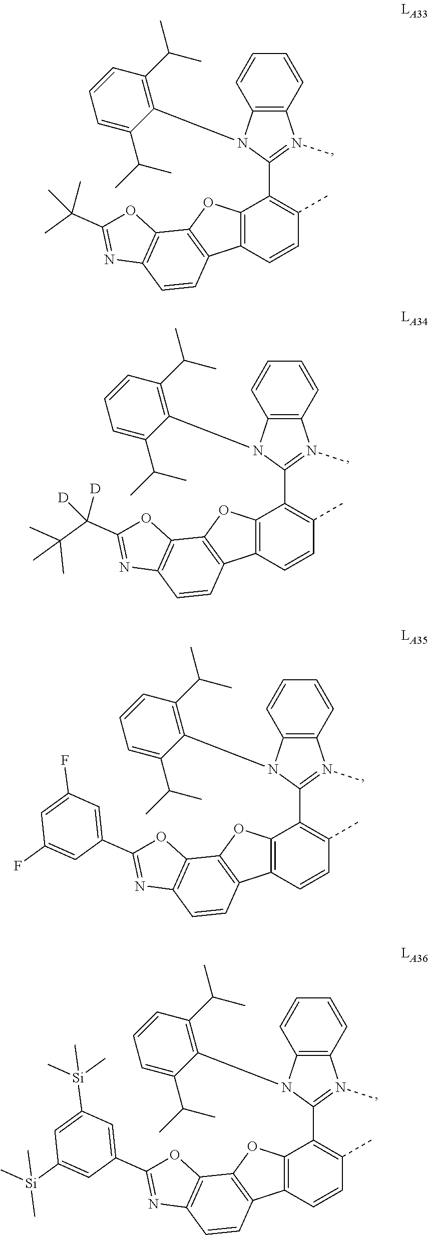

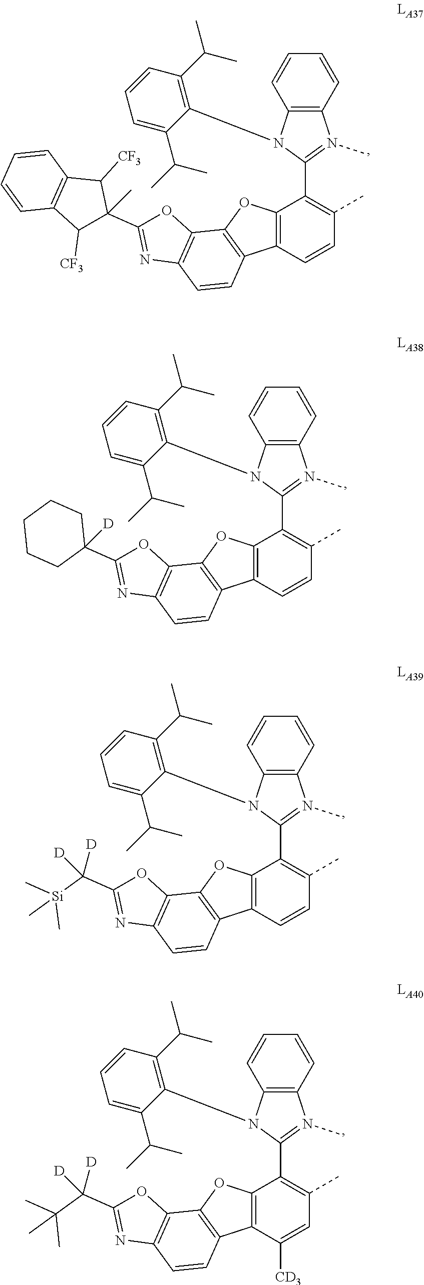

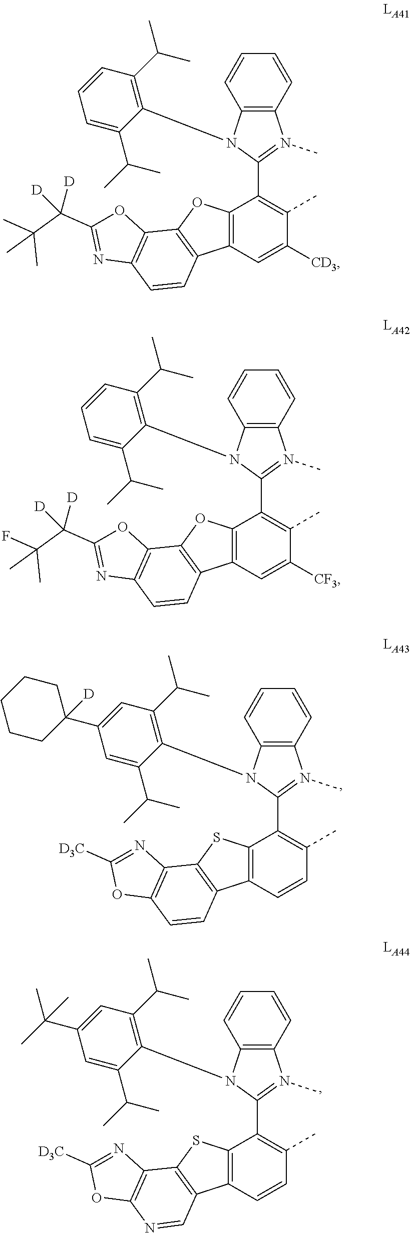

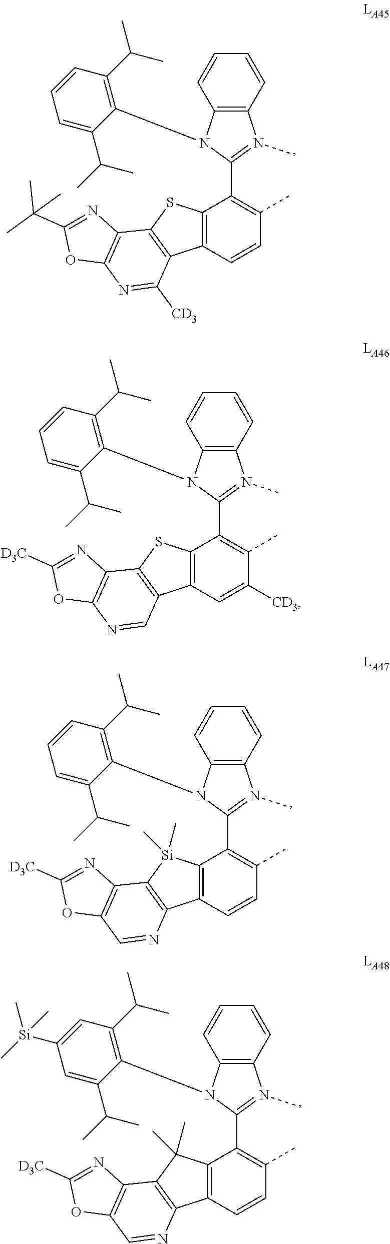

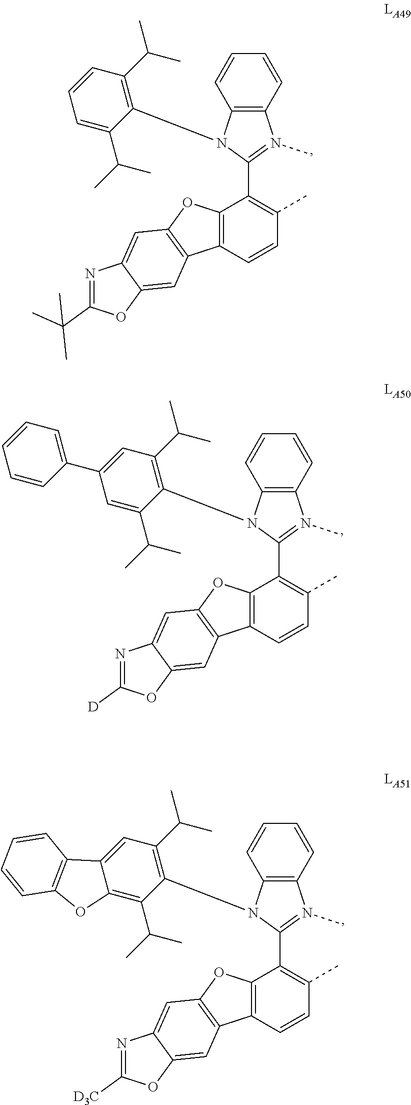

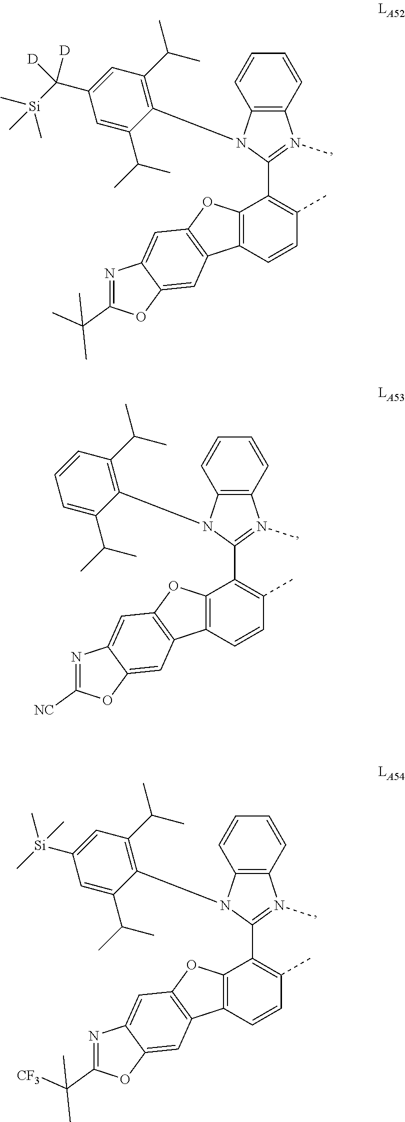

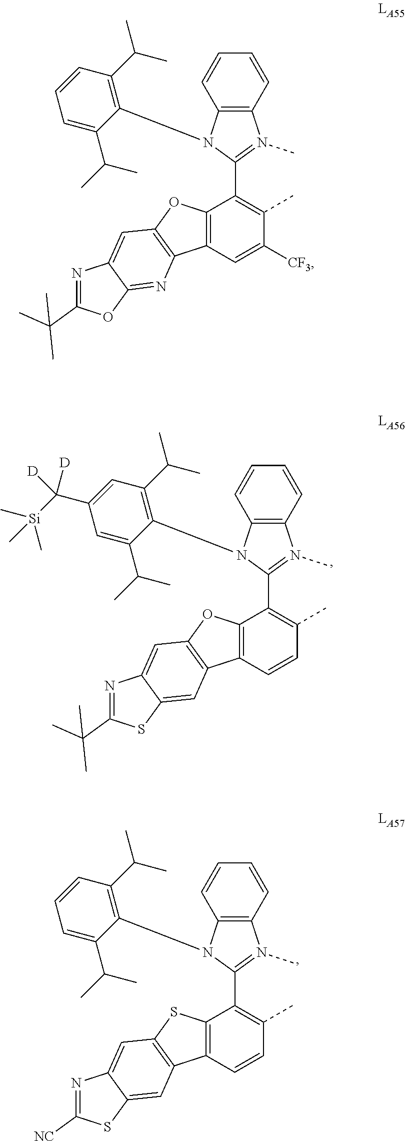

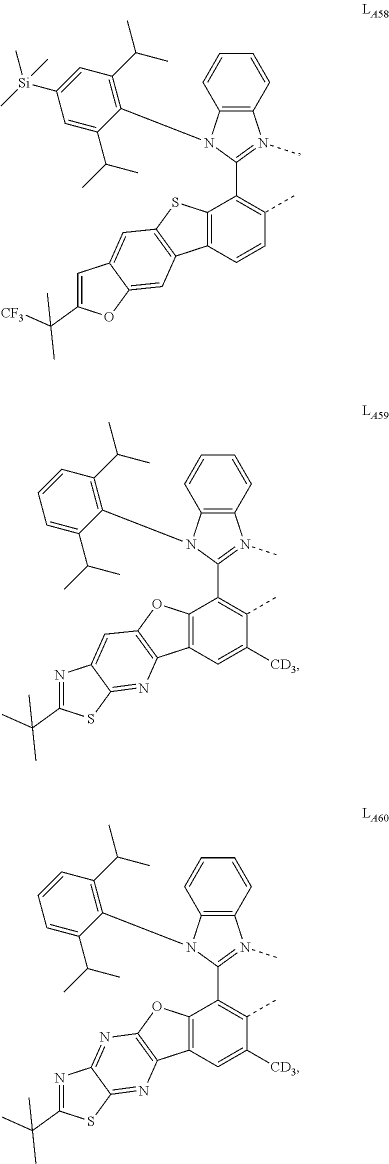

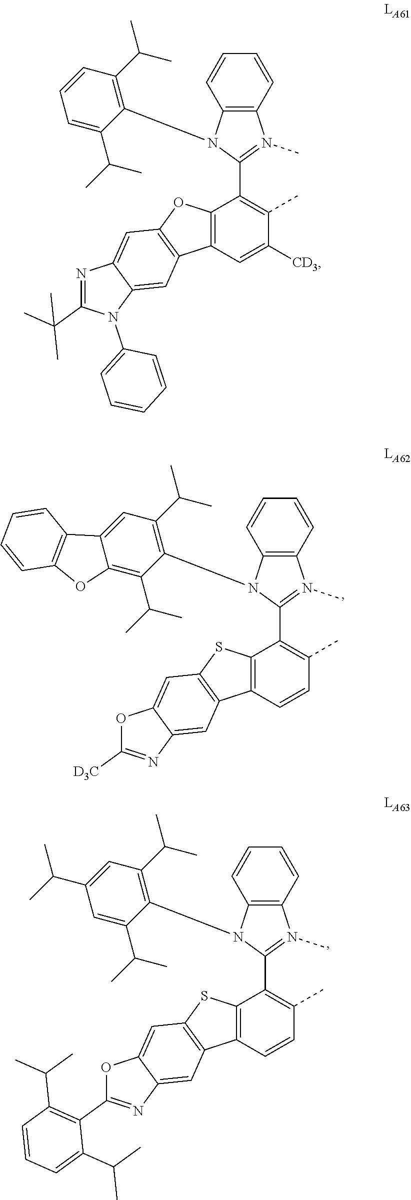

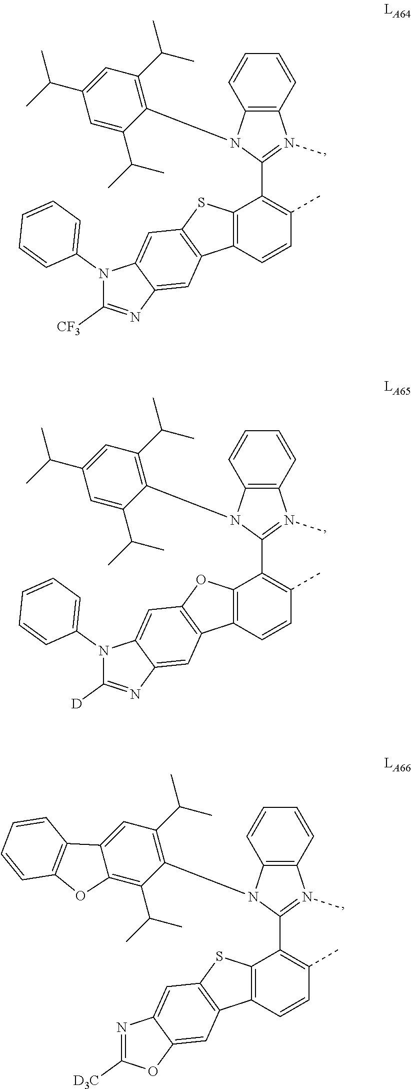

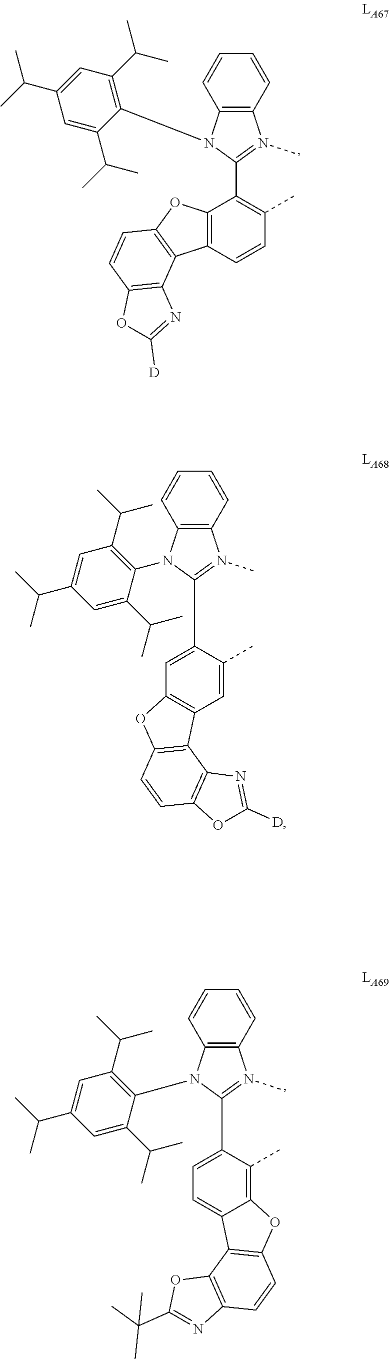

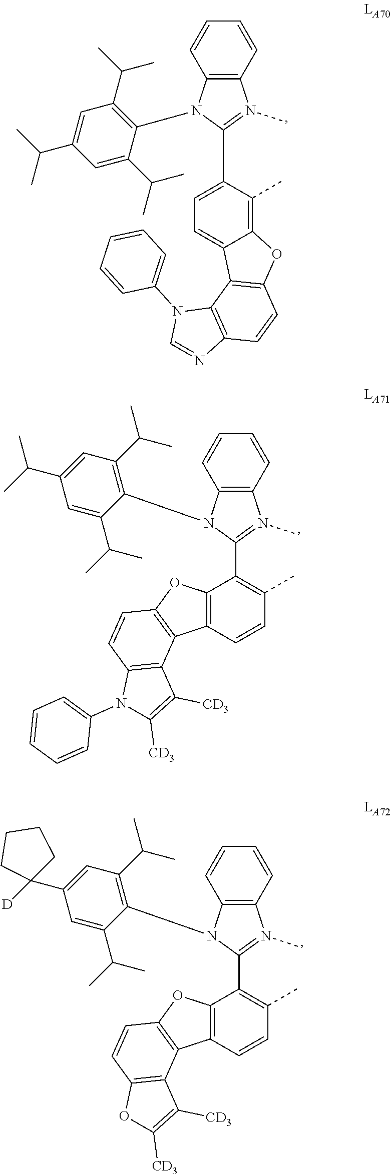

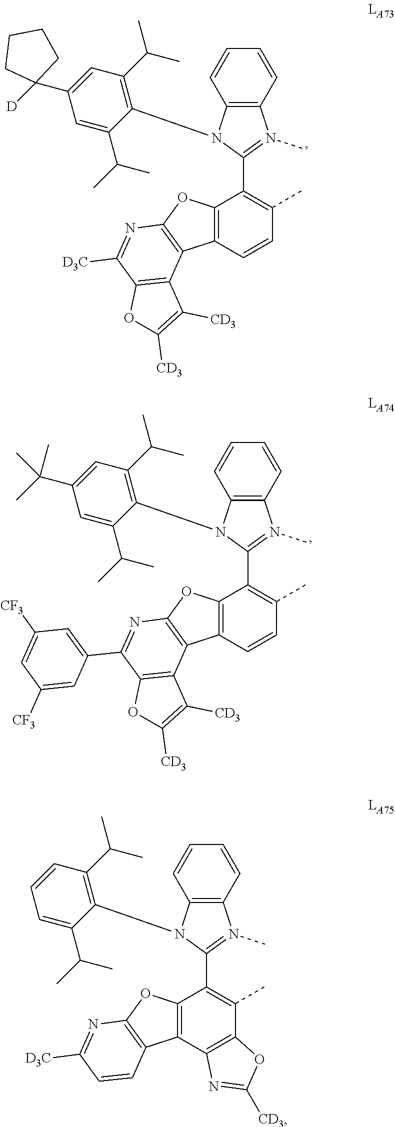

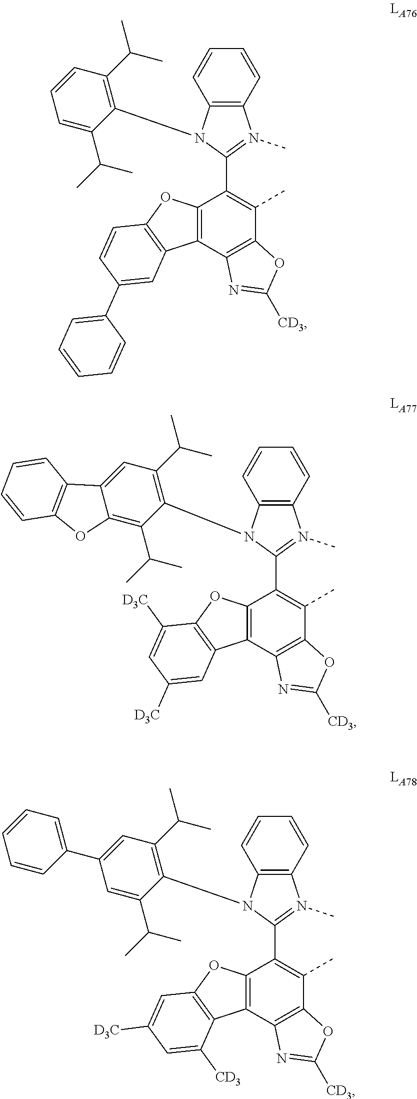

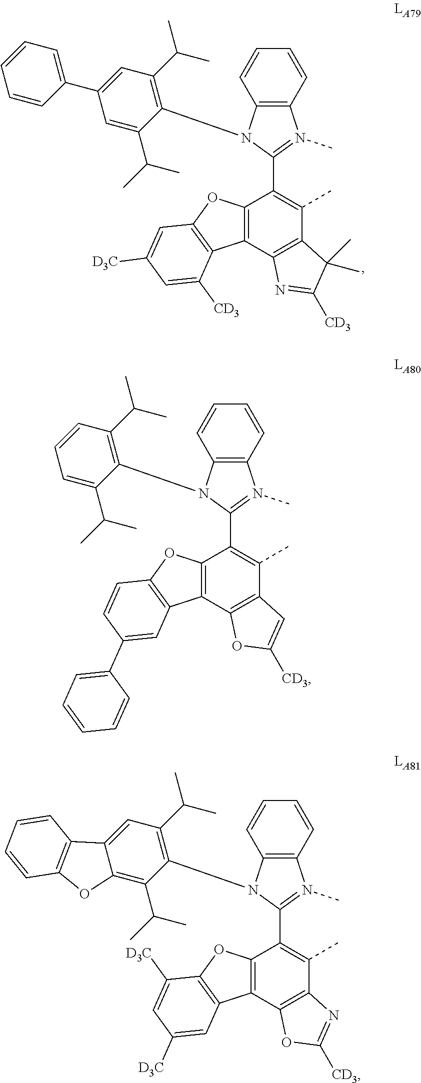

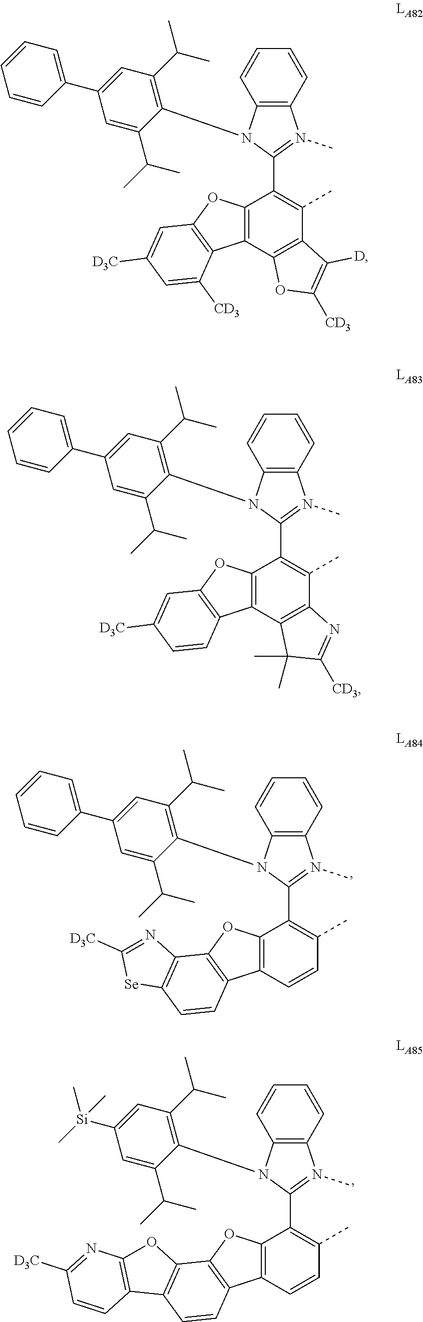

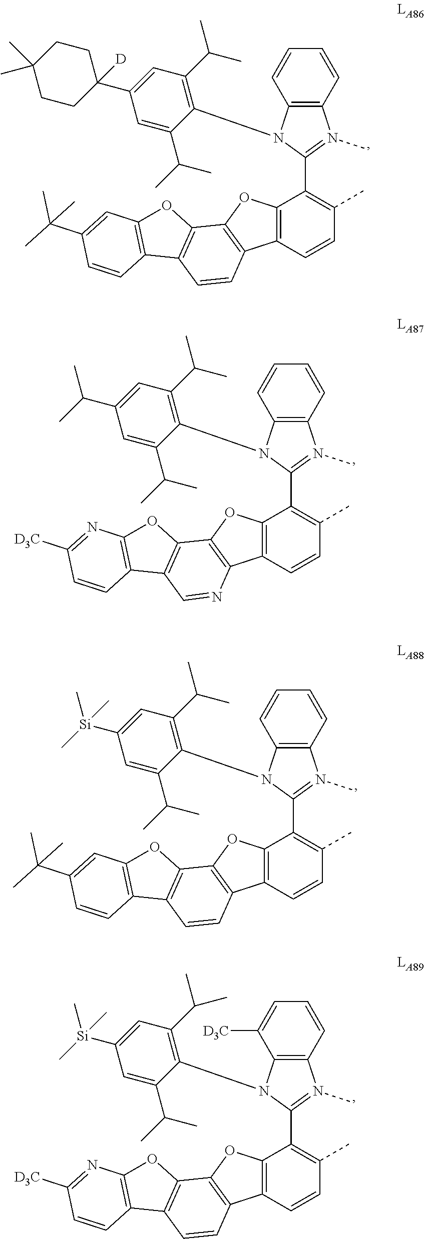

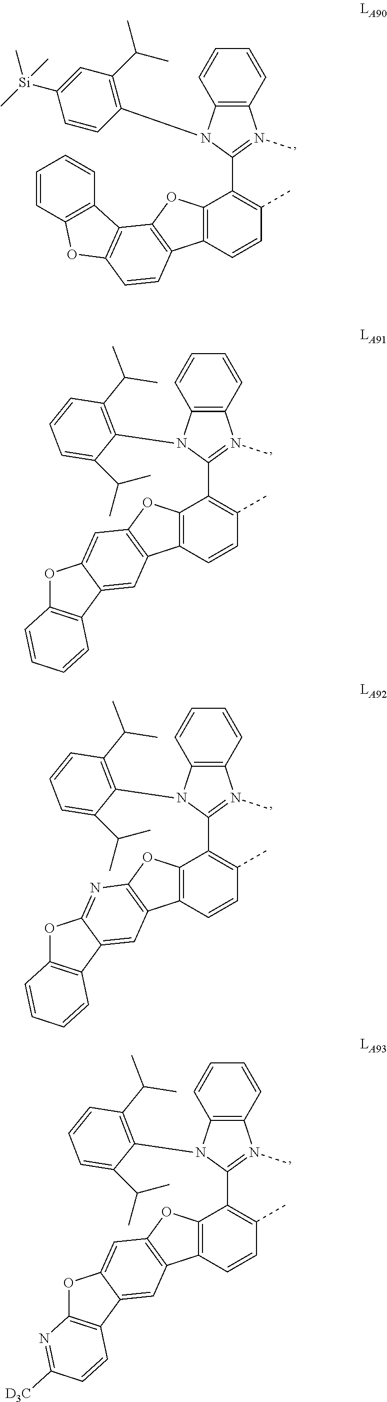

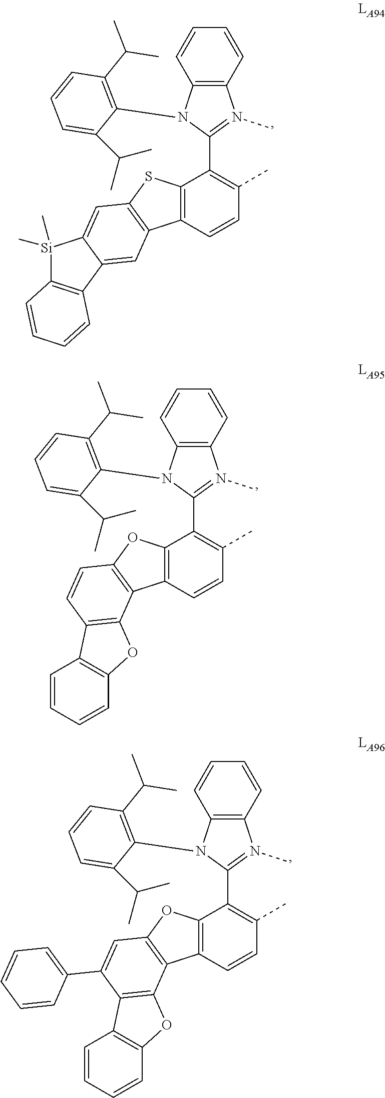

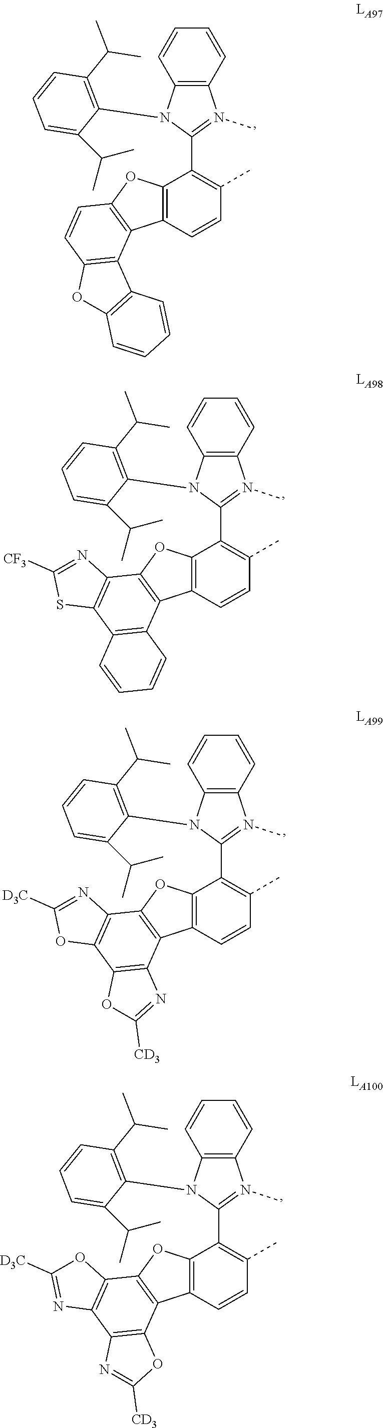

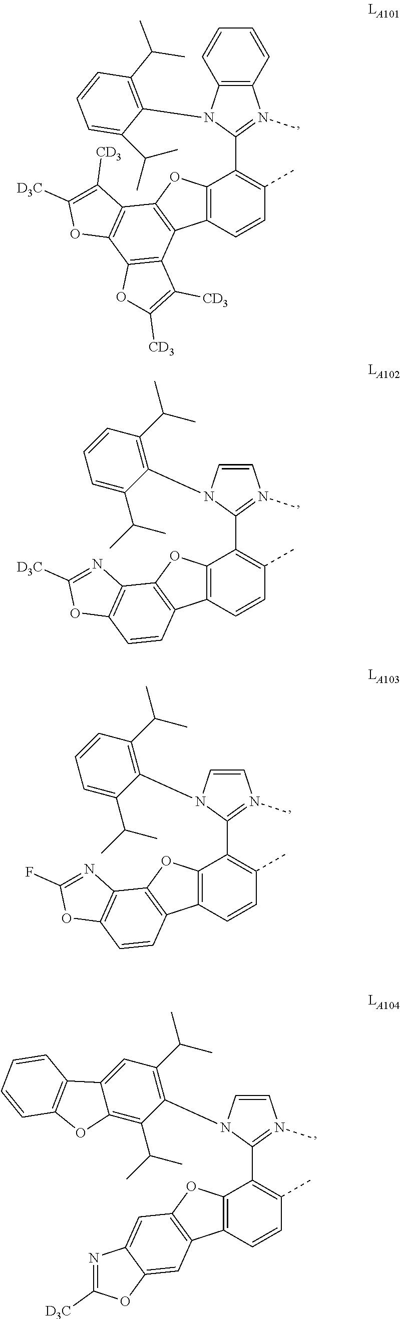

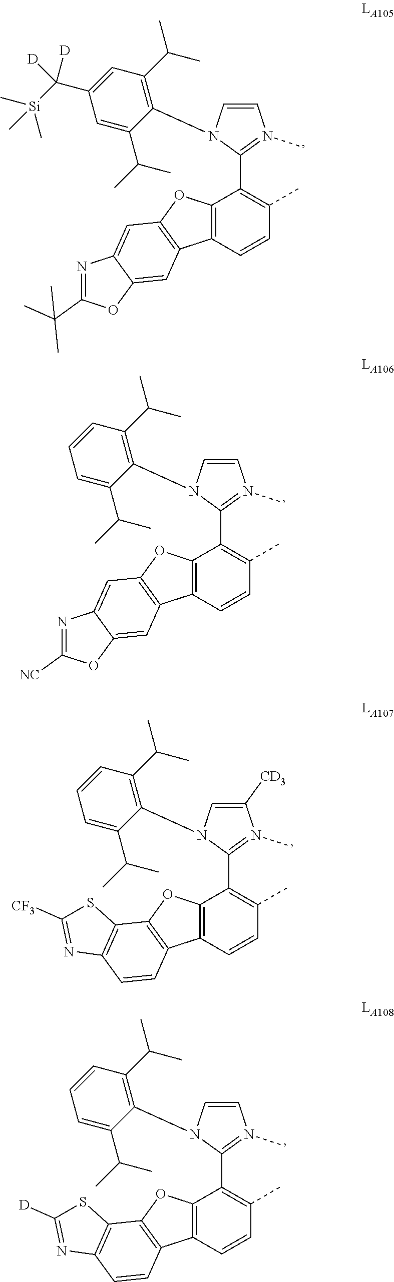

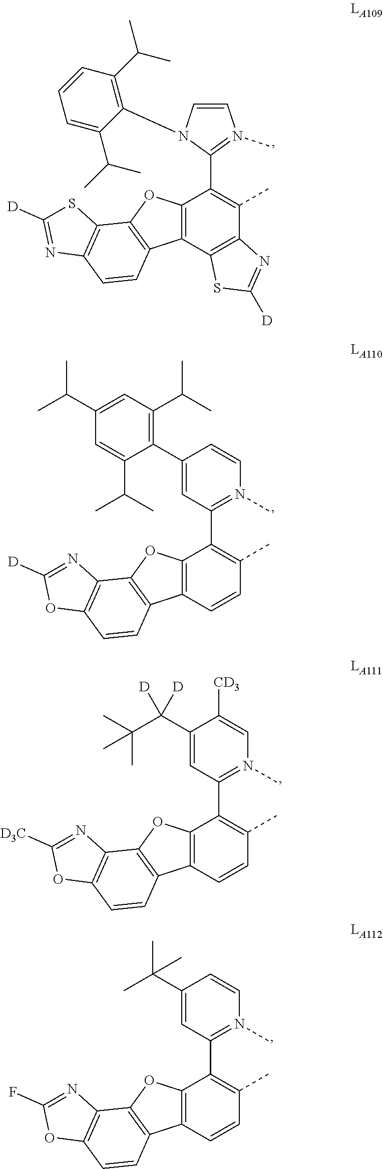

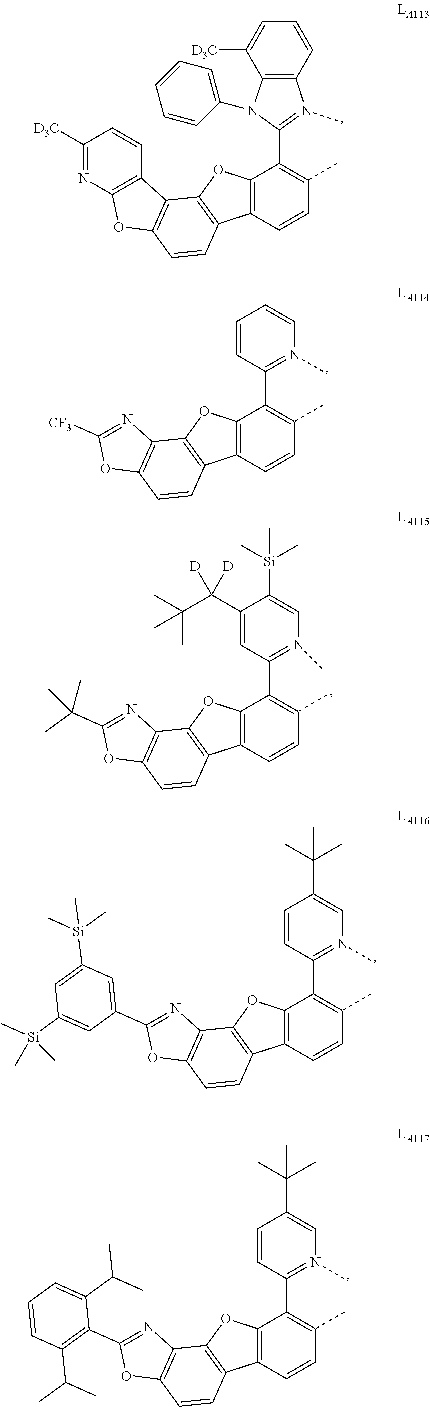

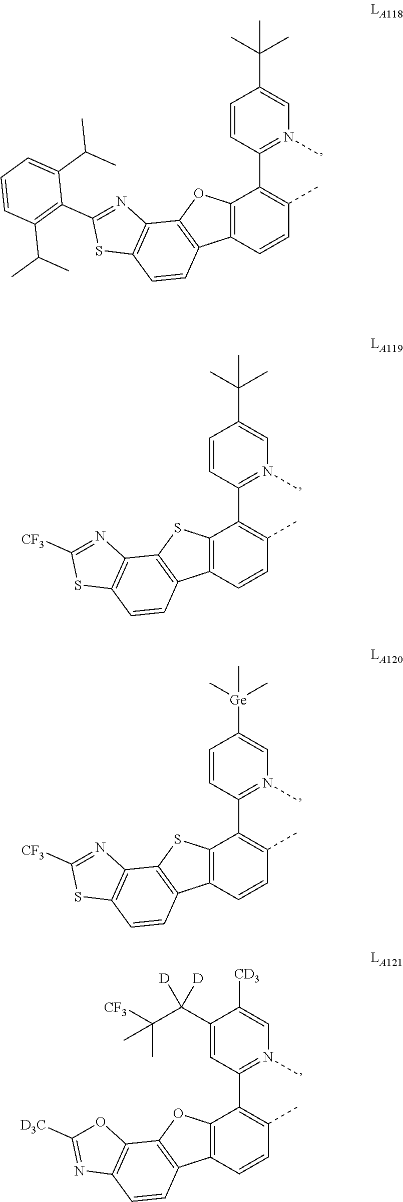

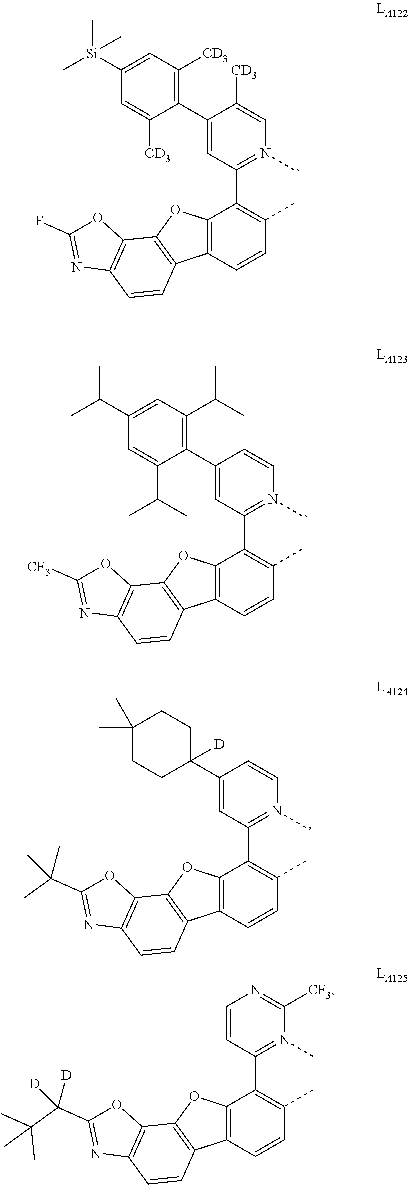

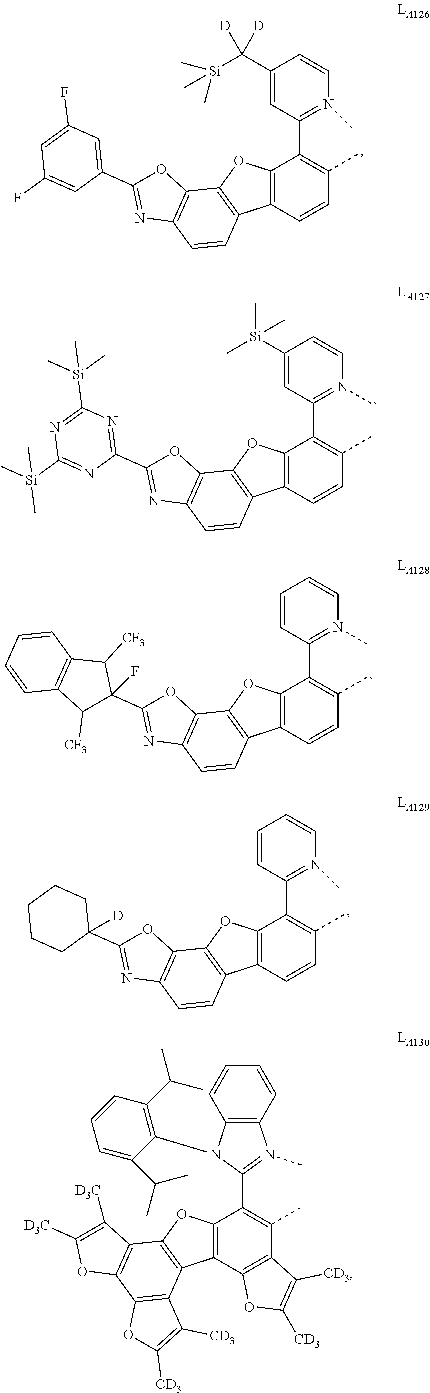

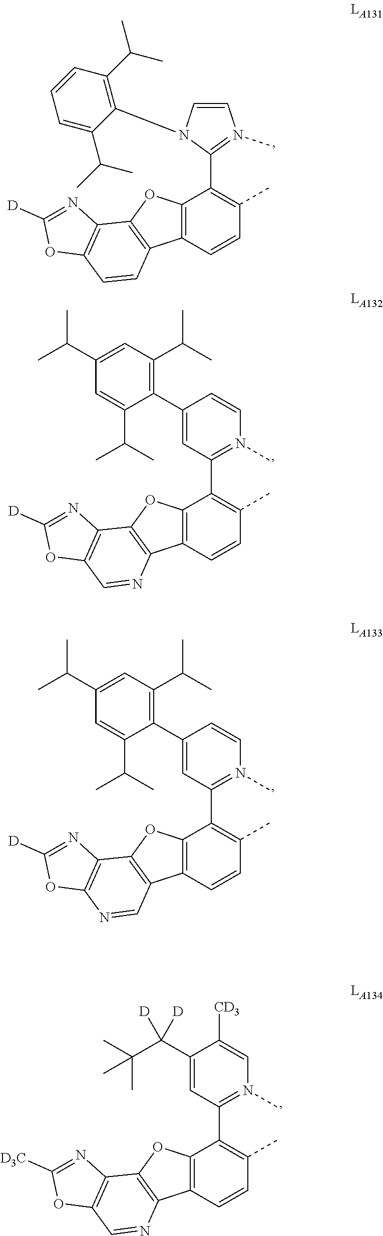

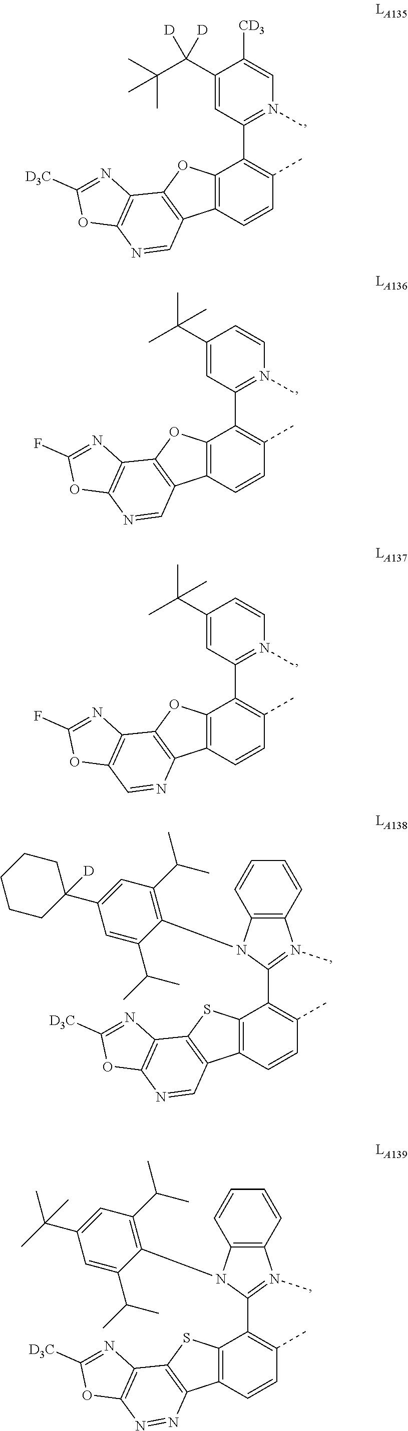

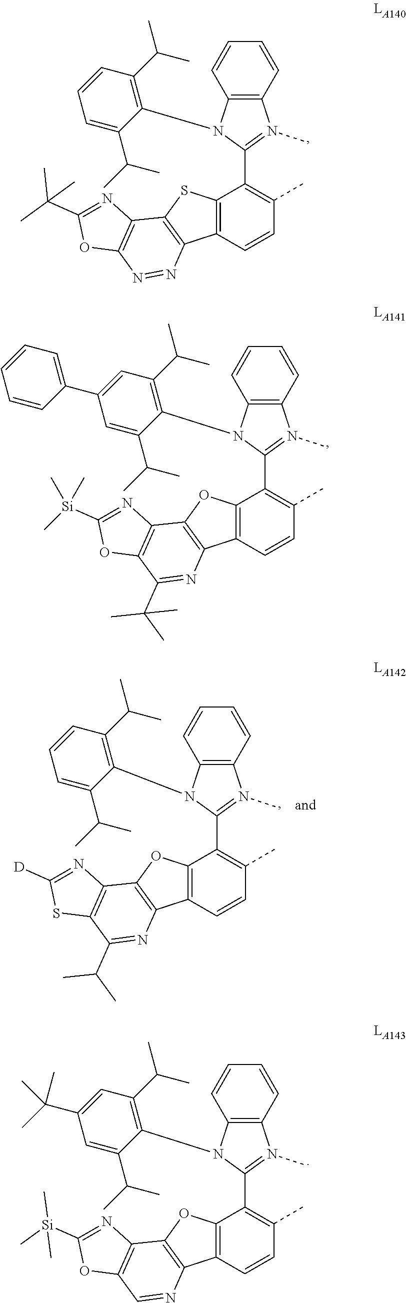

In some embodiments of the compound that comprises one or more of R^{C}, R^{D}, R^{E}, R^{F}, R^{DD}, and R^{FF}, at least one of the substituents R^{C}, R^{D}, R^{E}, R^{F}, R^{DD}, or R^{FF} is partially or fully deuterated. In some embodiments of the compound that comprises at least one R^{C}, at least one R^{C} is partially or fully deuterated. In some embodiments of the compound that comprises at least one R^{D}, at least one R^{D} is partially or fully deuterated. In some embodiments of the compound that comprises at least one R^{E}, at least one R^{E} is partially or fully deuterated. In some embodiments of the compound that comprises at least one R^{F}, at least one R^{F} is partially or fully deuterated. In some embodiments that comprises at least one R^{DD}, at least one R^{DD} is partially or fully deuterated. In some embodiments of the compound that comprises at least one R′, at least one R^{FF} is partially or fully deuterated.

In some embodiments, the ligand L_{B} is selected from the group consisting of the structures of the following LIST 4:

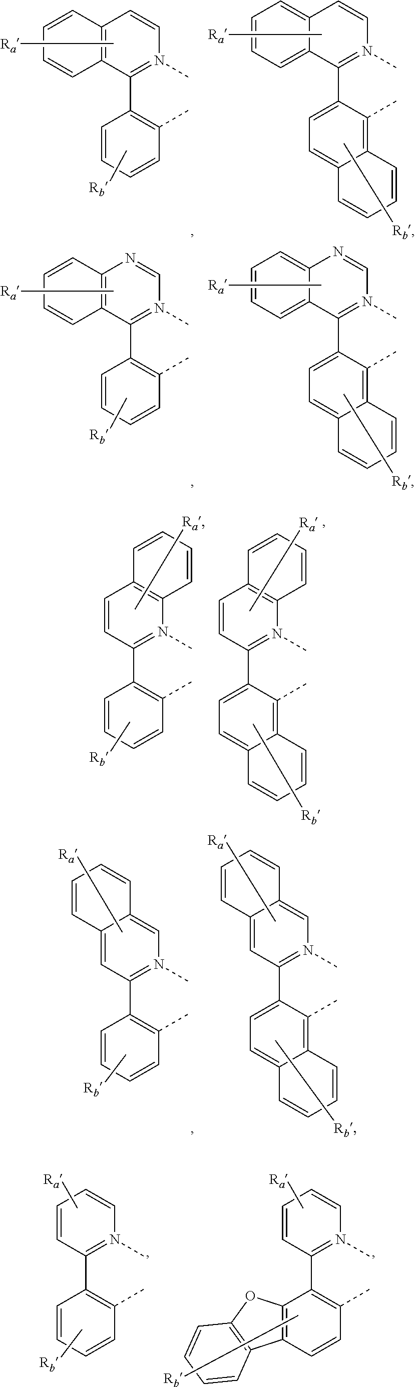

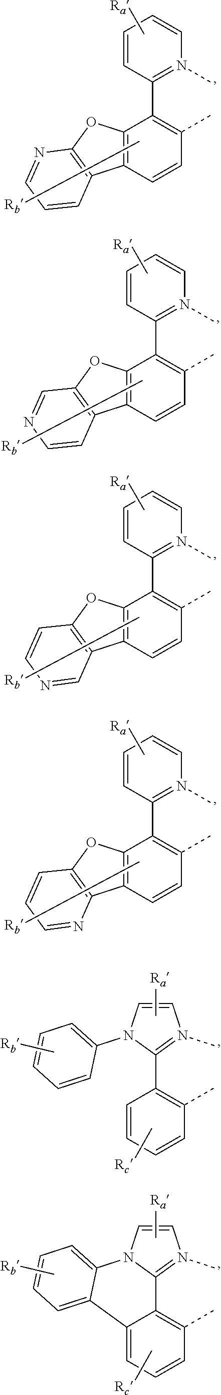

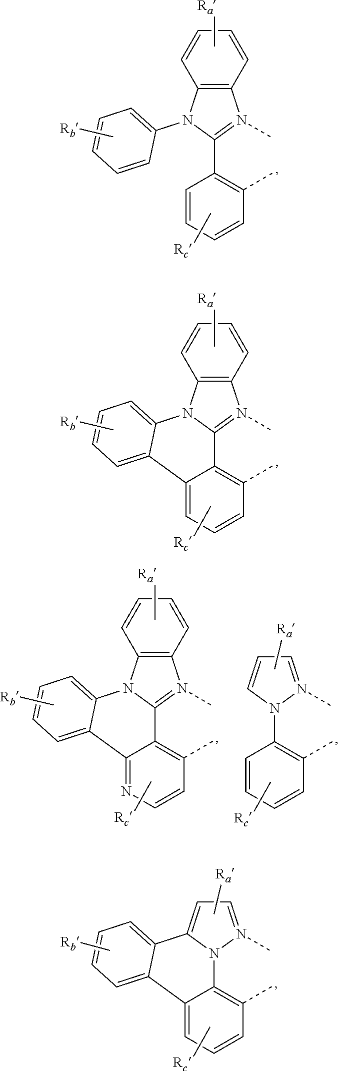

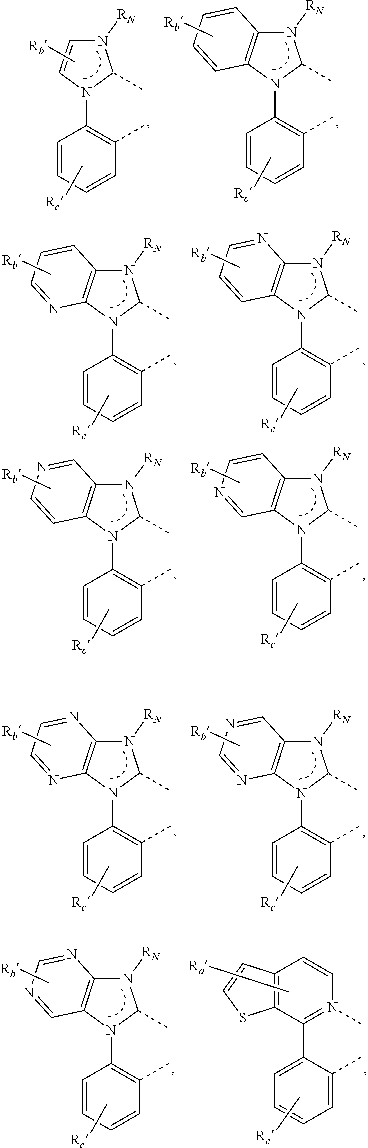

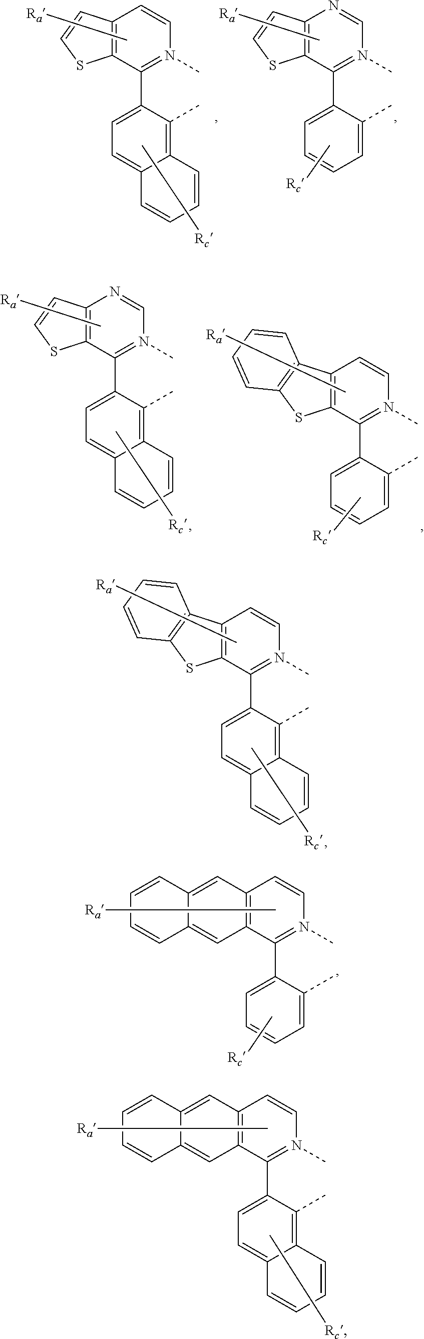

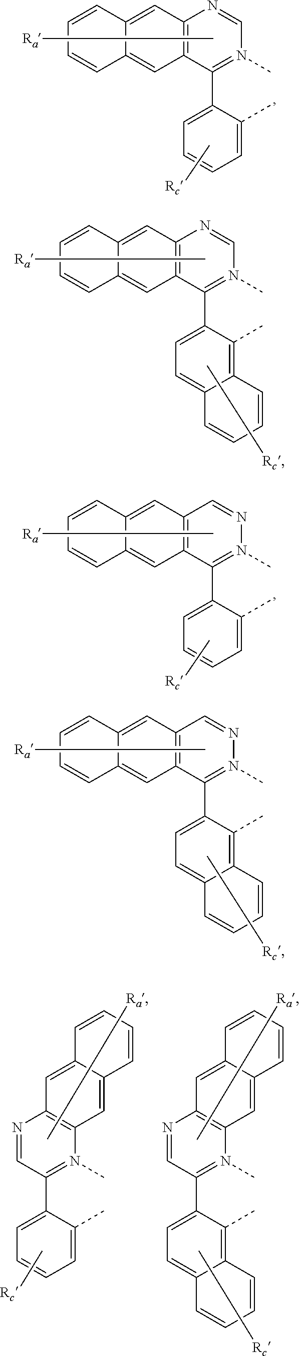

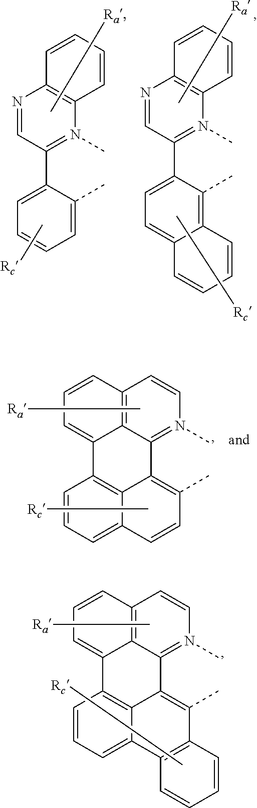

wherein:
Rₐ′, R_{b}′, and R_{c}′ each independently represent zero, mono, or up to a maximum allowed number of substitutions to its associated ring;
each of R_{N}, Rₐ′, R_{b}′, and R_{c}′ is independently hydrogen or a substituent selected from the group consisting of the Geneal Substituents defined herein; and
two adjacent Rₐ′, R_{b}′, and R_{c}′ can be fused or joined to form a ring or form a multidentate ligand, and
at least one of Rₐ′, R_{b}′, and R_{c}′ comprises trialkylsilyl group.

In some embodiments, ligand L_{B} is selected from the group consisting of the structures of the following LIST 5:

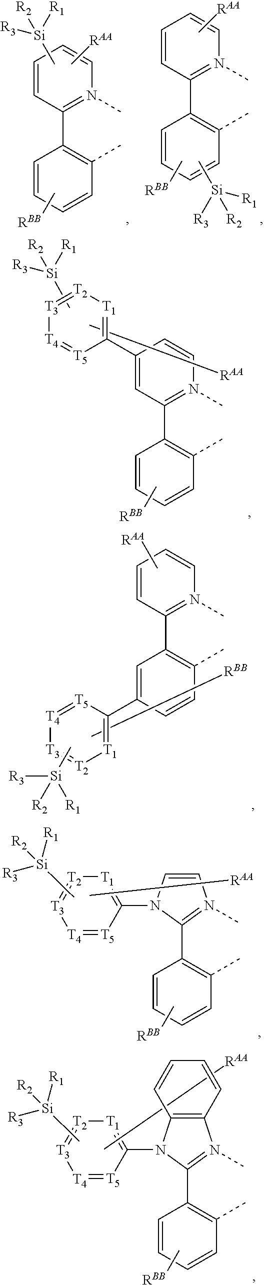

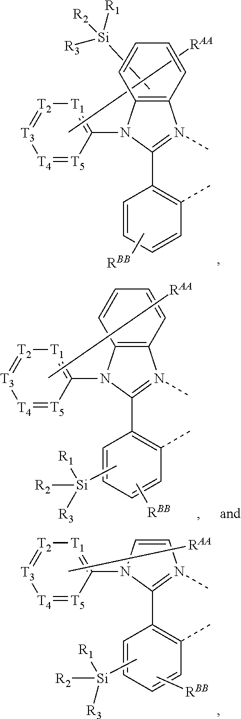

each R₁, R₂ and R₃ is independently a substituent selected from the group consisting of alkyl, cycloalkyl, heteroalkyl, arylalkyl, alkoxy, aryloxy, amino, silyl, boryl, germyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof;
T₁ to T₅ are each independently C or N;
each of R^{AA} and R^{BB} independently represents zero, mono, or up to a maximum allowed number of substitutions to its associated ring;
each R^{AA} and R^{BB} is independently hydrogen or a substituent selected from the group consisting of the General Substituents defined herein; and
any two substituents can be fused or joined to form a ring or form a multidentate ligand.

In some embodiments, each of T₁ to T₅ is C. In some embodiments, at least one of T₁ to T₅ is N. In some embodiments, exactly one of T₁ to T₅ is N.

In some embodiments, each of R¹ to R³ is alkyl or aryl. In some embodiments, each of R¹ to R³ is alkyl. In some embodiments, each of R¹ to R³ is methyl. In some embodiments, each of R¹ to R³ is aryl. In some embodiments, each of R¹ to R³ is phenyl.

In some embodiments, the ligand L_{B} is selected from the group consisting of L_{Bk}, where k is an integer from 1 to 176, and each L_{Bk} is defined in the following LIST 6:

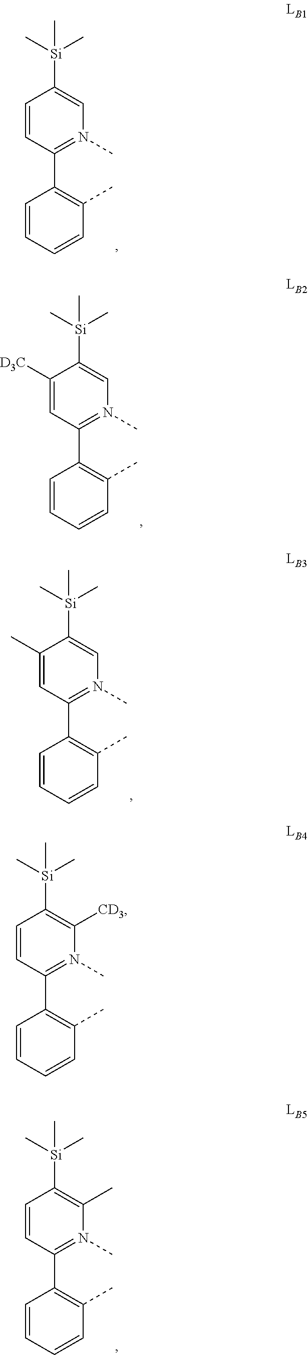

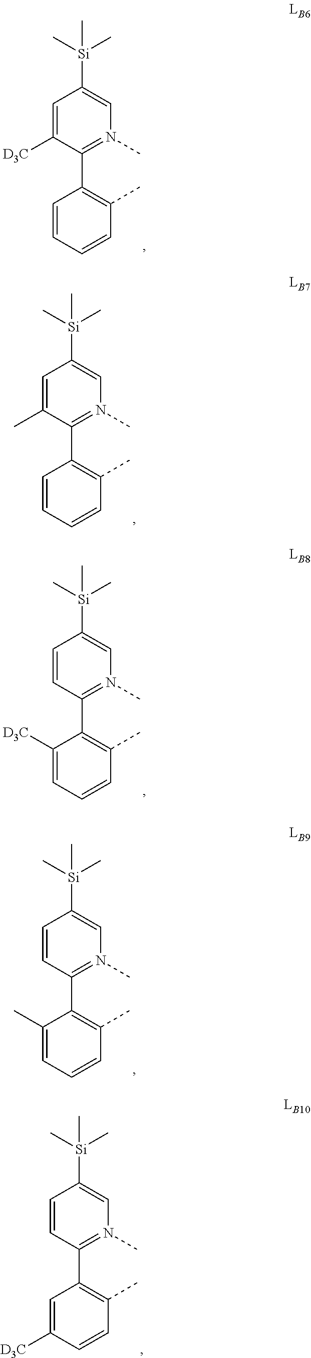

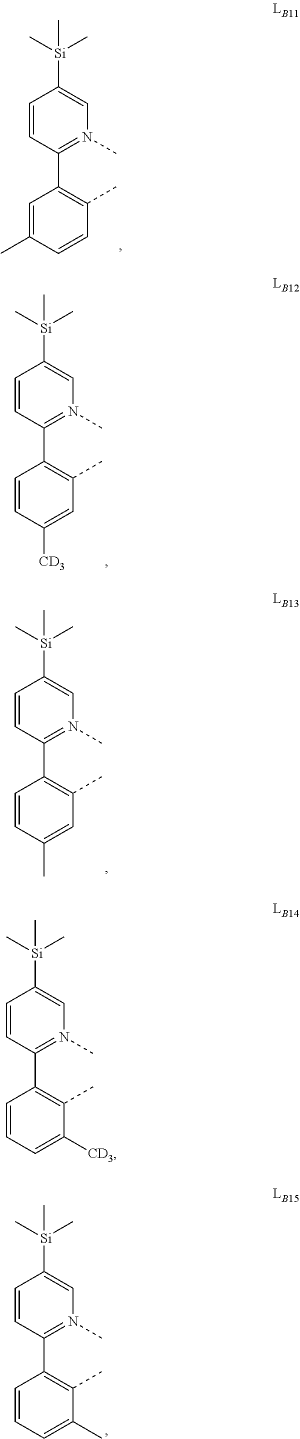

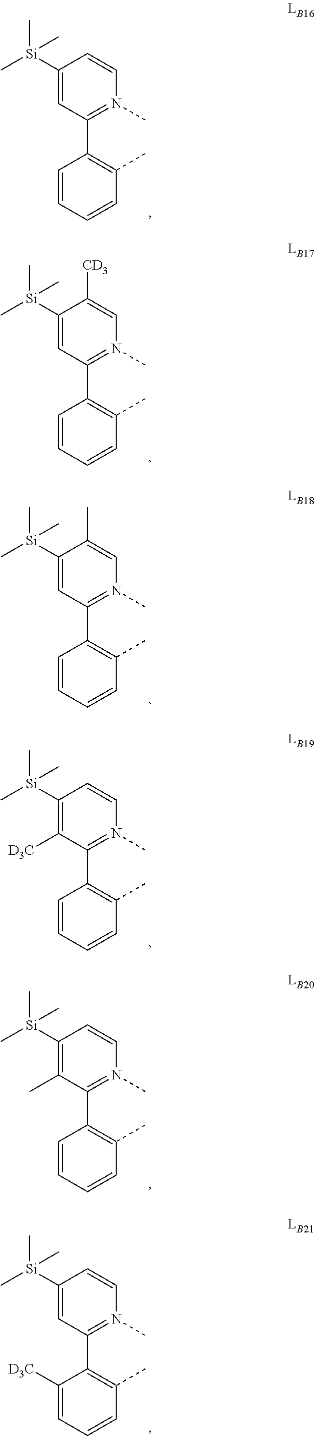

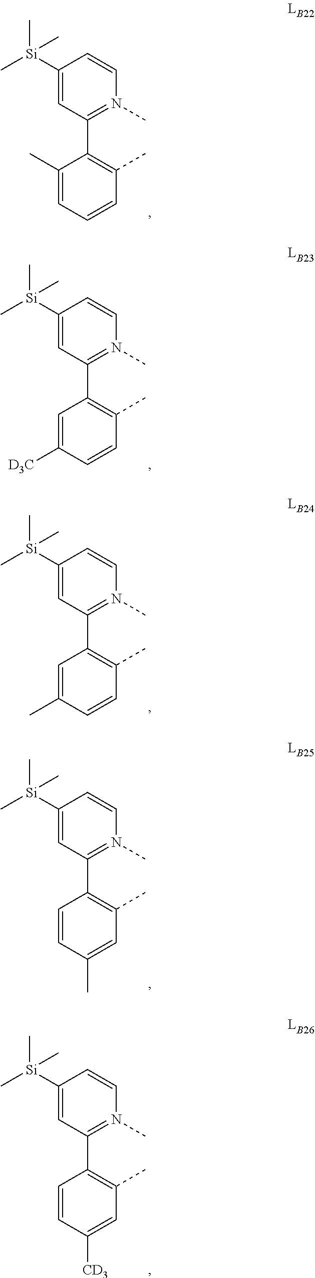

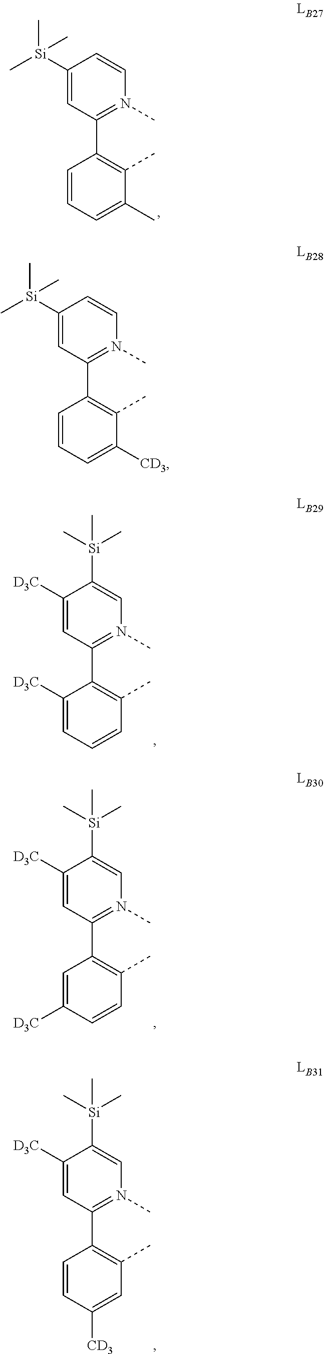

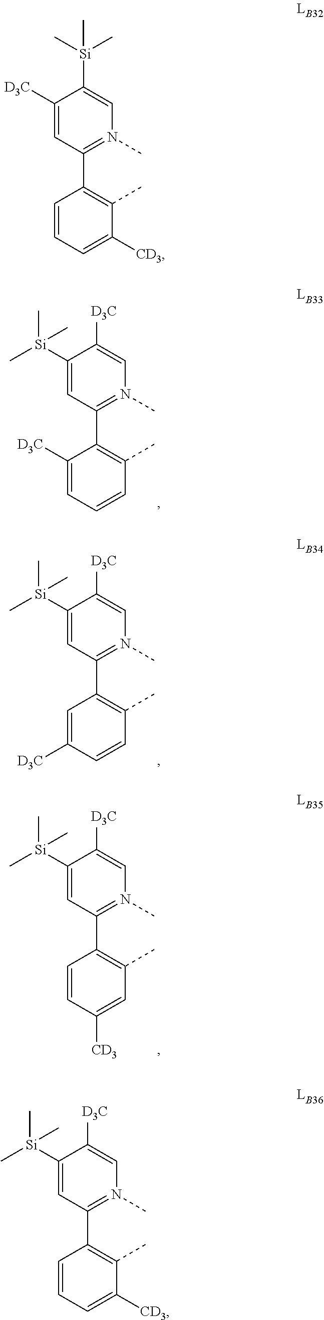

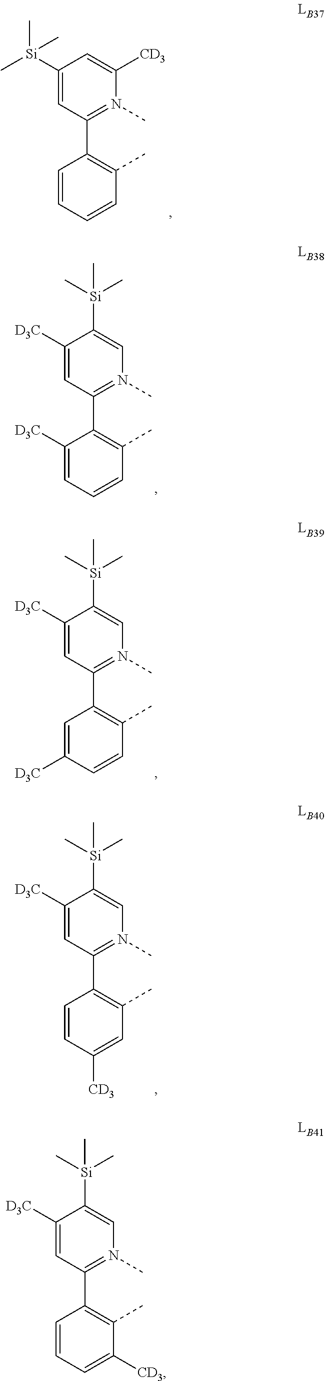

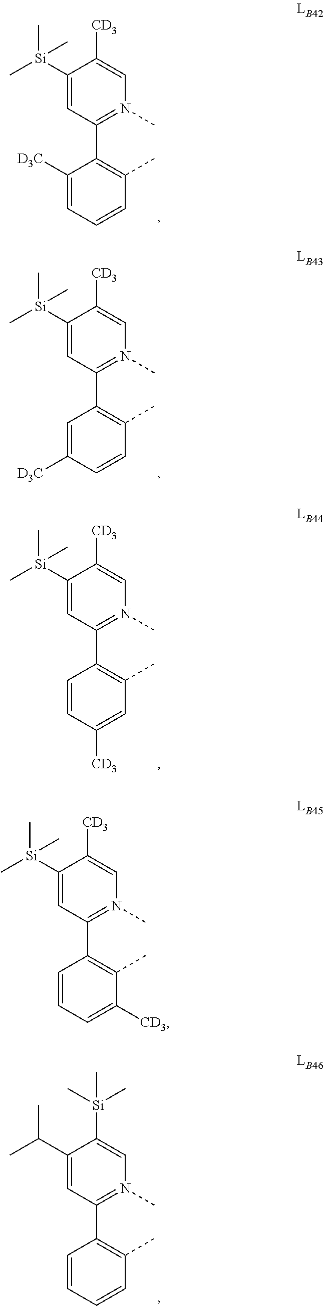

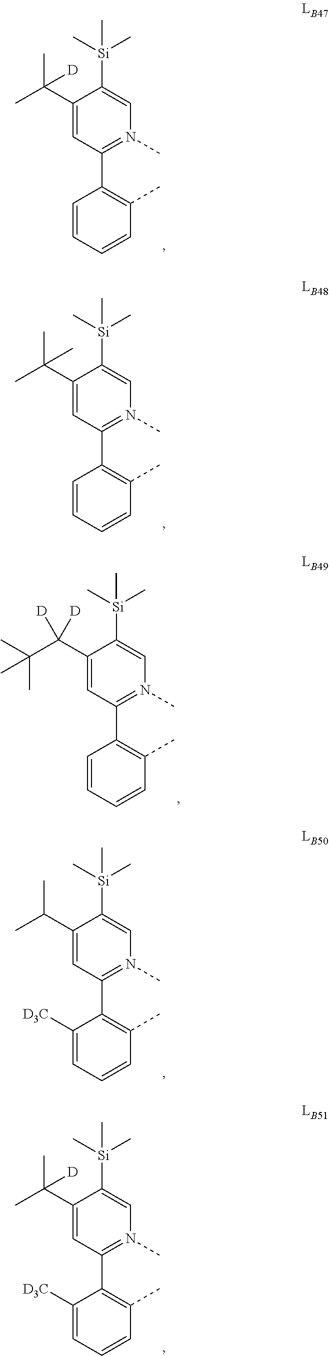

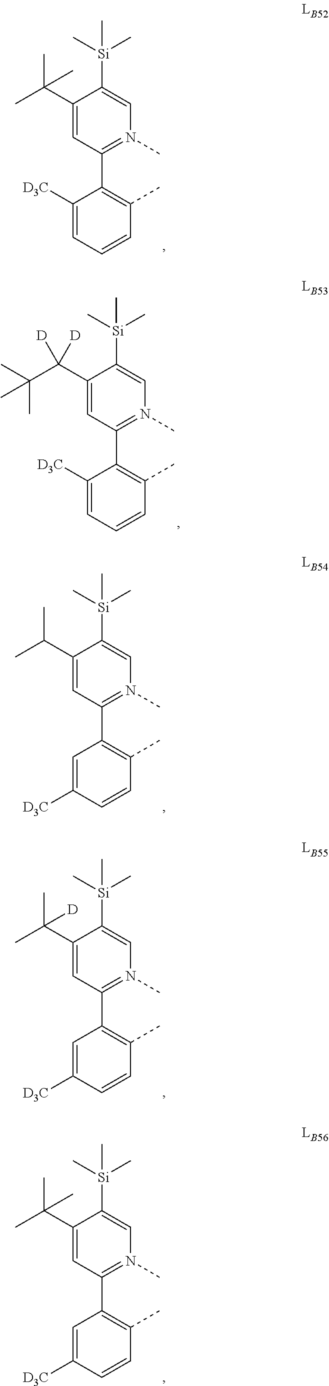

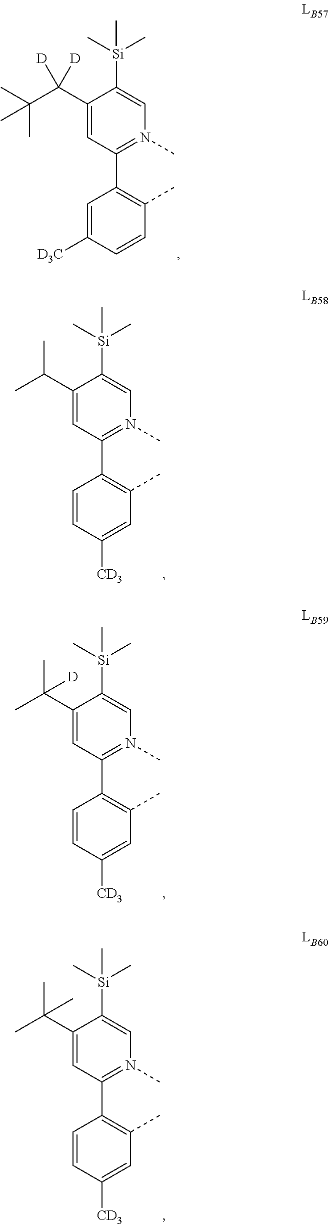

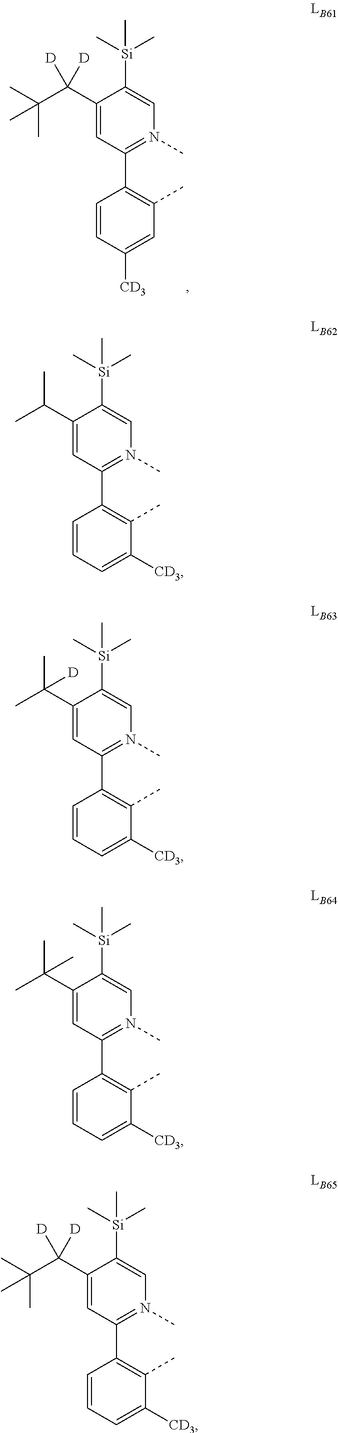

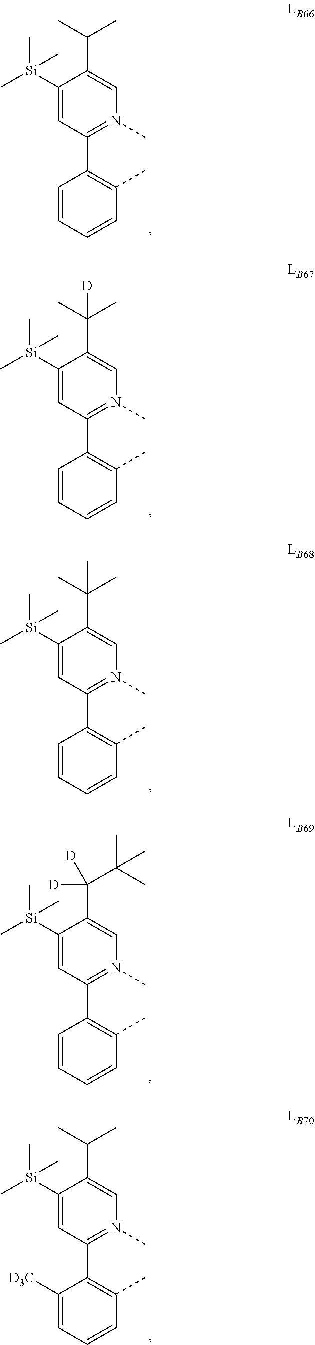

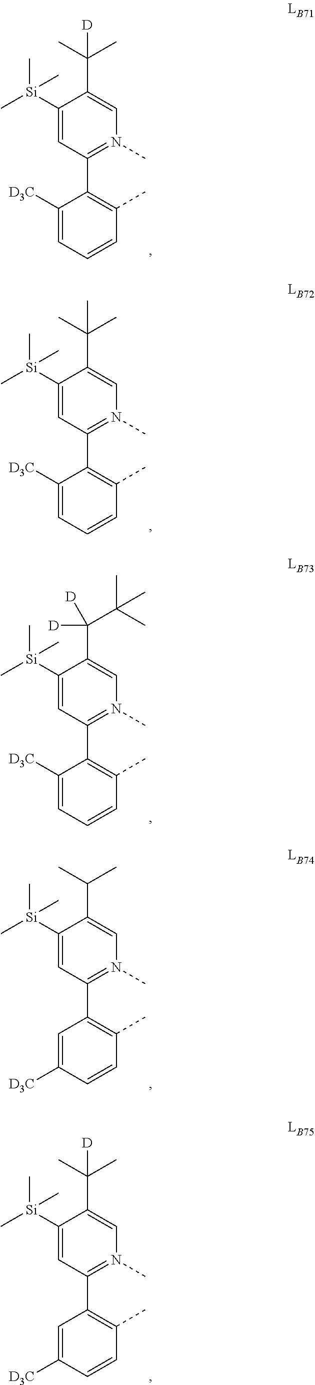

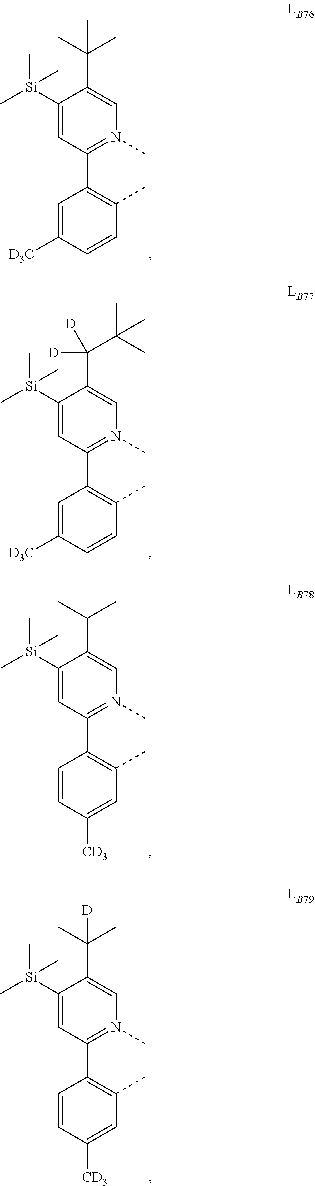

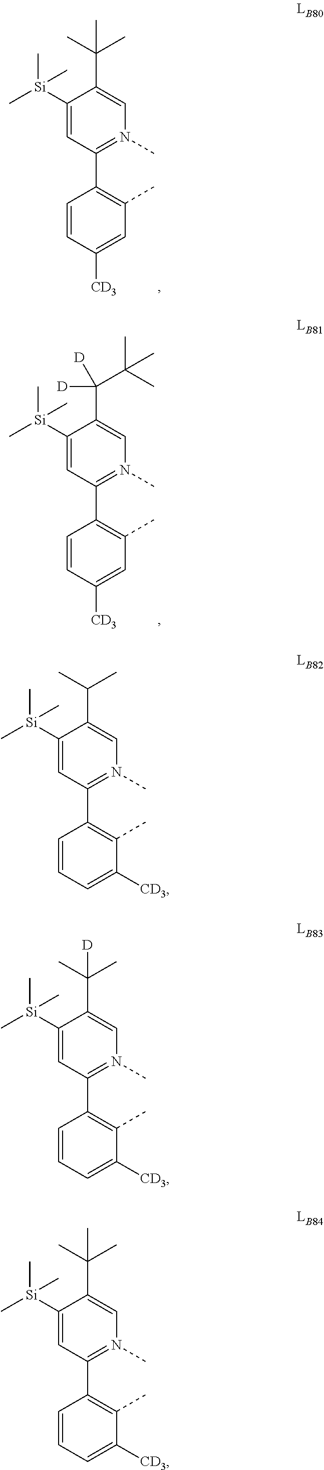

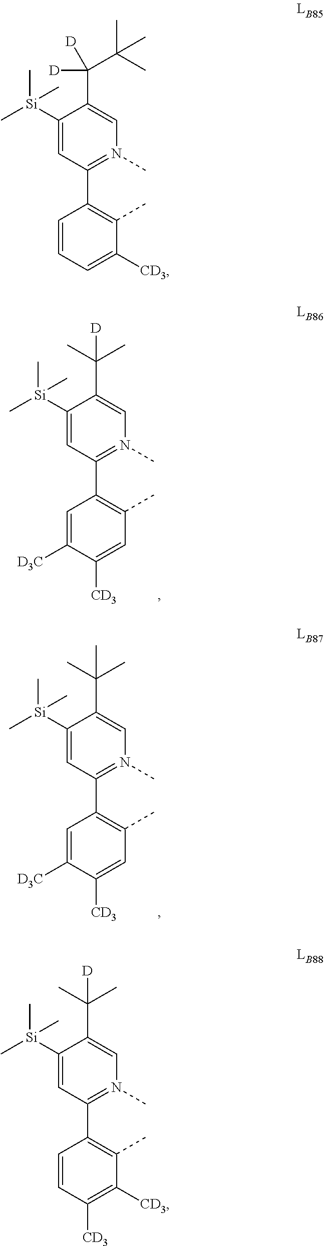

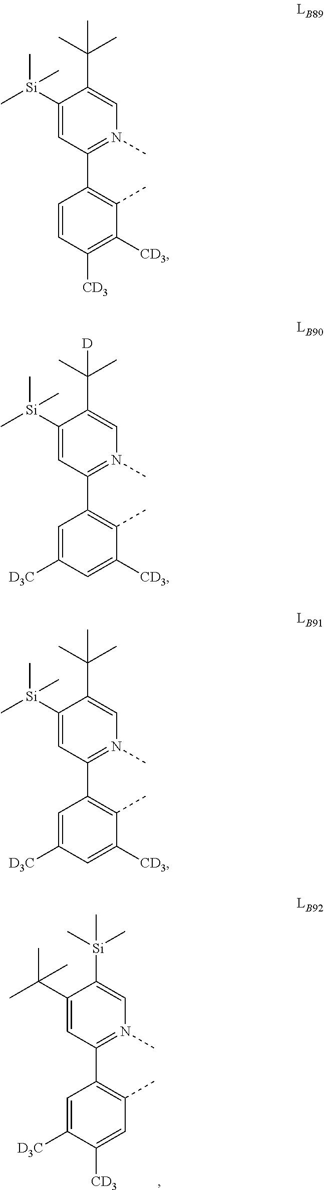

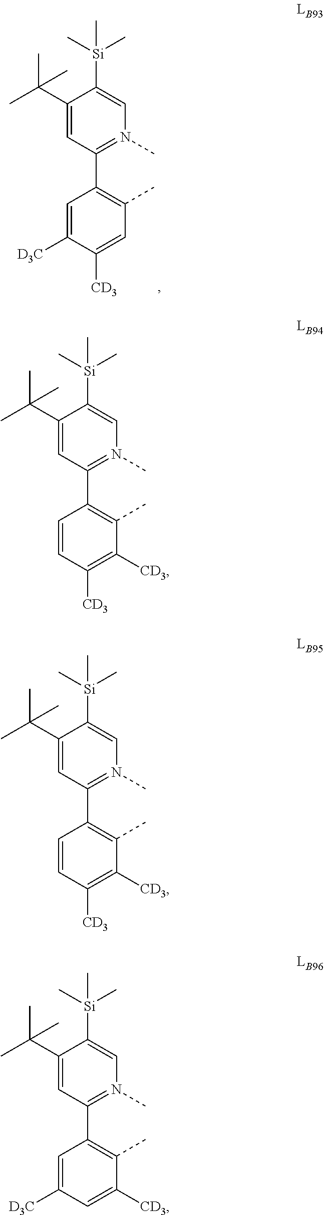

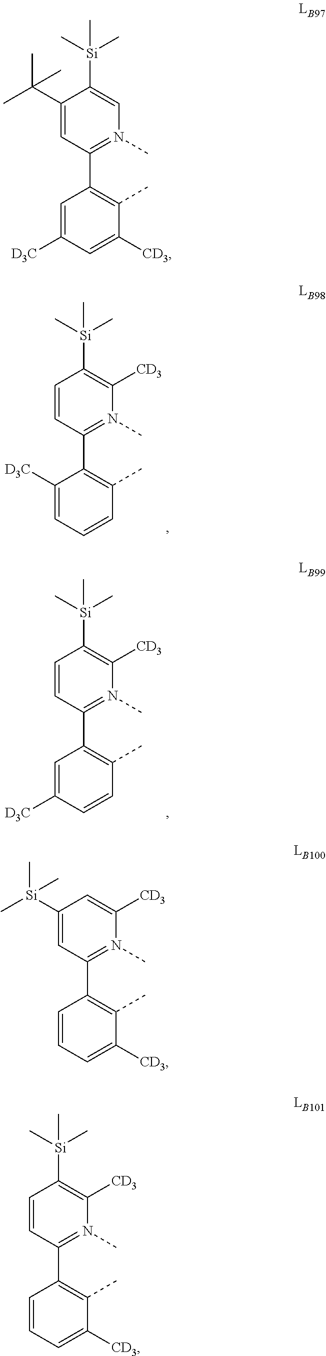

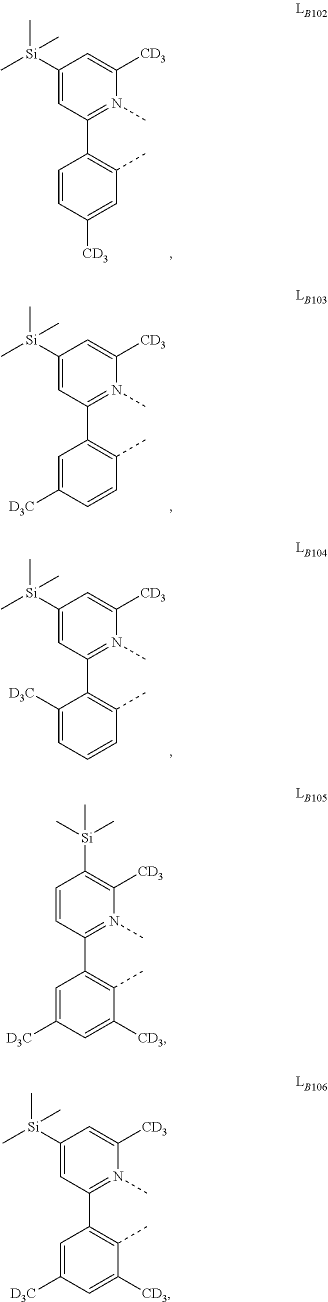

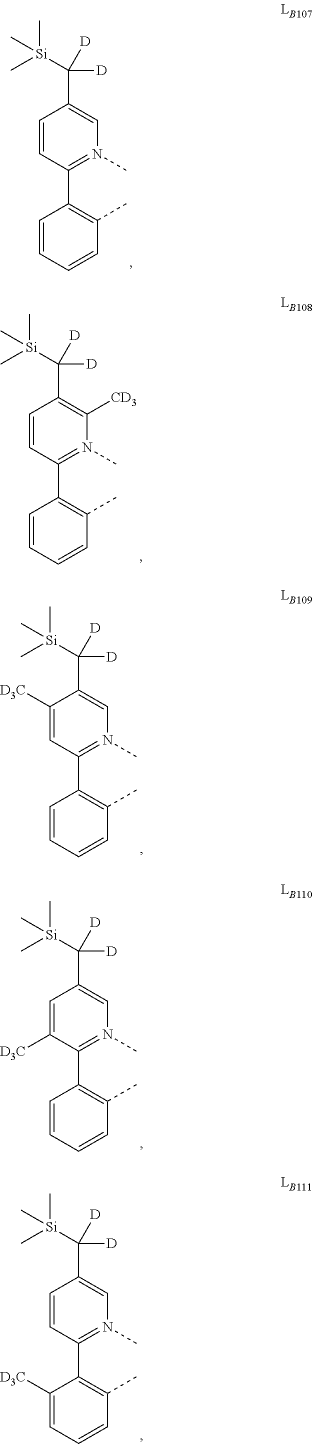

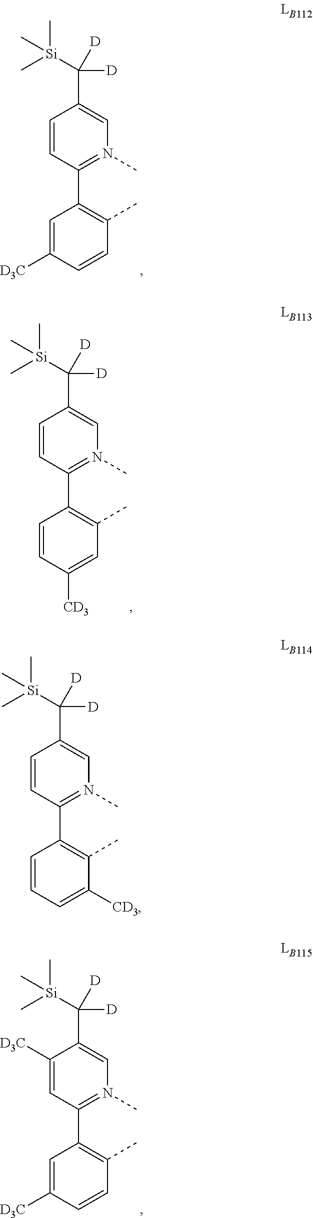

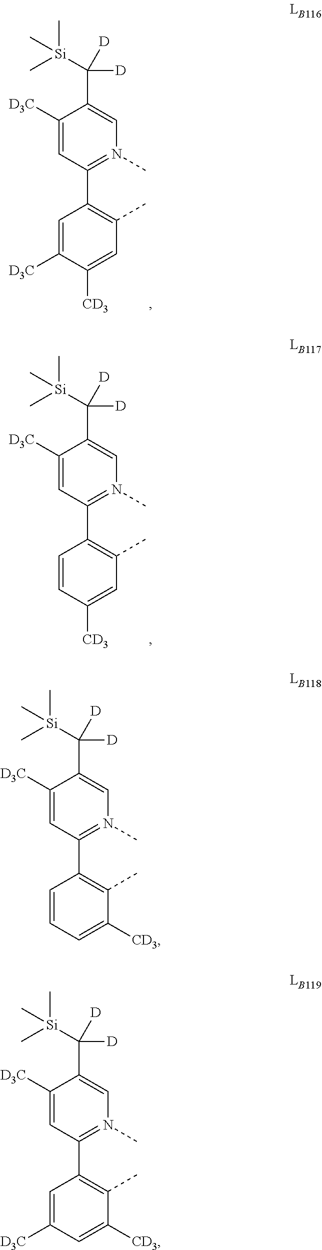

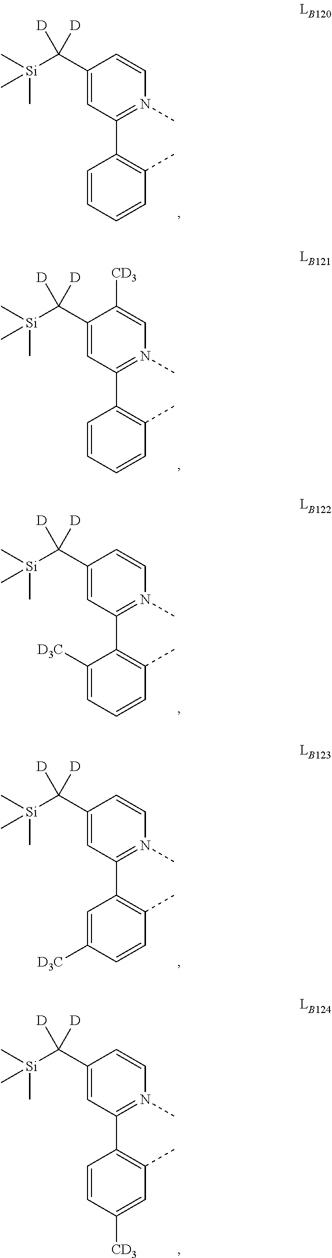

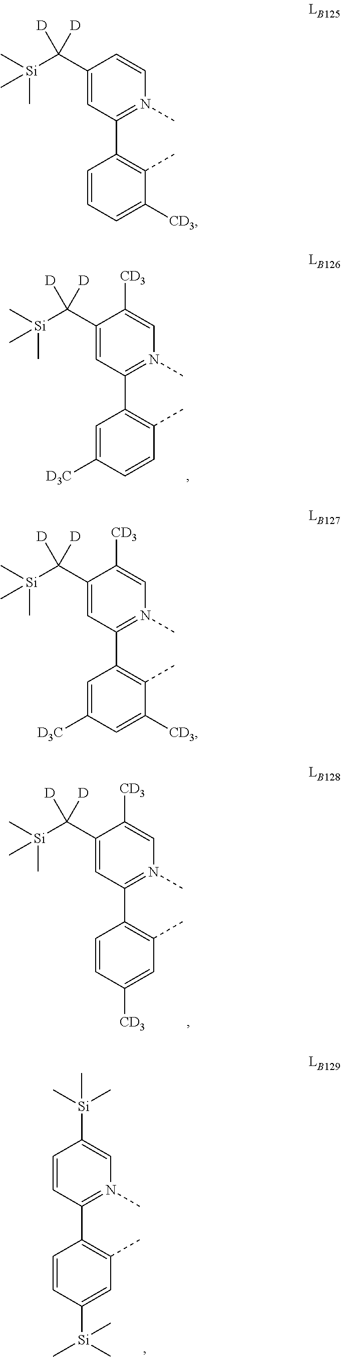

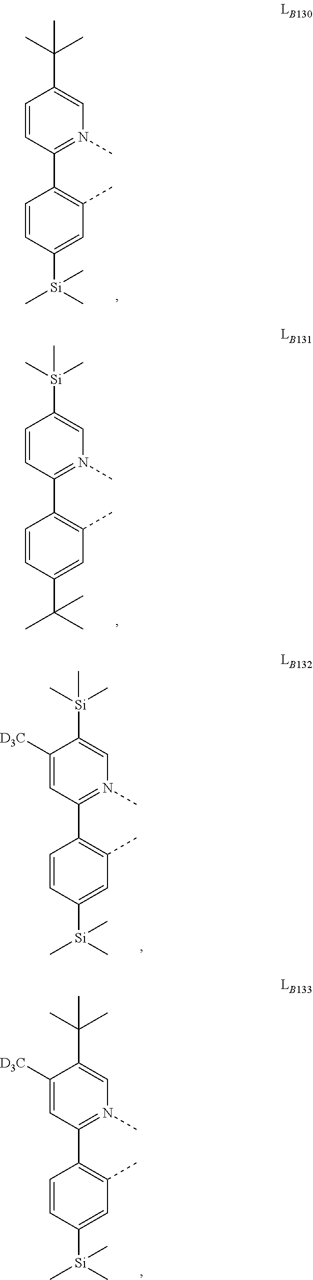

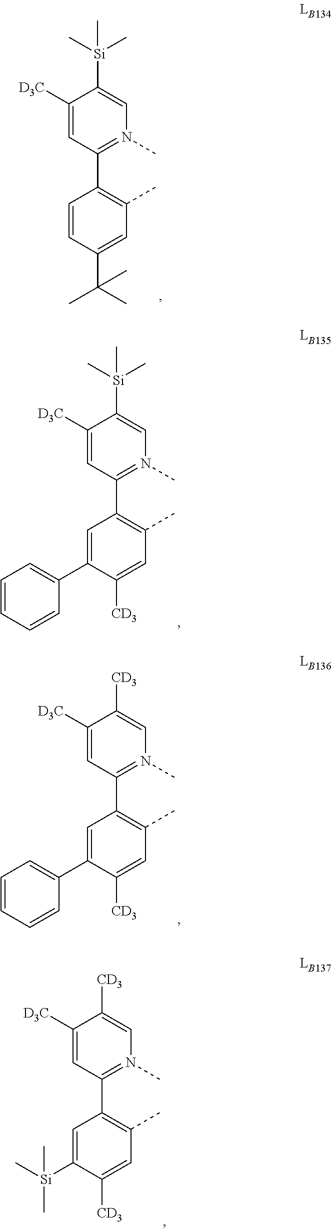

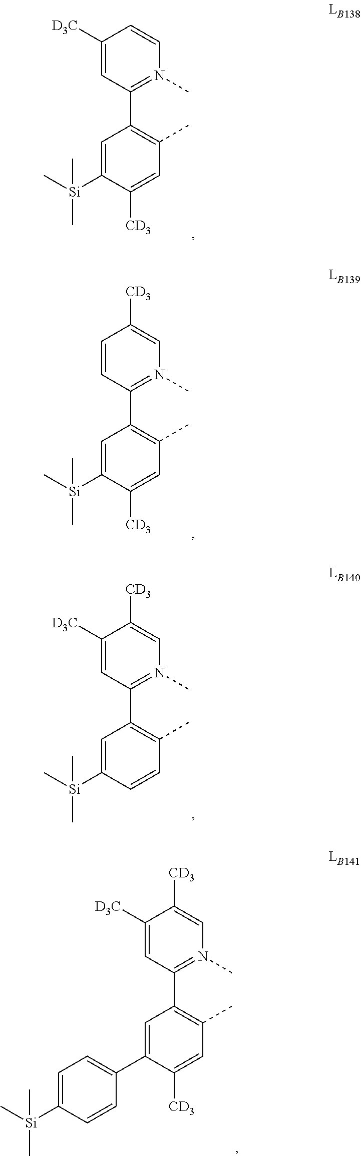

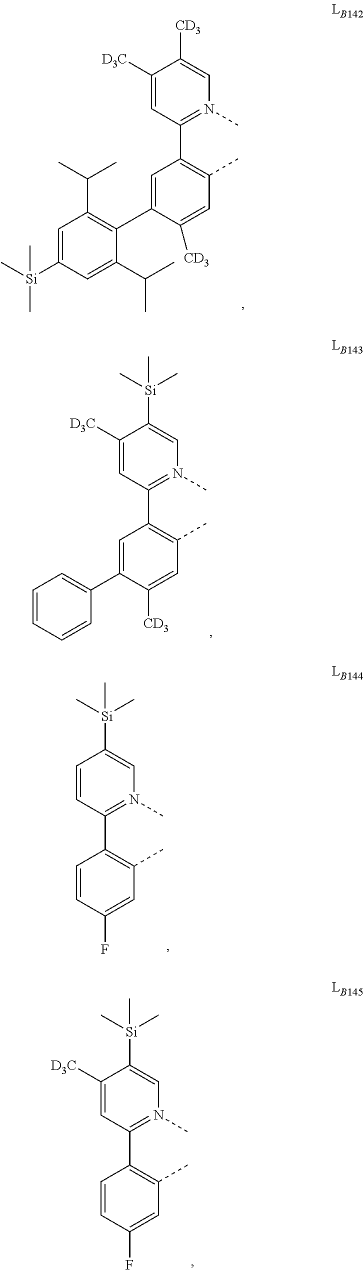

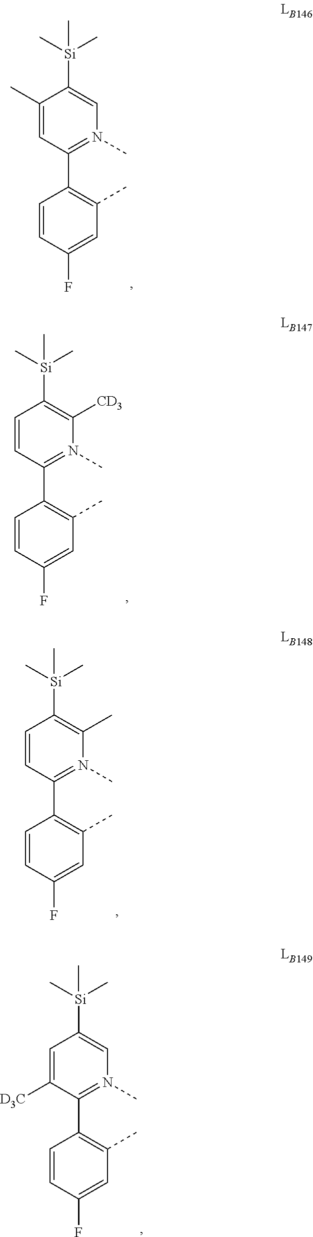

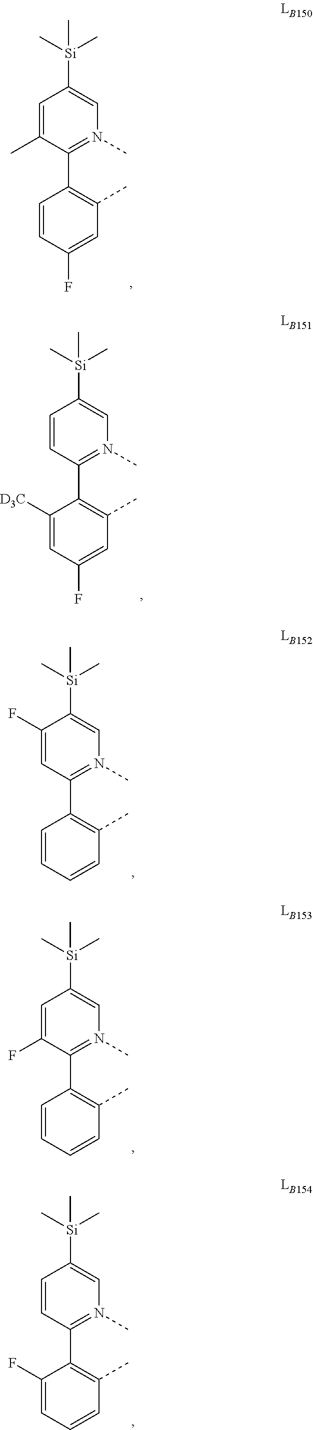

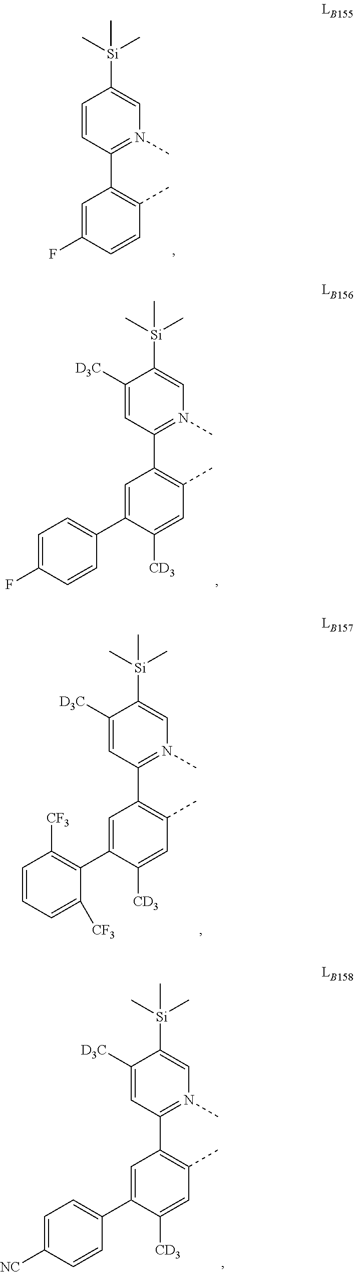

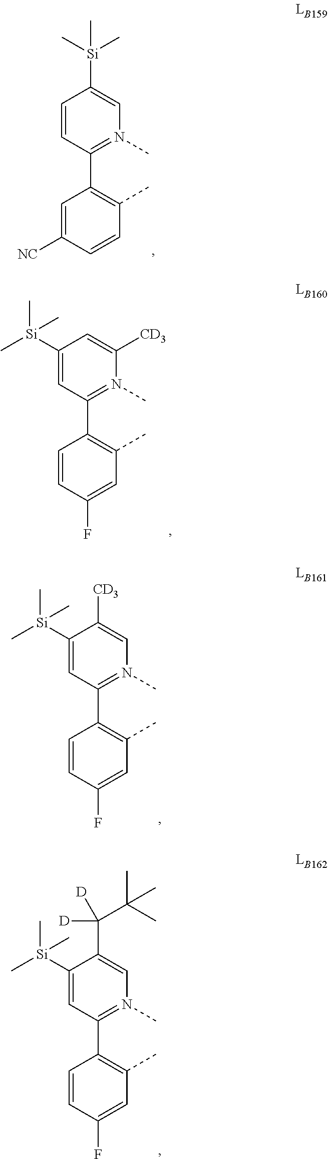

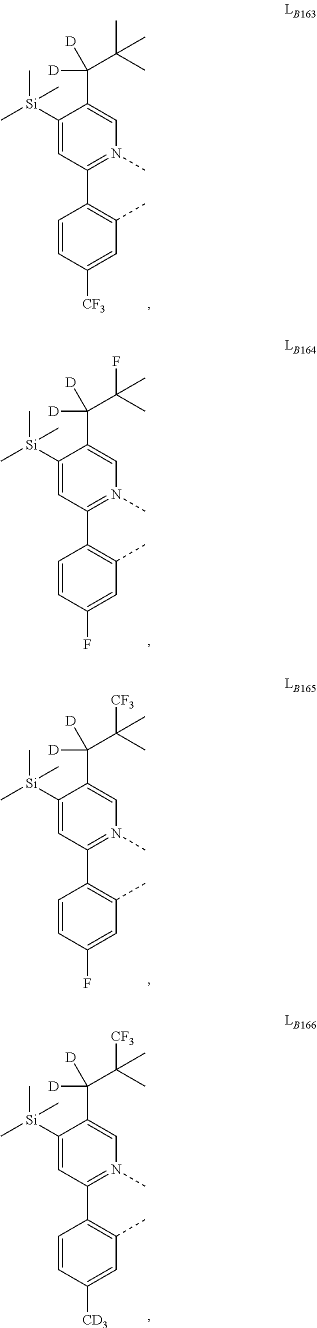

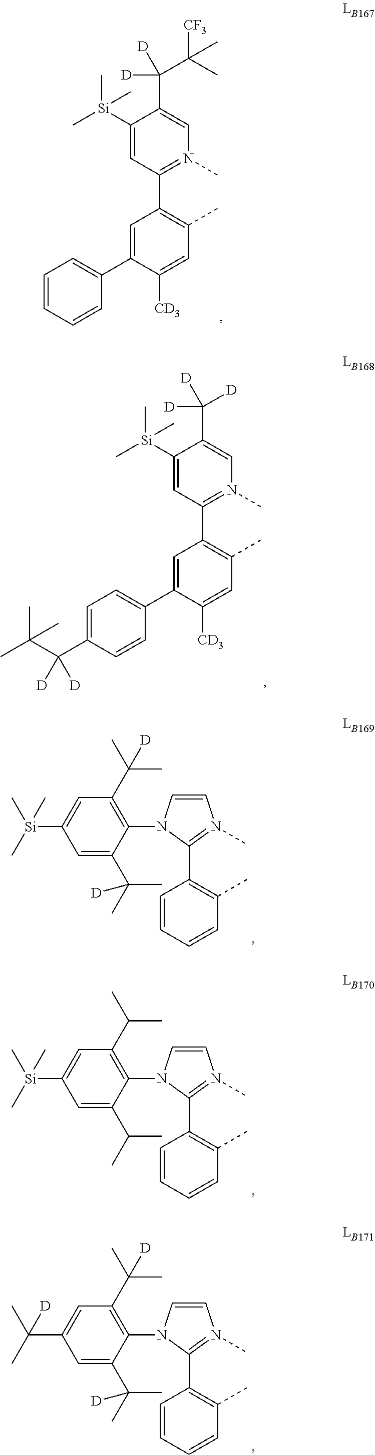

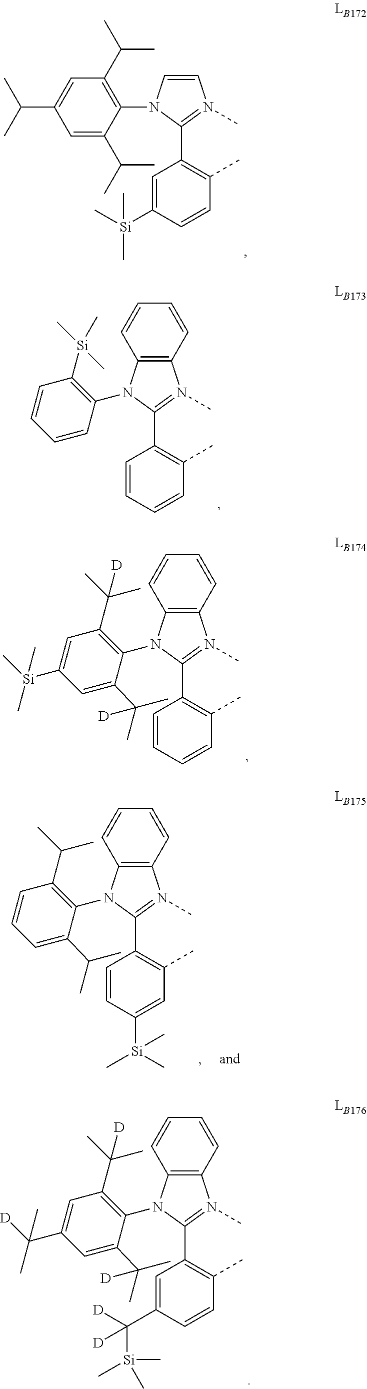

In some embodiments, L_{A} can be selected from L_{Ai}, wherein i is an integer from 1 to 143; and L_{B} can be selected from L_{Bk}, wherein k is an integer from 1 to 176, wherein:
when the compound has formula Ir(L_{Ai})(L_{Bk})₂, the compound is selected from the group consisting of Ir(L_{A1}(L_{B1})₂ to Ir(L_{A143})(L_{B176})₂; and when the compound has formula Ir(L_{Ai})₂(L_{Bk}), the compound is selected from the group consisting of Ir(L_{A1})₂(L_{B1}) to Ir(L_{A143})₂(L_{B176}).

In some embodiments, L_{A} is selected from the group consisting of the structures of LIST 1, LIST 2, LIST 3a, and LIST 3, and L_{B} is selected from the group consisting of the structures of LIST 4, LIST 5, and LIST 6. In some embodiments, L_{A} is selected from the group consisting of the structures of LIST 1 and L_{B} is selected from the group consisting of the structures of LIST 6. In some embodiments, L_{A} is selected from the group consisting of the structures of LIST 2 and L_{B} is selected from the group consisting of the structures of LIST 6. In some embodiments, L_{A} is selected from the group consisting of the structures of LIST 3a defined herein, and L_{B} is selected from the group consisting of the structures of LIST 6 (L_{B1} to L_{B176}) defined herein. In some embodiments, L_{A} is selected from the group consisting of the structures of LIST 3 (L_{A1} to L_{A143}) defined herein, and L_{B} is selected from the group consisting of the structures of LIST 6 (L_{B1} to L_{B176}) defined herein.

In some embodiments, the compound can be Ir(L_{A})₂(L_{B}), or Ir(L_{A})(L_{B})₂. In some of these embodiments, L_{A} can have a Formula I as defined herein. In some of these embodiments, L_{B} can have a Formula II as defined herein.

In some of these embodiments, L_{A} can be selected from the group consisting of the structures of LIST 1, LIST 2, and LIST 3 as defined herein. In some of these embodiments, L_{B} can be selected from the group consisting of the structures of LIST 4, LIST 5, and LIST 6 as defined herein. In some of these embodiments, the compound can be Ir(L_{Ai})₂(L_{B}), Ir(L_{Aw}(Rk)(Rl)(Rm)(Rn)(T)(Z))₂(L_{B}), Ir(L_{Ai})(L_{B})₂, Ir(L_{Aw}(Rk)(Rl)(Rm)(Rn)(T)(Z))(L_{B})₂, Ir(L_{A})₂(L_{Bk}), Ir(L_{A})(L_{Bk})₂, Ir(L_{Ai})₂(L_{Bk}) consisting of the compounds of Ir(L_{A1})₂(L_{B1}) to Ir(L_{A143})₂(L_{B176}), Ir(L_{Aw}(Rk)(Rl)(Rm)(Rn)(T)(Z))₂(L_{Bk}) consisting of the compounds of Ir(L_{A1}(R1)(R1)(R1)(R30)(T1)(Z1))₂(L_{B1}) to Ir(L_{A60}(R115)(R115)(R115)(R115)(T10)(Z6))₂(L_{B176}), Ir(L_{Aw}(Rk)(Rl)(Rm)(Rn)(T)(Z))(L_{Bk})₂ consisting of the compounds of Ir(L_{A1}(R1)(R1)(R1)(R30)(T1)(Z1))(L_{B1})₂ to Ir(L_{A60}(R115)(R115)(R115)(R115)(T10)(Z6))(L_{B176})₂, or Ir(L_{Ai})(L_{Bk})₂ consisting of the compounds of Ir(L_{A1})(L_{B1})₂ to Ir(L_{A143})(L_{B176})₂.

In some embodiments, the compound is selected from the group consisting of the structures of the

1. A compound having a formula of Ir(L_{A})ₚ(L_{B})_{q}(L_{C})ᵣ, wherein L_{A} has a structure of Formula IA: 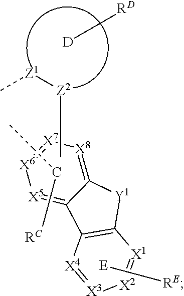
L_{B} has a structure of Formula IB; 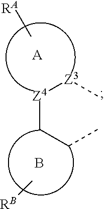
and L_{C} is a bidentate ligand; and wherein:
p is 1, 2, or 3; q is 0, 1, or 2; r is 0, 1, or 2; and p+q+r=3;
each of moiety A, moiety B, and moiety D is independently a monocyclic ring or a polycyclic fused ring system, wherein the monocyclic ring or each ring of the polycyclic fused ring system is independently a 5-membered or 6-membered carbocyclic or heterocyclic ring;
Z¹, Z², Z³, and Z⁴ are each independently C or N;
X¹, X², X³, X⁴, X⁵, X⁶, X⁷, and X⁸ are each independently C or N;
two adjacent R^{C} or two adjacent R^{E} are joined to form a structure of Formula II, 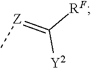
the dashed lines in Formula II represent bonds to two adjacent ones of X¹ to X⁸ that are C;
Y¹ and Y² are each independently selected from the group consisting of BR, NR, PR, P(O)R, O, S, Se, C═O, C═S, C═Se, C═NR′, C═CRR′ S═O, SO₂, CRR′, SiRR′, and GeRR′;
Z is CR^{Z} or N;
R^{A}, R^{B}, R^{C}, R^{D}, and R^{E} each independently represents mono to the maximum allowable substitution, or no substitution;
each R, R′, R^{A}, R^{B}, R^{C}, R^{D}, R^{E}, R^{F}, and R^{Z} is independently a hydrogen or a moiety selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
at least one of R^{A} or R^{B} comprises a silyl or germyl group; and
any two substituents may be joined or fused to form a ring.

2. The compound of claim 1, wherein the compound has a formula Ir(L_{B})ₘ(L_{A})ₙ, having a structure of Formula I, 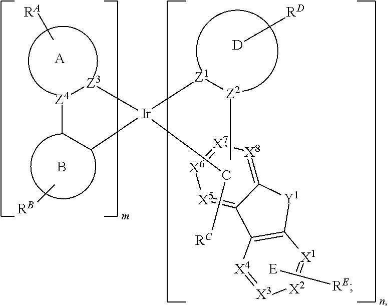
wherein:
m and n are each independently 1 or 2;
m+n=3;
when m is 2, each L_{B} can be the same or different;
each of moiety A, moiety B, and moiety D is independently a monocyclic ring or a polycyclic fused ring system, wherein the monocyclic ring or each ring of the polycyclic fused ring system is independently a 5-membered or 6-membered carbocyclic or heterocyclic ring;
Z¹, Z², Z³, and Z⁴ are each independently C or N;
X¹, X², X³, X⁴, X⁵, X⁶, X⁷, and X⁸ are each independently C or N;
two adjacent R^{C} or two adjacent R^{E} are joined to form a structure of Formula II, 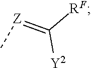
the dashed lines in Formula II represent bonds to two adjacent ones of X¹ to X⁸ that are C;
Y¹ and Y² are each independently selected from the group consisting of BR, NR, PR, P(O)R, O, S, Se, C═O, C═S, C═Se, C═NR′, C═CRR′ S═O, SO₂, CRR′, SiRR′, and GeRR′;
Z is CR^{Z} or N;
R^{A}, R^{B}, R^{C}, R^{D}, and R^{E} each independently represents mono to the maximum allowable substitution, or no substitution;
each R, R′, R^{A}, R^{B}, R^{C}, R^{D}, R^{E}, R^{F}, and R^{Z} is independently a hydrogen or a moiety selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
at least one of R^{A} or R^{B} comprises a silyl or gennyl group; and
any two substituents may be joined or fused to form a ring.

3. The compound of claim 1, wherein each R, R′, R^{A}, R^{B}, R^{C}, R^{D}, R^{E}, R^{F}, and R^{Z} is independently a hydrogen or a moiety selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

4. The compound of claim 1, wherein each of moiety A, moiety B, and moiety D is independently selected from the group consisting of benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

5. The compound of claim 1, wherein each of X¹ to X⁸ is C or wherein at least one of X¹ to X⁸ is N; and/or wherein Y¹ is selected from the group consisting of O, S, and Se; and/or wherein Z is N or CR^{Z}, and/or wherein Z is CR^{Z}, and R^{Z} is joined or fused to R^{F} to form a fused ring orfused ring system.

6. The compound of claim 1, wherein Formula II is bonded to X¹ and X², or to X² and X³, or to X³ and X⁴.

7. The compound of claim 1, wherein at least one R^{A} comprises a moiety selected from the group consisting of alkyl, silyl, partially or fully deuterated variants thereof, partially or fully fluorinated variants thereof, and combinations thereof; and/or wherein at least one R_{B} comprises a moiety selected from the group consisting of fluorine, CN, aryl, alkyl, partially or fully deuterated variants thereof, partially or fully fluorinated variants thereof, and combinations thereof; and/or wherein at least one R^{D} comprises a moiety selected from the group consisting of aryl, alkyl, cycloalkyl, silyl, heteroaryl, partially or fully deuterated variants thereof, and combinations thereof.

8. The compound of claim 1, wherein R^{F} is selected from the group consisting of aryl, alkyl, cycloalkyl, silyl, heteroaryl, partially or fully deuterated variants thereof, partially or fully fluorinated variants thereof, and combinations thereof.

9. The compound of claim 1, wherein the ligand L_{A} is selected from the group consisting of: 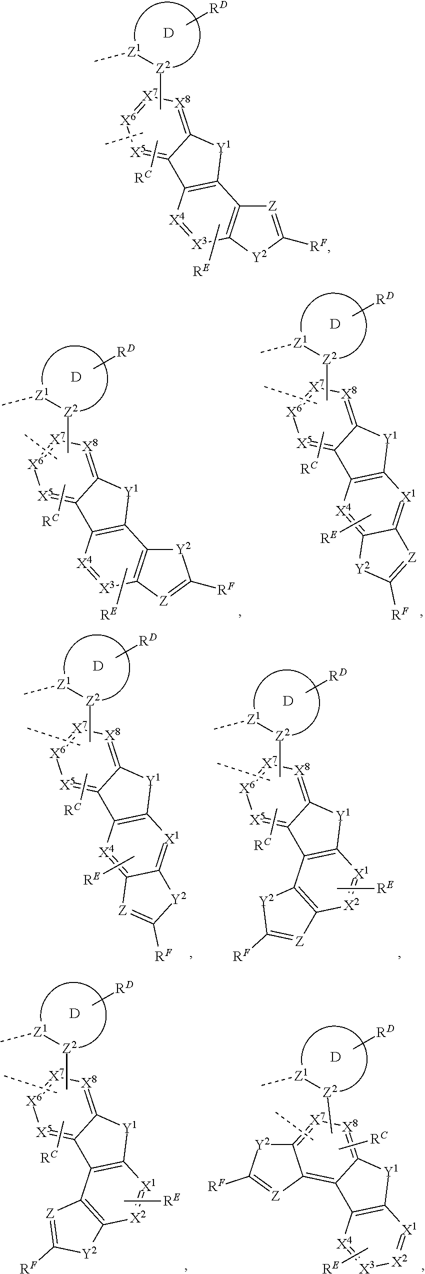 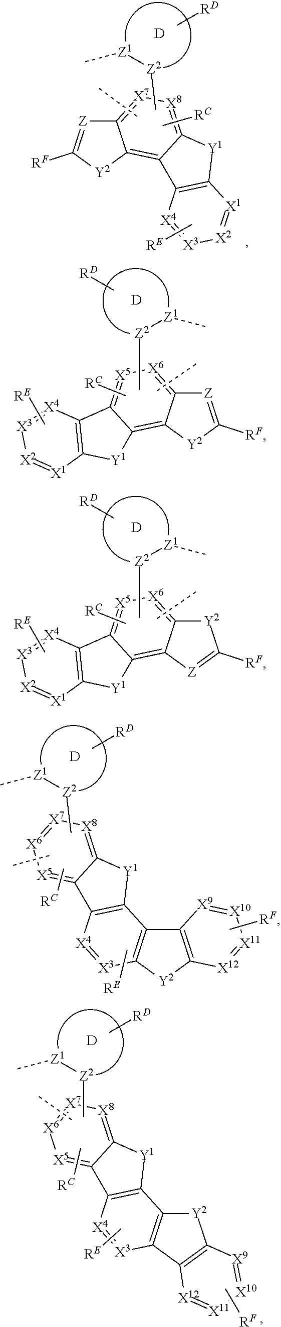 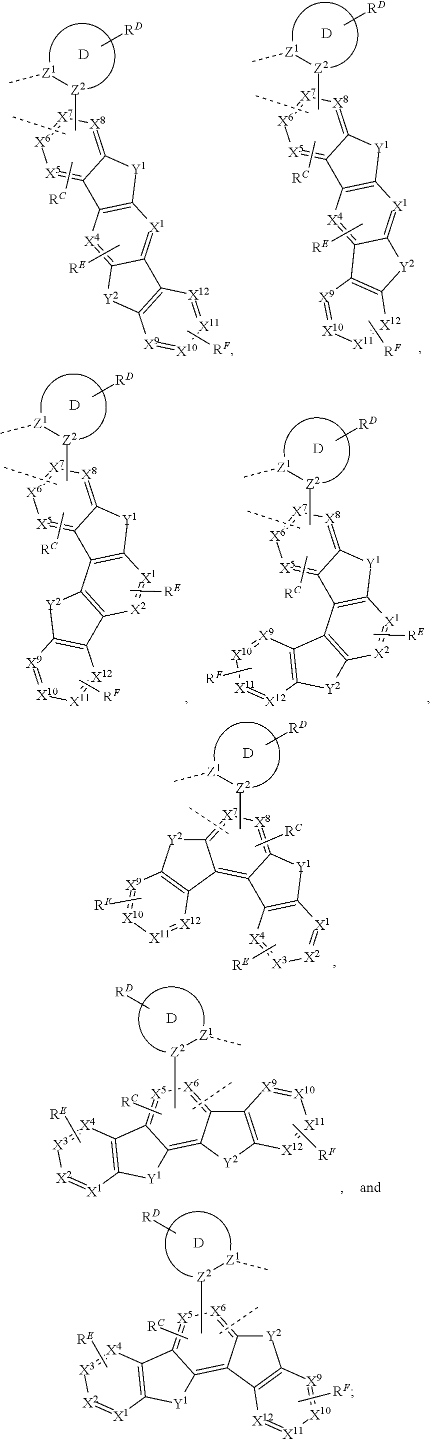
and
wherein each of X⁹ to X¹² is independently C or N.

10. The compound of claim 1, wherein the ligand L_{A} is selected from the group consisting of: 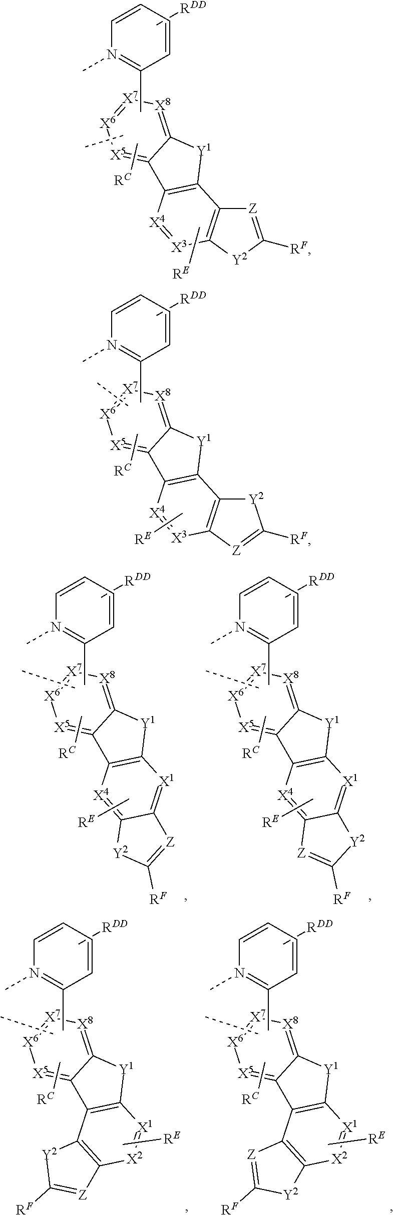 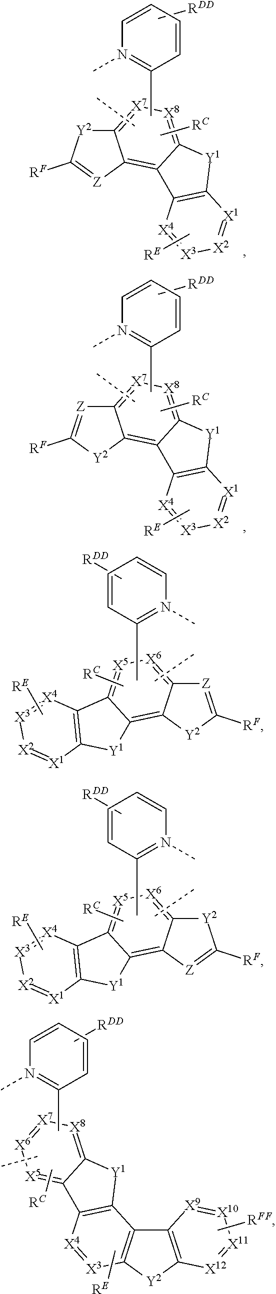 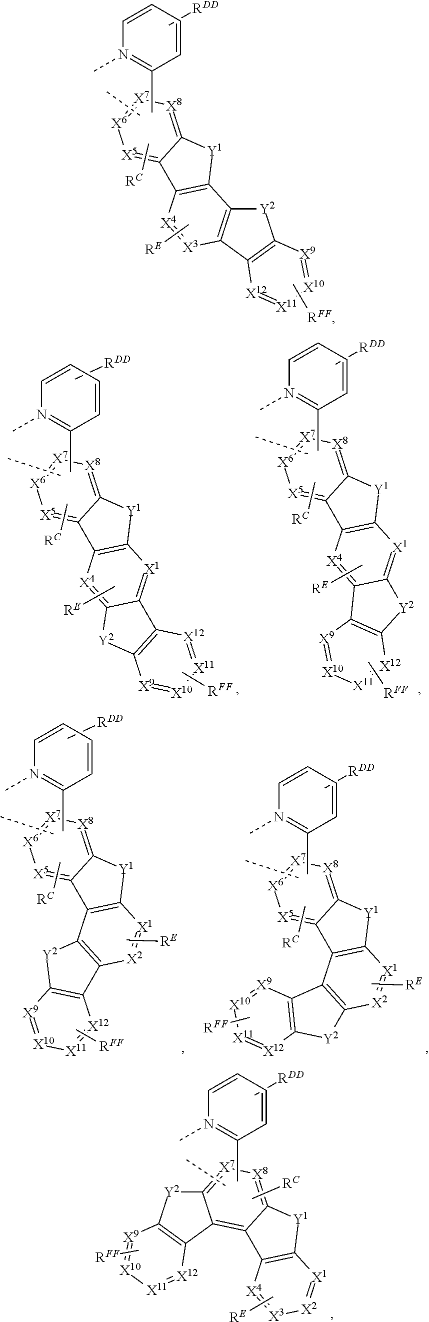 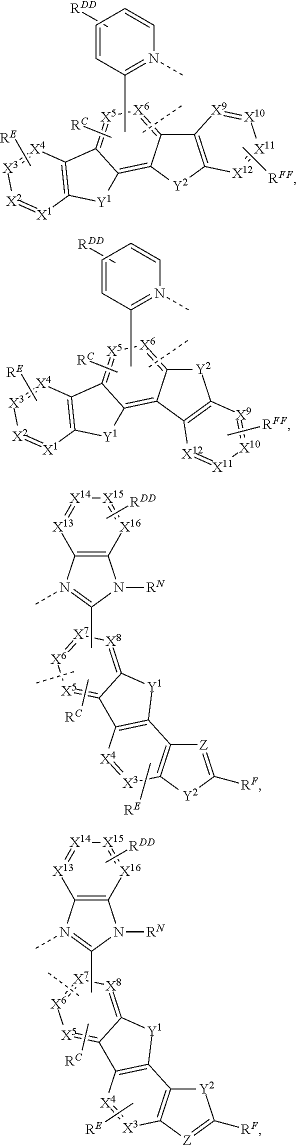 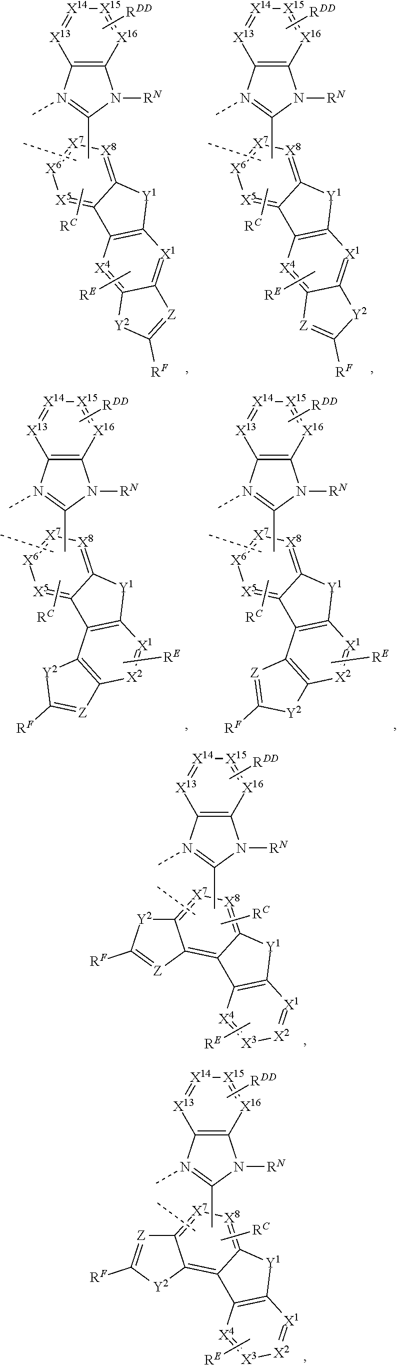 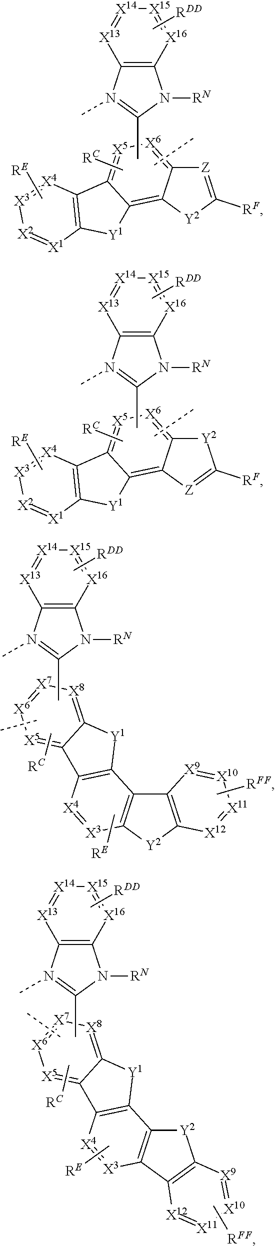 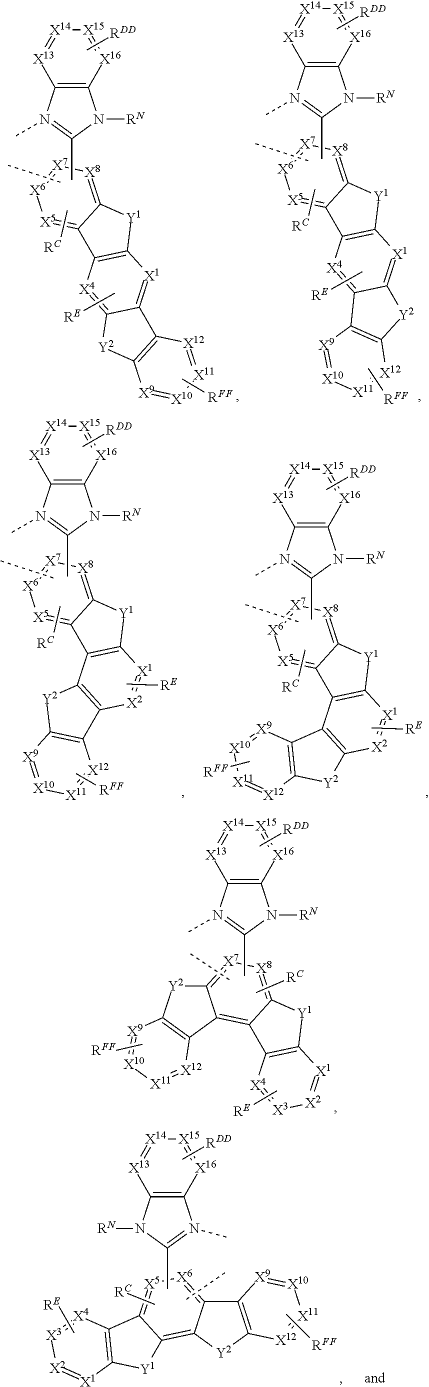 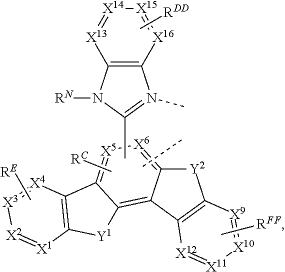
wherein:
each of X⁹ to X¹⁶ is independently C or N;
each of R^{DD} and R^{FF} independently represents mono to the maximum allowable substitutions, or no substitutions;
each R^{N}, R^{DD}, and R^{FF} is independently a hydrogen or a moiety selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents can be joined or fused to form a ring.

11. The compound of claim 1, wherein the ligand L_{A} is L_{Ai}, and i is an integer from 1 to 143, and each L_{Ai} is defined as follows:

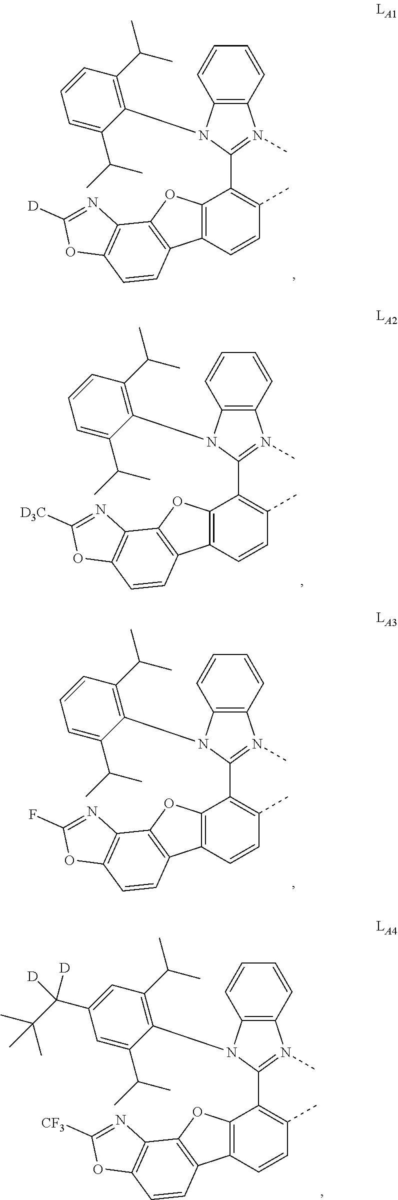

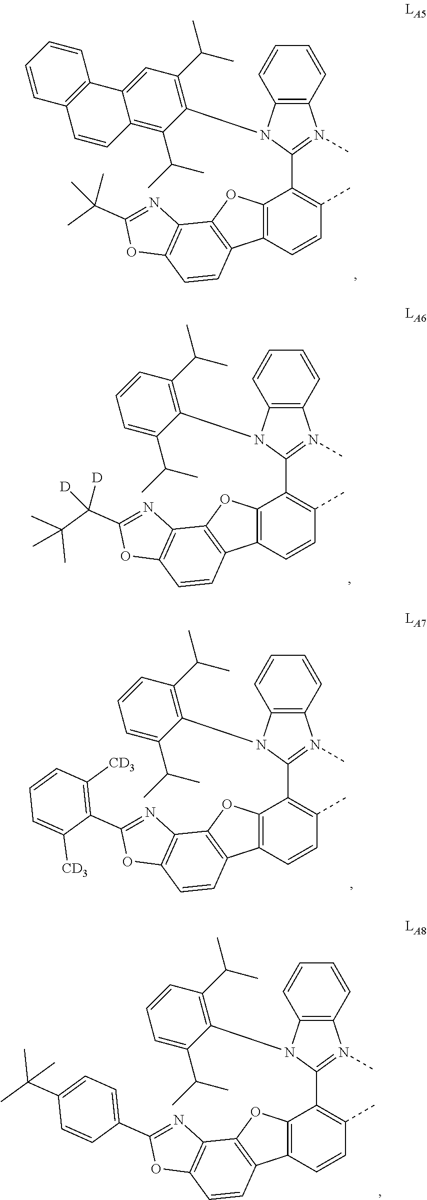

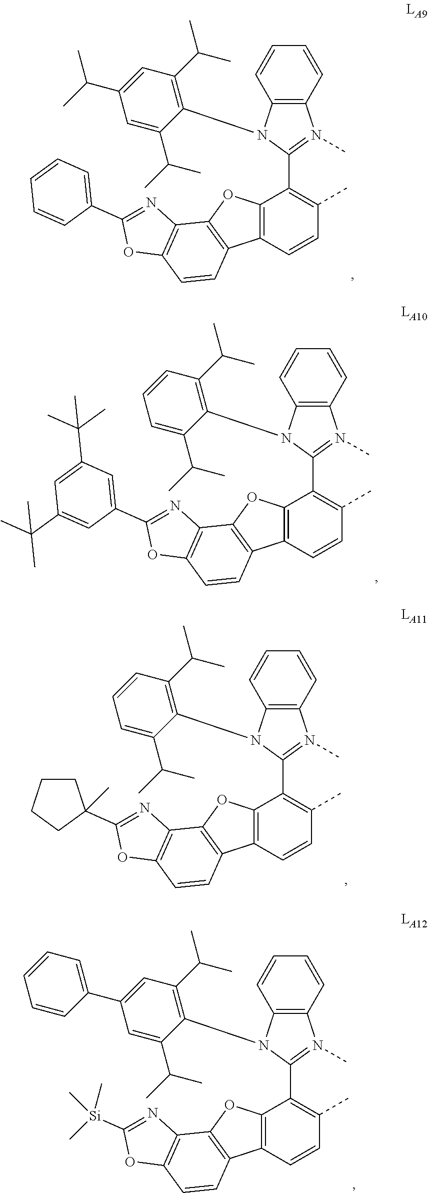

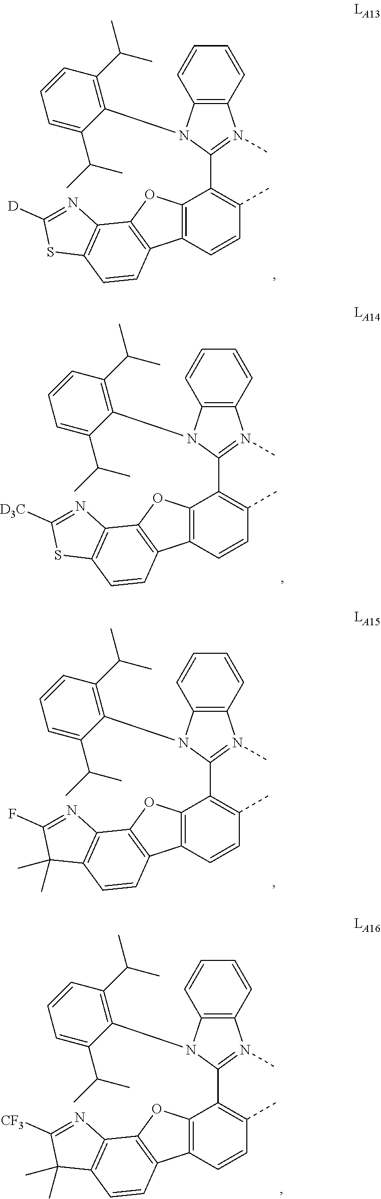

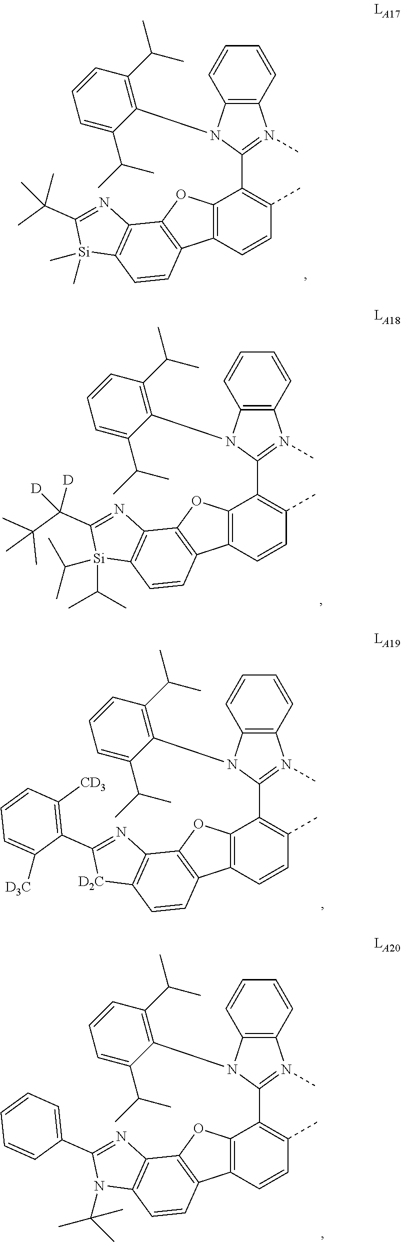

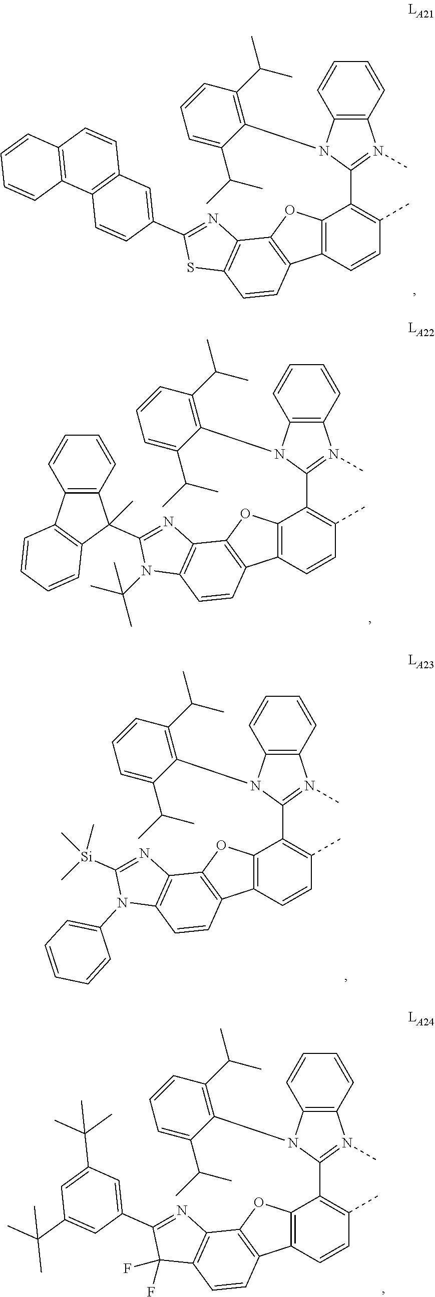

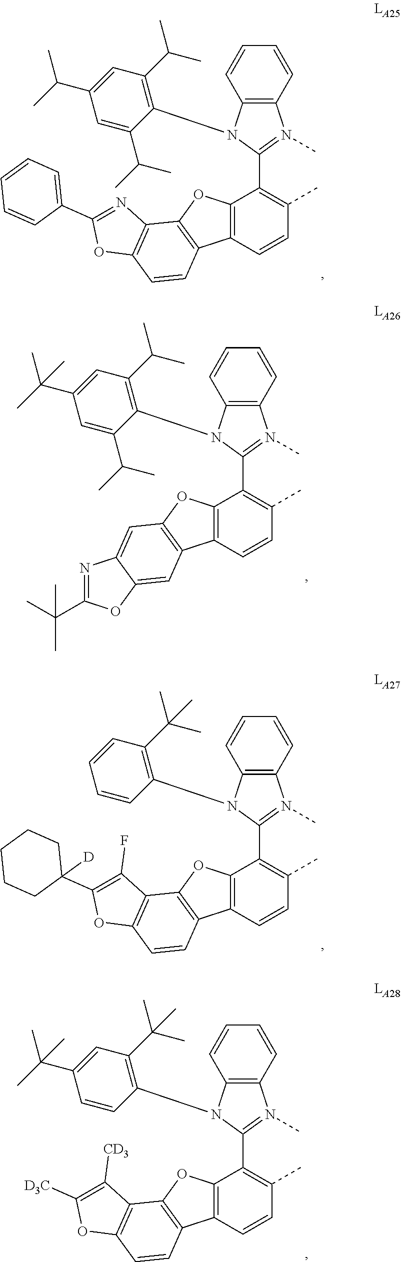

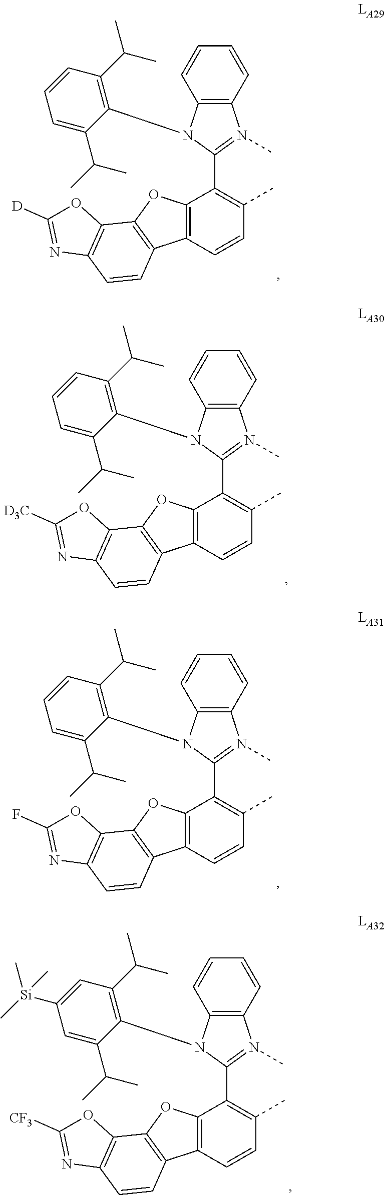

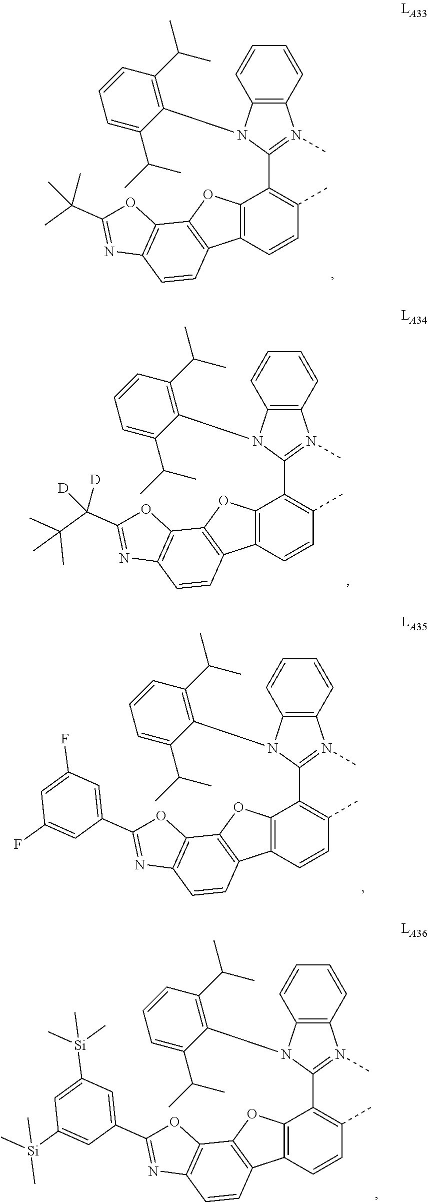

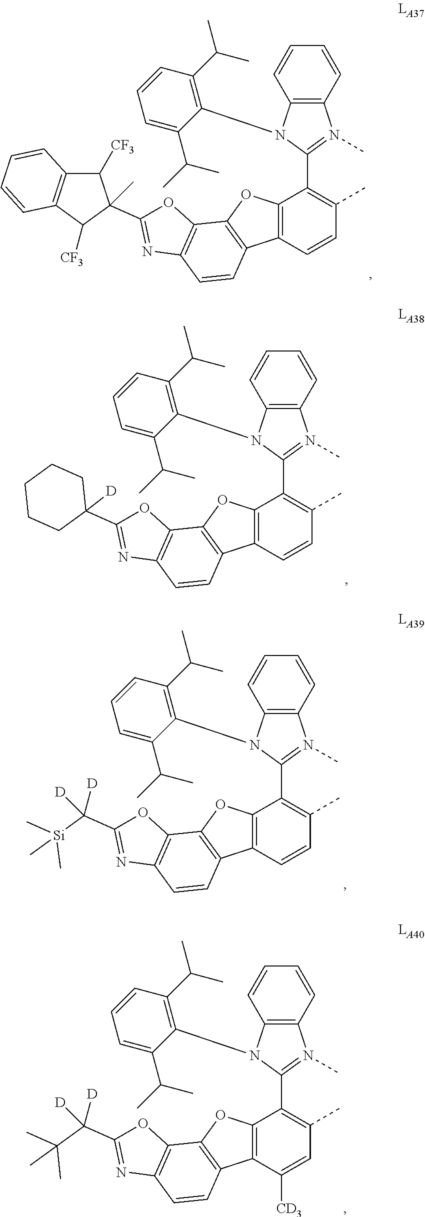

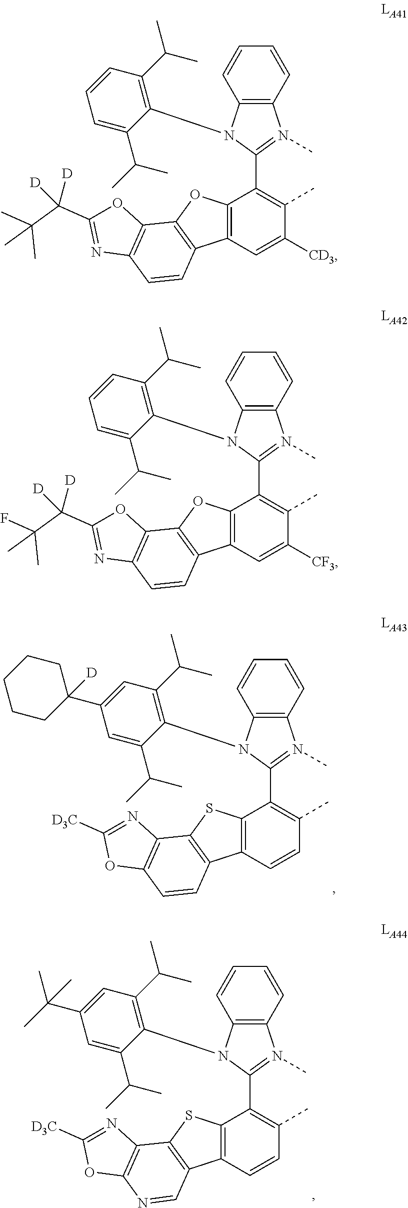

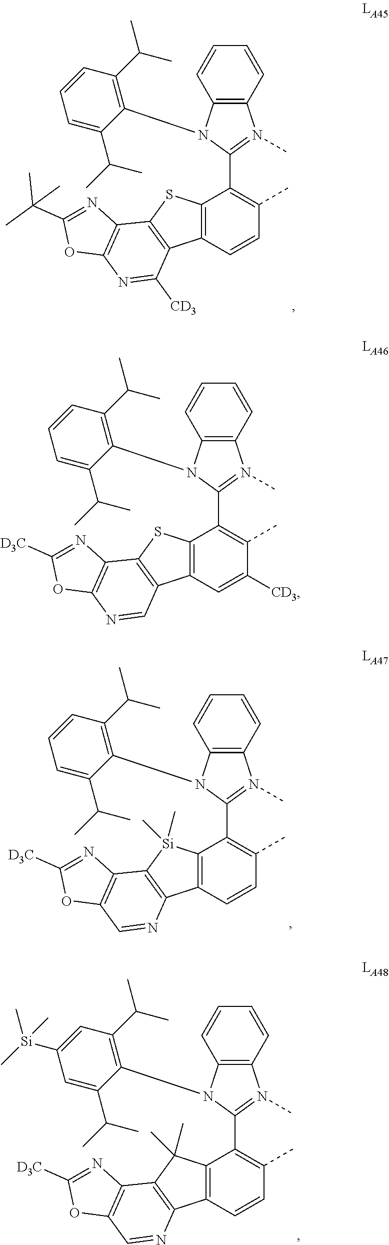

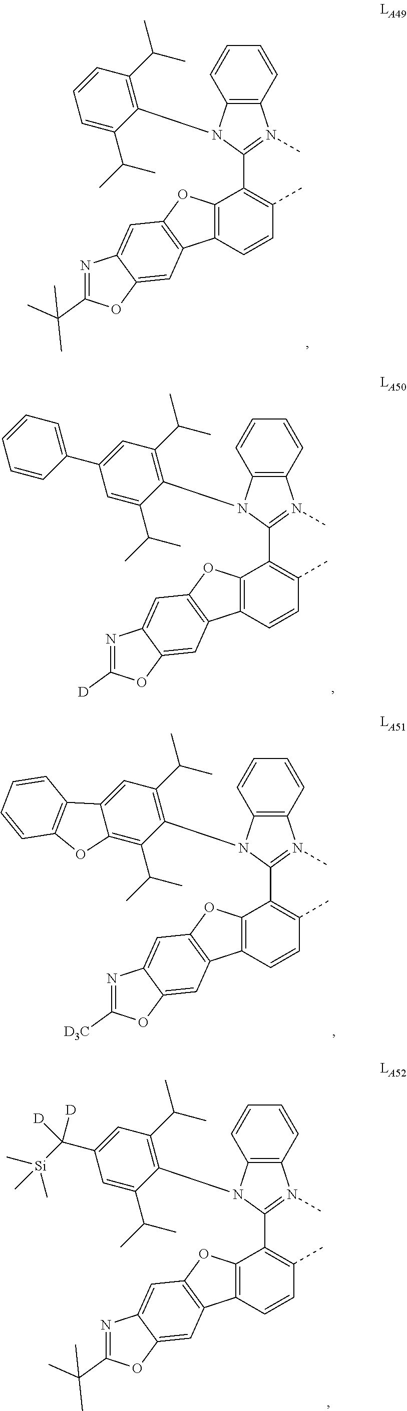

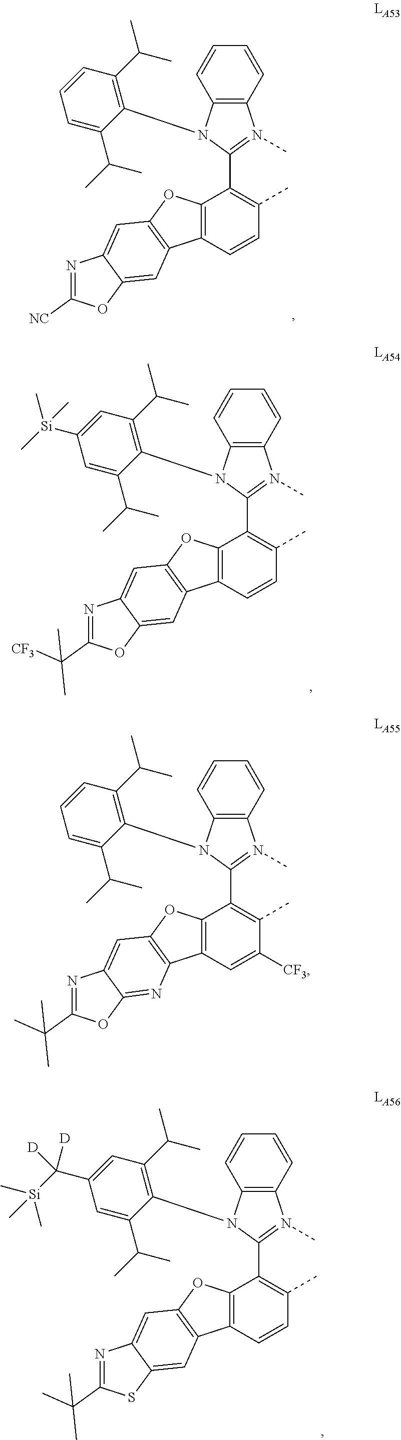

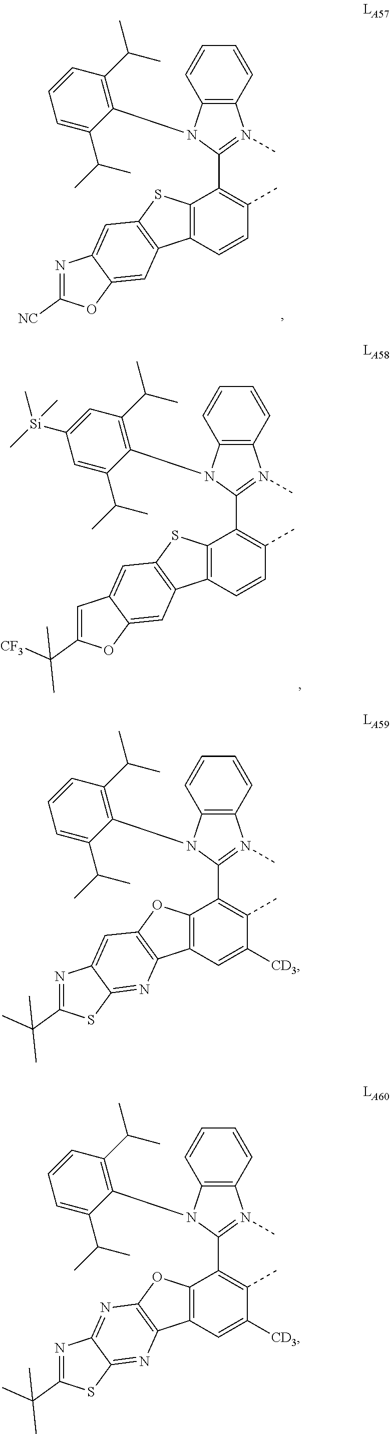

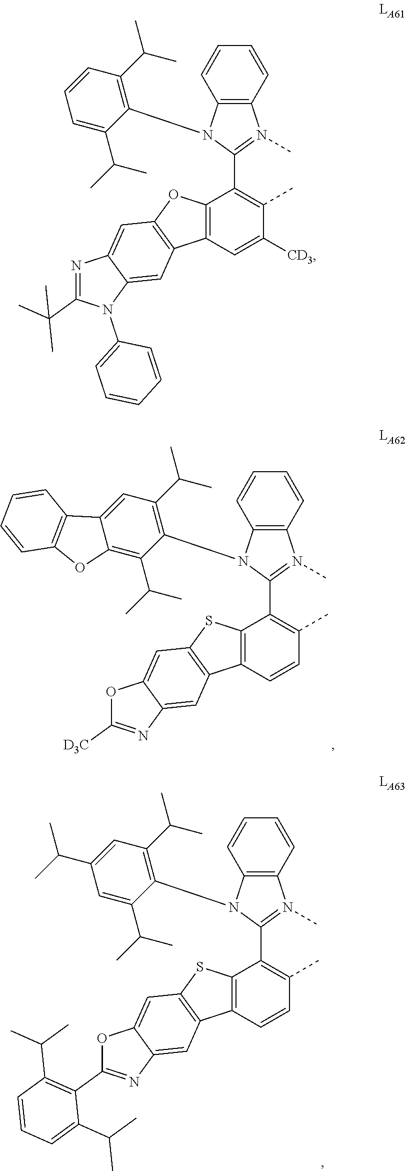

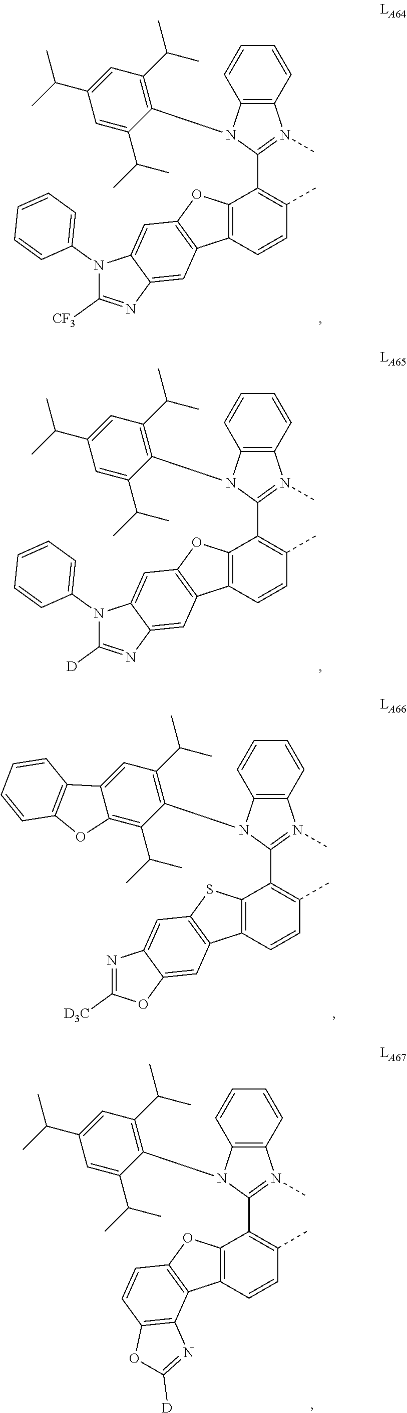

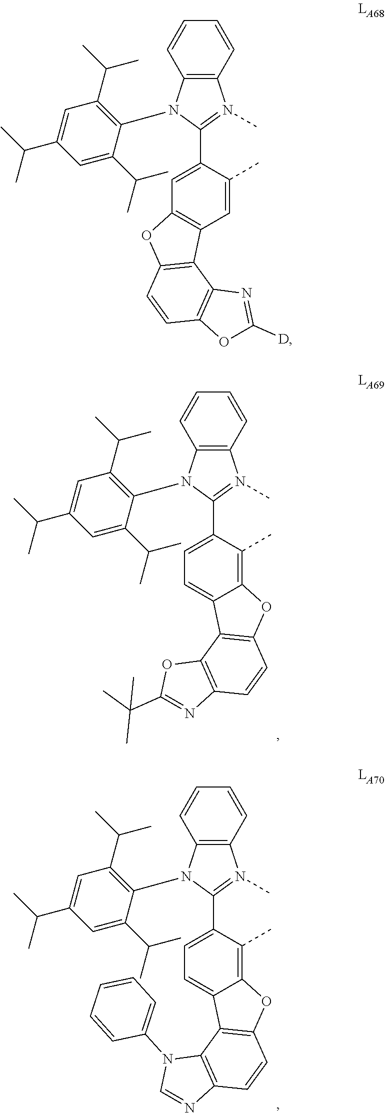

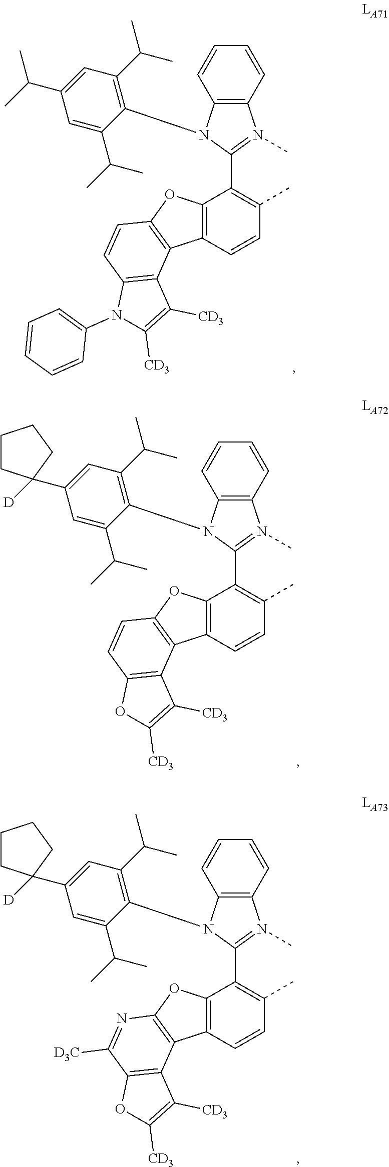

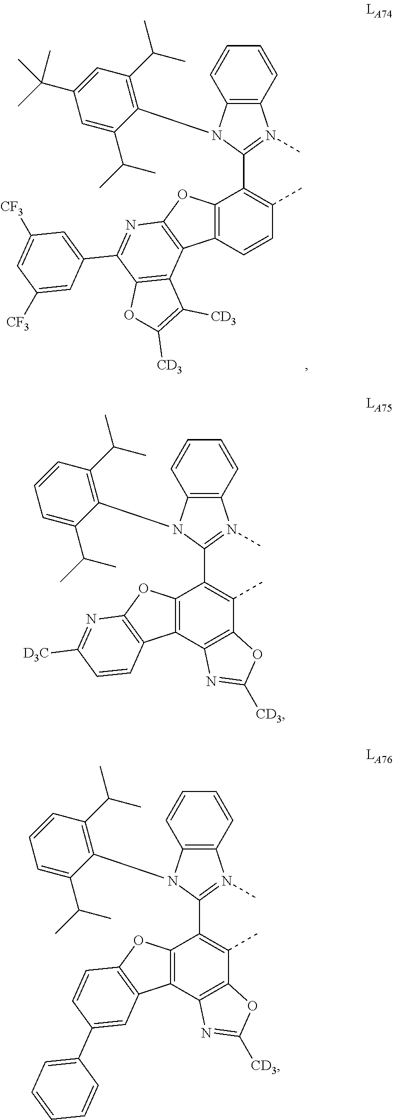

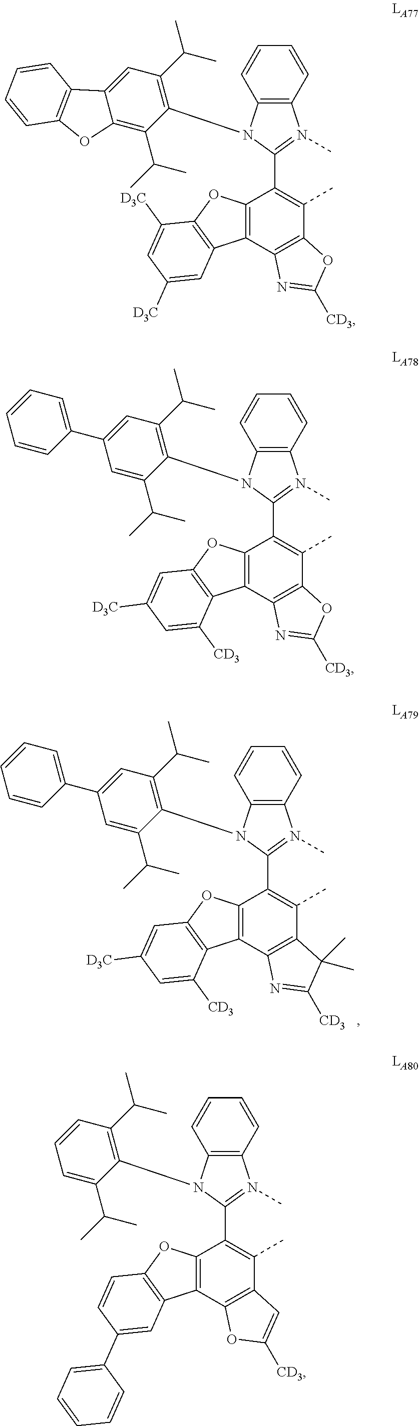

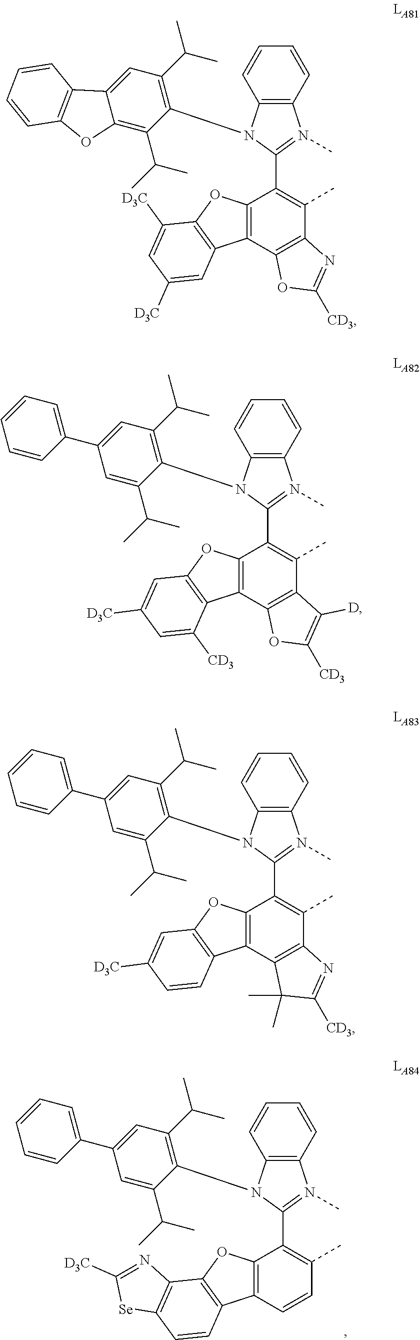

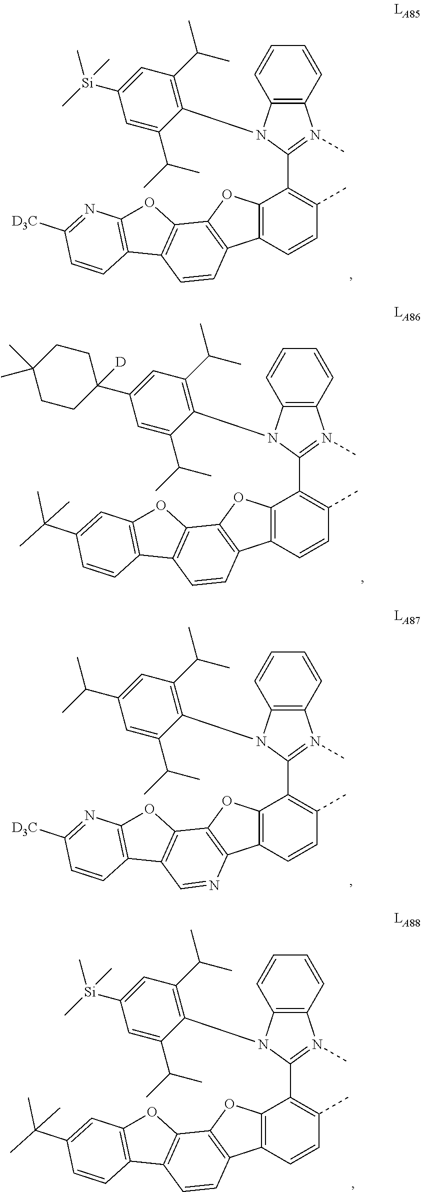

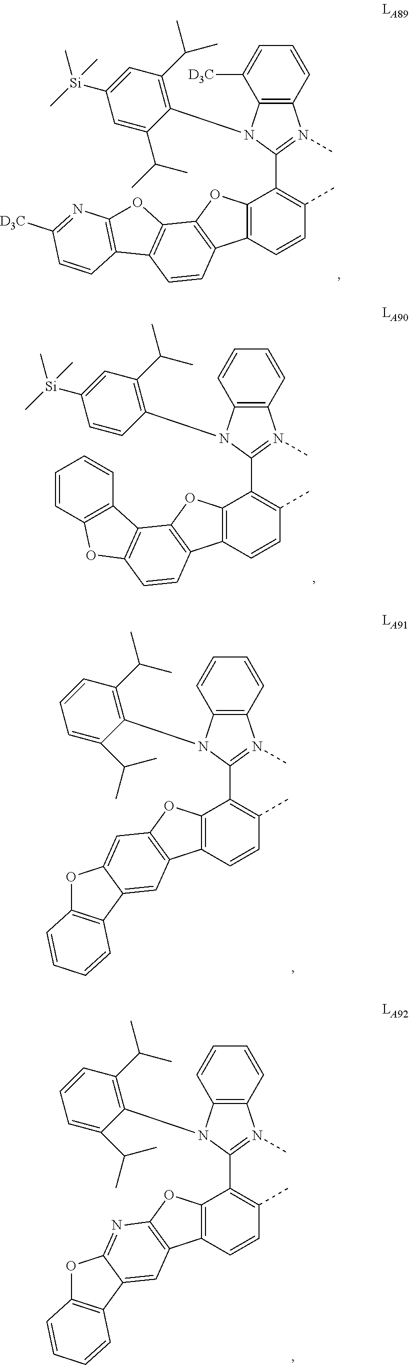

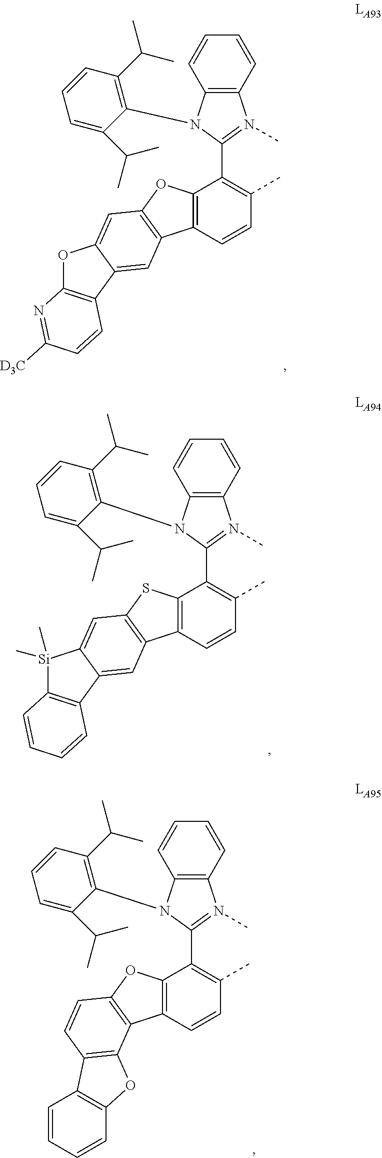

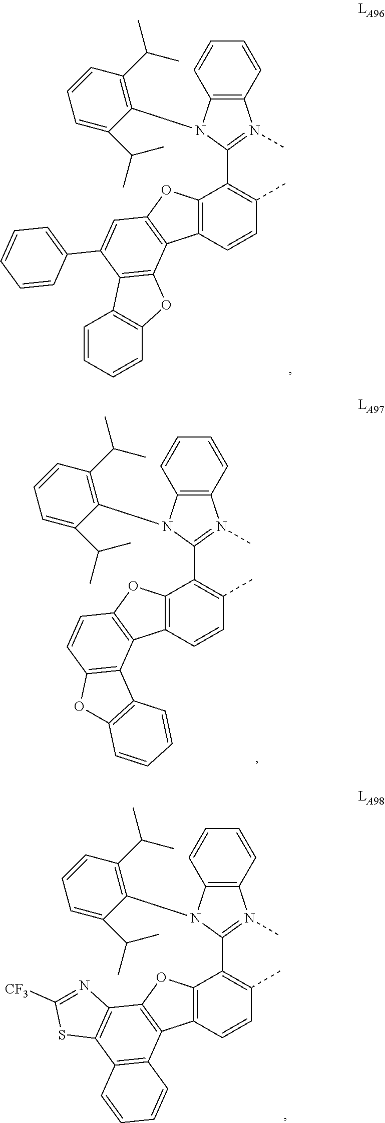

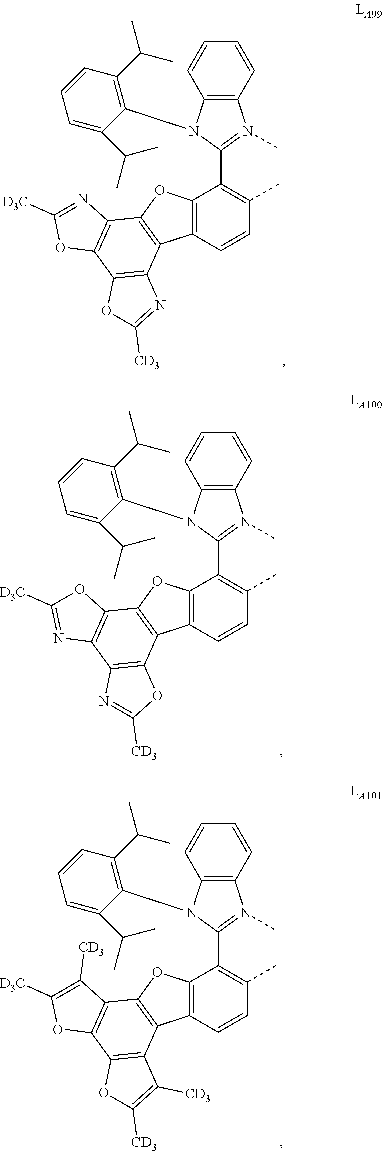

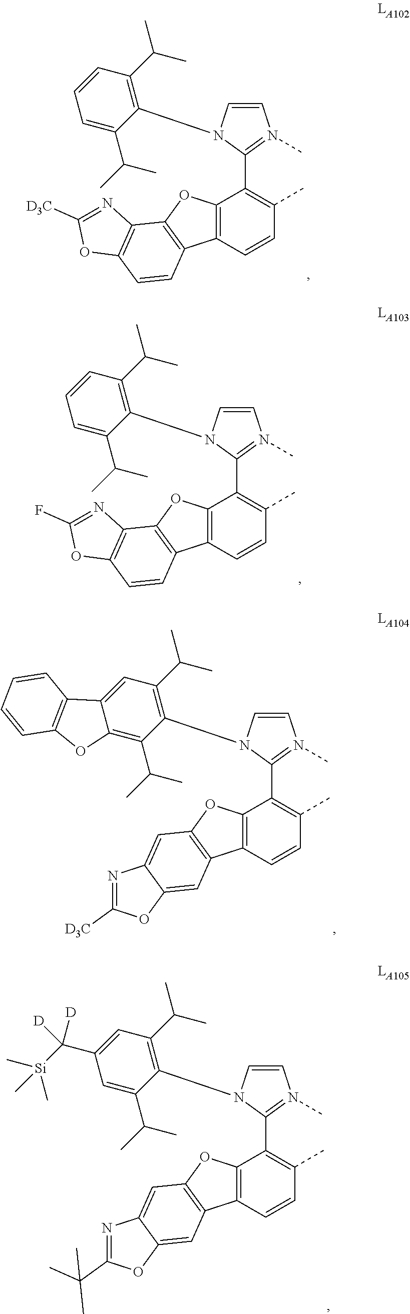

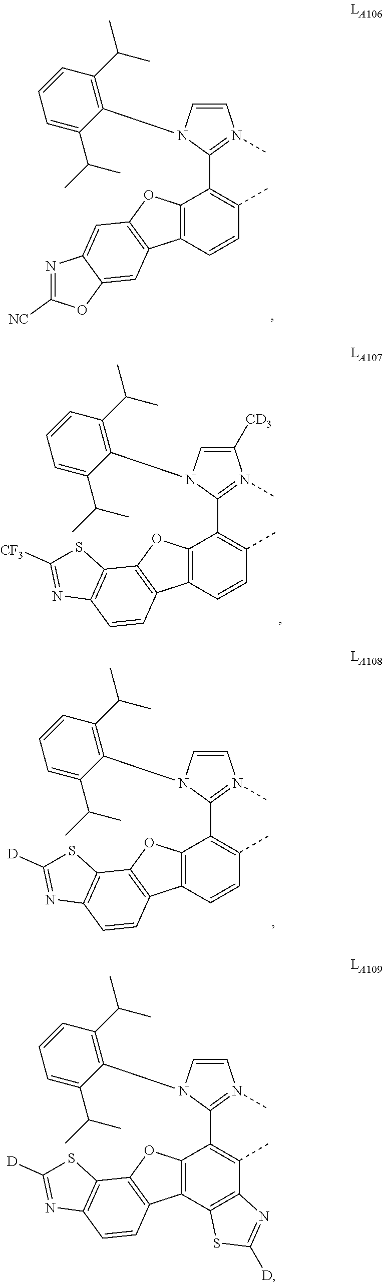

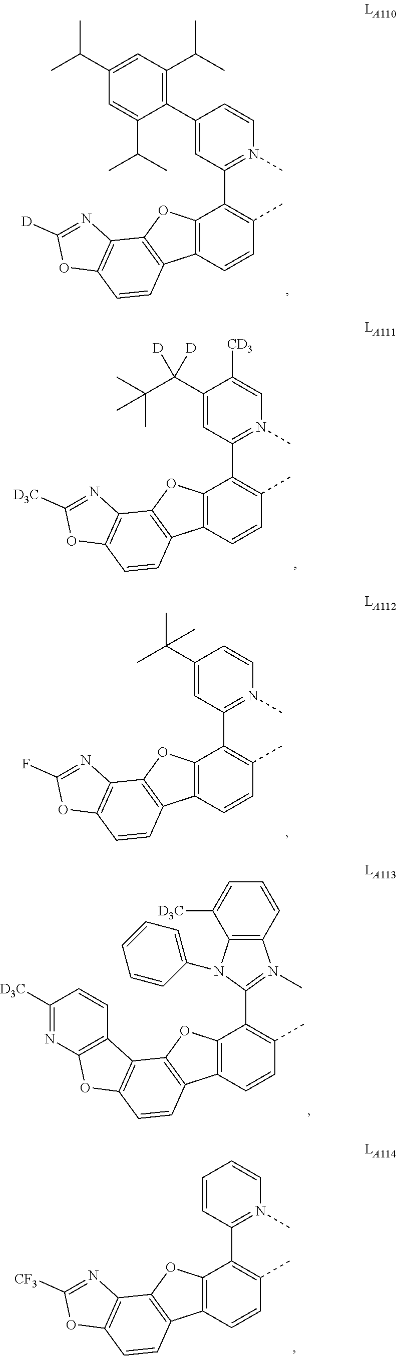

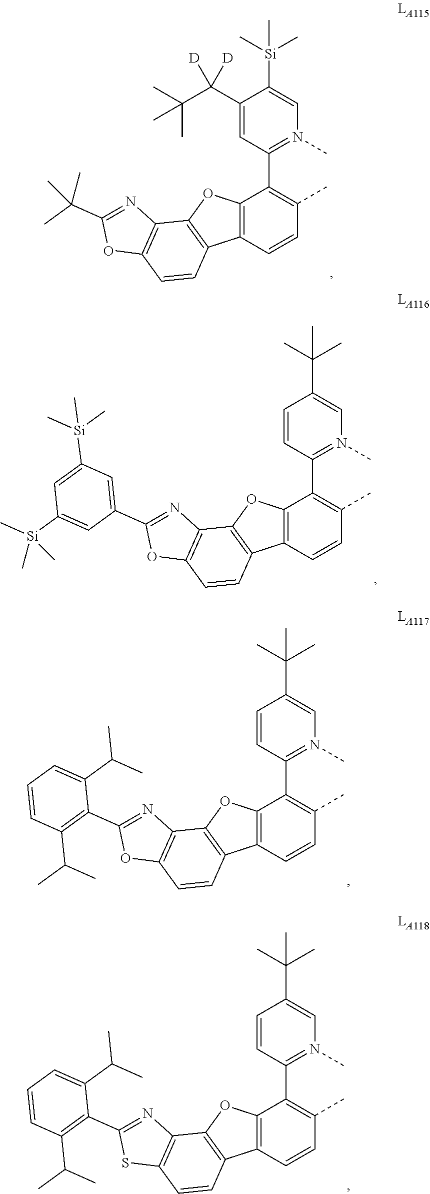

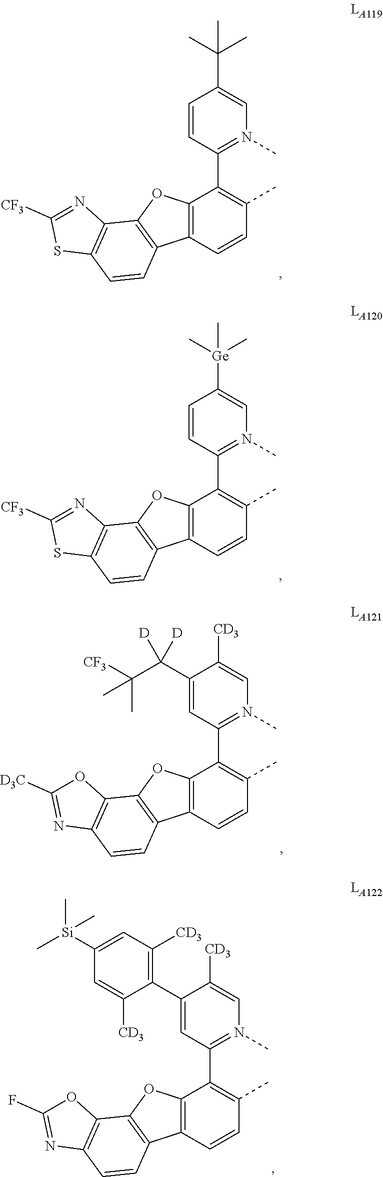

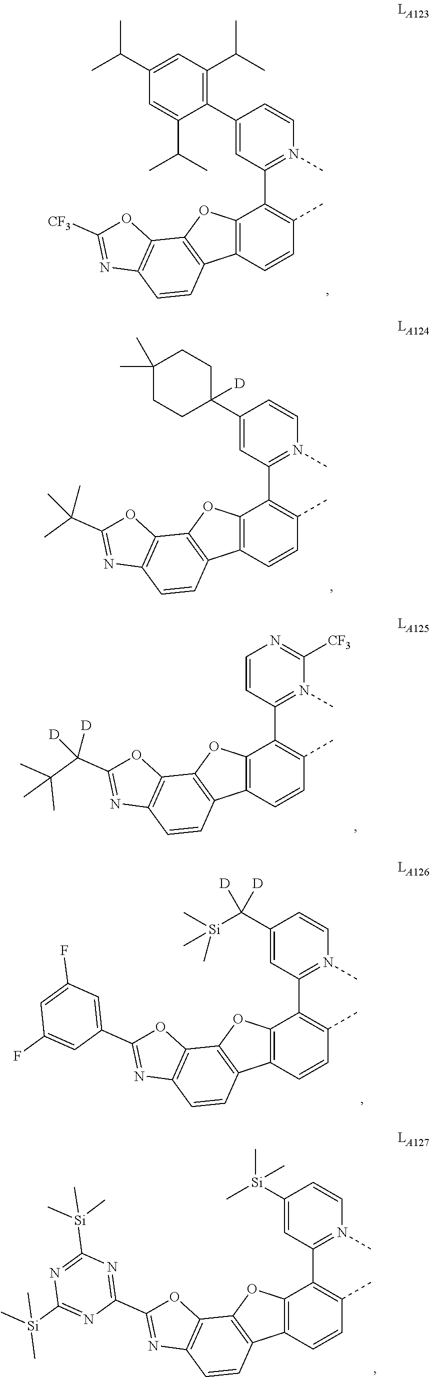

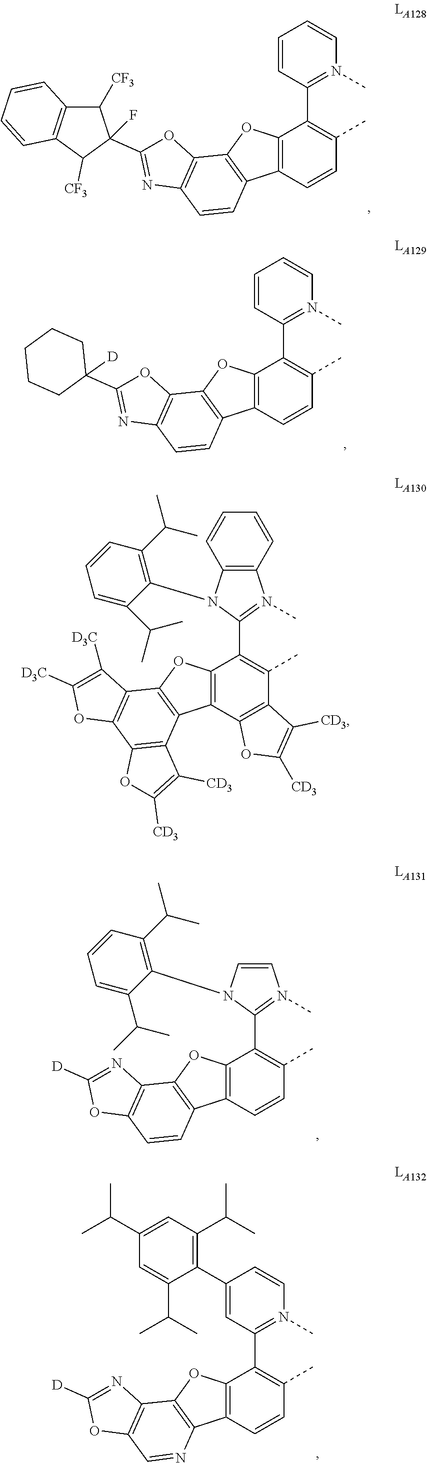

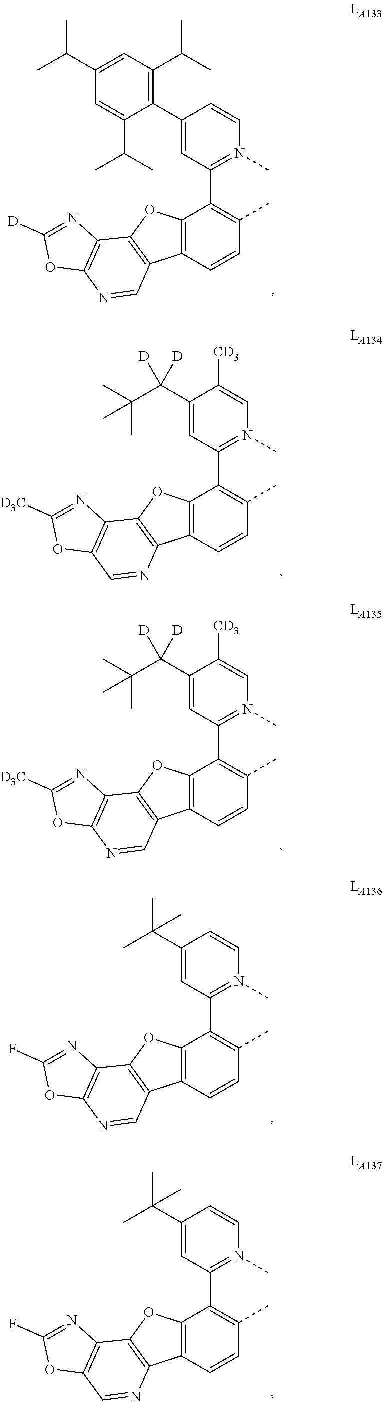

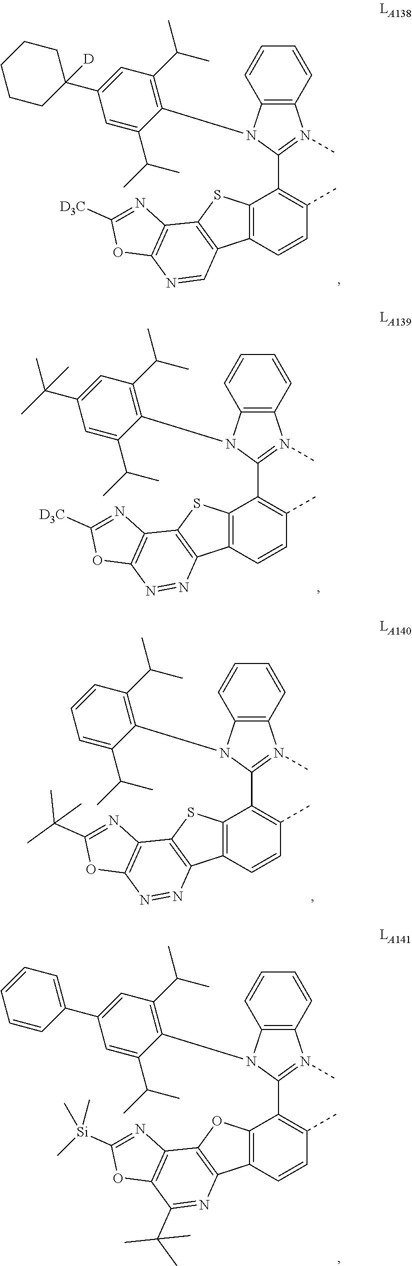

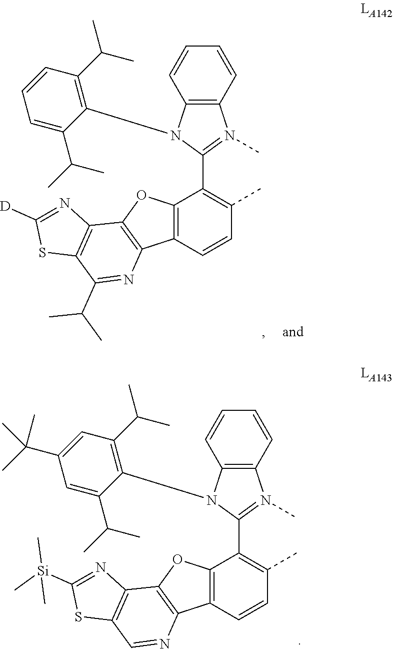

12. The compound of claim 1, wherein the ligand L_{B} is selected from the group consisting of: 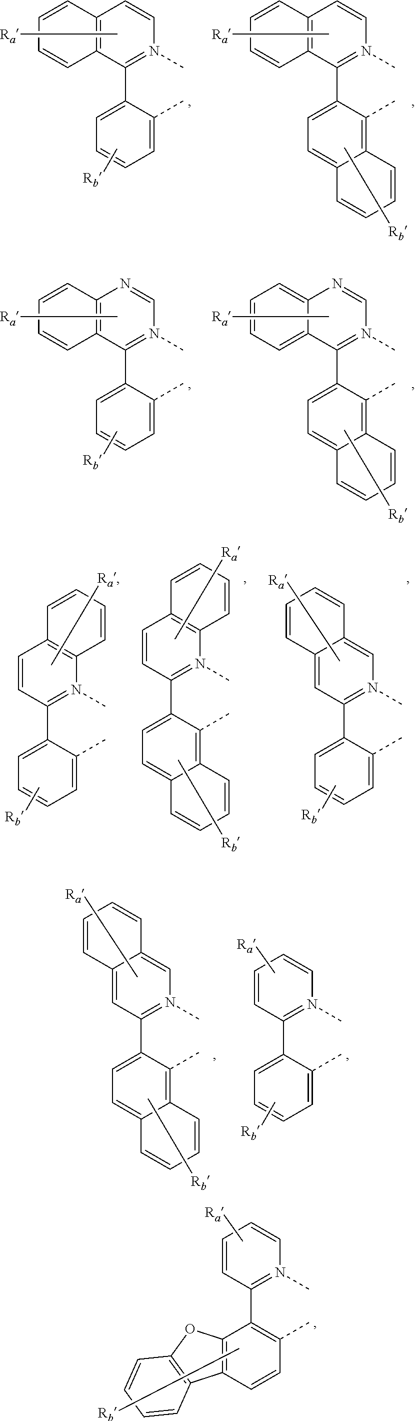 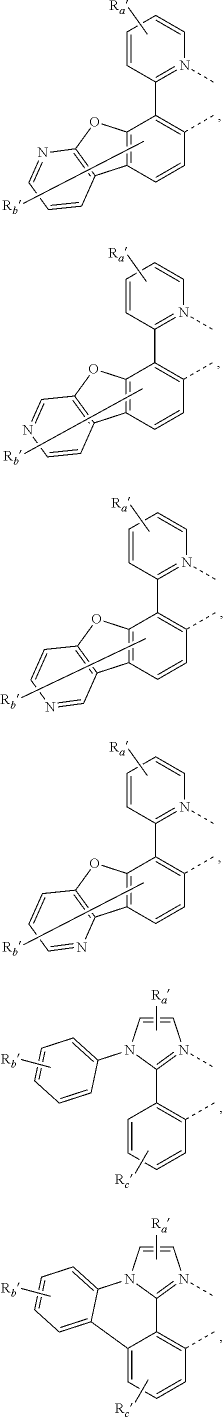 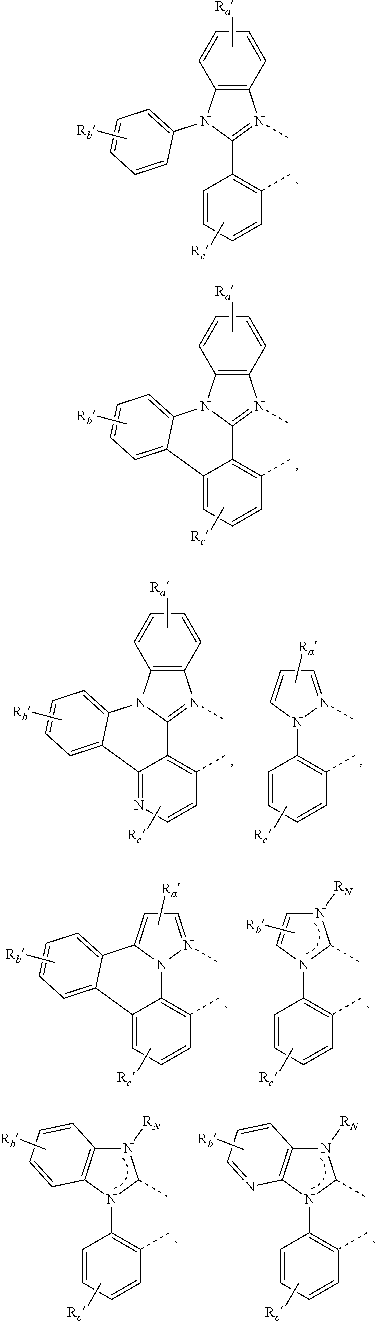 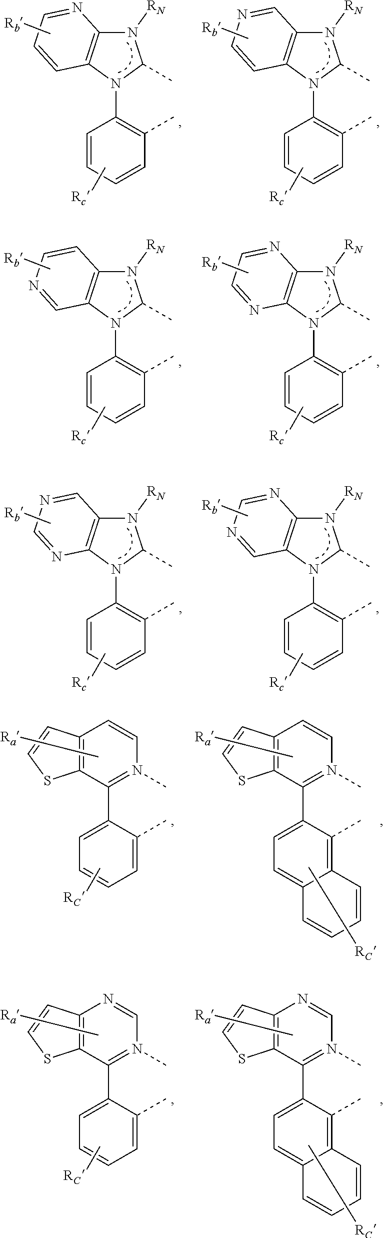 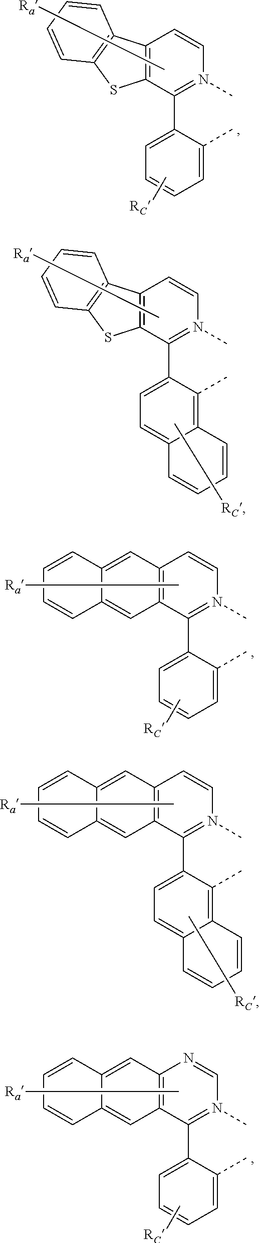 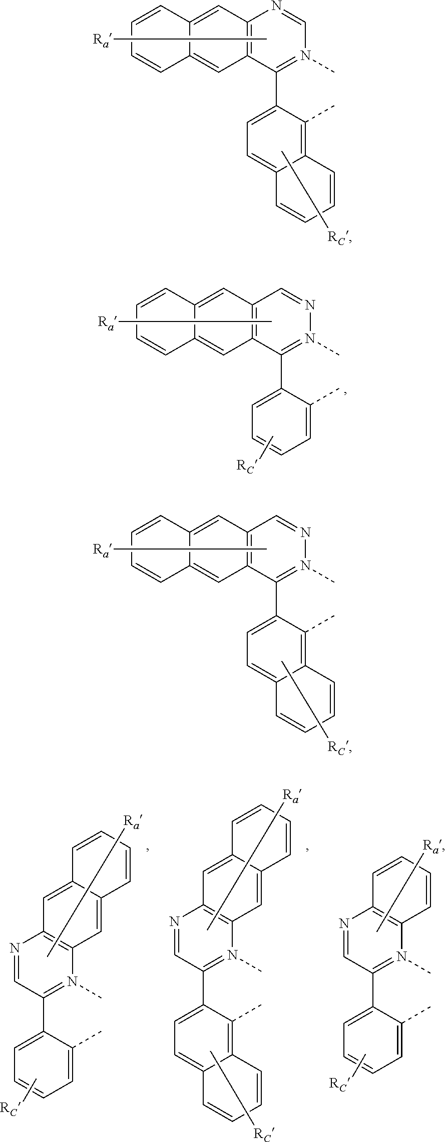 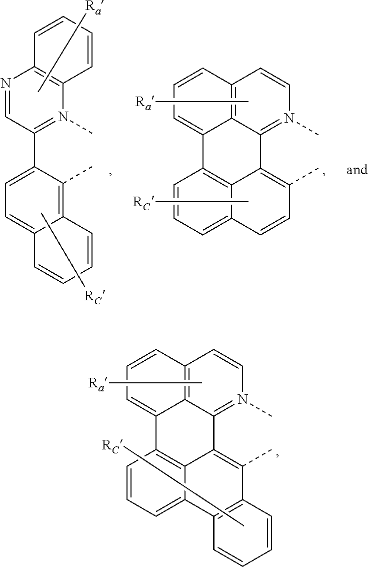
wherein:
Rₐ′, R_{b}′, and R_{c}′ each independently represent zero, mono, or up to a maximum allowed number of substitutions to its associated ring;
each of R_{N}, Rₐ′, R_{b}′, and R_{c}′ is independently hydrogen or a substituent selected from the group consisting of deuterium, halide, alkyl, cycloalkyl, heteroalkyl, arylalkyl, alkoxy, aryloxy, amino, silyl, boryl, germyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof; and
two adjacent Rₐ′, R_{b}′, and R_{c}′ can be fused or joined to form a ring or form a multidentate ligand, and
at least one of Rₐ′, R_{b}′, and R_{c}′ comprises trialkylsilyl group.

13. The compound of claim 1, wherein ligand L_{B} is selected from the group consisting of: 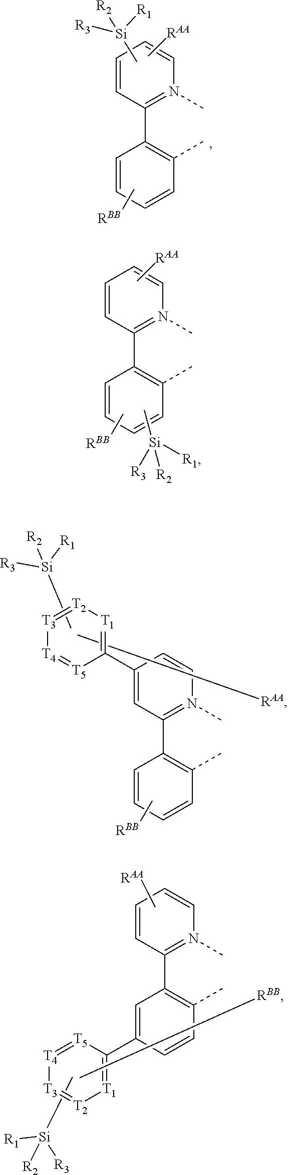 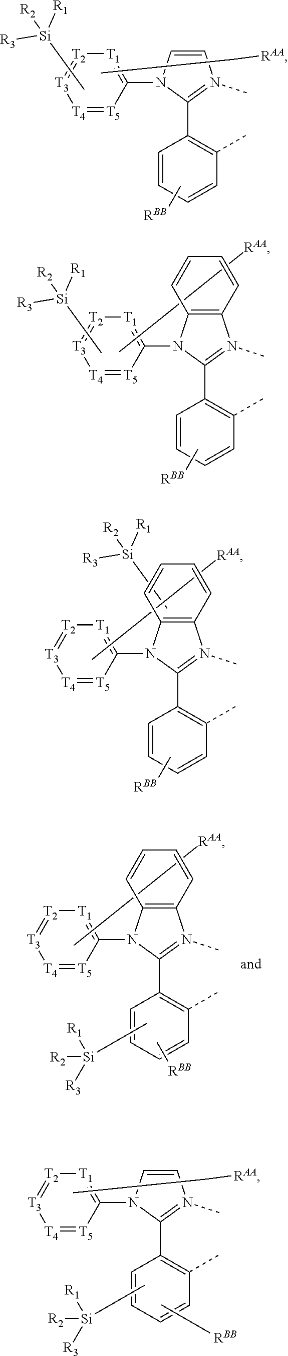
wherein:
each R₁, R₂ and R₃ is independently a substituent selected from the group consisting of alkyl, cycloalkyl, heteroalkyl, arylalkyl, alkoxy, aryloxy, amino, silyl, boryl, germyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof;
T₁ to T₅ are each independently C or N;
each of R^{AA} and R^{BB} independently represents zero, mono, or up to a maximum allowed number of substitutions to its associated ring;
each R^{AA} and R^{BB} is independently hydrogen or a substituent selected from the group consisting of deuterium, halide, alkyl, cycloalkyl, heteroalkyl, arylalkyl, alkoxy, aryloxy, amino, silyl, boryl, germyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof; and
any two substituents can be fused or joined to form a ring or form a multidentate ligand.

14. The compound of claim 1, wherein the ligand L_{B} is selected from the group consisting of L_{B} is an integer from 1 to 176, and each L_{Bk} is defined as follows:

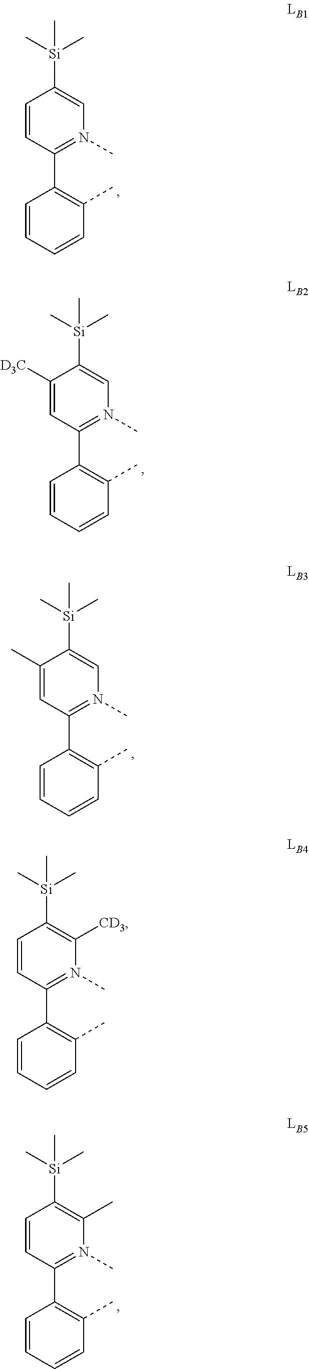

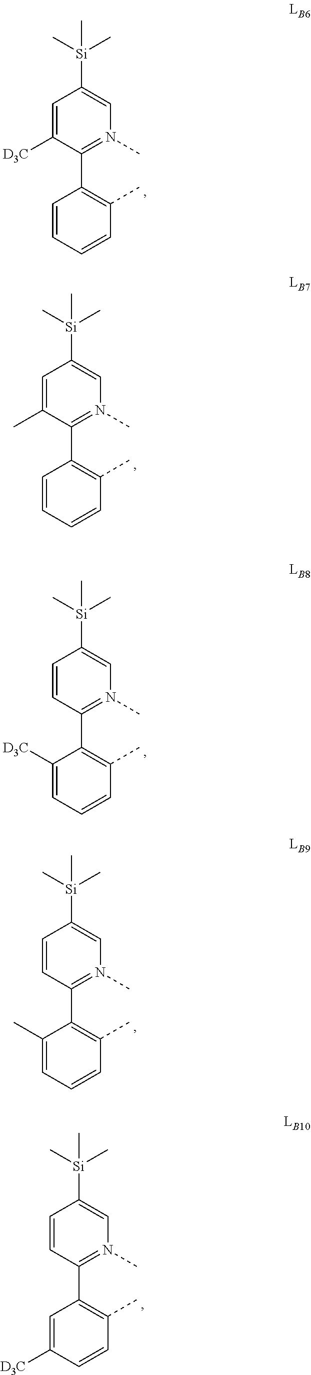

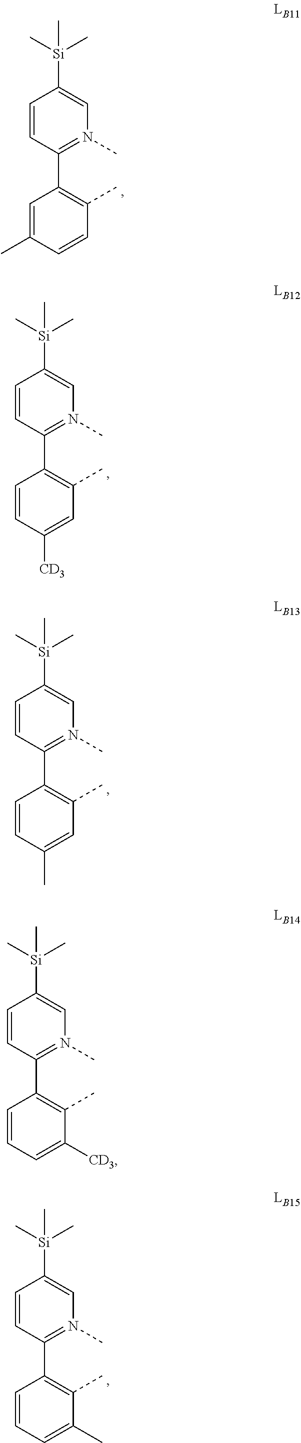

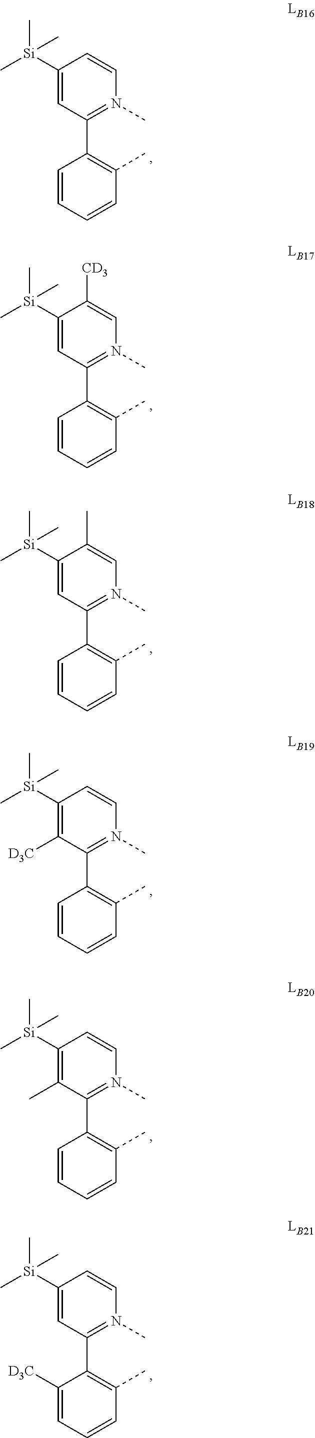

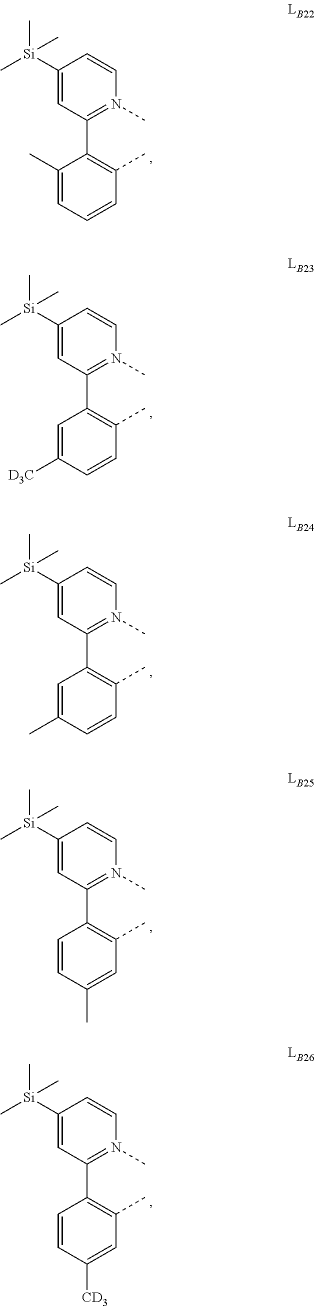

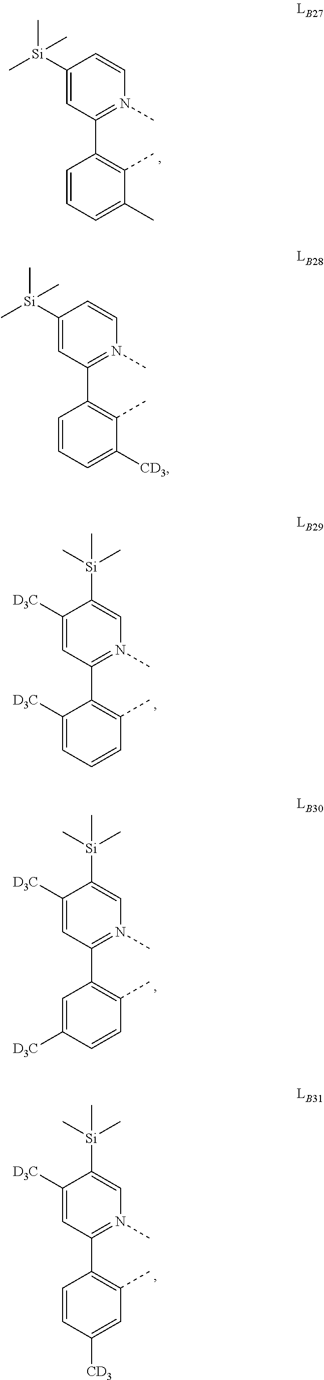

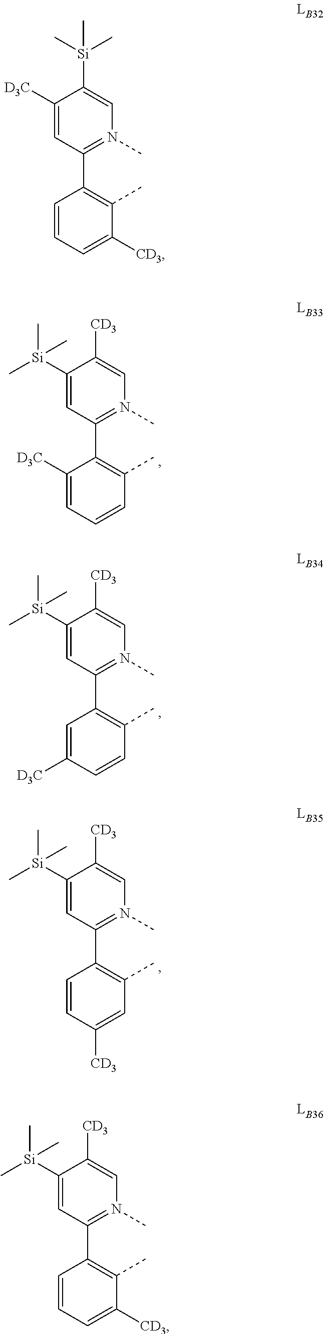

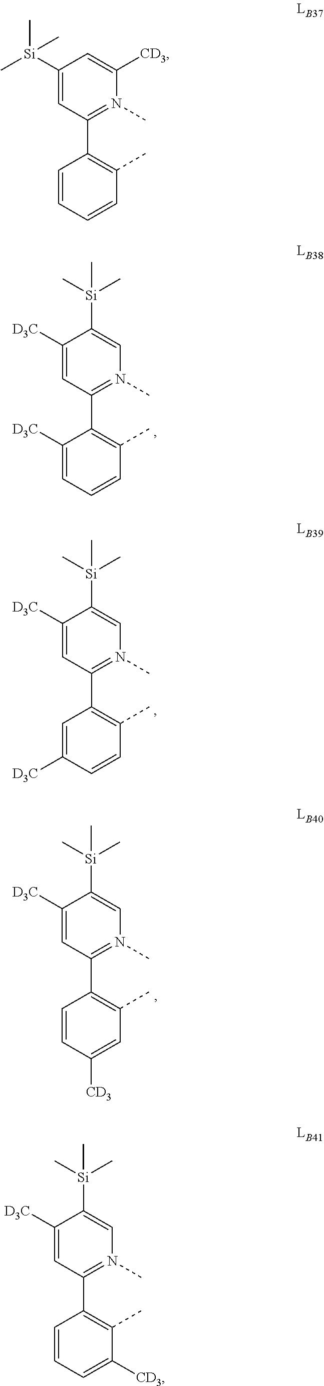

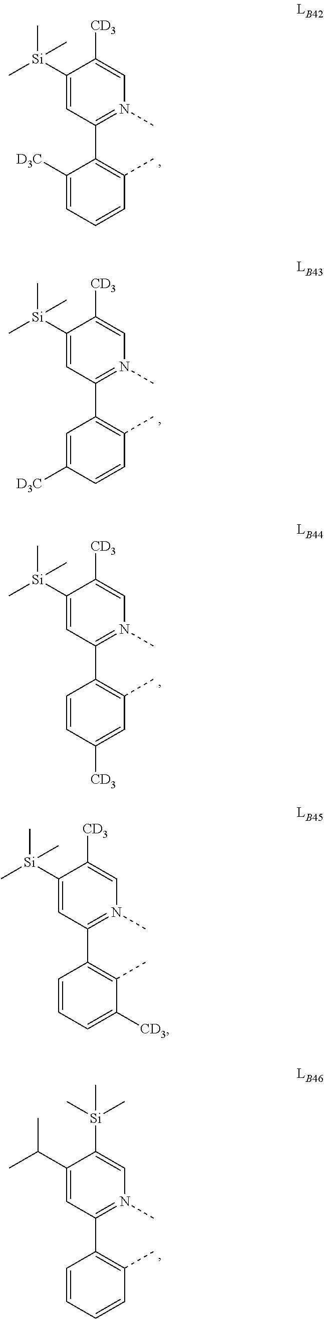

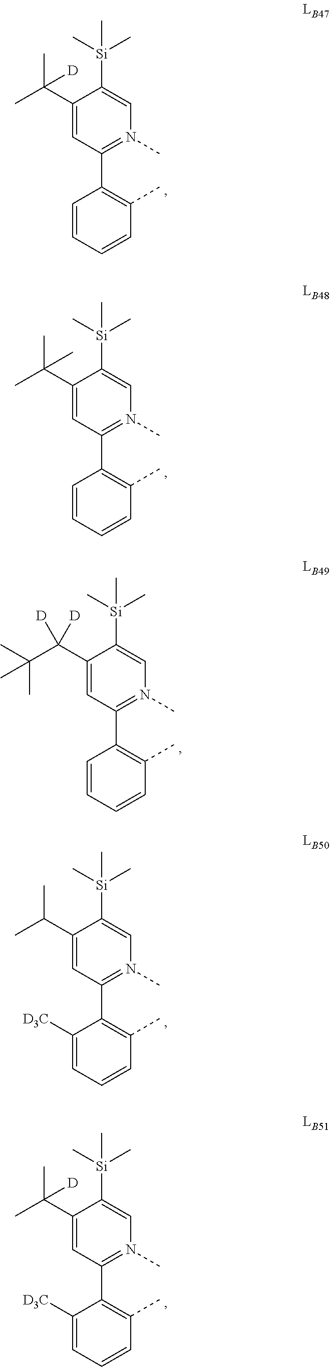

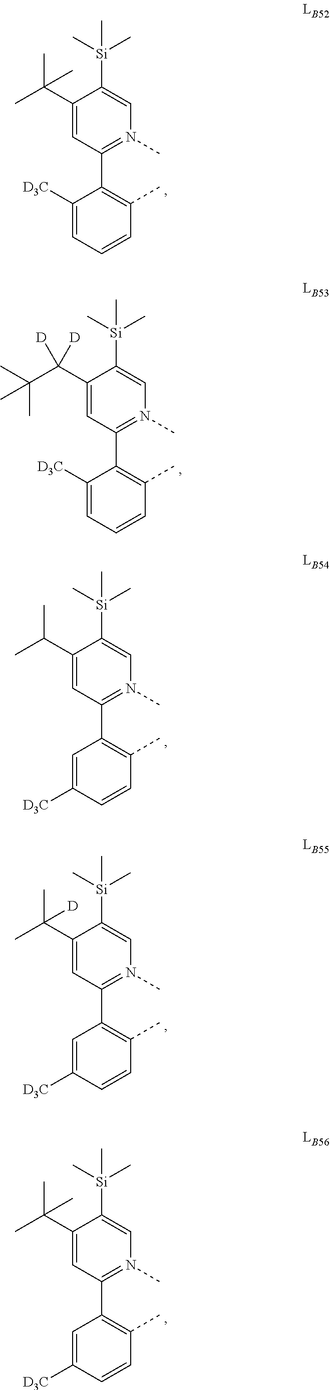

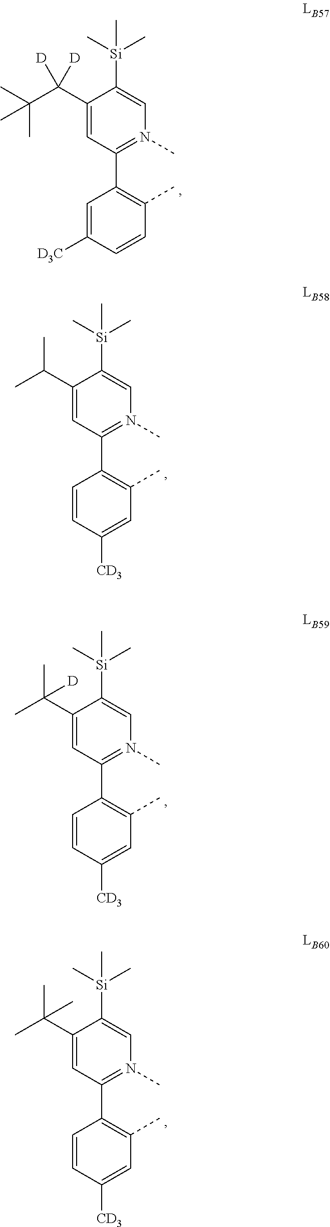

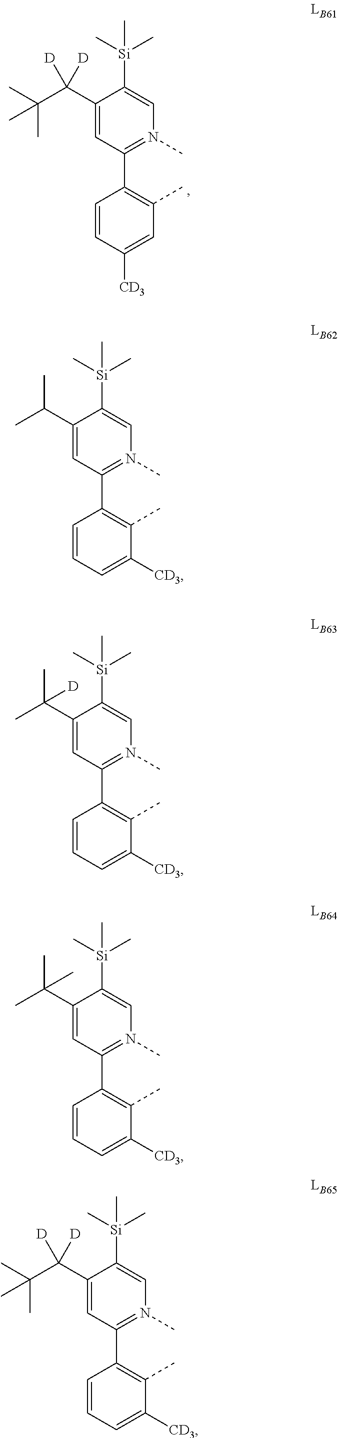

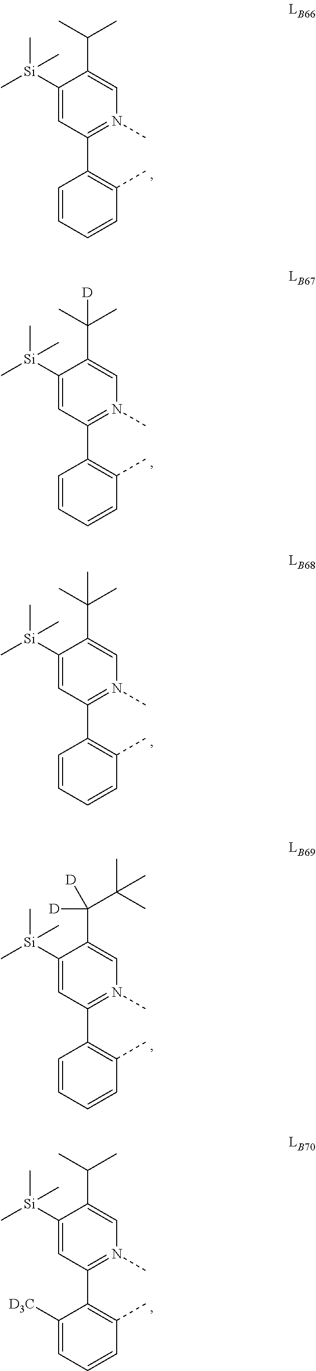

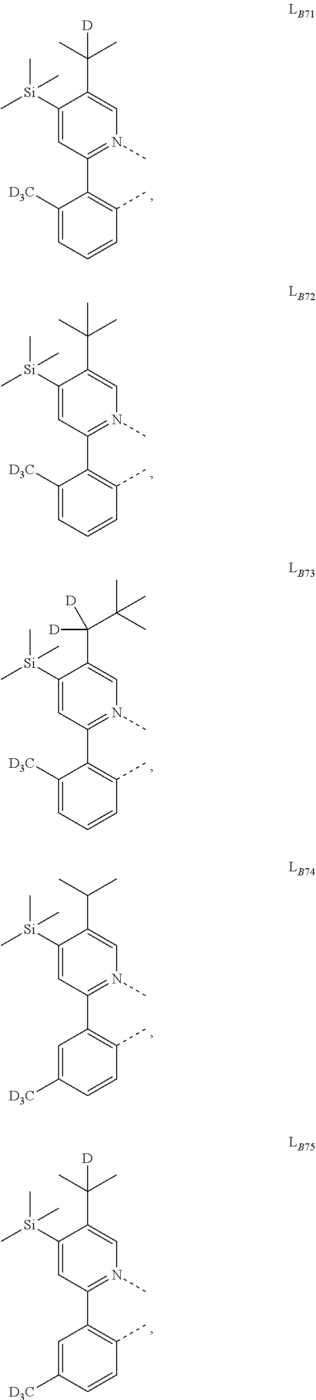

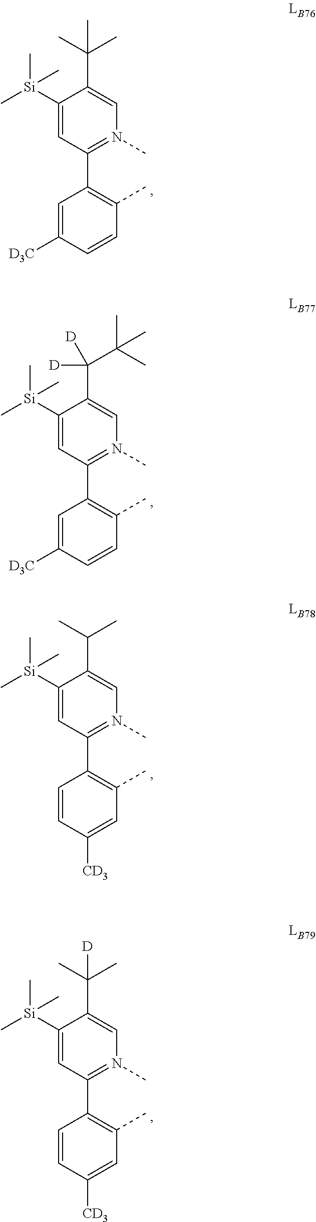

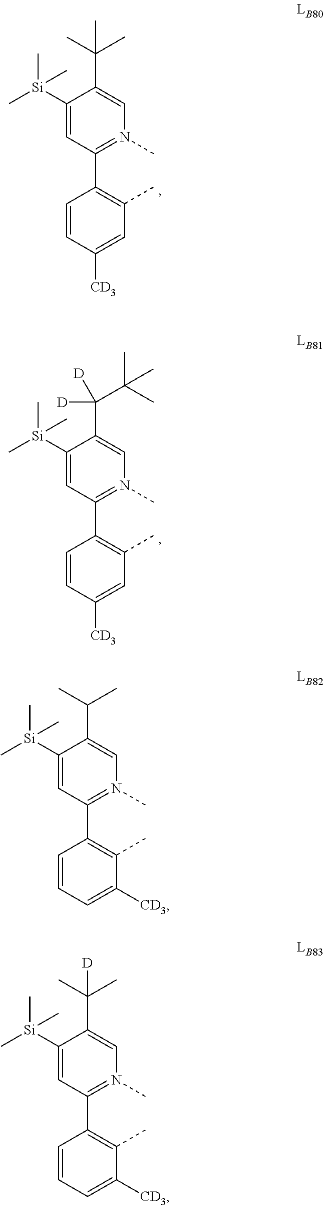

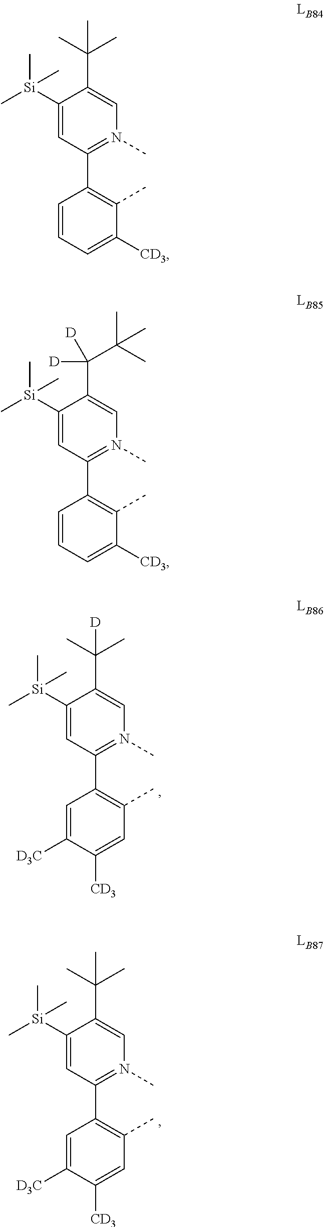

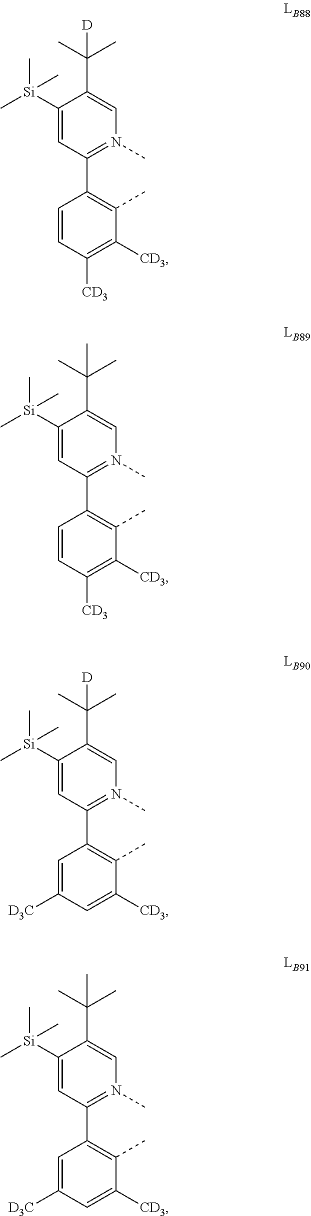

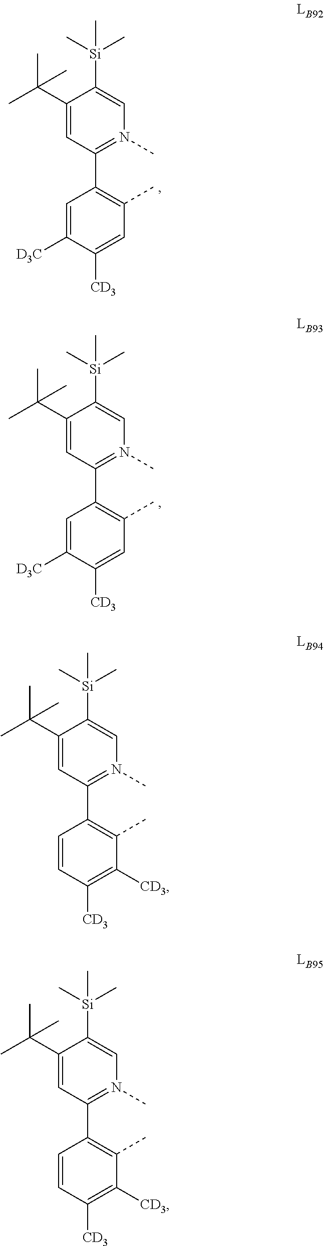

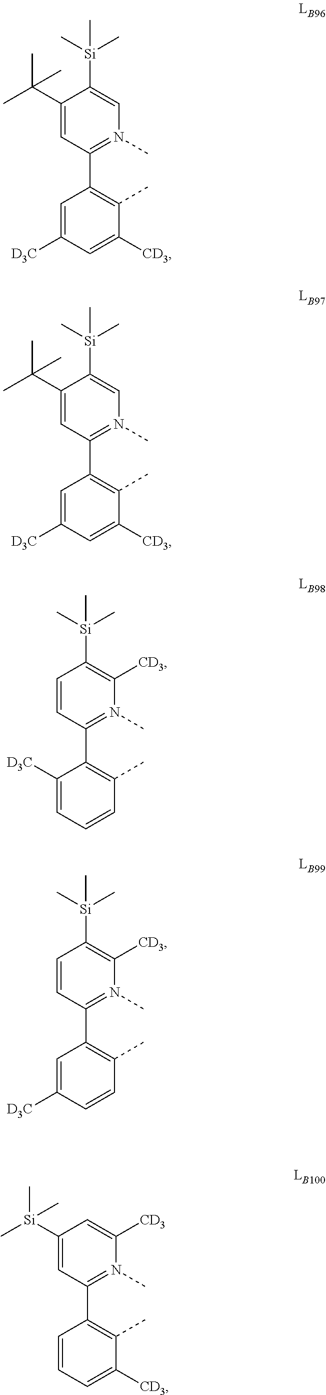

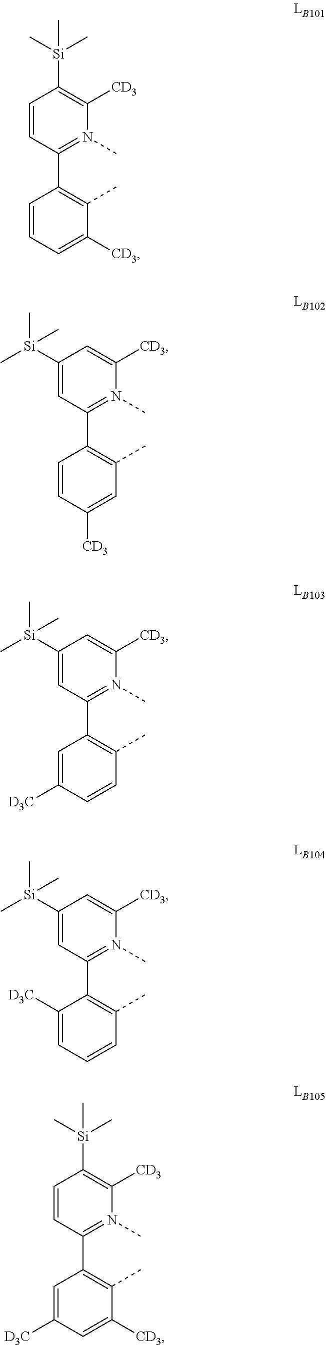

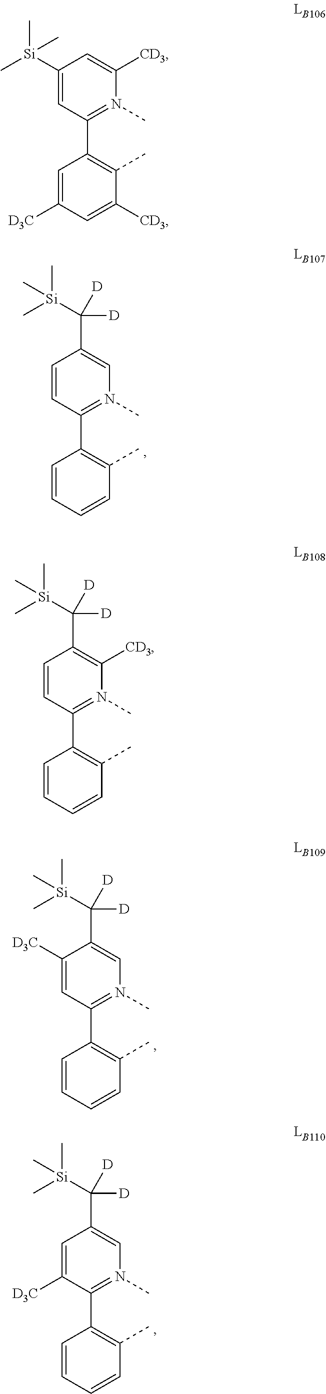

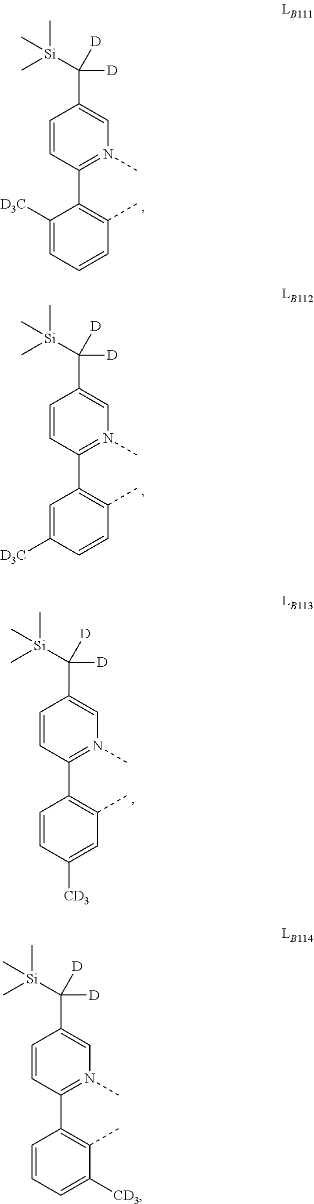

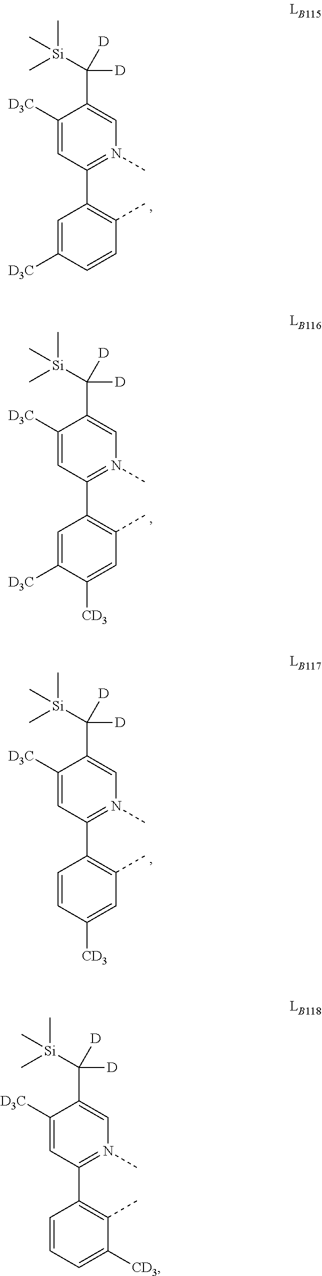

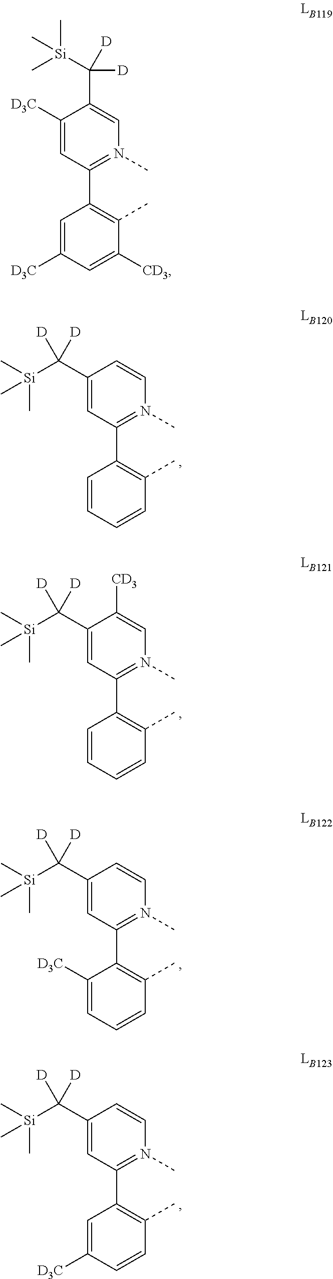

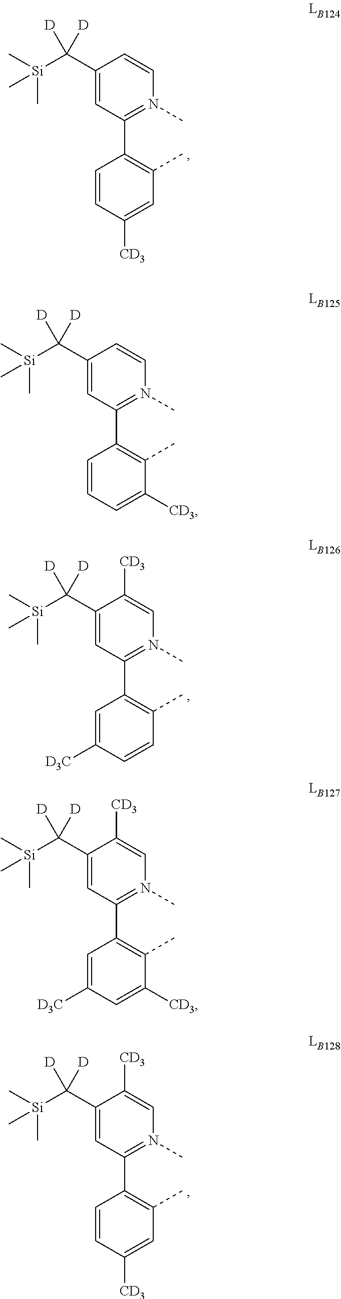

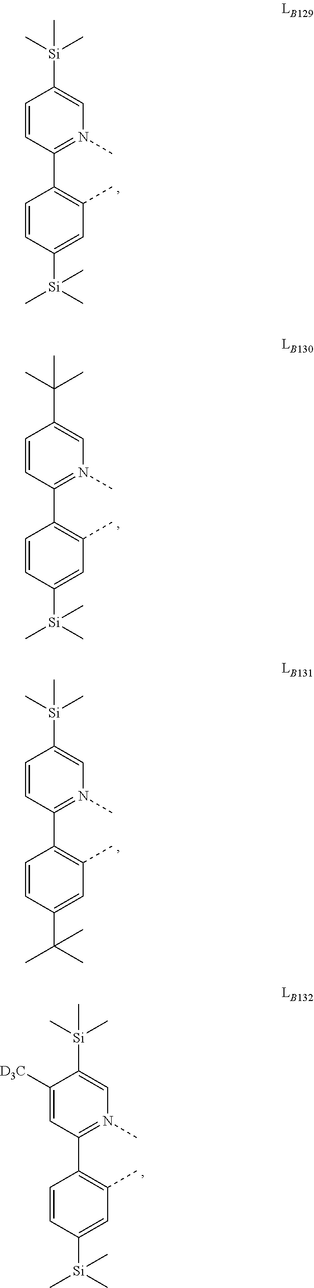

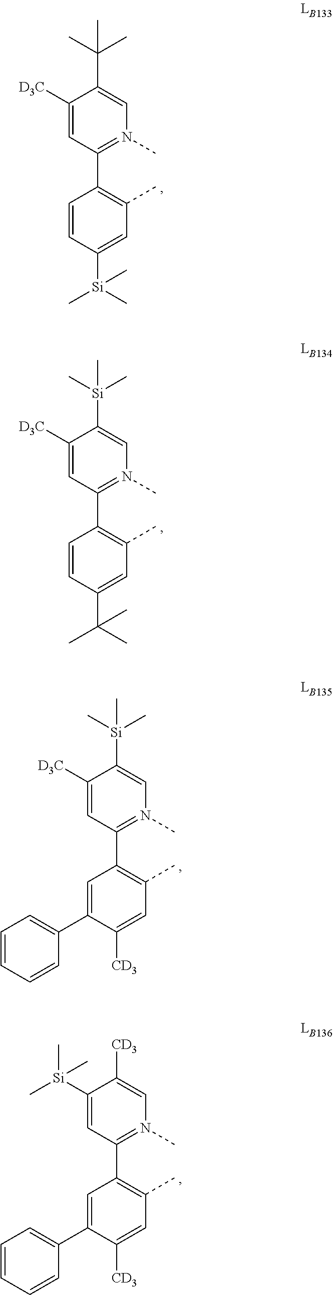

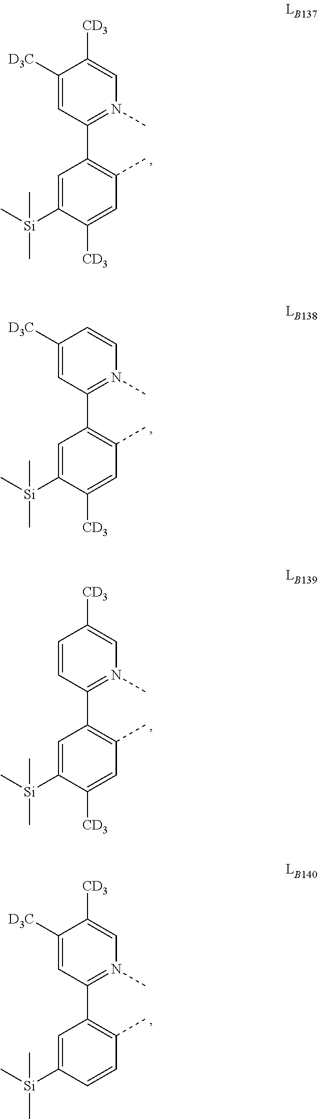

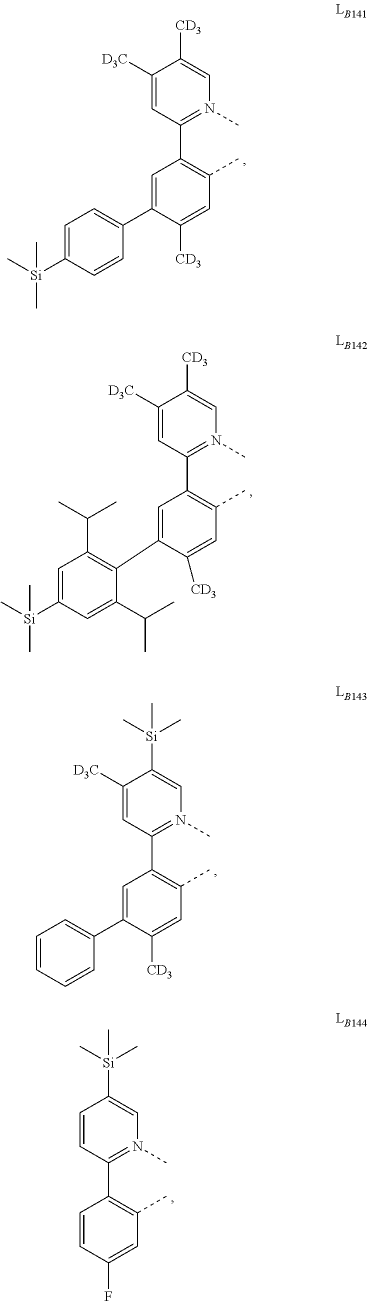

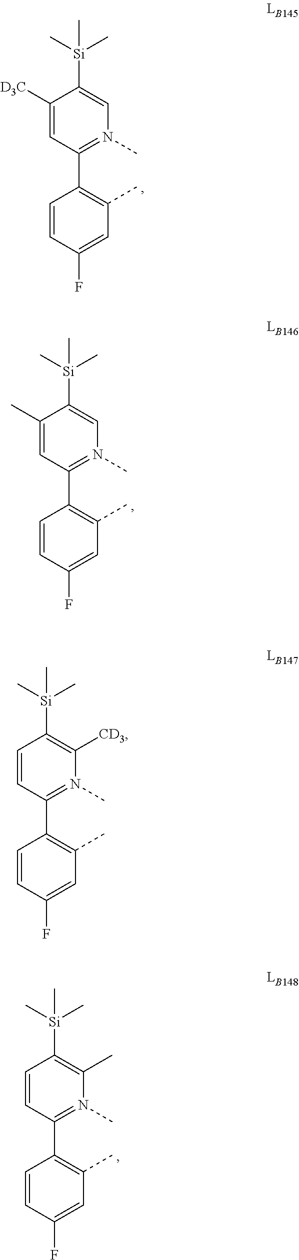

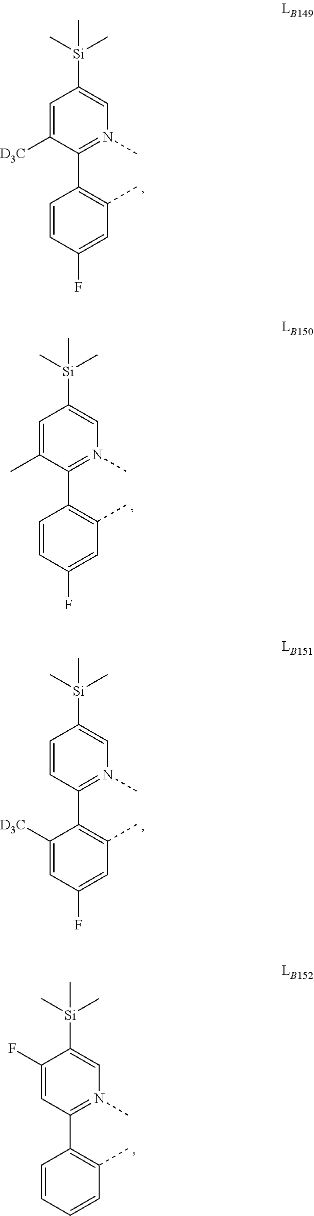

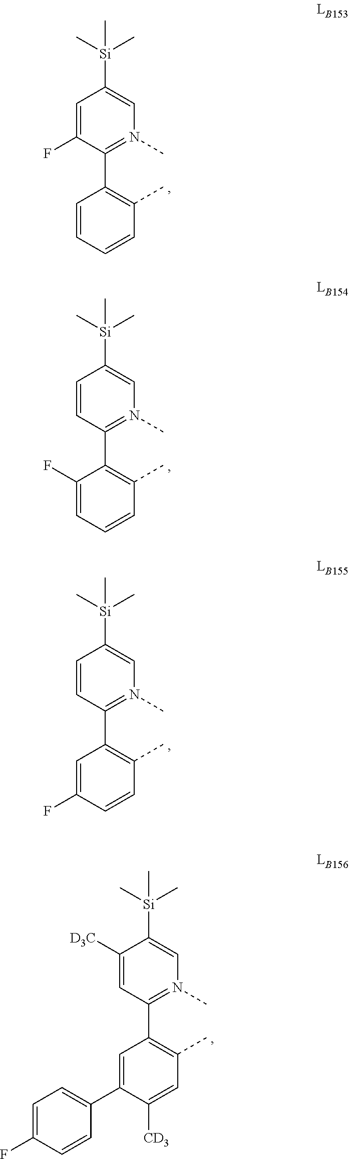

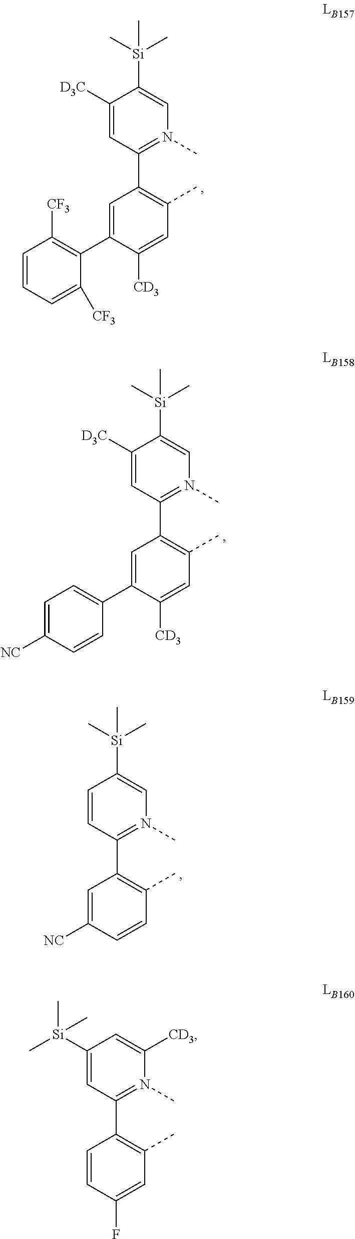

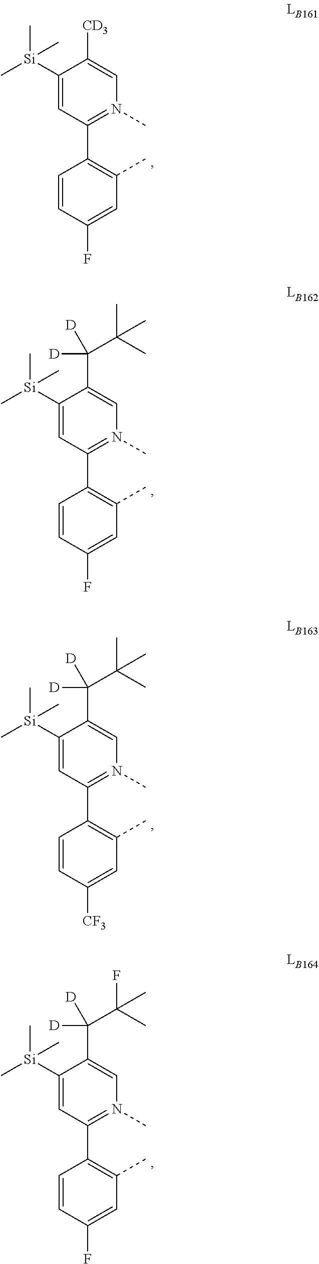

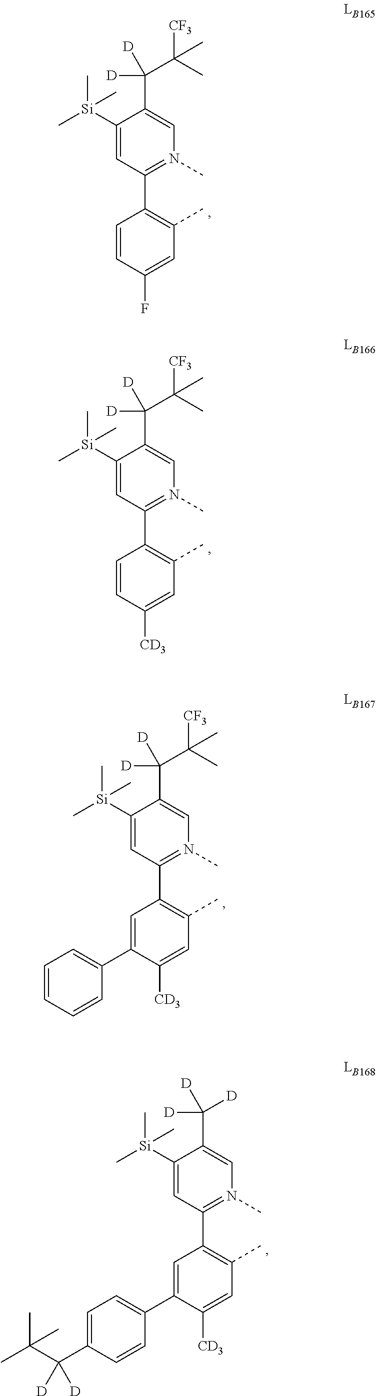

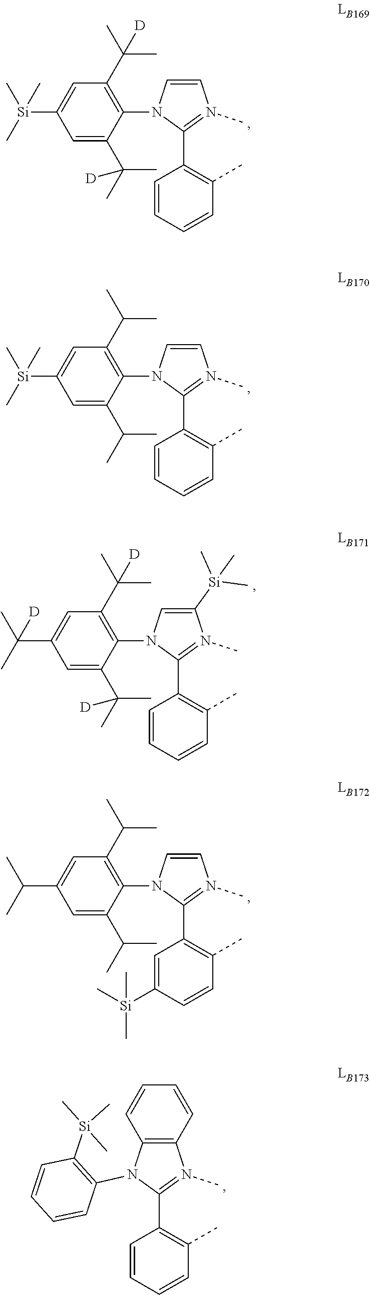

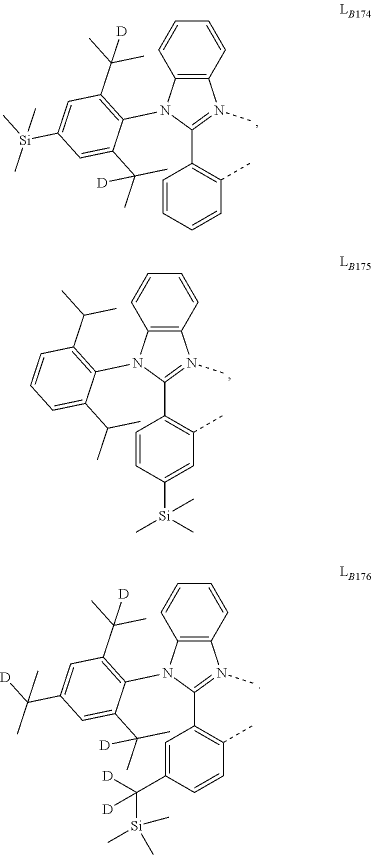

15. The compound of claim 1, wherein L_{A} can be selected from L_{Ai}, and L_{Aw}(Rk)(Rl)(Rm)(Rn)(T)(Z), wherein i is an integer from 1 to 143; and L_{B} can be selected from L_{Bk}, wherein k is an integer from 1 to 176, wherein w is an integer from 1 to 60, wherein:
when the compound has formula Ir(L_{Ai})(L_{Bk})₂, the compound is selected from the group consisting of Ir(L_{A1})(L_{B1})₂ to Ir(L_{A143})(L_{B176})₂;
when the compound has formula Ir(L_{Ai})₂(L_{Bk}), the compound is selected from the group consisting of Ir(L_{A1})₂(L_{B1}) to Ir(L_{A143})₂(L_{B176}),
when the compound has formula Ir(L_{Aw}(Rk)(Rl)(Rm)(Rn)(T)(Z))₂(L_{Bk}), the compound is selected from the group consisting of Ir(L_{A1}(R1)(R1)(R1)(R30)(T1)(Z1))₂(L_{B1}) to Ir(L_{A60}(R115)(R115)(R115)(R115)(T10)(Z6))₂(L_{B176}); and
when the compound has formula Ir(L_{Aw}(Rk)(Rl)(Rm)(Rn)(T)(Z))(L_{Bk})₂, the compound is selected from the group consisting of the compounds of Ir(L_{A1}(R1)(R1)(R1)(R30)(T1)(Z1))(L_{B1})₂ to Ir(L_{A60}(R115)(R115)(R115)(R115)(T10)(Z6))(L_{B176})₂.

16. The compound of claim 1, wherein the compound is selected from the group consisting of:

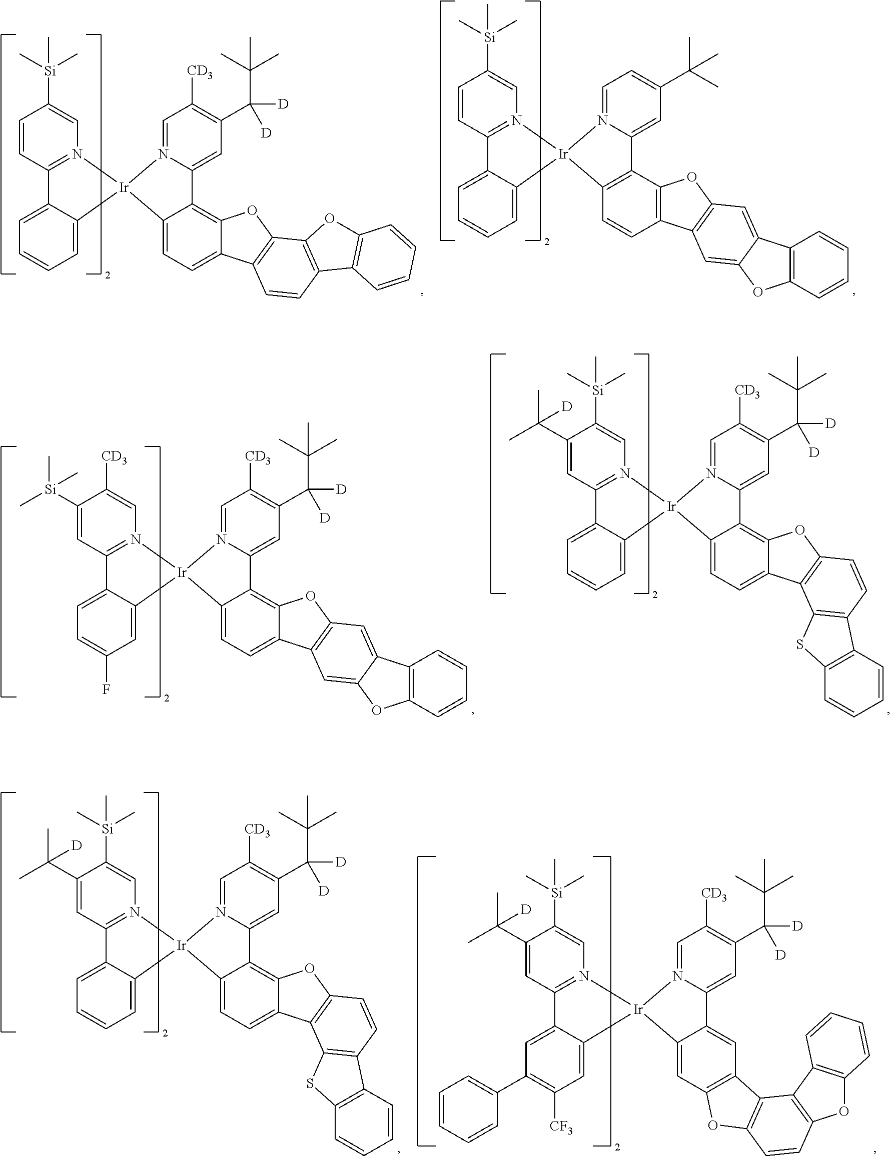

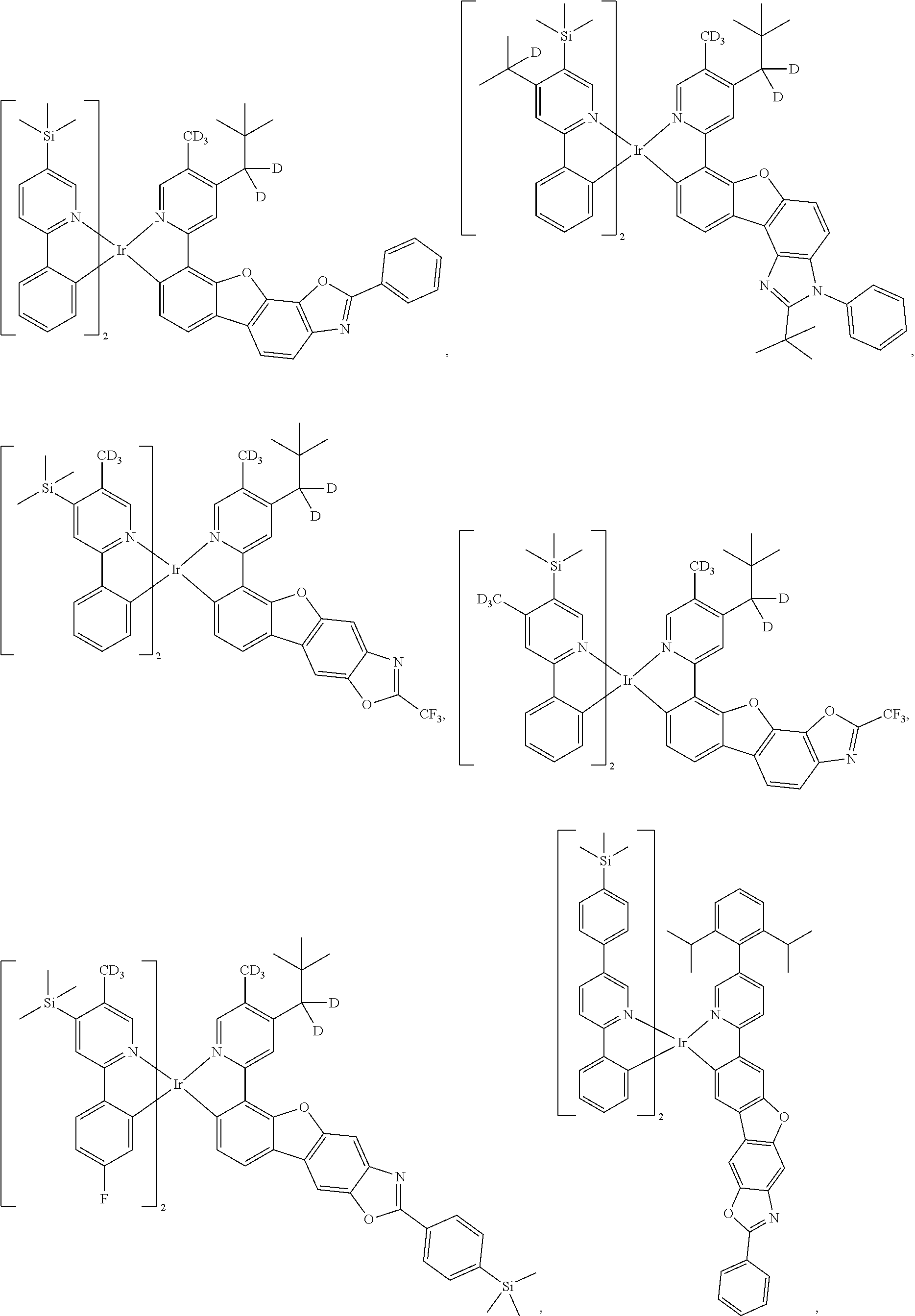

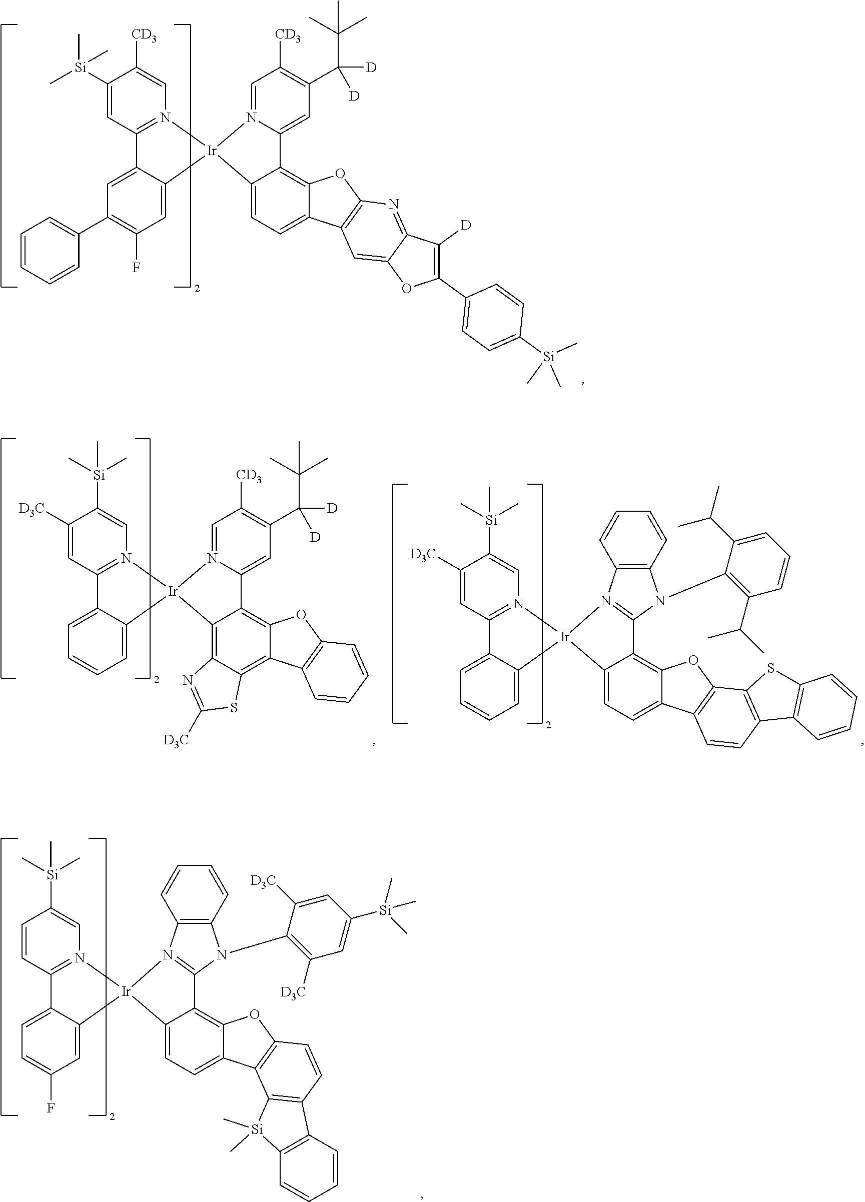

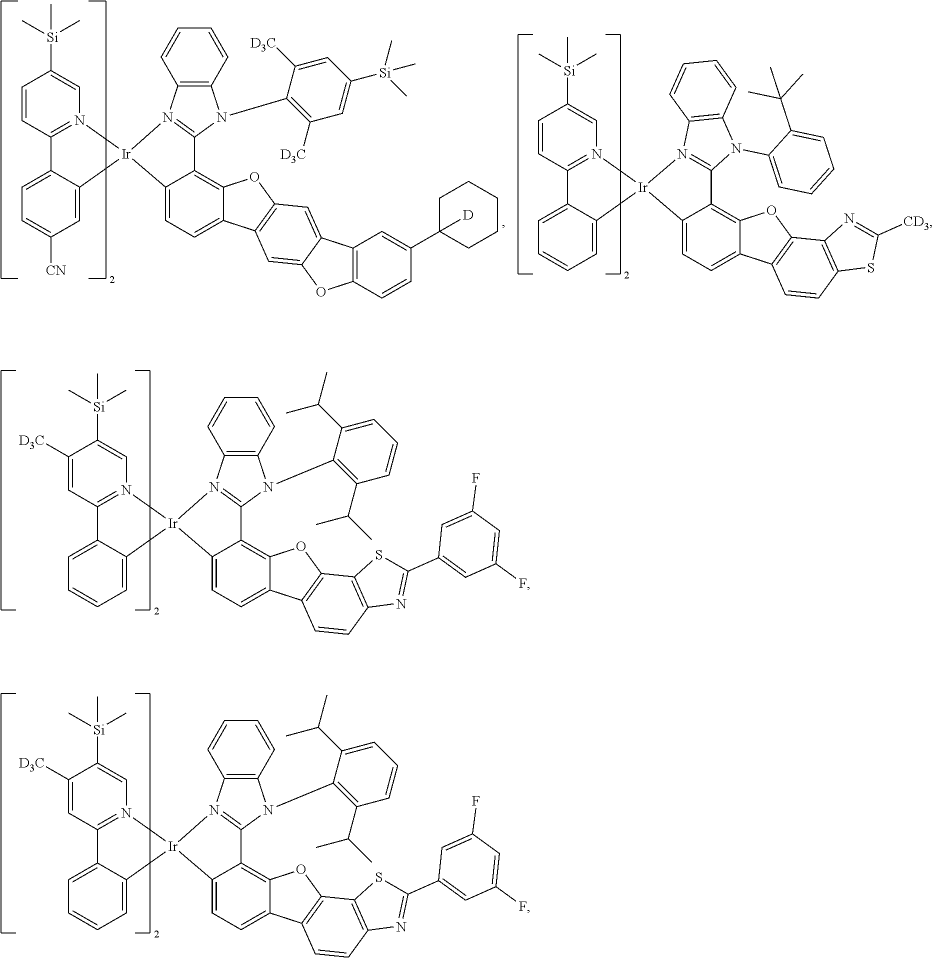

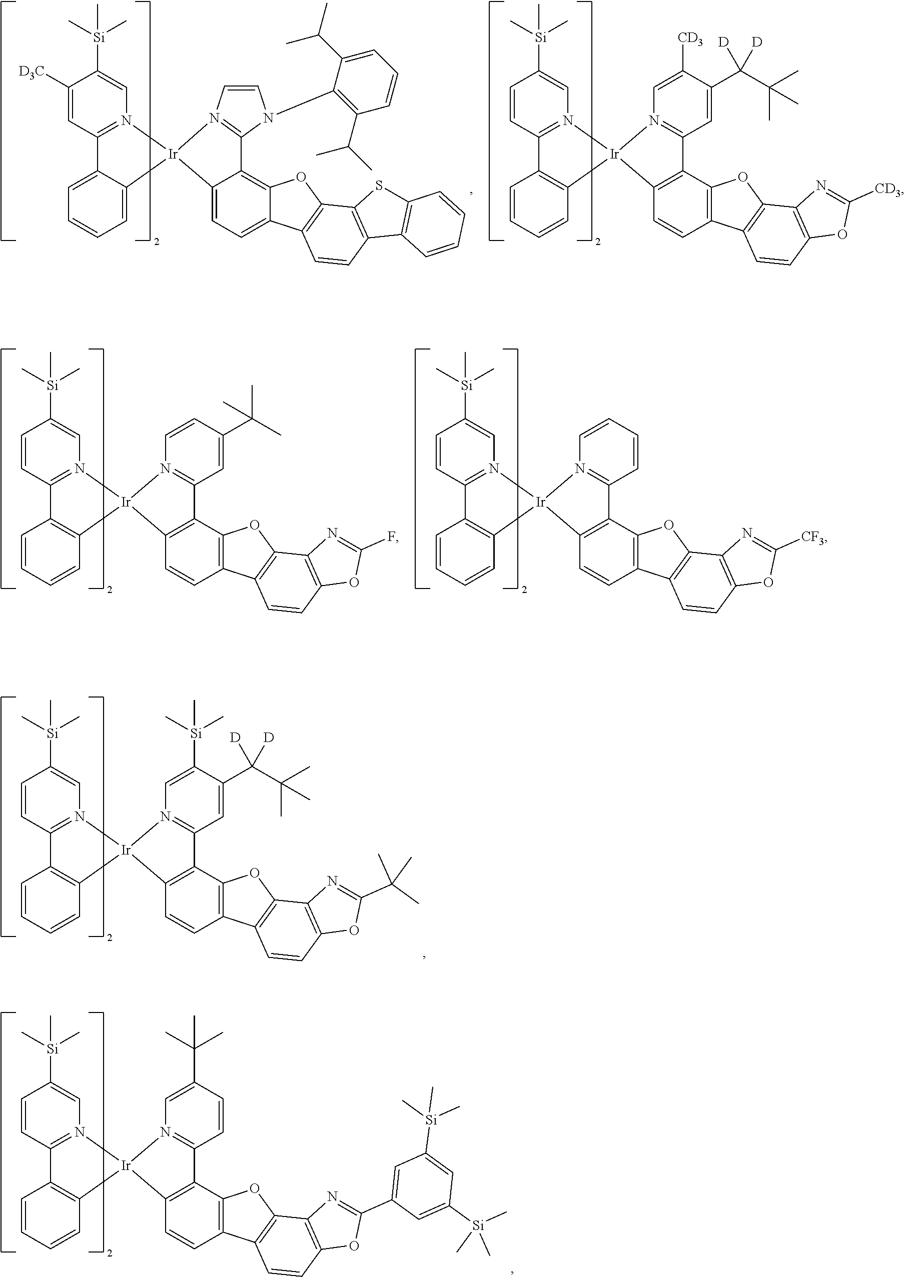

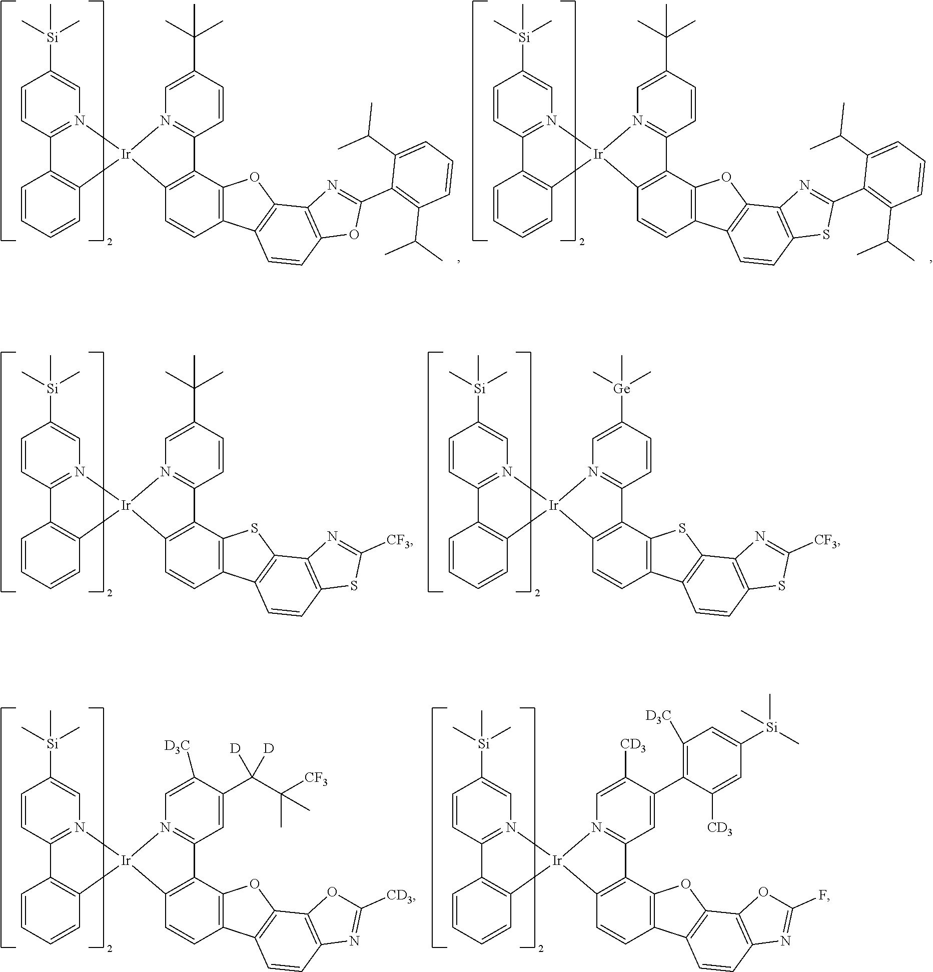

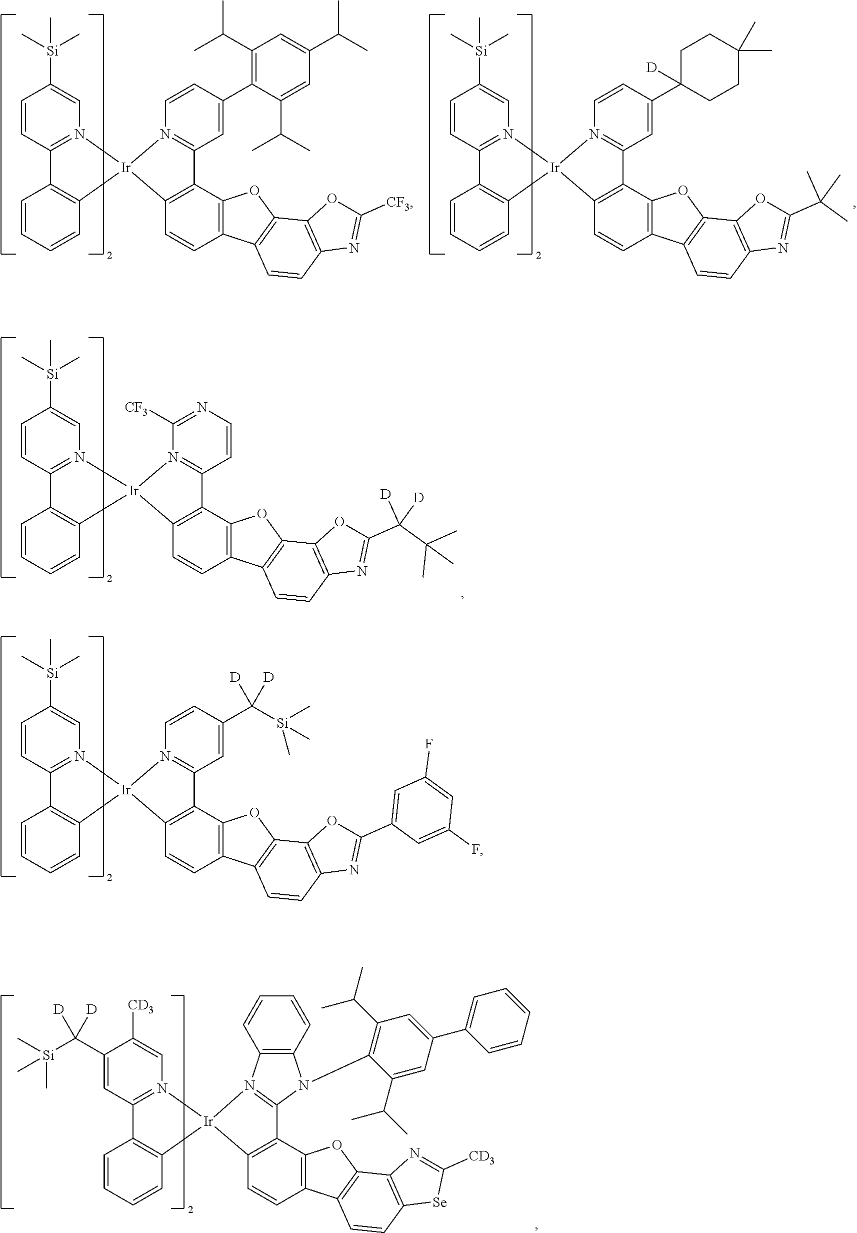

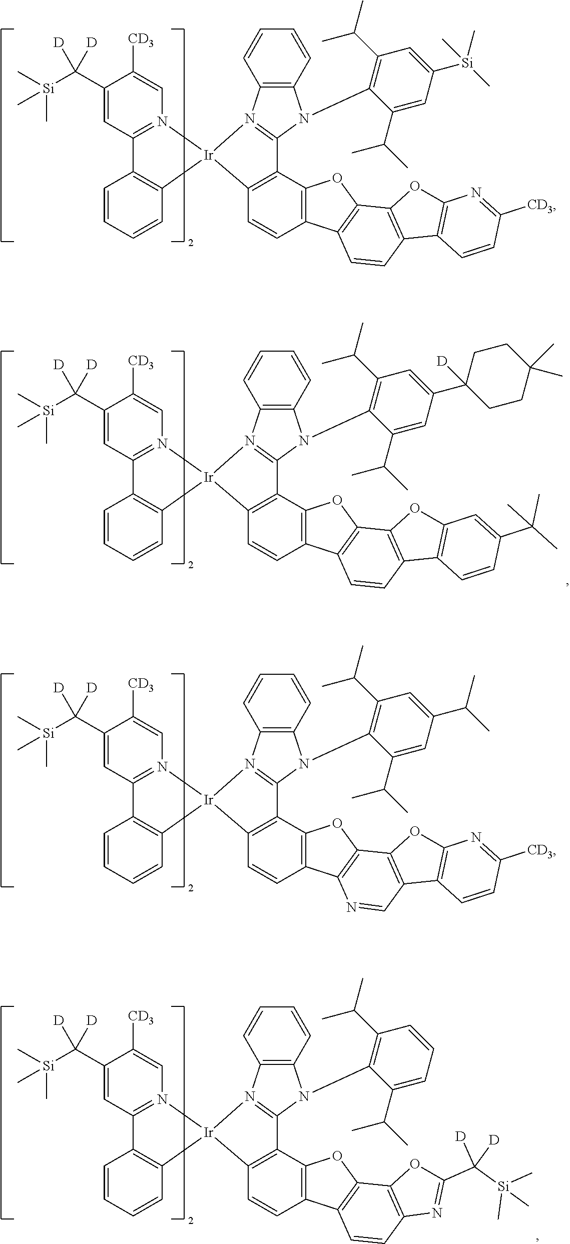

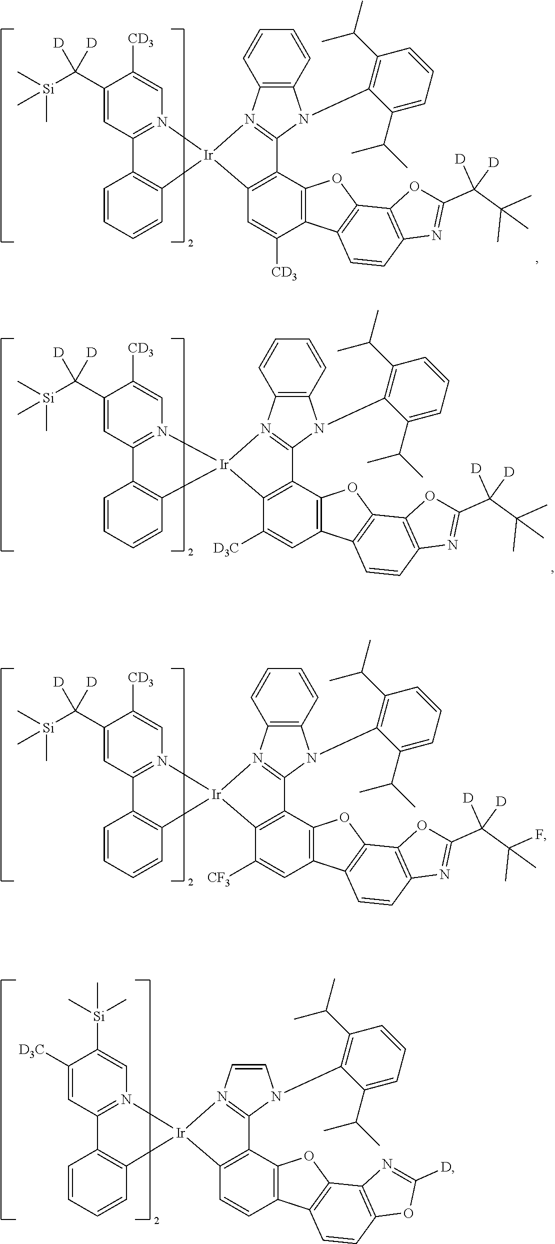

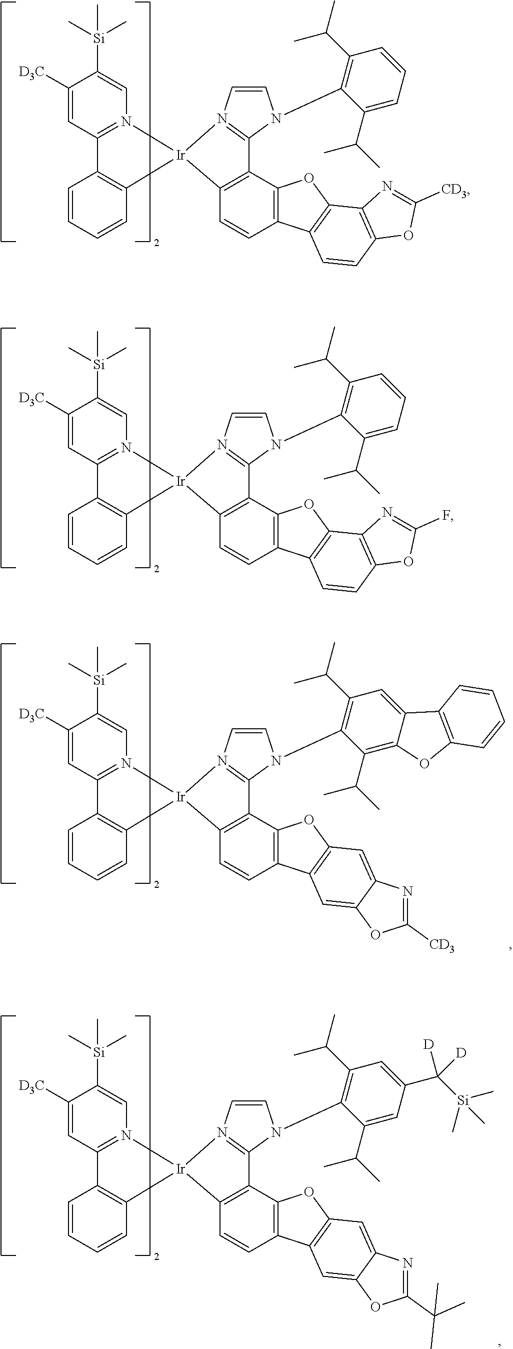

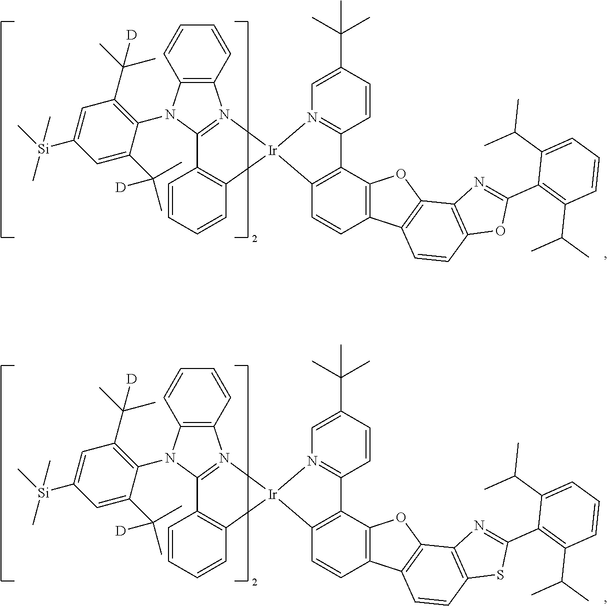

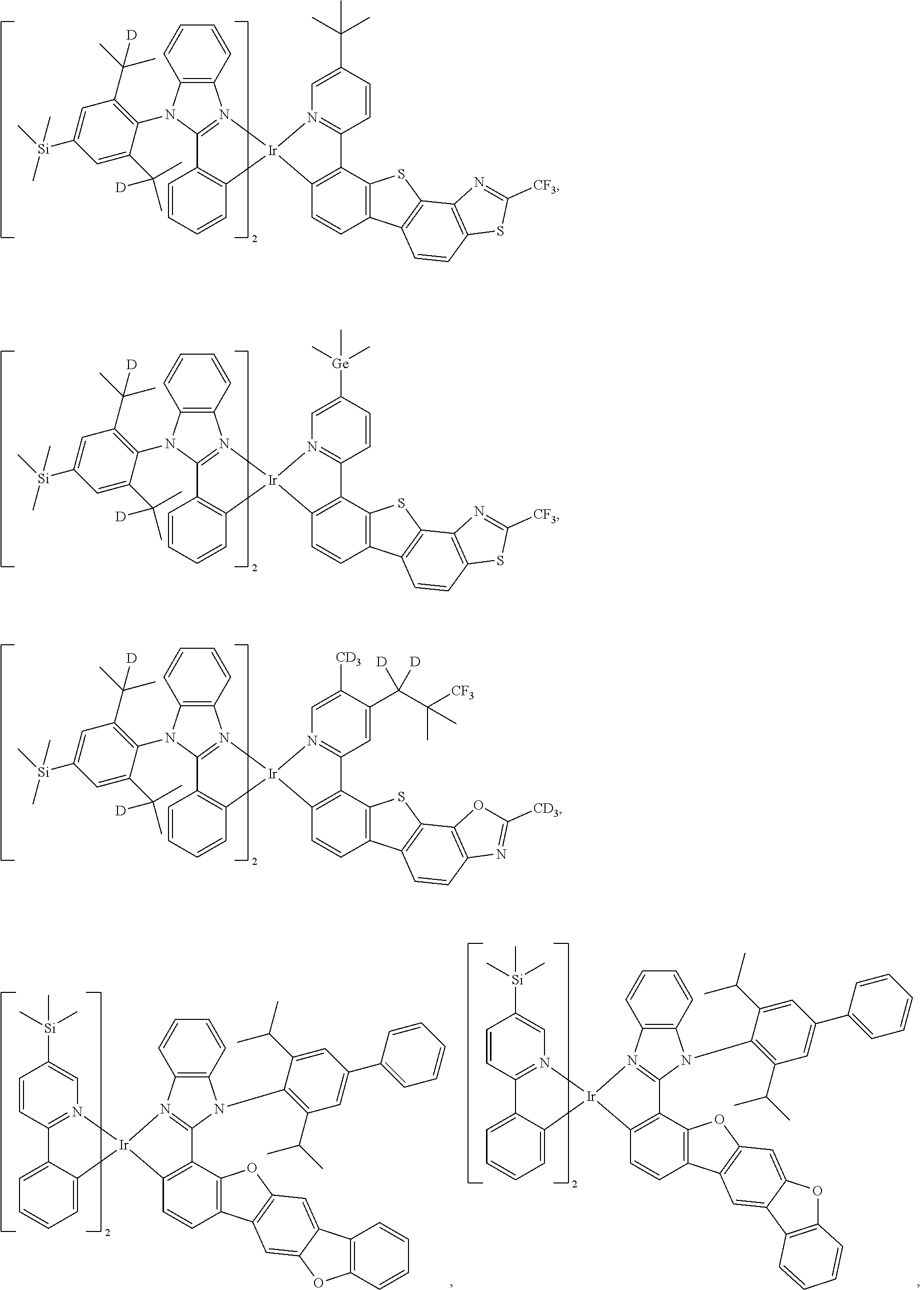

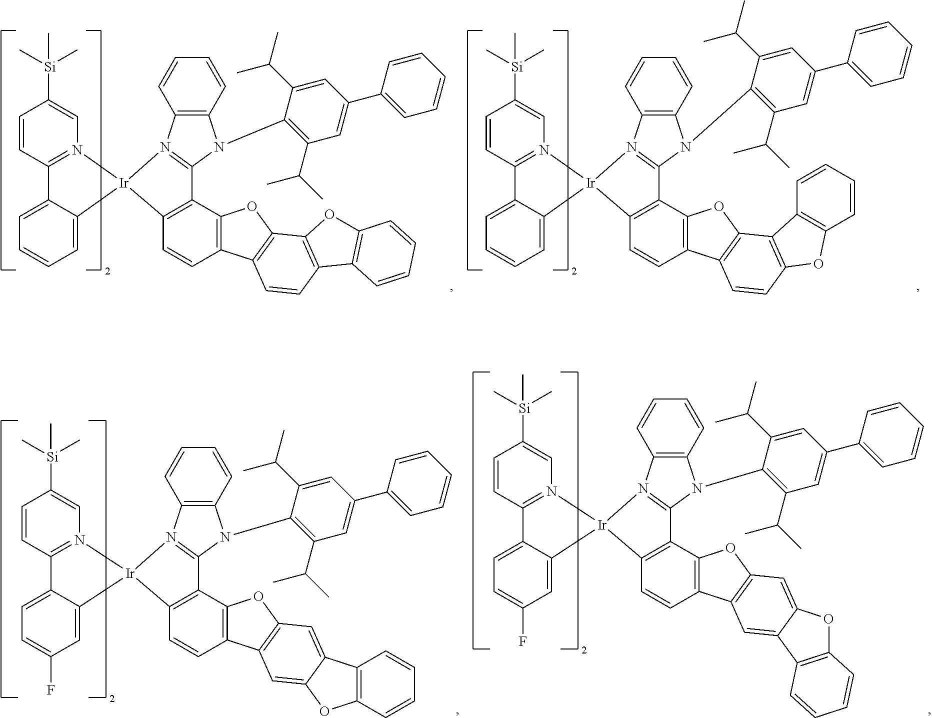

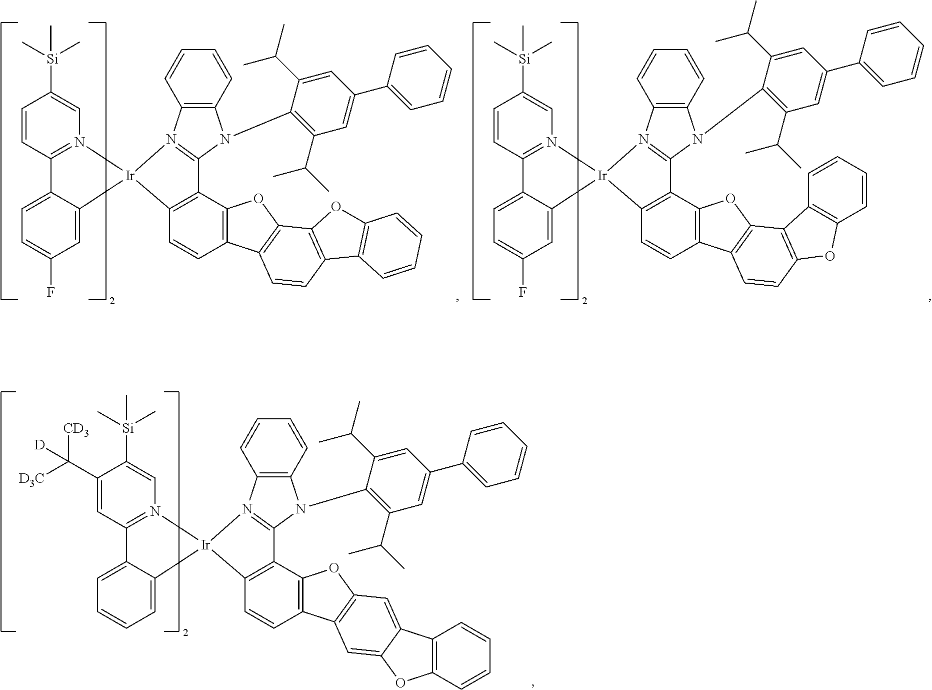

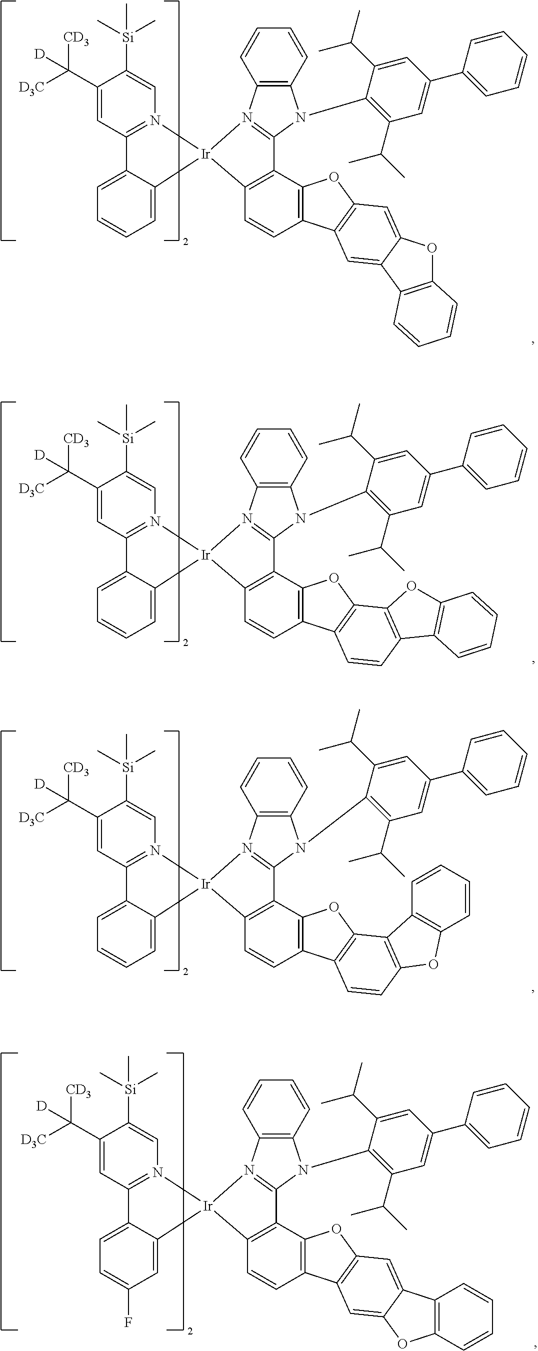

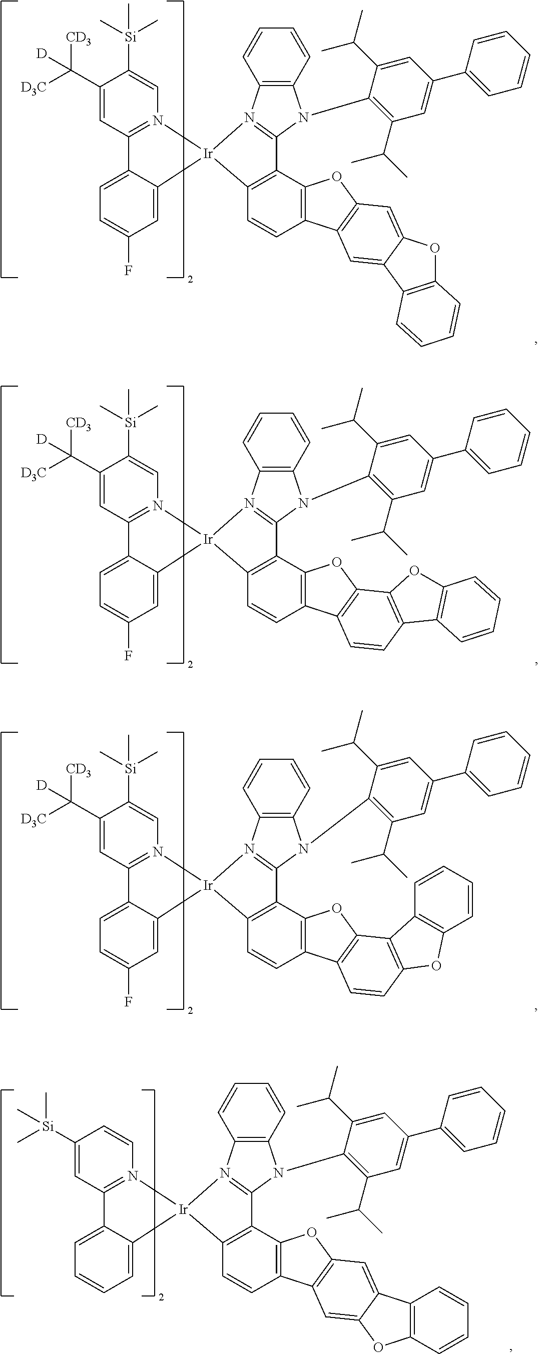

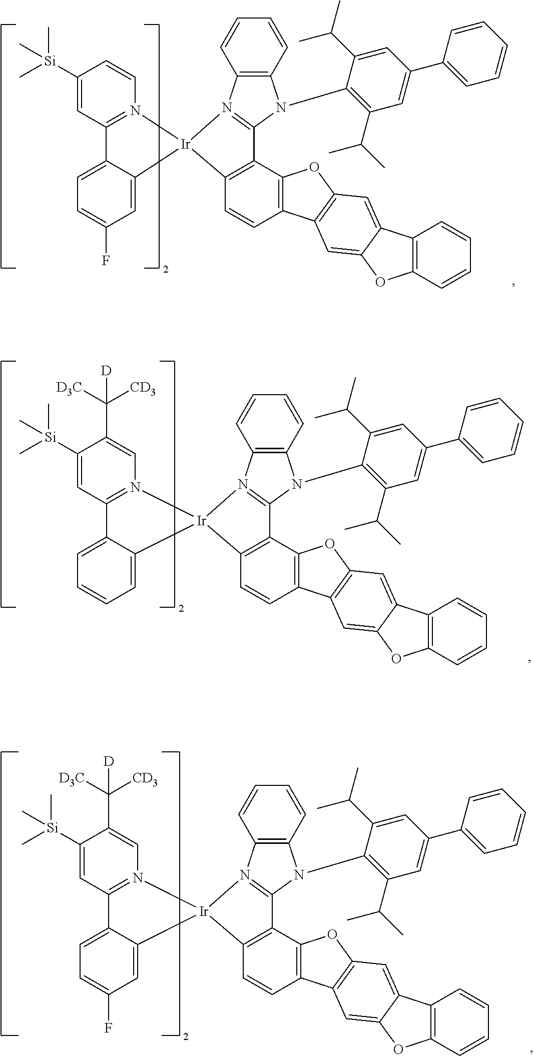

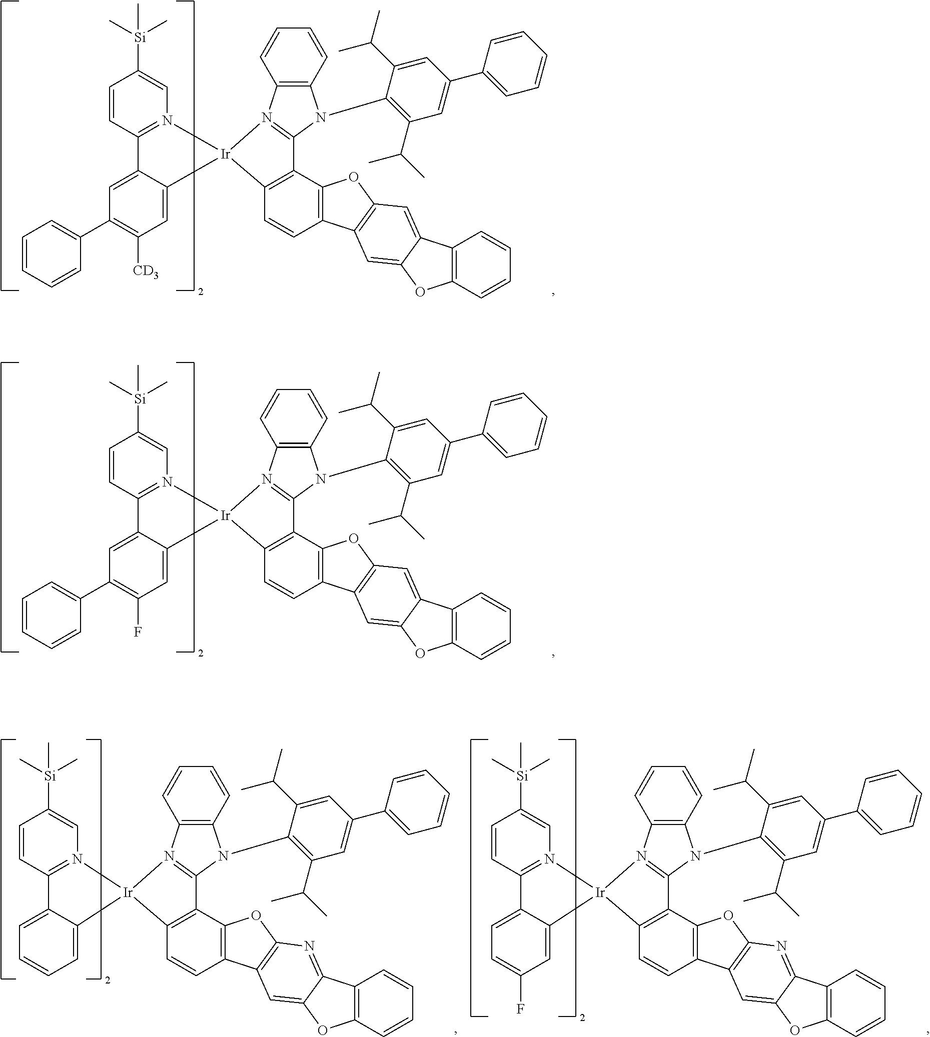

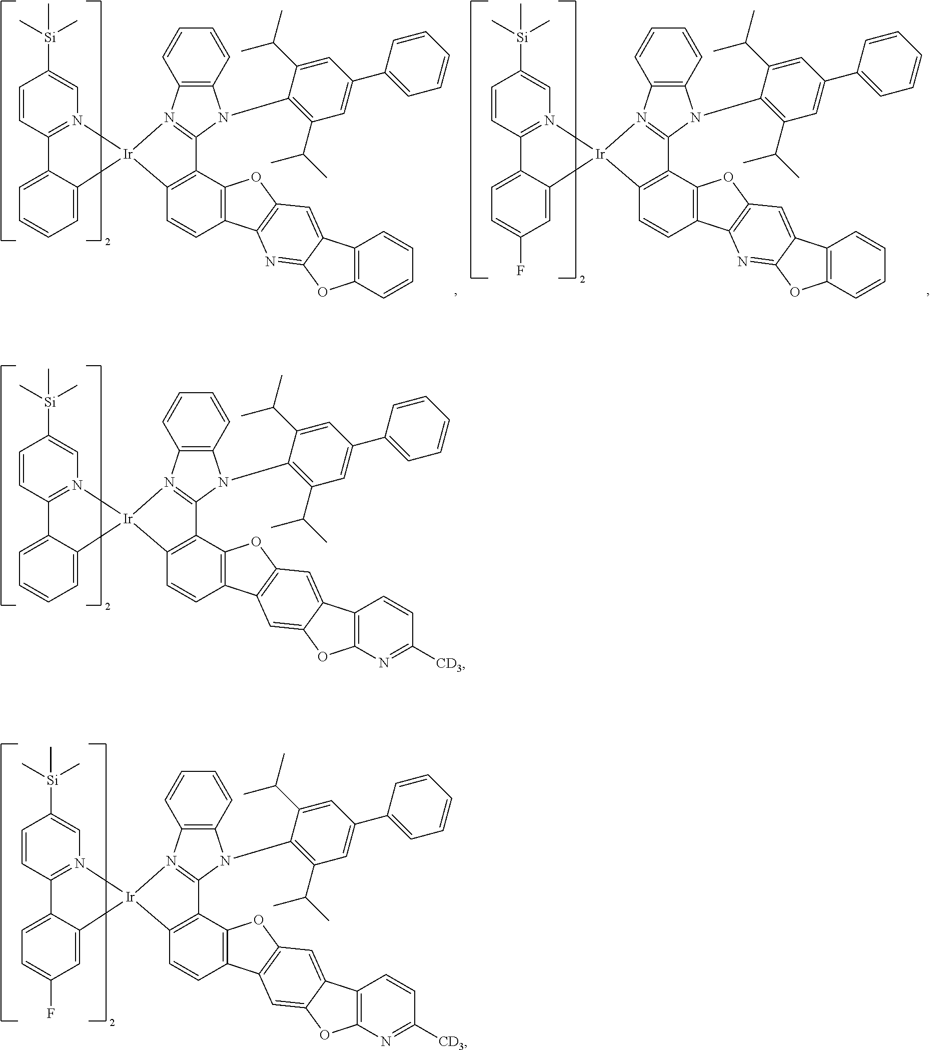

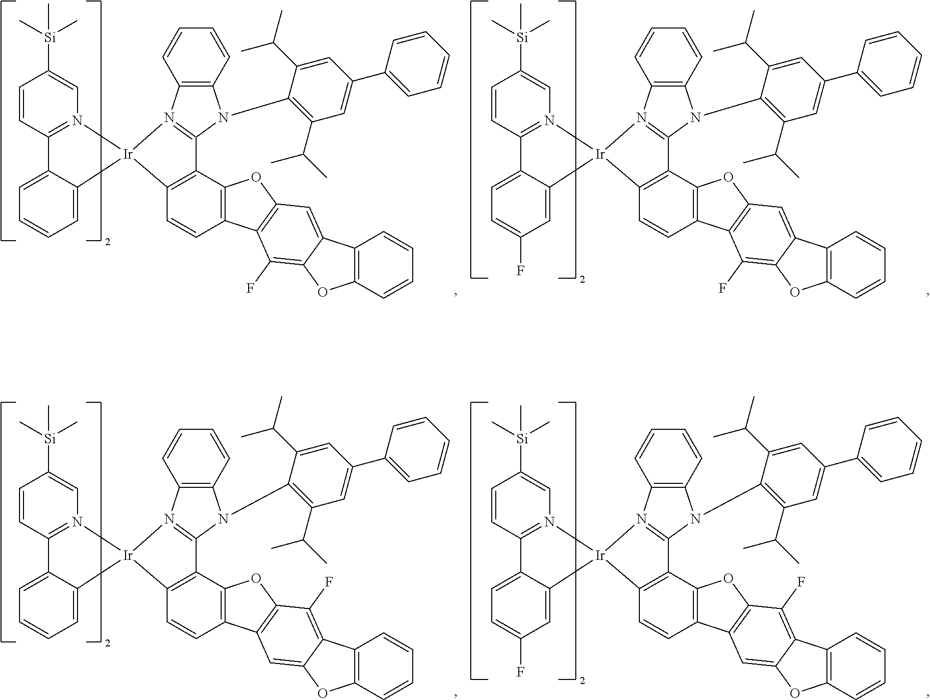

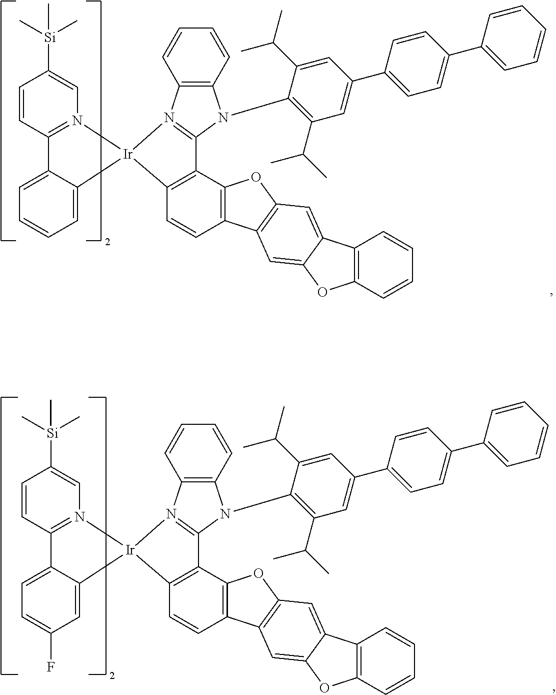

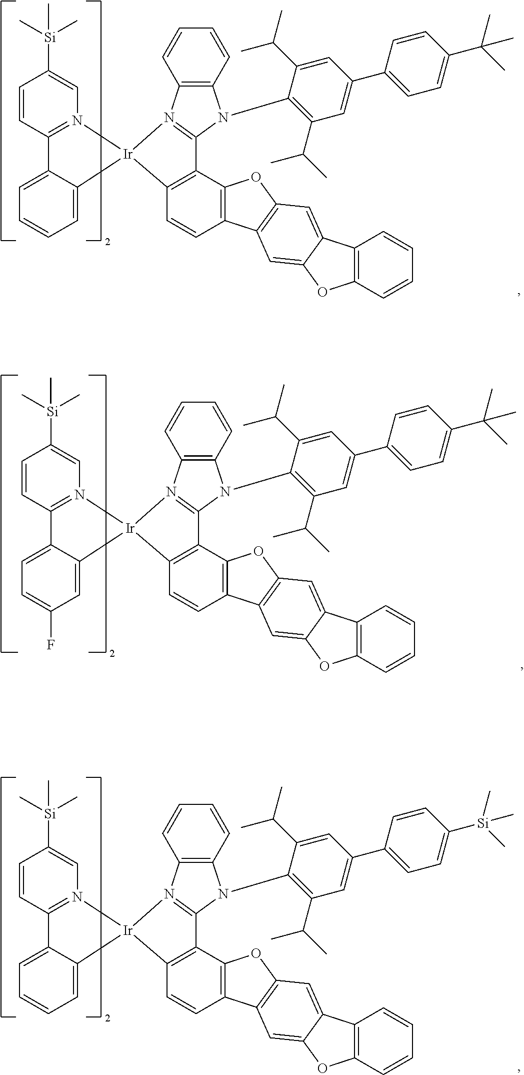

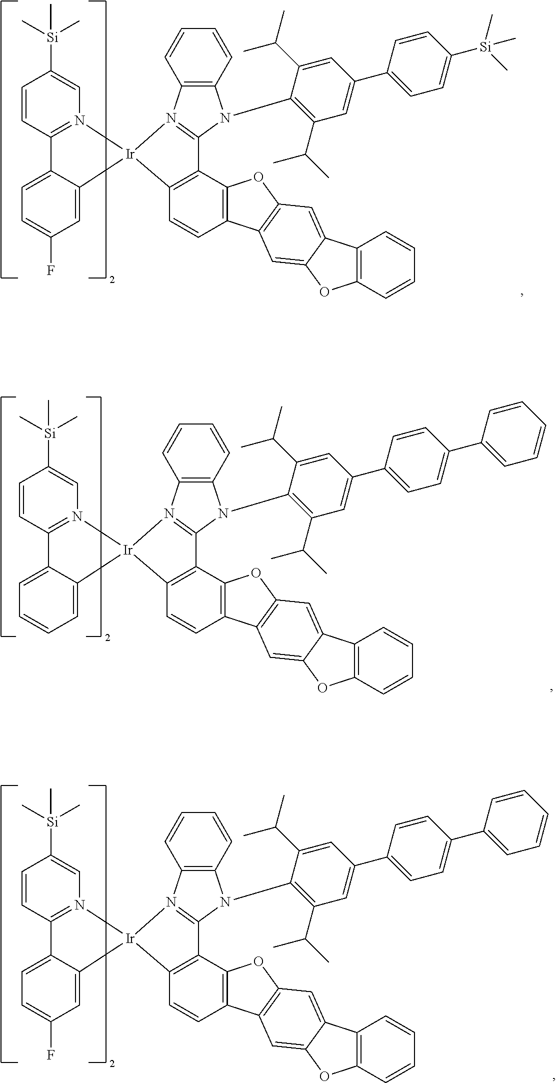

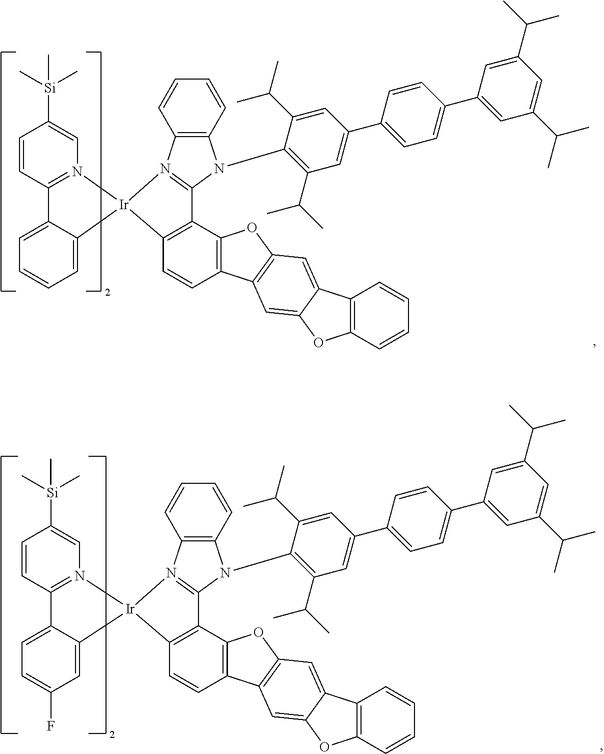

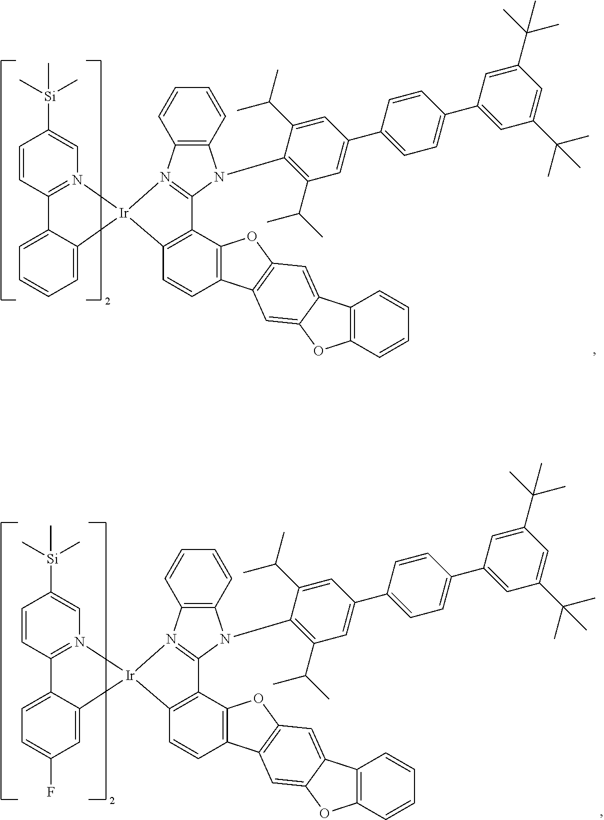

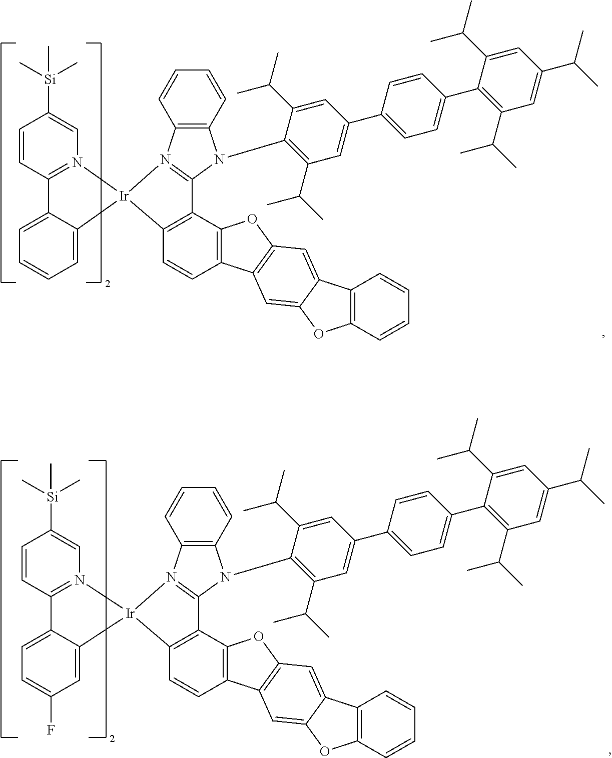

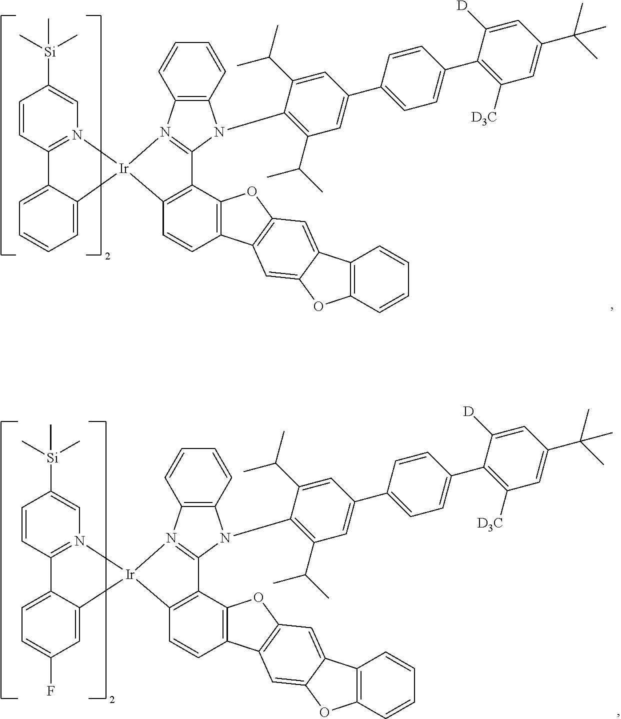

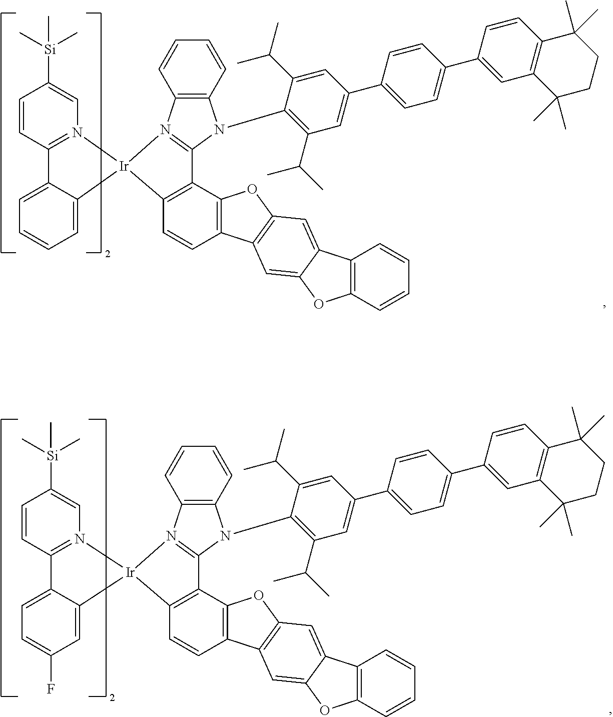

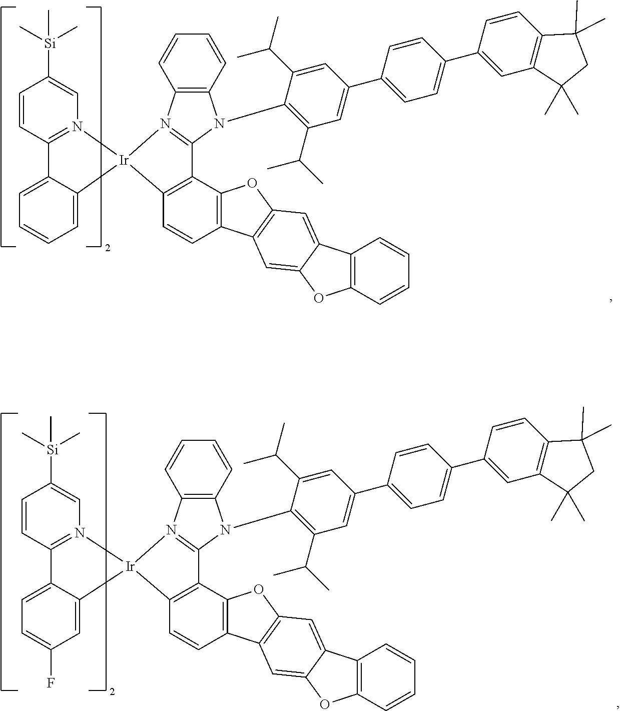

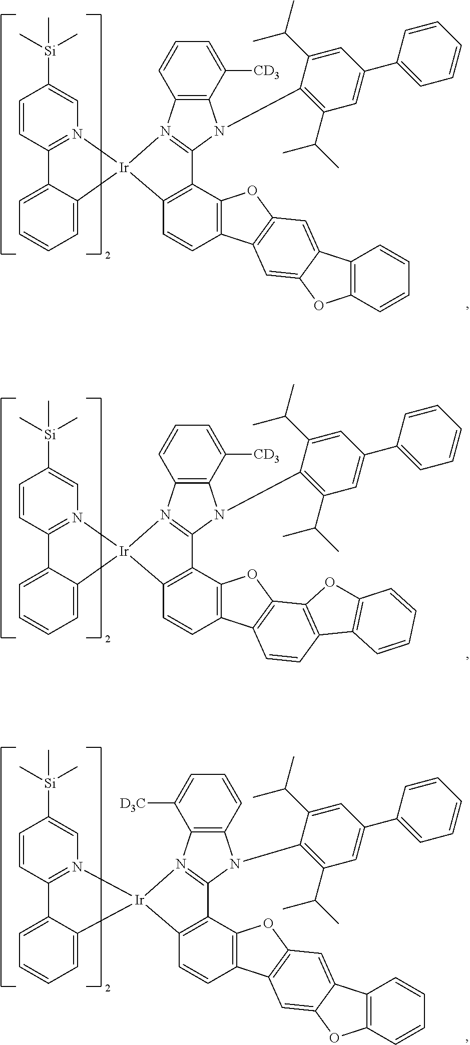

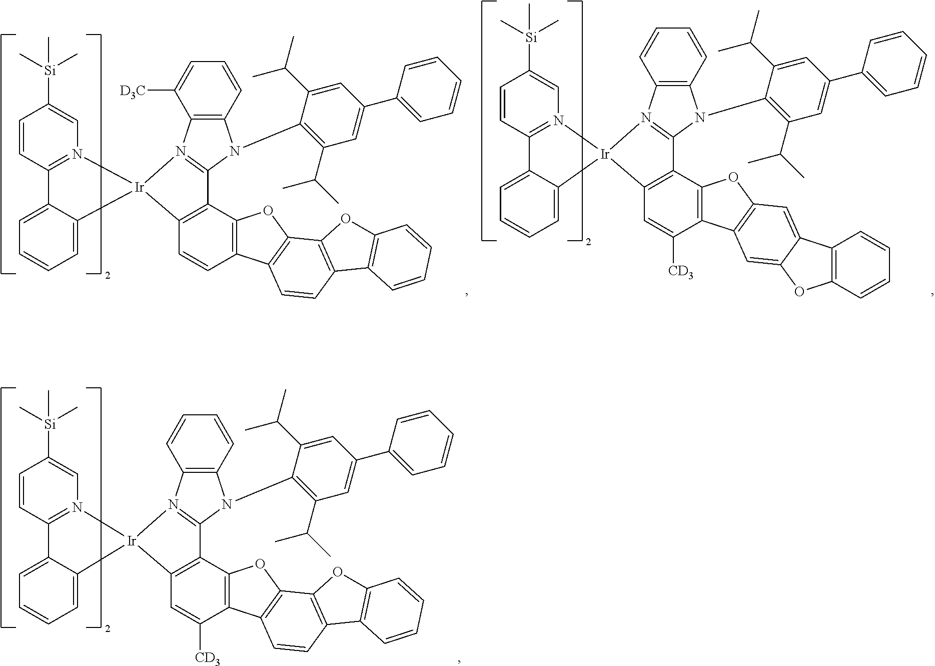

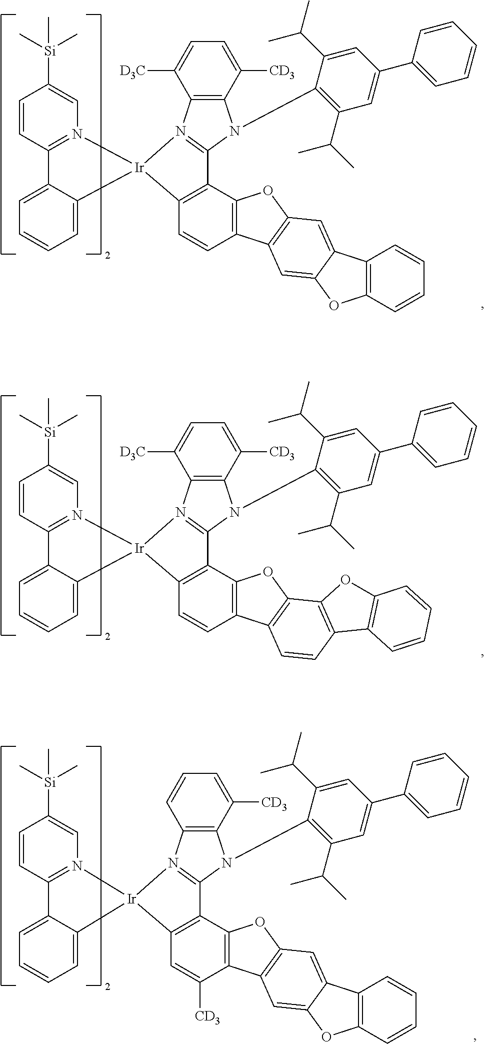

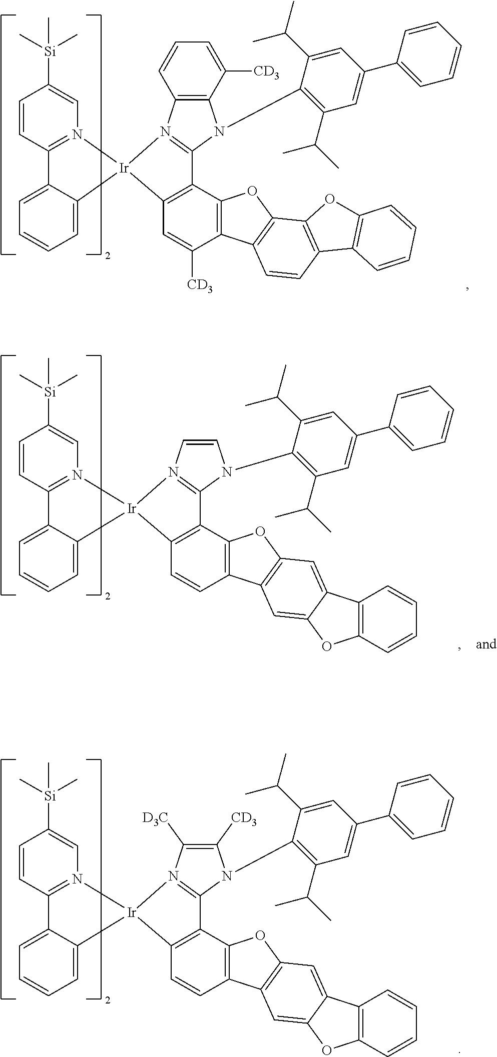

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein host comprises at least one chemical moiety selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

19. The OLED of claim 17, wherein the organic layer further comprises a host, wherein the host is selected from the group consisting of: 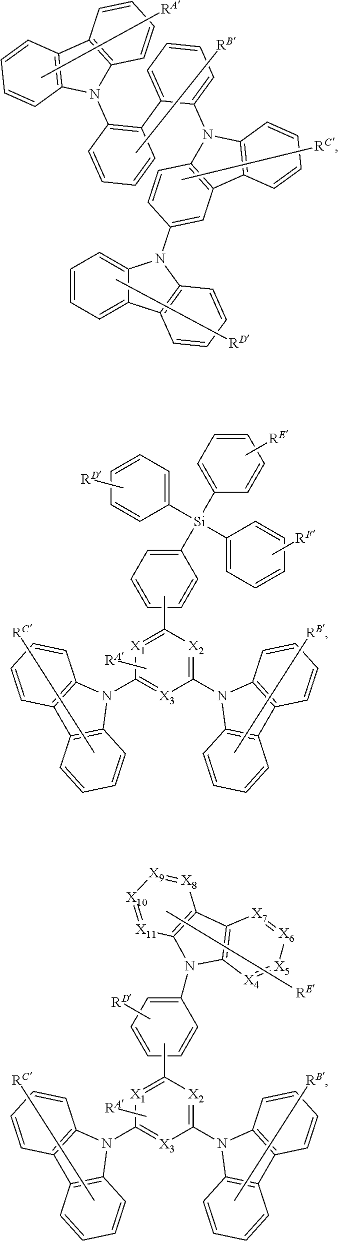 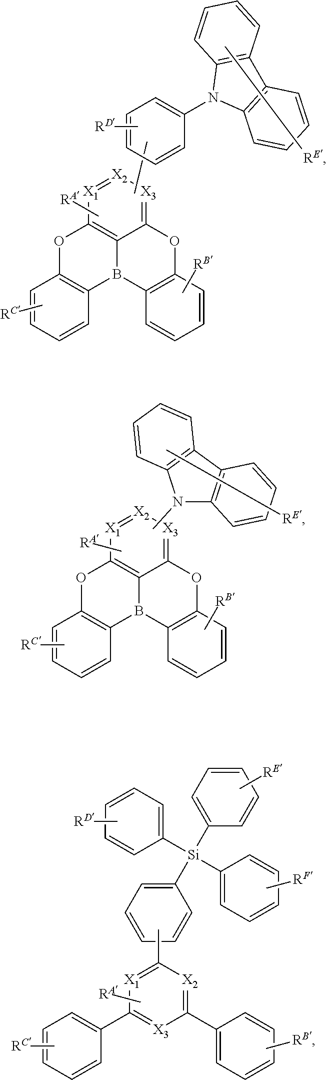 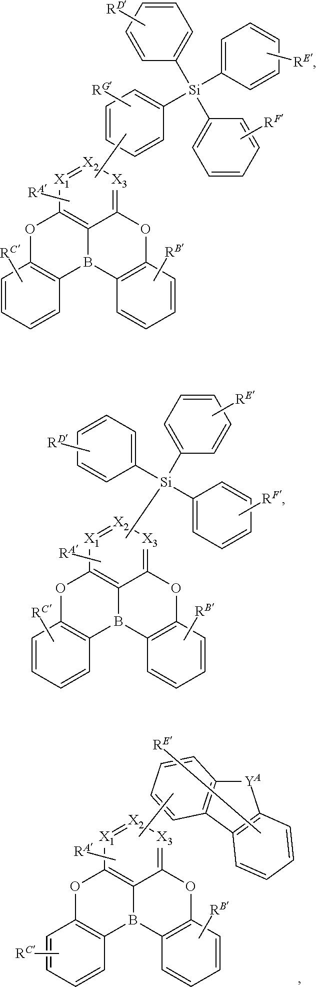 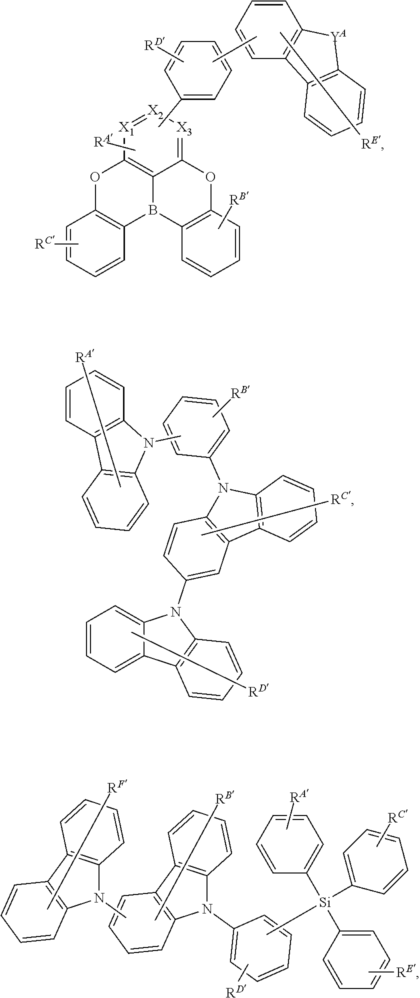 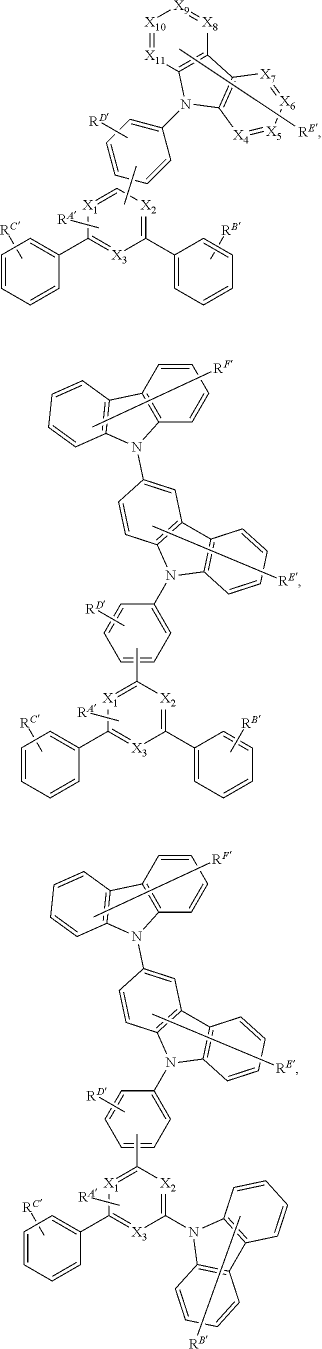 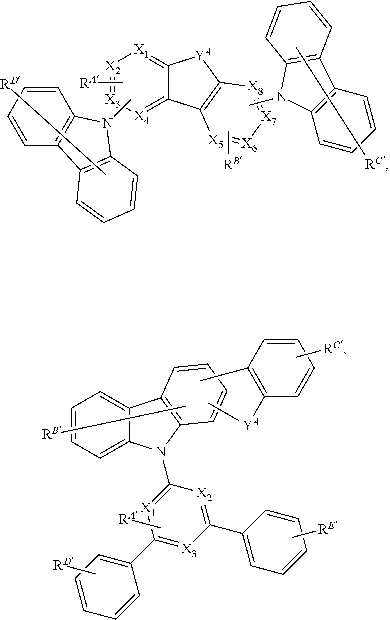 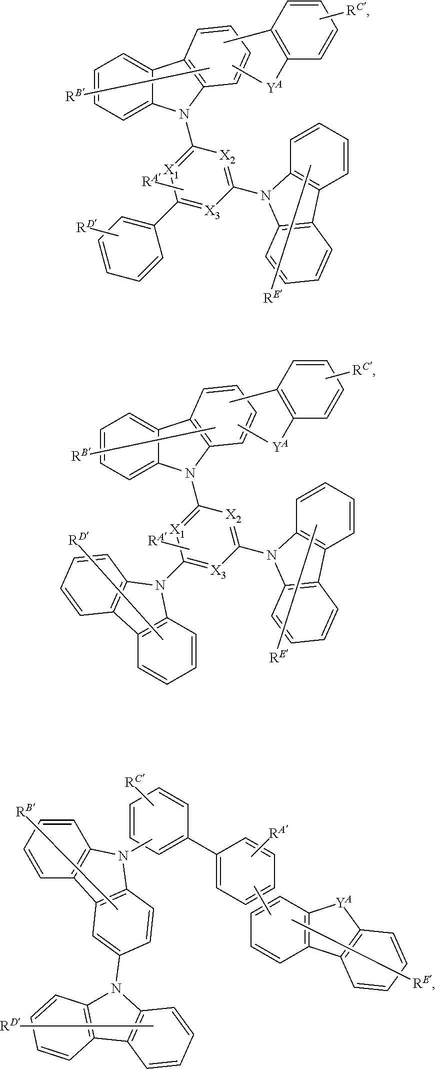 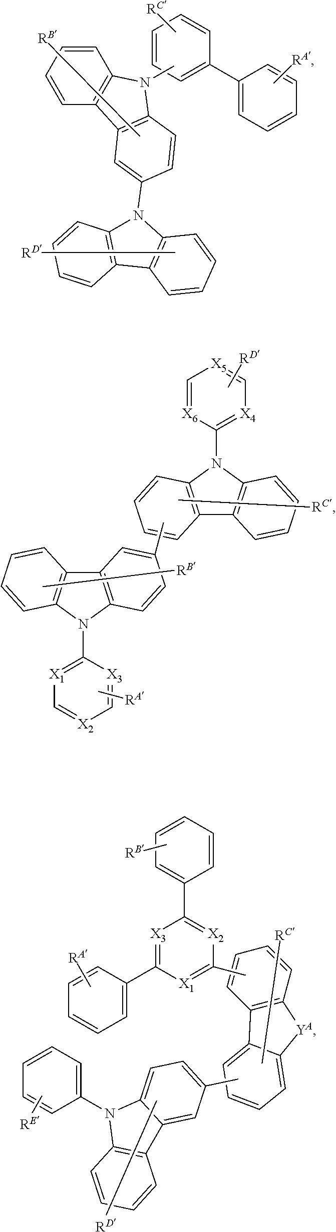 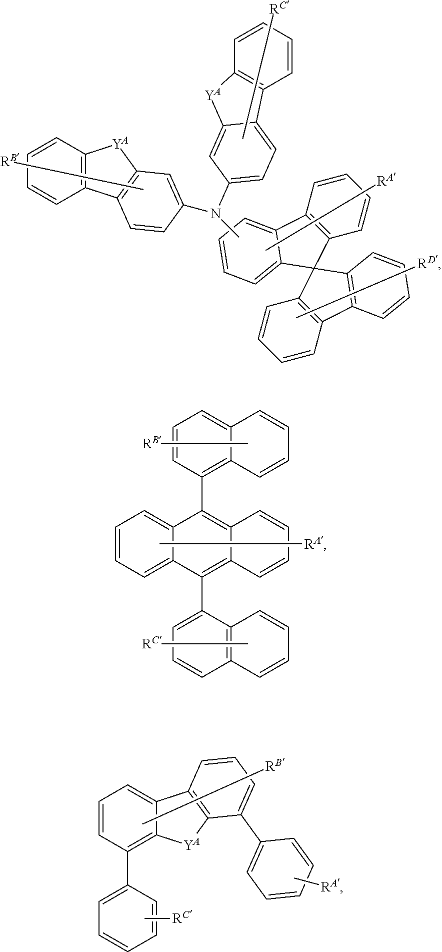 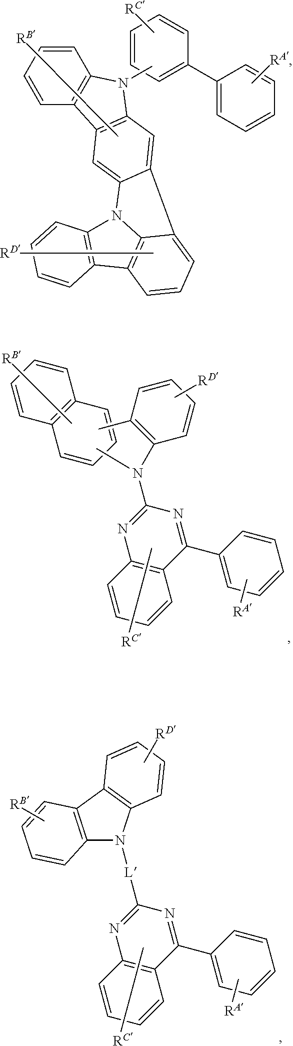 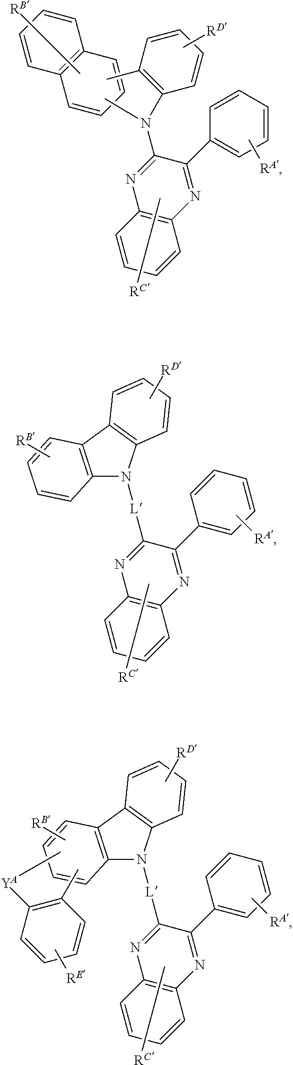 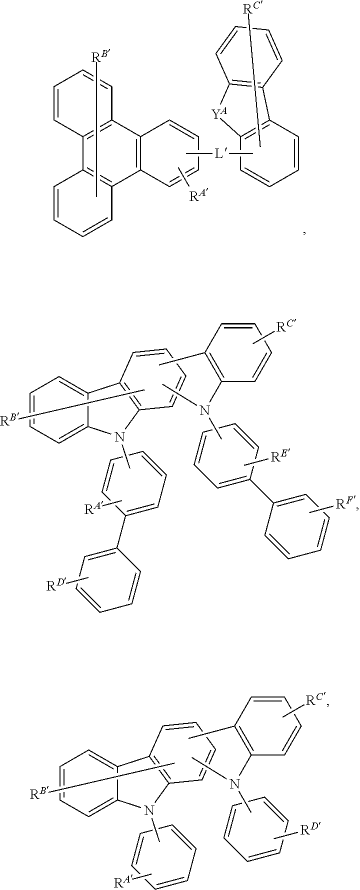 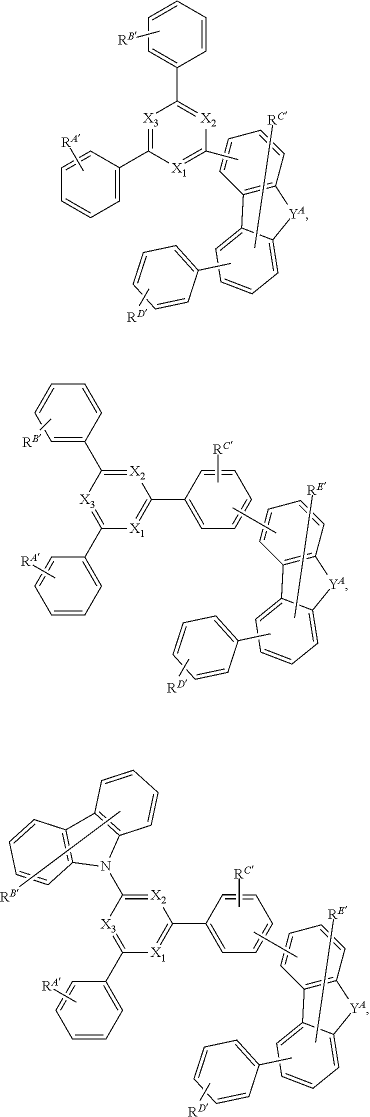 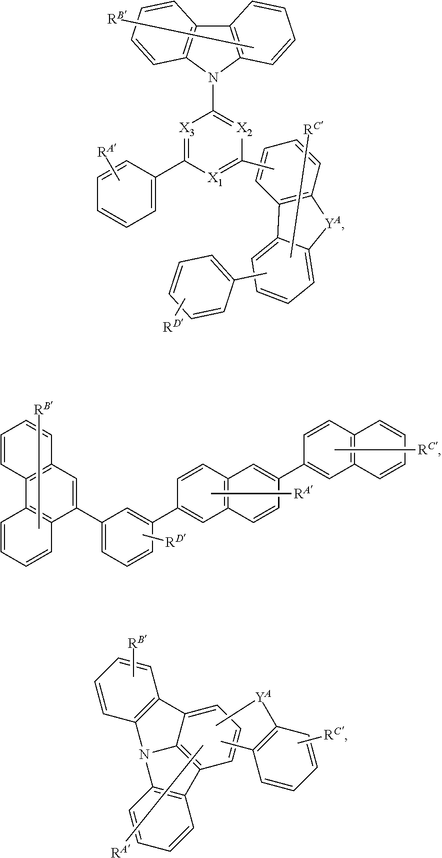 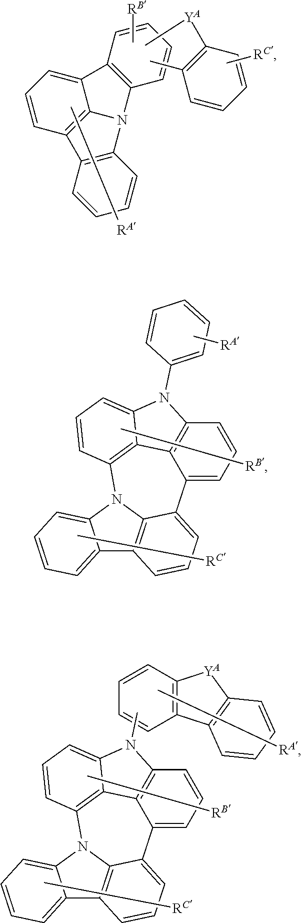 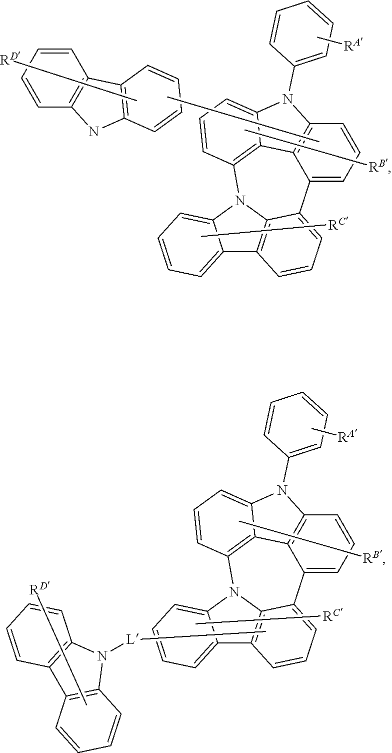 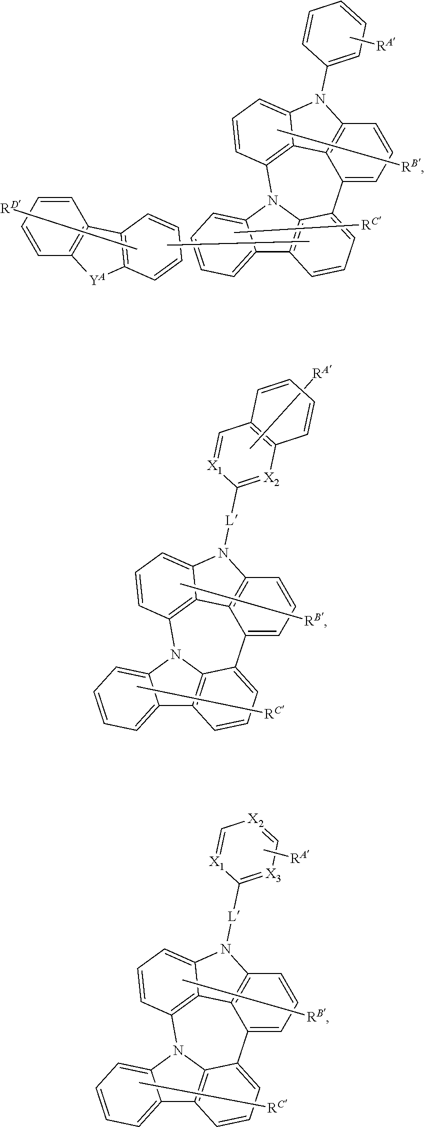 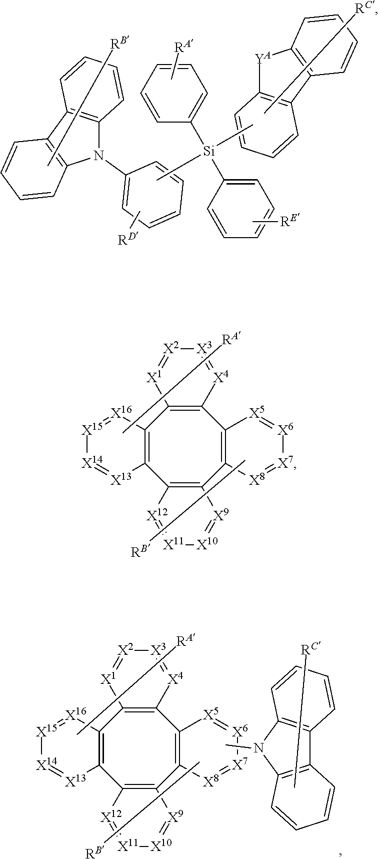 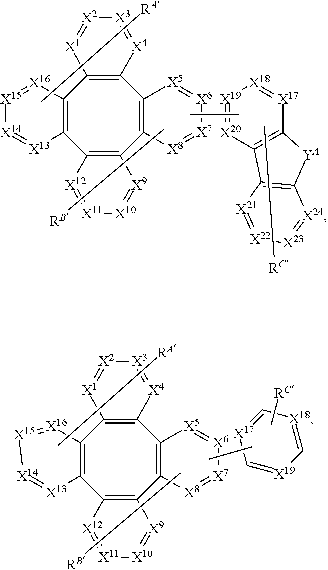 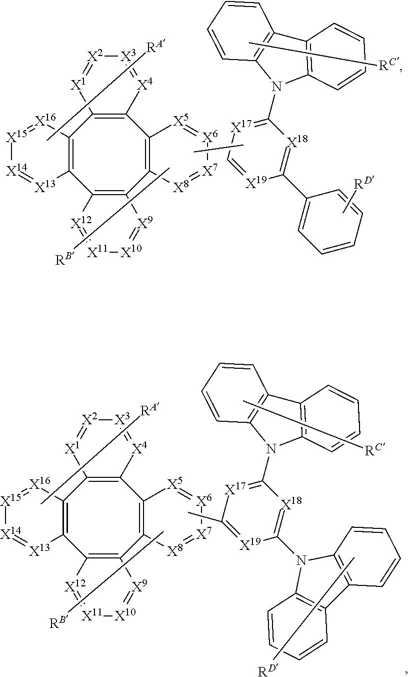 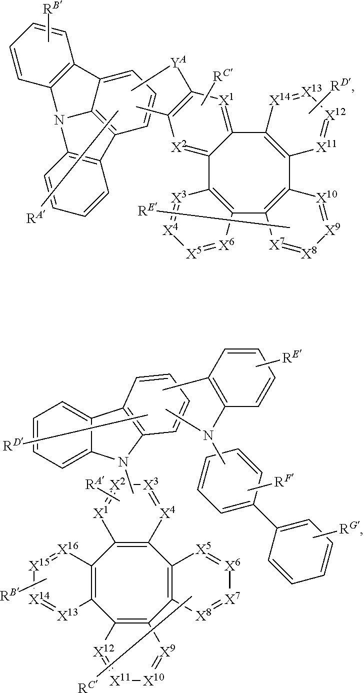 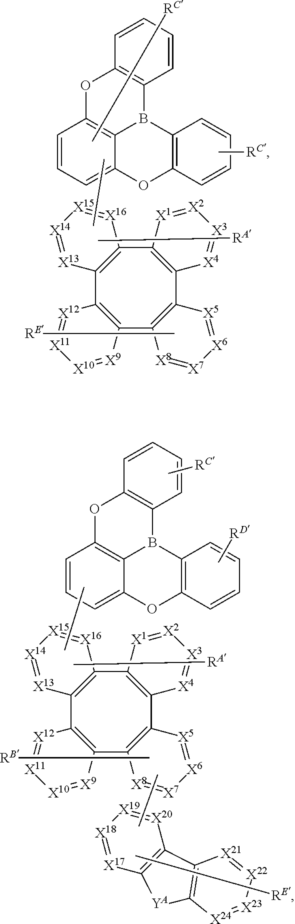 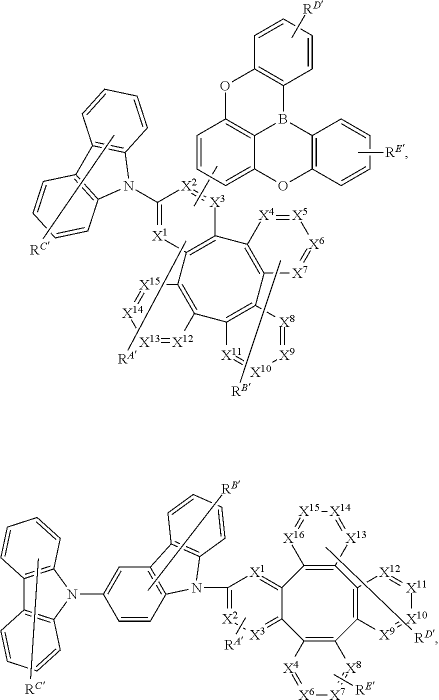 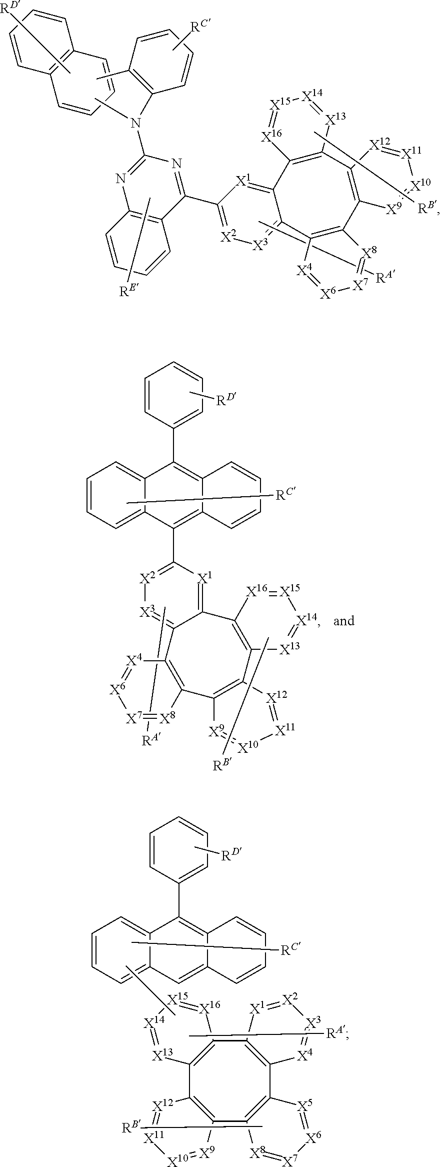
wherein:
each of X¹ to X²⁴ is independently C or N;
L′ is a direct bond or an organic linker;
each Y^{A} is independently selected from the group consisting of absent a bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof; wherein the organic layer further comprises a host,
two adjacent of R^{A′}, R^{B′}, R^{C′}, R^{D′}, R^{E′}, R^{F′}, and R^{G′} are optionally joined or fused to form a ring.

20. A consumer product comprising an organic light-emitting device (OLED) comprising:
an anode;
a cathode; and
an organic layer disposed between the anode and the cathode, wherein the organic layer comprises a compound according to claim 1.
